(19) United States
(12) Patent Application Publication
(10) Pub. No.: US 2024/0224798 A1
(43) Pub. Date: Jul. 4, 2024

(54) ORGANIC LIGHT EMITTING DIODE

(71) Applicant: LG DISPLAY CO., LTD., Seoul (KR)

(72) Inventors: Ji-Ae LEE, Paju-si (KR); Tae-Ryang HONG, Paju-si (KR)

(73) Assignee: LG DISPLAY CO., LTD., Seoul (KR)

(21) Appl. No.: 18/378,577

(22) Filed: Oct. 10, 2023

(30) Foreign Application Priority Data
Dec. 16, 2022 (KR) 10-2022-0176581

(51) Int. Cl. H10K 85/60; C09K 11/06

(52) U.S. Cl. CPC H10K 85/654; C09K 11/06; H10K 85/615; H10K 85/6572; H10K 85/6574; H10K 85/6576; H10K 2101/30

(57) ABSTRACT

The present disclosure relates to an organic light emitting diode where an emissive layer comprises a first compound fused with multiple aromatic and heteroaromatic rings and a second compound and an organic light emitting device comprising the diode. The first compound has a wide plate-like structure so that the first compound receives efficiently exciton energy from the second compound. The luminous efficiency, luminous lifespan and color purity of the organic light emitting diode and the organic light emitting device may be improved by introducing the first and second compounds into the emissive layer.

### CROSS-REFERENCE TO RELATED APPLICATION

This application claims the benefit of and the priority to Korean Patent Application No. 10-2022-0176581, filed in the Republic of Korea on Dec. 16, 2022, which is expressly incorporated hereby in its entirety into the present application.

### BACKGROUND

### Technical Field

The present disclosure relates to an organic light emitting diode, and more particularly to, an organic light emitting diode that may have beneficial luminous efficiency and luminous lifespan. The present disclosure also relates to an organic light emitting device comprising the diode.

### Description of the Related Art

A flat display device comprising an organic light emitting diode (OLED) has attracted attention as a display device that may replace a liquid crystal display device (LCD). The electrode configurations in the OLED may implement unidirectional or bidirectional images. Also, the OLED may be formed even on a flexible transparent substrate such as a plastic substrate so that a flexible or a foldable display device may be realized with ease using the OLED. In addition, the OLED may be driven at a lower voltage and the OLED has advantageous high color purity compared to the LCD.

Since fluorescent material uses only singlet excitons in the luminous process, the fluorescent material in the related art shows low luminous efficiency. On the contrary, phosphorescent material may show high luminous efficiency since it uses triplet exciton as well as singlet excitons in the luminous process. However, examples of phosphorescent material comprise metal complexes, which have a short luminous lifespan for commercial use. It may be necessary to develop a compound or an organic light emitting diode having improved luminous efficiency and luminous lifespan.

### SUMMARY

Accordingly, embodiments of the present disclosure are directed to an organic light emitting diode and an organic light emitting device that substantially obviate one or more of the problems due to the limitations and disadvantages of the related art.

An object of the present disclosure is to provide an organic light emitting diode having beneficial luminous efficiency and advantageous luminous lifespan, and an organic light emitting device comprising the diode.

Additional features and objects will be set forth in the description that follows, and in part will be apparent from the description, or may be learned by practice of the disclosed concepts provided herein. Other features and aspects of the disclosed concept may be realized and attained by the structure particularly pointed out in the written description, or derivable therefrom, and the claims hereof as well as the appended drawings.

To achieve these and other advantages and in accordance with objects of the disclosure, as embodied and broadly described, an organic light emitting diode comprises a first electrode; a second electrode facing the first electrode; and an emissive layer disposed between the first electrode and the second electrode, the emissive layer comprising at least one emitting material layer that comprises a first compound comprising a first organic compound represented by Chemical Formula 1, and a second compound comprising a second organic compound represented by Chemical Formula 4:

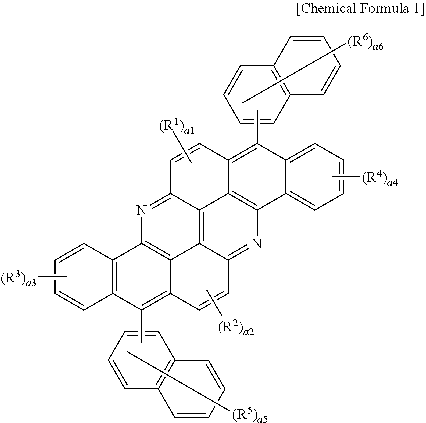

wherein, in the Chemical Formula 1,
each of R¹, R², R³, R⁴, R⁵, and R⁶ is independently a halogen atom, a cyano group, an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ heteroaryl group, an unsubstituted or substituted C₆-C₃₀ aryl amino group or an unsubstituted or substituted C₃-C₃₀ heteroaryl amino group, where each R¹ is identical to or different from each other when a1 is 2, each R² is identical to or different from each other when a2 is 2, each R³ is identical to or different from each other when a3 is 2, 3 or 4, each R⁴ is identical to or different from each other when a4 is 2, 3 or 4, each R⁵ is identical to or different from each other when a5 is 2, 3, 4, 5, 6 or 7 and each R⁶ is identical to or different from each other when a6 is 2, 3, 4, 5, 6 or 7;
each of a1 and a2 is independently 0, 1 or 2;
each of a3 and a4 is independently 0, 1, 2, 3 or 4; and
each of a5, and a6 is independently 0, 1, 2, 3, 4, 5, 6 or 7,

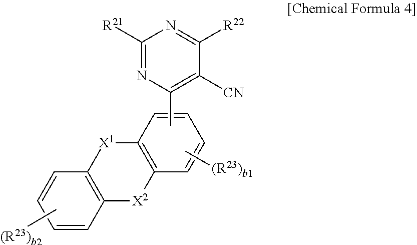

wherein, in the Chemical Formula 4,
one of X¹ and X² is a single bond and the other of X¹ and X² is NR^{A}, O or S;
each of R²¹, R²², R²³, R²⁴ and R^{A} is independently an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ heteroaryl group, an unsubstituted or substituted C₆-C₃₀ aryl amino group or an unsubstituted or substituted C₃-C₃₀ heteroaryl amino group, where each R²³ is identical to or different from each other when b1 is 2 or 3 and each R²⁴ is identical to or different from each other when b2 is 2, 3 or 4, or
optionally, two adjacent R²³ are linked together to form an unsubstituted or substituted C₆-C₂₀ aromatic ring or an unsubstituted or substituted C₃-C₂₀ heteroaromatic ring when b1 is 2 or 3 and/or two adjacent R²⁴ are linked together to form an unsubstituted or substituted C₆-C₂₀ aromatic ring or an unsubstituted or substituted C₃-C₂₀ heteroaromatic ring when b2 is 2, 3 or 4;
b1 is 0, 1, 2 or 3; and
b2 is 0, 1, 2, 3 or 4.

In some embodiments, the first compound may be represented by Chemical Formula 2A or Chemical Formula 2B:

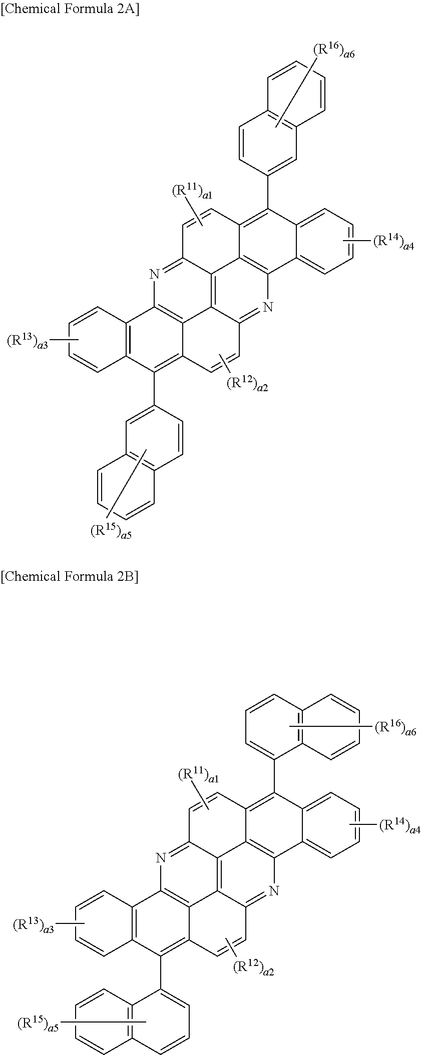

wherein, in the Chemical Formulae 2A and 2B,
each of a1, a2, a3, a4, a5, and a6 is as defined in Chemical Formula 1,
each of R¹¹, R¹², R¹³, R¹⁴, R¹⁵, and R¹⁶ is independently an unsubstituted or a substituted C₁-C₂₀ alkyl group or an unsubstituted or C₁-C₁₀ alkyl-substituted C₆-C₃₀ aryl group, where each R¹¹ is identical to or different from each other when a1 is 2, each R¹² is identical to or different from each other when a2 is 2, each R¹³ is identical to or different from each other when a3 is 2, 3 or 4, each R¹⁴ is identical to or different from each other when a4 is 2, 3 or 4, each R¹⁵ is identical to or different from each other when a5 is 2, 3, 4, 5, 6 or 7 and each R¹⁶ is identical to or different from each other when a6 is 2, 3, 4, 5, 6 or 7.

In some embodiments, each of a1 and a2 may be 0, each of a3, a4, a5, and a6 may be independently 0 or 1, and each of R³, R⁴, R⁵, and R⁶ may be independently an unsubstituted or a substituted C₁-C₁₀ alkyl group or an unsubstituted or C₁-C₁₀ alkyl-substituted C₆-C₃₀ aryl group.

In some embodiments, each of a1 and a2 may be 0, each of R³ and R⁴ may be independently an unsubstituted or C₁-C₁₀ alkyl-substituted C₆-C₃₀ aryl group, each of a3 and a4 may be independently 0 or 1, each of R⁵ and R⁶ may be independently an unsubstituted or a substituted C₁-C₁₀ alkyl group, and each of a5 and a6 may be independently 0 or 1.

In some embodiments, the first organic compound may include at least one of the compounds in Chemical Formula 3.

In some embodiments, the second compound may comprise an organic compound represented by Chemical Formula 5:

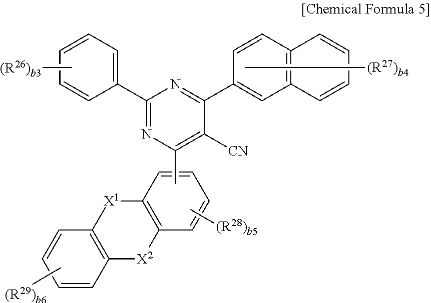

wherein, in the Chemical Formula 5,
each of X1 and X2 is as defined in Chemical Formula 4;
b3 may be 0, 1, 2, 3, 4 or 5;
b4 may be 0, 1, 2, 3, 4, 5, 6 or 7;
b5 may be 0, 1, 2 or 3;
b6 may be 0, 1, 2, 3 or 4;
each of R²⁶, R²⁷, R²⁸, and R²⁹ is independently an unsubstituted or substituted C₆-C₃₀ aryl group or an unsubstituted or substituted C₃-C₃₀ heteroaryl group, where each R²⁶ is identical to or different from each other when b3 is 2, 3, 4 or 5, each R²⁷ is identical to or different from each other when b4 is 2, 3, 4, 5, 6 or 7, each R²⁸ is identical to or different from each other when b5 is 2 or 3 and each R²⁹ is identical to or different from each other when b6 is 2, 3 or 4, or
optionally, two adjacent R²⁶ are linked together to form a heteroaromatic ring represented by Chemical Formula 6 when b3 is 2, 3, 4 or 5, two adjacent R²⁷ are linked together to form the heteroaromatic ring represented by Chemical Formula 6 when b4 is 2, 3, 4, 5, 6 or 7, two adjacent R²⁸ are linked together to form the heteroaromatic ring represented by Chemical Formula 6 when b5 is 2 or 3 and/or two adjacent R²⁹ are linked together to form the heteroaromatic ring represented by Chemical Formula 6 when b6 is 2, 3 or 4; and
the dotted line indicates a portion optionally fused to the ring represented by Chemical Formula 6,

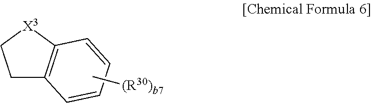

wherein, in the Chemical Formula 6,
X³ is NR^{B}, O or S;
R^{B} is hydrogen, an unsubstituted or substituted C₁-C₂₀ alkyl group, an unsubstituted or substituted C₆-C₃₀ aryl group or an unsubstituted or substituted C₃-C₃₀ heteroaryl group;
R³⁰ is an unsubstituted or substituted C₁-C₂₀ alkyl group, an unsubstituted or substituted C₁-C₂₀ alkyl amino group, an unsubstituted or substituted C₆-C₃₀ aryl group or an unsubstituted or substituted C₃-C₃₀ heteroaryl group, where each R³⁰ is identical to or different from each other when b7 is 2, 3 or 4;
b7 is 0, 1, 2, 3 or 4; and
the dotted line indicates a portion fused to the dotted line in Chemical Formula 5.

In some embodiments, an energy bandgap between a highest occupied molecular orbital (HOMO) energy level of the first compound and a HOMO energy level of the second compound may be less than 0.2 eV.

In some embodiments, an energy bandgap between a lowest unoccupied molecular orbital (LUMO) energy level of the first compound and a LUMO energy level of the second compound may be less than about 0.4 eV.

In some embodiments, the first organic compound is at least one of the compounds in Chemical Formula 3.

In some embodiments, the second organic compound may include at least one of the compounds in Chemical Formula 7.

In some embodiments, the at least one emitting material layer may further comprise a third compound.

In some embodiments, the third compound may comprise a third organic compound represented by Chemical Formula 8:

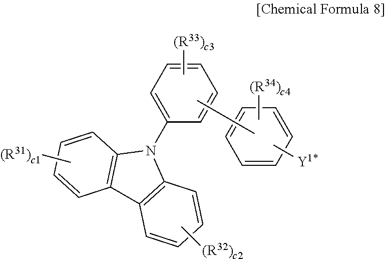

wherein, in the Chemical Formula 8,
each of R³¹ and R³² is independently an unsubstituted or substituted C₁-C₂₀ alkyl group or an unsubstituted or substituted C₆-C₃₀ aryl group, where each R³¹ is identical to or different from each other when c1 is 2, 3 or 4 and each R³² is identical to or different from each other when c2 is 2, 3 or 4;
each of R³³ and R³⁴ is independently an unsubstituted or substituted C₁-C₂₀ alkyl group or an unsubstituted or substituted C₆-C₃₀ aryl group, where each R³³ is identical to or different from each other when c3 is 2, 3 or 4 and each R³⁴ is identical to or different from each other when c4 is 2, 3 or 4, or R³³ or R³⁴ is linked to the adjacent 6-membered aromatic ring to form a heteroring that is optionally substituted with an unsubstituted or substituted C₆-C₃₀ aryl group;
Y¹ is represented by Chemical Formula 9A or Chemical Formula 9B;
each of c1, c2, c3 and c4 is independently 0, 1, 2, 3 or 4; and
an asterisk indicates a link position to the Chemical Formula 9A or Chemical Formula 9B,

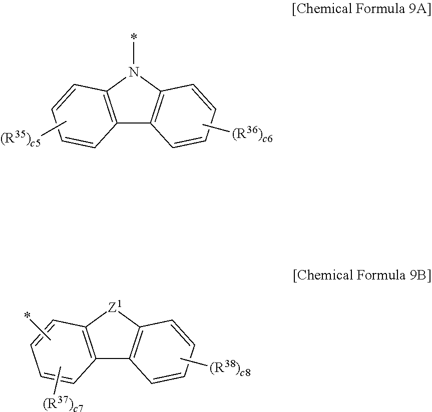

wherein, in the Chemical Formulae 9A and 9B,
each of R³⁵, R³⁶, R³⁷, and R³⁸ is independently an unsubstituted or substituted C₁-C₂₀ alkyl group or an unsubstituted or substituted C₆-C₃₀ aryl group, where each R³⁵ is identical to or different from each other when c5 is 2, 3 or 4, each R³⁶ is identical to or different from each other when c6 is 2, 3 or 4, each R³⁷ is identical to or different from each other when c7 is 2 or 3, and each R³⁸ is identical to or different from each other when c8 is 2, 3 or 4;
Z¹ is NR³⁹, O or S, where R³⁹ is hydrogen, an unsubstituted or substituted C₁-C₂₀ alkyl group or an unsubstituted or substituted C₆-C₃₀ aryl group;
each of c5, c6, and c8 is independently 0, 1, 2, 3 or 4;
c7 is 0, 1, 2 or 3; and
an asterisk indicates a link position to the Chemical Formula 8.

In some embodiments, the third organic compound includes at least one of the following compounds in Chemical Formula 10.

In some embodiments, the emissive layer may further comprise a charge control layer disposed between the at least one emitting material layer and the second electrode, and wherein the charge control layer comprises the second organic compound.

In some embodiments, the emissive layer may have a single emitting part or may have multiple emitting parts to form a tandem structure.

In some embodiments, the emissive layer may include: a first emitting part disposed between the first and second electrodes and comprising a first emitting material layer; a second emitting part disposed between the first emitting part and the second electrode and comprising a second emitting material layer; and a first charge generation layer disposed between the first emitting part and the second emitting part, wherein at least one of the first emitting material layer and the second emitting material layer comprises the first compound and the second compound.

In some embodiments, the second emitting material layer may comprise the first compound and the second compound.

In some embodiments, the second emitting material layer may comprise: a first layer disposed between the first charge generation layer and the second electrode; and a second layer disposed between the first layer and the second electrode, wherein at least one of the first layer and the second layer comprises the first compound and the second compound.

In some embodiments, the emissive layer may further comprise: a third emitting part disposed between the second emitting part and the second electrode and comprising a third emitting material layer; and a second charge generation layer disposed between the second emitting part and the third emitting part, wherein the second emitting material layer may comprise the first compound and the second compound.

In some embodiments, the second emitting material layer may comprise: a first layer disposed between the first charge generation layer and the second charge generation layer; and a second layer disposed between the first layer and the second charge generation layer, wherein at least one of the first layer and the second layer comprises the first compound and the second compound.

In another aspect, the present disclosure provides an organic light emitting device, for example, an organic light emitting display device or organic light emitting luminance device, where the organic light emitting diode is disposed on a substrate.

The first compound may have a fused structure of multiple aromatic and/or heteroaromatic rings to have a wide plate-like structure. The emitting material layer may comprise at least one host that has controlled energy level. The host may transfer exciton energy to the first compound by FRET mechanism where the singlet exciton of the second compound is transferred to the singlet exciton of the first compound of the emitter.

The first compound may utilize only the singlet exciton because the first compound is fluorescent material. The amount of the singlet exciton, which may be utilized by the first compound and may contribute the emission of the first compound, is increased as the exciton energy is transferred to the first compound by FRET mechanism that may transfer singlet-singlet exciton energy. Accordingly, the luminous efficiency and the luminous lifespan of an organic light emitting diode may be improved by using the first compound as final emitting material.

It is to be understood that both the foregoing general description and the following detailed description are merely by way of example and explanatory, and are intended to provide further explanation of the inventive concepts as claimed.

### BRIEF DESCRIPTION OF THE DRAWINGS

The accompanying drawings, which are included to provide a further understanding of the disclosure, are incorporated in and constitute a part of this application, illustrate embodiments of the disclosure and together with the description serve to explain principles of the disclosure.

FIG. 1 illustrates a schematic circuit diagram of an organic light emitting display device in accordance with the present disclosure.

FIG. 2 illustrates a schematic cross-sectional view of an organic light emitting display device as an example of an organic light emitting device in accordance with an example embodiment of the present disclosure.

FIG. 3 illustrates a schematic cross-sectional view of an organic light emitting diode having a single emitting part in accordance with an example embodiment of the present disclosure.

FIG. 4 illustrates a schematic diagram where exciplex between the first compound (FD) and the host (NH′) is generated when the energy level between the first compound and the host is not matched.

FIG. 5 illustrates a schematic diagram where no exciplex between the first compound (FD) and the host (NH′) is generated and exciton energy is transferred to the first compound from the host when the energy level between the first compound and the host is matched.

FIG. 6 illustrates a schematic cross-sectional view of an organic light emitting diode having a single emitting part in accordance with another example embodiment of the present disclosure.

FIG. 7 illustrates a schematic cross-sectional view of an organic light emitting display device in accordance with another example embodiment of the present disclosure.

FIG. 8 illustrates a schematic cross-sectional view of an organic light emitting diode with two emitting parts forming a tandem structure in accordance with another example embodiment of the present disclosure.

FIG. 9 illustrates a schematic cross-sectional view of an organic light emitting diode with three emitting parts forming a tandem structure in accordance with another example embodiment of the present disclosure.

### DETAILED DESCRIPTION

Reference will now be made in detail to aspects of the disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. The same or similar elements are designated by the same reference numerals throughout the specification unless otherwise specified.

In the following description, where the detailed description of the relevant known function or configuration may unnecessarily obscure an important point of the present disclosure, a detailed description of such known function of configuration may be omitted.

In the present specification, where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is to be construed as including an error or tolerance range even where no explicit description of such an error or tolerance range is provided.

In the description of the various embodiments of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used.

Although the terms “first,” “second,” and the like may be used herein to describe various elements, the elements should not be limited by these terms. These terms are used only to identify one element from another. For example, a first element could be termed a second element, and similarly, a second element could be termed a first element, without departing from the scope of the present disclosure.

Although the terms “first,” “second,” A, B, (a), (b), and the like may be used herein to describe various elements, the elements should not be interpreted to be limited by these terms as they are not used to define a particular order, precedence, or number of the corresponding elements. These terms are used only to identify one element from another.

The expression that an element or layer is “connected” to another element or layer means that the element or layer can not only be directly connected to another element or layer, but also be indirectly connected or adhered to another element or layer with one or more intervening elements or layers “disposed,” or “interposed” between the elements or layers, unless otherwise specified.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in a co-dependent relationship.

Hereinafter, example embodiments of the present disclosure will be described in detail with reference to the accompanying drawings. In adding reference numerals to elements of each of the drawings, although the same elements are illustrated in other drawings, like reference numerals may refer to like elements. Also, for convenience of description, a scale in which each of elements is illustrated in the accompanying drawings may differ from an actual scale. Thus, the illustrated elements are not limited to the specific scale in which they are illustrated in the drawings.

The present disclosure relates to an organic light emitting diode comprising a first compound having a plate-like structure and may receive efficiently exciton energy from the host and/or other luminous material. In one example embodiment, an emissive layer comprising the first compound may be applied to an organic light emitting diode having a single emitting part in a red pixel region. Alternatively, the emissive layer comprising the first compound may be applied to an organic light emitting diode having a tandem structure where at least two emitting parts are stacked.

The organic light emitting diode where an emissive layer comprises the first compound may be applied to an organic light emitting device such as an organic light emitting display device or an organic light emitting illumination device. As an example, an organic light emitting display device will be described.

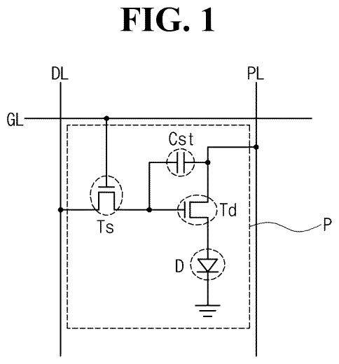

FIG. 1 illustrates a schematic circuit diagram of an organic light emitting display device in accordance with the present disclosure. As illustrated in FIG. 1, a gate line GL, a data line DL and power line PL, each of which crosses each other to define a pixel region P, in an organic light emitting display device 100. A switching thin film transistor Ts, a driving thin film transistor Td, a storage capacitor Cst and an organic light emitting diode D are disposed within the pixel region P. The pixel region P may comprise a red (R) pixel region, a green (G) pixel region and a blue (B) pixel region. However, embodiments of the present disclosure are not limited to such examples.

The switching thin film transistor Ts is connected to the gate line GL and the data line DL. The driving thin film transistor Td and the storage capacitor Cst are connected between the switching thin film transistor Ts and the power line PL. The organic light emitting diode D is connected to the driving thin film transistor Td. When the switching thin film transistor Ts is turned on by a gate signal applied to the gate line GL, a data signal applied to the data line DL is applied to a gate electrode of the driving thin film transistor Td and one electrode of the storage capacitor Cst through the switching thin film transistor Ts.

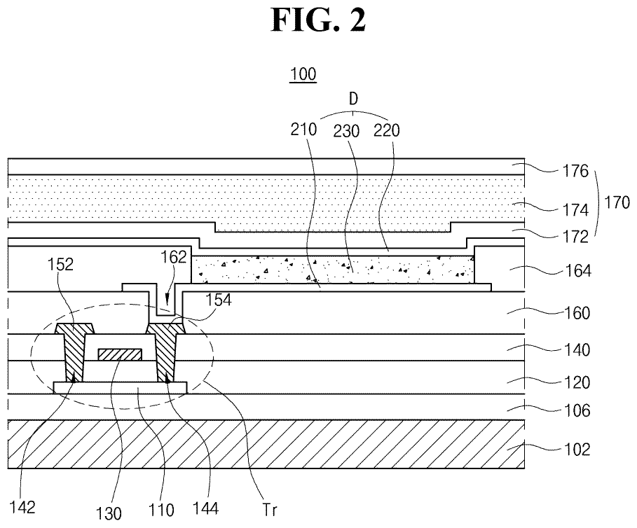

The driving thin film transistor Td is turned on by the data signal applied to the gate electrode 130 (FIG. 2) so that a current proportional to the data signal is supplied from the power line PL to the organic light emitting diode D through the driving thin film transistor Td. And then, the organic light emitting diode D emits light having a luminance proportional to the current flowing through the driving thin film transistor Td. In this case, the storage capacitor Cst is charged with a voltage proportional to the data signal so that the voltage of the gate electrode in the driving thin film transistor Td is kept constant during one frame. Therefore, the organic light emitting display device may display a desired image.

FIG. 2 illustrates a schematic cross-sectional view of an organic light emitting display device in accordance with an example embodiment of the present disclosure. As illustrated in FIG. 2, the organic light emitting display device 100 comprises a substrate 102, a thin-film transistor Tr on the substrate 102, and an organic light emitting diode D connected to the thin film transistor Tr.

As an example, the substrate 102 may comprise a red pixel region, a green pixel region and a blue pixel region and an organic light emitting diode D may be located in each pixel region. Each of the organic light emitting diodes D emitting red, green and blue light, respectively, is located correspondingly in the red pixel region, the green pixel region and the blue pixel region.

The substrate 102 may comprise, but is not limited to, glass, thin flexible material and/or polymer plastics. For example, the flexible material may be selected from the group of, but is not limited to, polyimide (PI), polyethersulfone (PES), polyethylenenaphthalate (PEN), polyethylene terephthalate (PET), polycarbonate (PC) and/or combinations thereof. The substrate 102, on which the thin film transistor Tr and the organic light emitting diode D are arranged, forms an array substrate.

A buffer layer 106 may be disposed on the substrate 102. The thin film transistor Tr may be disposed on the buffer layer 106. In certain embodiments, the buffer layer 106 may be omitted.

A semiconductor layer 110 is disposed on the buffer layer 106. In one example embodiment, the semiconductor layer 110 may comprise, but is not limited to, oxide semiconductor materials. In this case, a light-shield pattern may be disposed under the semiconductor layer 110, and the light-shield pattern may prevent or reduce chances of light from being incident toward the semiconductor layer 110, and thereby, preventing or reducing the semiconductor layer 110 from being degraded by the light. Alternatively, the semiconductor layer 110 may comprise polycrystalline silicon. In this case, opposite edges of the semiconductor layer 110 may be doped with impurities.

A gate insulating layer 120 comprising an insulating material is disposed on the semiconductor layer 110. The gate insulating layer 120 may comprise, but is not limited to, an inorganic insulating material such as silicon oxide (SiOₓ, wherein 0<x≤2) or silicon nitride (SiNₓ, wherein 0<x≤2).

A gate electrode 130 made of a conductive material such as a metal is disposed on the gate insulating layer 120 so as to correspond to a center of the semiconductor layer 110. While the gate insulating layer 120 is disposed on a whole area of the substrate 102 as shown in FIG. 2, the gate insulating layer 120 may be patterned identically as the gate electrode 130.

An interlayer insulating layer 140 comprising an insulating material is disposed on the gate electrode 130 with and covers an entire surface of the substrate 102. The interlayer insulating layer 140 may comprise, but is not limited to, an inorganic insulating material such as silicon oxide (SiOₓ) or silicon nitride (SiNₓ), or an organic insulating material such as benzocyclobutene or photo-acryl.

The interlayer insulating layer 140 has first and second semiconductor layer contact holes 142 and 144 that expose the semiconductor layer 110 or do not cover a portion of the surface of the semiconductor layer 110 nearer to the opposing ends than to a center of the semiconductor layer 110. The first and second semiconductor layer contact holes 142 and 144 are disposed on opposite sides of the gate electrode 130 and spaced apart from the gate electrode 130. The first and second semiconductor layer contact holes 142 and 144 are formed within the gate insulating layer 120 in FIG. 2. Alternatively, the first and second semiconductor layer contact holes 142 and 144 may be formed only within the interlayer insulating layer 140 when the gate insulating layer 120 is patterned identically as the gate electrode 130.

A source electrode 152 and a drain electrode 154, which are made of conductive material such as a metal, are disposed on the interlayer insulating layer 140. The source electrode 152 and the drain electrode 154 are spaced apart from each other on opposing sides of the gate electrode 130, and contact both sides of the semiconductor layer 110 through the first and second semiconductor layer contact holes 142 and 144, respectively.

The semiconductor layer 110, the gate electrode 130, the source electrode 152 and the drain electrode 154 constitute the thin film transistor Tr, which acts as a driving element. The thin film transistor Tr in FIG. 2 has a coplanar structure in which the gate electrode 130, the source electrode 152 and the drain electrode 154 are disposed on the semiconductor layer 110. Alternatively, the thin film transistor Tr may have an inverted staggered structure in which a gate electrode is disposed under a semiconductor layer and a source and drain electrodes are disposed on the semiconductor layer. In this case, the semiconductor layer may comprise amorphous silicon.

The gate line GL and the data line DL, which cross each other to define a pixel region P, and a switching element Ts, which is connected to the gate line GL and the data line DL, may be further formed in the pixel region P. The switching element Ts is connected to the thin film transistor Tr, which is a driving element. In addition, the power line PL is spaced apart in parallel from the gate line GL or the data line DL. The thin film transistor Tr may further comprise a storage capacitor Cst configured to constantly keep a voltage of the gate electrode 130 for one frame.

A passivation layer 160 is disposed on the source and drain electrodes 152 and 154. The passivation layer 160 covers the thin film transistor Tr on the whole substrate 102. The passivation layer 160 has a flat top surface and a drain contact hole 162 that exposes the drain electrode 154 or does not cover the drain electrode 154 of the thin film transistor Tr. While the drain contact hole 162 is disposed on the second semiconductor layer contact hole 144, it may be spaced apart from the second semiconductor layer contact hole 144.

The organic light emitting diode (OLED) D comprises a first electrode 210 that is disposed on the passivation layer 160 and connected to the drain electrode 154 of the thin film transistor Tr. The OLED D further comprises an emissive layer 230 and a second electrode 220 each of which is disposed sequentially on the first electrode 210.

The first electrode 210 is disposed in each pixel region. The first electrode 210 may be an anode and comprise conductive material having relatively high work function value. For example, the first electrode 210 may comprise a transparent conductive oxide (TCO). In some embodiments, the first electrode 210 may comprise, but is not limited to, indium tin oxide (ITO), indium zinc oxide (IZO), indium tin zinc oxide (ITZO), tin oxide (SnO), zinc oxide (ZnO), indium cerium oxide (ICO), aluminum doped zinc oxide (AZO), and/or combinations thereof.

In one example embodiment, when the organic light emitting display device 100 is a bottom-emission type, the first electrode 210 may have a single-layered structure of the TCO. Alternatively, when the organic light emitting display device 100 is a top-emission type, a reflective electrode or a reflective layer may be disposed under the first electrode 210. For example, the reflective electrode or the reflective layer may comprise, but is not limited to, silver (Ag) or aluminum-palladium-copper (APC) alloy. In the OLED D of the top-emission type, the first electrode 210 may have a triple-layered structure of ITO/Ag/ITO or ITO/APC/ITO.

In addition, a bank layer 164 is disposed on the passivation layer 160 in order to cover edges of the first electrode 210. The bank layer 164 exposes the first electrode 210 or does not cover a center of the first electrode 210 corresponding to each pixel region. In certain embodiments, the bank layer 164 may be omitted.

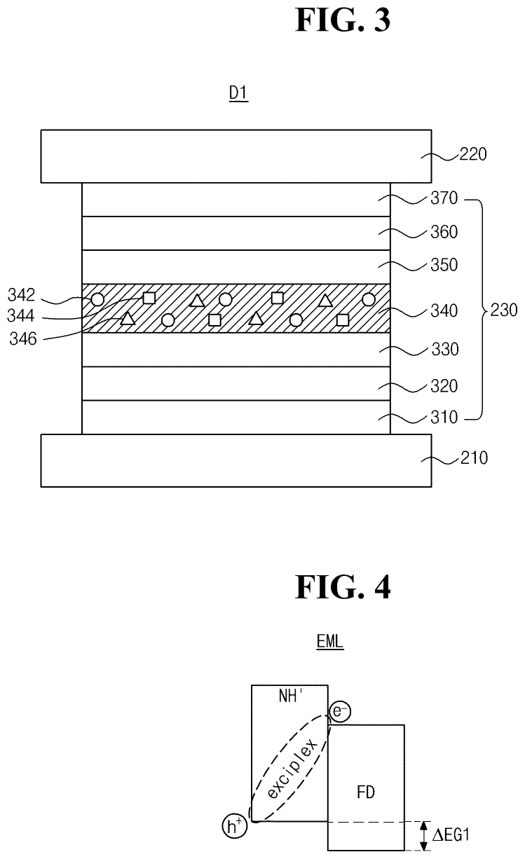

An emissive layer 230 is disposed on the first electrode 210. In one example embodiment, the emissive layer 230 may have a single-layered structure of an emitting material layer (EML). Alternatively, the emissive layer 230 may have a multiple-layered structure including a hole injection layer (HIL), a hole transport layer (HTL), an electron blocking layer (EBL), an EML, a hole blocking layer (HBL), an electron transport layer (ETL), an electron injection layer (EIL) and/or a charge generation layer (CGL) (FIG. 3). In one aspect, the emissive layer 230 may have a single emitting part. Alternatively, the emissive layer 230 may have multiple emitting parts to form a tandem structure. For example, the emissive layer 230 may be applied to an OLED with a single emitting part located each of the red pixel region, the green pixel region and the blue pixel region. Alternatively, the emissive layer 230 may be applied to a tandem-type OLED where at least two emitting parts are stacked.

The emissive layer 230 may comprise a first compound having a plate-like structure and at least one host that may transfer exciton energy to the first compound. The luminous efficiency and the luminous lifespan of the OLED D and the organic light emitting display device 100 may be improved by comprising the luminous materials.

The second electrode 220 is disposed on the substrate 102 above which the emissive layer 230 is disposed. The second electrode 220 may be disposed on a whole display area. The second electrode 220 may comprise a conductive material with a relatively low work function value compared to the first electrode 210. The second electrode 220 may be a cathode providing electrons. For example, the second electrode 220 may comprise at least one of, but is not limited to, aluminum (Al), magnesium (Mg), calcium (Ca), silver (Ag), alloy thereof and/or combinations thereof such as aluminum-magnesium alloy (Al—Mg). When the organic light emitting display device 100 is a top-emission type, the second electrode 220 is thin so as to have light-transmissive (semi-transmissive) property.

In addition, an encapsulation film 170 may be disposed on the second electrode 220 in order to prevent or reduce outer moisture from penetrating into the OLED D. The encapsulation film 170 may have, but is not limited to, a laminated structure of a first inorganic insulating film 172, an organic insulating film 174 and a second inorganic insulating film 176. In certain embodiments, the encapsulation film 170 may be omitted.

A polarizing plate may be attached onto the encapsulation film 170 to reduce reflection of external light. For example, the polarizing plate may be a circular polarizing plate. When the organic light emitting display device 100 is a bottom-emission type, the polarizing plate may be disposed under the substrate 102. Alternatively, when the organic light emitting display device 100 is a top-emission type, the polarizing plate may be disposed on the encapsulation film 170. In addition, a cover window may be attached to the encapsulation film 170 or the polarizing plate. In this case, the substrate 102 and the cover window may have a flexible property, thus the organic light emitting display device 100 may be a flexible display device.

The OLED D is described in more detail. FIG. 3 illustrates a schematic cross-sectional view of an organic light emitting diode having a single emitting part in accordance with an example embodiment of the present disclosure. As illustrated in FIG. 3, the organic light emitting diode (OLED) D1 in accordance with the present disclosure comprises first and second electrodes 210 and 220 facing each other and an emissive layer 230 disposed between the first and second electrodes 210 and 220. The organic light emitting display device 100 comprises a red pixel region, a green pixel region and a blue pixel region, and the OLED D1 may be disposed in the red pixel region, the green pixel region and the blue pixel region. As an example, the OLED D1 may be disposed in the red pixel region.

In an example embodiment, the emissive layer 230 comprises an emitting material layer (EML) 340 disposed between the first and second electrodes 210 and 220. Also, the emissive layer 230 may comprise at least one of a hole transport layer (HTL) 320 disposed between the first electrode 210 and the EML 340 and an electron transport layer (ETL) 360 disposed between the second electrode 220 and the EML 340. In addition, the emissive layer 230 may further comprise at least one of a hole injection layer (HIL) 310 disposed between the first electrode 210 and the HTL 320 and an electron injection layer (EIL) 370 disposed between the second electrode 220 and the ETL 360. Alternatively, the emissive layer 230 may further comprise a first exciton blocking layer, i.e. an electron blocking layer (EBL) 330 disposed between the HTL 320 and the EML 340 and/or a second exciton blocking layer, i.e. a hole blocking layer (HBL) 350 disposed between the EML 340 and the ETL 360.

The first electrode 210 may be an anode that provides holes into the EML 340. The first electrode 210 may comprise a conductive material having a relatively high work function value, for example, a transparent conductive oxide (TCO). In an example embodiment, the first electrode 210 may comprise, but is not limited to, ITO, IZO, ITZO, SnO, ZnO, ICO, AZO, and/or combinations thereof.

The second electrode 220 may be a cathode that provides electrons into the EML 340. The second electrode 220 may comprise a conductive material having a relatively low work function values, i.e., a highly reflective material such as Al, Mg, Ca, Ag, and/or alloy thereof and/or combinations thereof such as Al—Mg.

The HIL 310 is disposed between the first electrode 210 and the HTL 320 and may improve an interface property between the inorganic first electrode 210 and the organic HTL 320. In one example embodiment, hole injecting material of the HIL 310 may comprise, but is not limited to, 4,4′,4″-Tris(3-methylphenylamino)triphenylamine (MTDATA), 4,4′,4″-Tris(N,N-diphenyl-amino)triphenylamine (NATA), 4,4′,4″-Tris(N-(naphthalene-1-yl)-N-phenyl-amino)triphenylamine (1T-NATA), 4,4′,4″-Tris(N-(naphthalene-2-yl)-N-phenyl-amino)triphenylamine (2T-NATA), Copper phthalocyanine (CuPc), Tris(4-carbazoyl-9-yl-phenyl)amine (TCTA), N,N′-Diphenyl-N,N′-bis(1-naphthyl)-1,1′-biphenyl-4,4″-diamine (NPB; NPD), N,N′-Bis{4-[bis(3-methylphenyl)amino]phenyl}-N,N′-diphenyl-4,4′-biphenyldiamine (DNTPD), 1,4,5,8,9,11-Hexaazatriphenylenehexacarbonitrile (Dipyrazino[2,3-f:2′3′-h]quinoxaline-2,3,6,7,10,11-hexacarbonitrile; HAT-CN), 2,3,5,6-tetrafluoro-7,7,8,8-tetracyanoquinodimethane (F4-TCNQ), 1,3,4,5,7,8-hexafluorotetracyanonaphthoquinodimethane (F6-TCNNQ), 1,3,5-tris[4-(diphenylamino)phenyl]benzene (TDAPB), poly(3,4-ethylenedioxythiophene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine, N,N′-diphenyl-N,N′-di[4-(N,N′-diphenyl-amino)phenyl]benzidine (NPNPB) and/or combinations thereof.

In another example embodiment, the HIL 310 comprises the hole transporting material doped with hole injecting material (e.g., HAT-CN, F4-TCNQ and/or F6-TCNNQ). In this case, the contents of the hole injection material in the HIL 310 may be between about 2 wt % and about 15 wt %. In certain embodiments, the HIL 310 may be omitted in compliance of the OLED D1 property.

The HTL 320 is disposed adjacent to the EML 340 between the first electrode 210 and the EML 340. In one example embodiment, hole transporting material of the HTL 320 may comprise, but is not limited to, N,N′-Diphenyl-N,N′-bis(3-methylphenyl)-1,1′-biphenyl-4,4′-diamine (TPD), NPB(NPD), DNTPD, 4,4′-bis(N-carbazolyl)-1,1′-biphenyl (CBP), Poly[N,N′-bis(4-butylphenyl)-N,N′-bis(phenyl)-benzidine] (Poly-TPD), Poly[(9,9-dioctylfluorenyl-2,7-diyl)-co-(4,4′-(N-(4-sec-butylphenyl)diphenylamine))] (TFB), Di-[4-(N,N-di-p-tolyl-amino)-phenyl]cyclohexane (TAPC), 3,5-Di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine), N-([1,1′-Biphenyl]-4-yl)-9,9-dimethyl-N-(4-(9-phenyl-9H-carbazol-3-yl)phenyl)-9H-fluoren-2-amine and/or combinations thereof.

The EML 340 may comprise a first compound 342 and a second compound 346, and optionally, a third compound 346, and ultimate emission may occur at the first compound 342. The EML 340 may emit red to yellow-green color light, for example, red color light.

The first compound 342 may be a fluorescent emitter (fluorescent dopant) emitting red to yellow-green color light. The first compound 342 has a wide plate-like structure and may be receive efficiently singlet exciton energy from the second and third compounds 344 and 346 acting as host or other luminous materials. The luminous efficiency and luminous lifespan of the OLED D1 may be improved by using the first compound 342 as the final emitting material. The first compound may have the following structure of Chemical Formula 1:

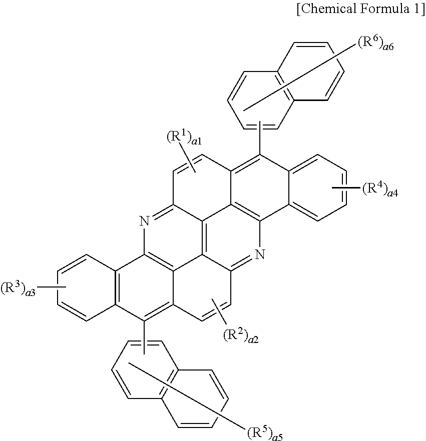

wherein, in the Chemical Formula 1,
each of R¹, R², R³, R⁴, R⁵, and R⁶ is independently a halogen atom, a cyano group, an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ heteroaryl group, an unsubstituted or substituted C₆-C₃₀ aryl amino group or an unsubstituted or substituted C₃-C₃₀ heteroaryl amino group, where each R¹ is identical to or different from each other when a1 is 2, each R² is identical to or different from each other when a2 is 2, each R³ is identical to or different from each other when a3 is 2, 3 or 4, each R⁴ is identical to or different from each other when a4 is 2, 3 or 4, each R⁵ is identical to or different from each other when a5 is 2, 3, 4, 5, 6 or 7 and each R⁶ is identical to or different from each other when a6 is 2, 3, 4, 5, 6 or 7;
each of a1 and a2 is independently 0, 1 or 2;
each of a3 and a4 is independently 0, 1, 2, 3 or 4; and
each of a5 and a6 is independently 0, 1, 2, 3, 4, 5, 6 or 7.

As used herein, the term “unsubstituted” means that hydrogen is directly linked to a carbon atom. “Hydrogen”, as used herein, may refer to protium, deuterium and tritium.

As used herein, “substituted” means that the hydrogen is replaced with a substituent. The substituent may comprise, but is not limited to, an unsubstituted or halogen-substituted C₁-C₂₀ alkyl group, an unsubstituted or halogen-substituted C₁-C₂₀ alkoxy, halogen, a cyano group, a hydroxyl group, a carboxylic group, a carbonyl group, an amino group, a C₁-C₁₀ alkyl amino group, a C₆-C₃₀ aryl amino group, a C₃-C₃₀ heteroaryl amino group, a nitro group, a hydrazyl group, a sulfonate group, an unsubstituted or halogen-substituted C₁-C₁₀ alkyl silyl group, an unsubstituted or a halogen-substituted C₁-C₁₀ alkoxy silyl group, an unsubstituted or halogen-substituted C₃-C₂₀ cyclo alkyl silyl group, an unsubstituted or halogen-substituted C₆-C₃₀ aryl silyl group, an unsubstituted or substituted C₆-C₃₀ aryl group, or an unsubstituted or substituted C₃-C₃₀ heteroaryl group.

For example, each of the C₆-C₃₀ aryl group and the C₃-C₃₀ heteroaryl group may be substituted with at least one of C₁-C₂₀ alkyl, C₆-C₃₀ aryl and C₃-C₃₀ heteroaryl.

As used herein, the term “hetero” in terms such as “a heteroaromatic group”, “a heterocyclo alkylene group”, “a heteroarylene group”, “a heteroaryl alkylene group”, “a heteroaryl oxylene group”, “a heterocyclo alkyl group”, “a heteroaryl group”, “a heteroaryl alkyl group”, “a heteroaryloxy group”, “a heteroaryl amino group” and the likes means that at least one carbon atom, for example 1 to 5 carbons atoms, constituting an aliphatic chain, an alicyclic group or ring or an aromatic group or ring is substituted with at least one heteroatom selected from the group consisting of N, O, S and P.

As used herein, the C₆-C₃₀ aryl group may comprise, but is not limited to, an unfused or fused aryl group such as phenyl, biphenyl, terphenyl, naphthyl, anthracenyl, pentalenyl, indenyl, indeno-indenyl, heptalenyl, biphenylenyl, indacenyl, phenalenyl, phenanthrenyl, benzo-phenanthrenyl, dibenzo-phenanthrenyl, azulenyl, pyrenyl, fluoranthenyl, triphenylenyl, chrysenyl, tetraphenylenyl, tetracenyl, pleiadenyl, picenyl, pentaphenylenyl, pentacenyl, fluorenyl, indeno-fluorenyl or spiro-fluorenyl. The C₆-C₃₀ arylene group may comprise, but is not limited to, any bivalent linking group corresponding to the above aryl group. As used herein, the C₆-C₃₀ arylene group may be a bivalent linking group corresponding to each of the C6-C30 aryl group.

As used herein, the C₃-C₃₀ heteroaryl group may comprise, but is not limited to, an unfused or fused heteroaryl group such as pyrrolyl, pyridinyl, pyrimidinyl, pyrazinyl, pyridazinyl, triazinyl, tetrazinyl, imidazolyl, pyrazolyl, indolyl, iso-indolyl, indazolyl, indolizinyl, pyrrolizinyl, carbazolyl, benzo-carbazolyl, dibenzo-carbazolyl, indolo-carbazolyl, indeno-carbazolyl, benzo-furo-carbazolyl, benzo-thieno-carbazolyl, carbolinyl, quinolinyl, iso-quinolinyl, phthlazinyl, quinoxalinyl, cinnolinyl, quinazolinyl, quinolizinyl, purinyl, benzo-quinolinyl, benzo-iso-quinolinyl, benzo-quinazolinyl, benzo-quinoxalinyl, acridinyl, phenazinyl, phenoxazinyl, phenothiazinyl, phenanthrolinyl, perimidinyl, phenanthridinyl, pteridinyl, naphthyridinyl, furanyl, pyranyl, oxazinyl, oxazolyl, oxadiazolyl, triazolyl, dioxinyl, benzo-furanyl, dibenzo-furanyl, thiopyranyl, xanthenyl, chromenyl, iso-chromenyl, thioazinyl, thiophenyl, benzo-thiophenyl, dibenzo-thiophenyl, difuro-pyrazinyl, benzofuro-dibenzo-furanyl, benzothieno-benzo-thiophenyl, benzothieno-dibenzo-thiophenyl, benzothieno-benzo-furanyl, benzothieno-dibenzo-furanyl, xanthene-linked spiro acridinyl, dihydroacridinyl substituted with at least one C₁-C₁₀ alkyl and N-substituted spiro fluorenyl. The C₃-C₃₀ heteroarylene group may comprise, but is not limited to, any bivalent linking group corresponding to the heteroabove aryl group.

As an example, each of the aryl group or the heteroaryl group of R¹ to R⁶ in Chemical Formula 1 may consist of one to four, for example, one to three aromatic and/or heteroaromatic rings. When the number of the aromatic and/or heteroaromatic rings of R¹ to R⁶ becomes more than four, conjugated structure among the within the whole molecule becomes too long, thus, the organometallic compound may have too narrow energy bandgap. For example, each of the aryl group or the heteroaryl group of R¹ to R⁶ may comprise independently, but is not limited to, phenyl, biphenyl, naphthyl, anthracenyl, pyrrolyl, triazinyl, imidazolyl, pyrazolyl, pyridinyl, pyrazinyl, pyrimidinyl, pyridazinyl, furanyl, benzo-furanyl, dibenzo-furanyl, thiophenyl, benzo-thiophenyl, dibenzo-thiophenyl, carbazolyl, acridinyl, carbolinyl, phenazinyl, phenoxazinyl, or phenothiazinyl.

The first compound 342 having the structure of Chemical Formula 1 comprises a fused ring system of multiple aromatic rings and/or heteroaromatic rings, so that the first compound 342 has a wide plate-like structure. The excited singlet exciton energy of the second compound 344 and/or the third and fourth compounds 346 and 348 may be transferred efficiently to the singlet exciton of the first compound 342 having the structure of Chemical Formula 1 through Forster Resonance Energy Transfer (FRET) mechanism.

The first compound 342 may not utilize triplet excitons because the first compound 342 having the structure of Chemical Formula 1 is fluorescent material. Only the singlet exciton energy transferred by the FRET mechanism may contribute to the emission of the first compound having the structure of Chemical Formula 1. The amount of singlet exciton energy that may be utilized by the first compound 342 having the structure of Chemical Formula 1 and be contribute the emission of the first compound 342 is increased as the exciton energies are transferred to the first compound 342 through the FRET mechanism that may transfer only singlet-singlet exciton energy that may contribute the emission of the first compound 342 having the structure of Chemical Formula 1. The luminous efficiency and luminous lifespan of the OLED D1 may be improved by using the first compound 342 having the structure of Chemical Formula 1 as the final emitting material.

For example, the first compound 342 having the structure of Chemical Formula 1 may emit red to yellow-green color light. Applying the first compound 342 into the emissive layer 230 enables the OLED D1 to improve its luminous efficiency and luminous lifespan.

In one example embodiment, each of R¹, R², R³, R⁴, R⁵, and R⁶ in Chemical Formula 1 may be independently a C₁-C₁₀ alkyl group or an unsubstituted or C₁-C₁₀ alkyl-substituted C₆-C₃₀ aryl group. The first compound 342 with such a structure may comprise an organic compound having the following structure of Chemical Formula 2A or Chemical Formula 2B:

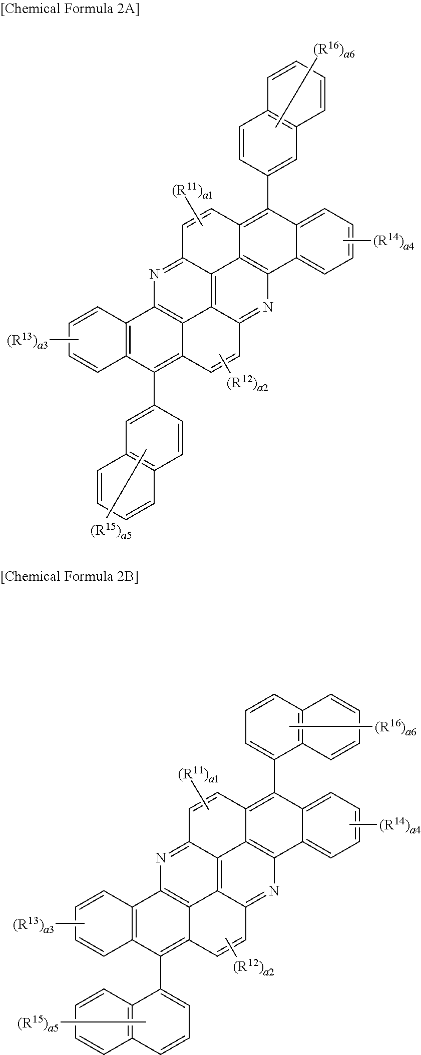

wherein, in the Chemical Formulae 2A and 2B,
each of a1, a2, a3, a4, a5, and a6 is identical as defined in Chemical Formula 1,
each of R¹¹, R¹², R¹³, R¹⁴, R¹⁵, and R¹⁶ is independently a C₁-C₂₀ alkyl group or an unsubstituted or C₁-C₁₀ alkyl-substituted C₆-C₃₀ aryl group, where each R¹¹ is identical to or different from each other when a1 is 2, each R¹² is identical to or different from each other when a2 is 2, each R¹³ is identical to or different from each other when a3 is 2, 3 or 4, each R¹⁴ is identical to or different from each other when a4 is 2, 3 or 4, each R¹⁵ is identical to or different from each other when a5 is 2, 3, 4, 5, 6 or 7 and each R¹⁶ is identical to or different from each other when a6 is 2, 3, 4, 5, 6 or 7.

In another example embodiment, each of R¹, R², R³, R⁴, R⁵, and R⁶ in Chemical Formula 1 may be independently a C₁-C₁₀ alkyl group (e.g., methyl, tert-propyl or tert-butyl) or an unsubstituted or C₁-C₁₀ alkyl (e.g., methyl, tert-propyl or tert-butyl)-substituted C₆-C₃₀ aryl group (e.g., phenyl or naphthyl), each of a1 and a2 may be 0, and each of a3, a4, a5, and a6 may be independently 0 or 1, but is not limited thereto.

In another example embodiment, each of a1 and a2 may be 0, each of R³ and R⁴ may be independently an unsubstituted or C₁-C₁₀ alkyl (e.g., methyl, tert-propyl or tert-butyl)-substituted C₆-C₃₀ aryl group (e.g., phenyl or naphthyl), each of a3 and a4 may be independently 0 or 1, each of R⁵, and R⁶ may be independently a C₁-C₁₀ alkyl group (e.g., methyl, tert-propyl or tert-butyl), and each of a5, and a6 may be independently 0 or 1.

In some embodiments, the first compound 342 including the organic compound having the structure of Chemical Formula 1 may be, but is not limited to, at least one of the following compounds in Chemical Formula 3:

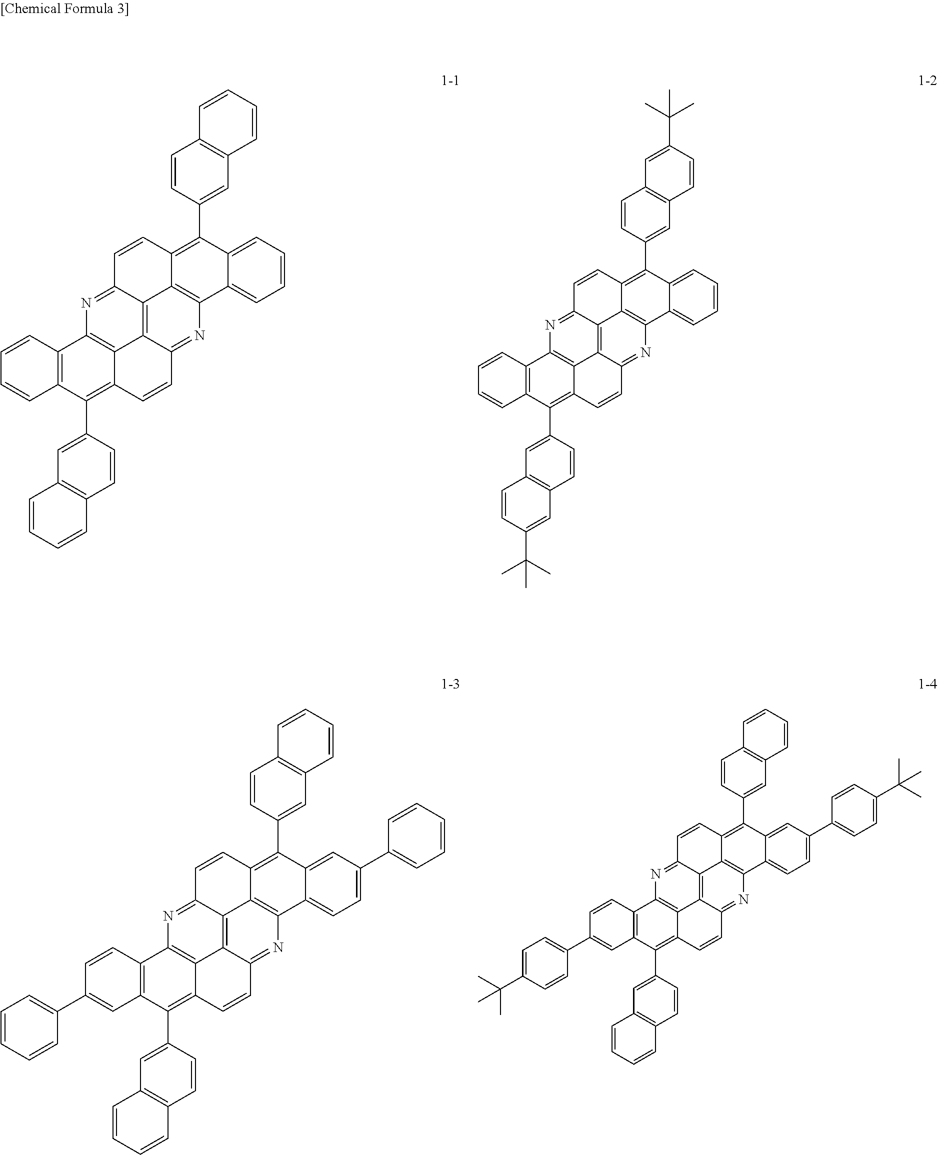 [SMILES: c1ccc2cc(-c3c4ccccc4c4nc5ccc6c(-c7ccc8ccccc8c7)c7ccccc7c7nc8ccc3c4c8c5c67)ccc2c1 ; CC(C)(C)c1ccc2cc(-c3c4ccccc4c4nc5ccc6c(-c7ccc8cc(C(C)(C)C)ccc8c7)c7ccccc7c7nc8ccc3c4c8c5c67)ccc2c1 ; c1ccc(-c2ccc3c(c2)c(-c2ccc4ccccc4c2)c2ccc4nc5c6ccc(-c7ccccc7)cc6c(-c6ccc7ccccc7c6)c6ccc7nc3c2c4c7c65)cc1 ; CC(C)(C)c1ccc(-c2ccc3c(c2)c(-c2ccc4ccccc4c2)c2ccc4nc5c6ccc(-c7ccc(C(C)(C)C)cc7)cc6c(-c6ccc7ccccc7c6)c6ccc7nc3c2c4c7c65)cc1]

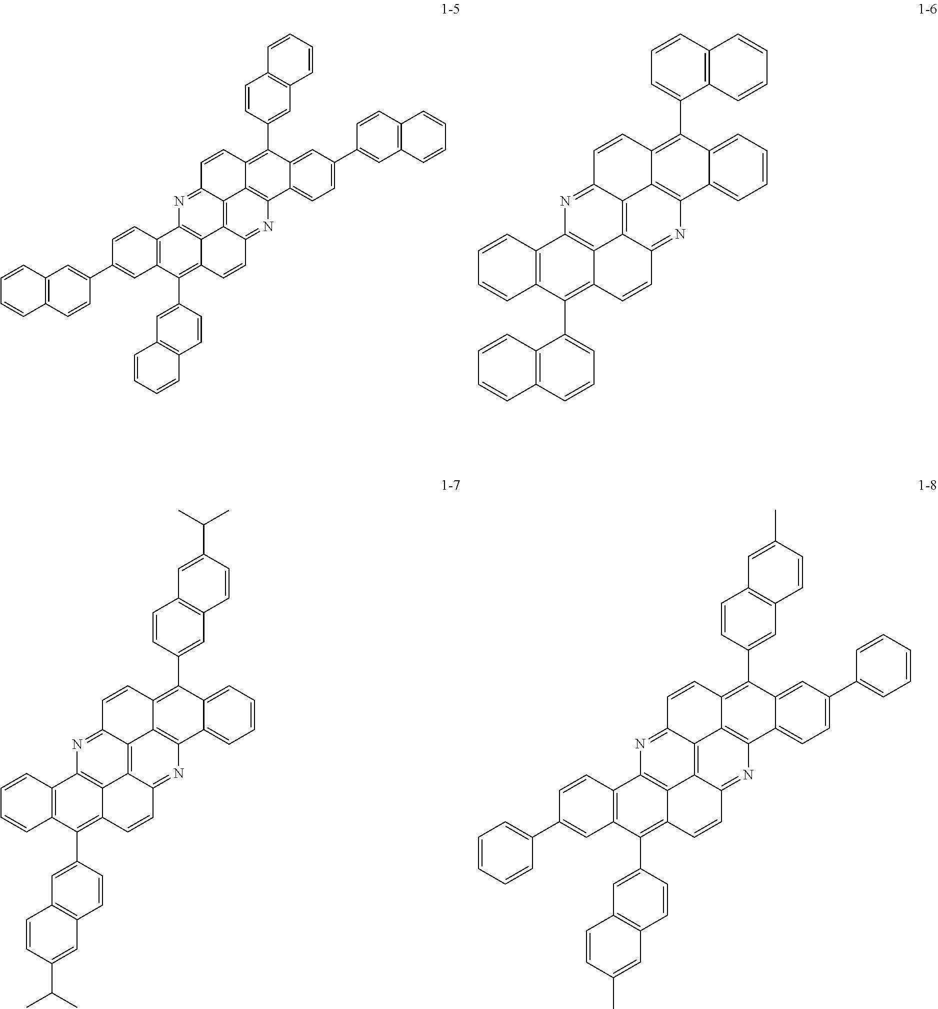 [SMILES: c1ccc2cc(-c3ccc4c(c3)c(-c3ccc5ccccc5c3)c3ccc5nc6c7ccc(-c8ccc9ccccc9c8)cc7c(-c7ccc8ccccc8c7)c7ccc8nc4c3c5c8c76)ccc2c1 ; c1ccc2c(-c3c4ccccc4c4nc5ccc6c(-c7cccc8ccccc78)c7ccccc7c7nc8ccc3c4c8c5c67)cccc2c1 ; CC(C)c1ccc2cc(-c3c4ccccc4c4nc5ccc6c(-c7ccc8cc(C(C)C)ccc8c7)c7ccccc7c7nc8ccc3c4c8c5c67)ccc2c1 ; Cc1ccc2cc(-c3c4cc(-c5ccccc5)ccc4c4nc5ccc6c(-c7ccc8cc(C)ccc8c7)c7cc(-c8ccccc8)ccc7c7nc8ccc3c4c8c5c67)ccc2c1]

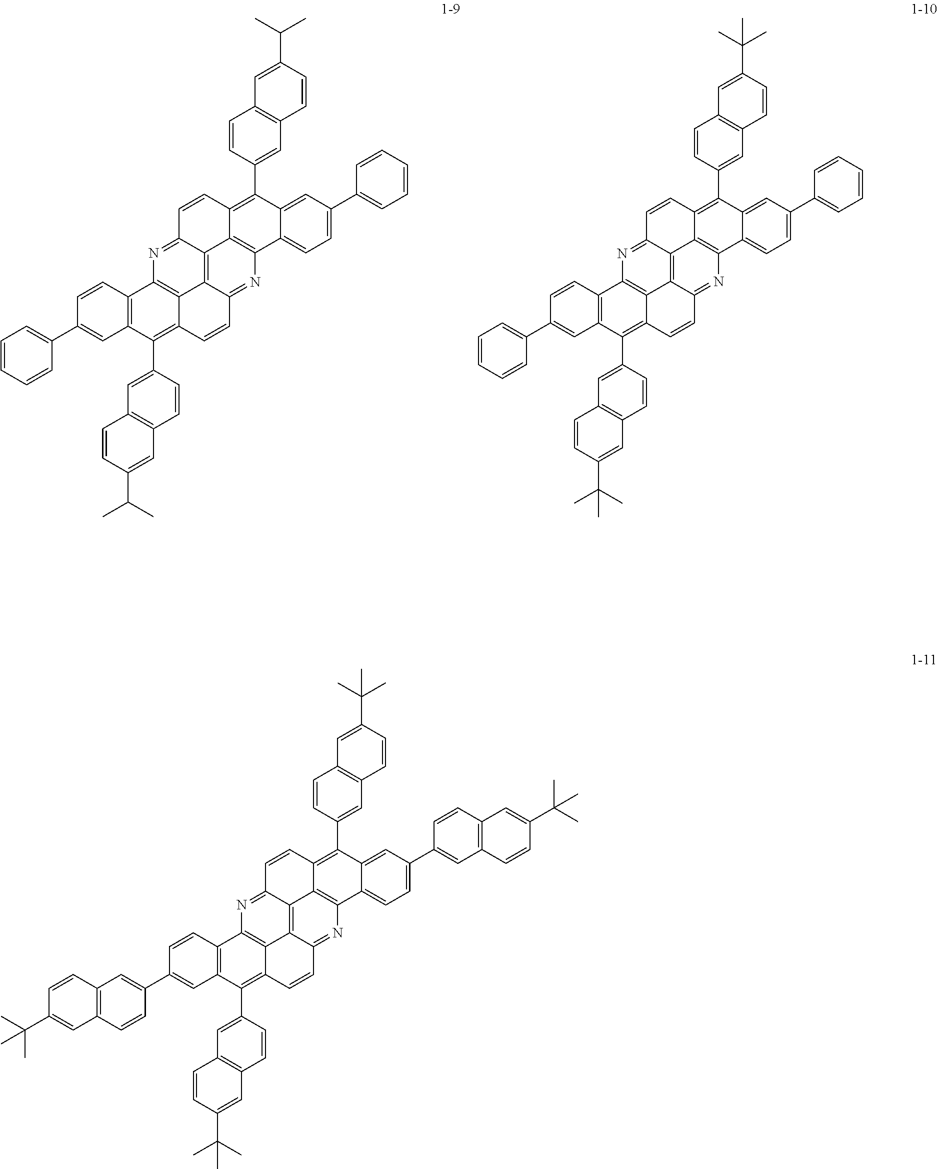 [SMILES: CC(C)c1ccc2cc(-c3c4cc(-c5ccccc5)ccc4c4nc5ccc6c(-c7ccc8cc(C(C)C)ccc8c7)c7cc(-c8ccccc8)ccc7c7nc8ccc3c4c8c5c67)ccc2c1 ; CC(C)(C)c1ccc2cc(-c3c4cc(-c5ccccc5)ccc4c4nc5ccc6c(-c7ccc8cc(C(C)(C)C)ccc8c7)c7cc(-c8ccccc8)ccc7c7nc8ccc3c4c8c5c67)ccc2c1 ; CC(C)(C)c1ccc2cc(-c3ccc4c(c3)c(-c3ccc5cc(C(C)(C)C)ccc5c3)c3ccc5nc6c7ccc(-c8ccc9cc(C(C)(C)C)ccc9c8)cc7c(-c7ccc8cc(C(C)(C)C)ccc8c7)c7ccc8nc4c3c5c8c76)ccc2c1]

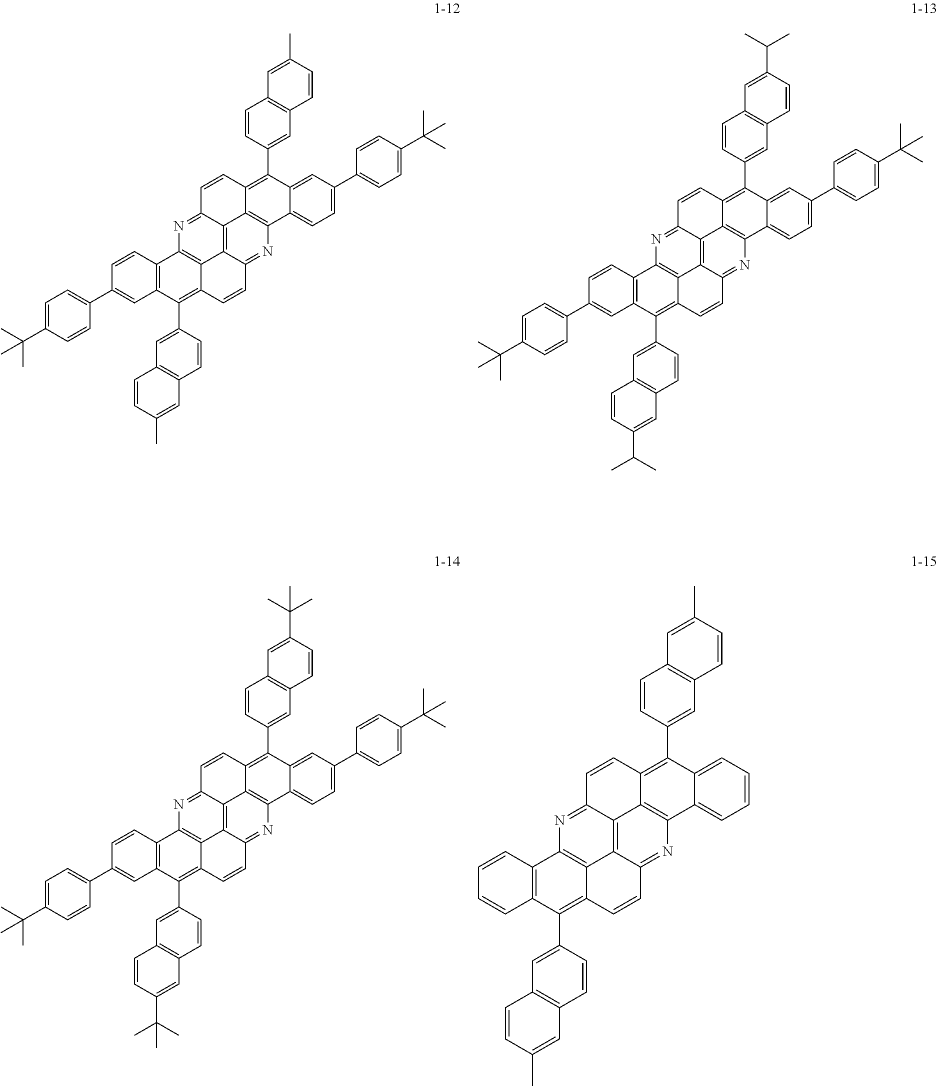 [SMILES: Cc1ccc2cc(-c3c4cc(-c5ccc(C(C)(C)C)cc5)ccc4c4nc5ccc6c(-c7ccc8cc(C)ccc8c7)c7cc(-c8ccc(C(C)(C)C)cc8)ccc7c7nc8ccc3c4c8c5c67)ccc2c1 ; CC(C)c1ccc2cc(-c3c4cc(-c5ccc(C(C)(C)C)cc5)ccc4c4nc5ccc6c(-c7ccc8cc(C(C)C)ccc8c7)c7cc(-c8ccc(C(C)(C)C)cc8)ccc7c7nc8ccc3c4c8c5c67)ccc2c1 ; CC(C)(C)c1ccc(-c2ccc3c(c2)c(-c2ccc4cc(C(C)(C)C)ccc4c2)c2ccc4nc5c6ccc(-c7ccc(C(C)(C)C)cc7)cc6c(-c6ccc7cc(C(C)(C)C)ccc7c6)c6ccc7nc3c2c4c7c65)cc1 ; Cc1ccc2cc(-c3c4ccccc4c4nc5ccc6c(-c7ccc8cc(C)ccc8c7)c7ccccc7c7nc8ccc3c4c8c5c67)ccc2c1]

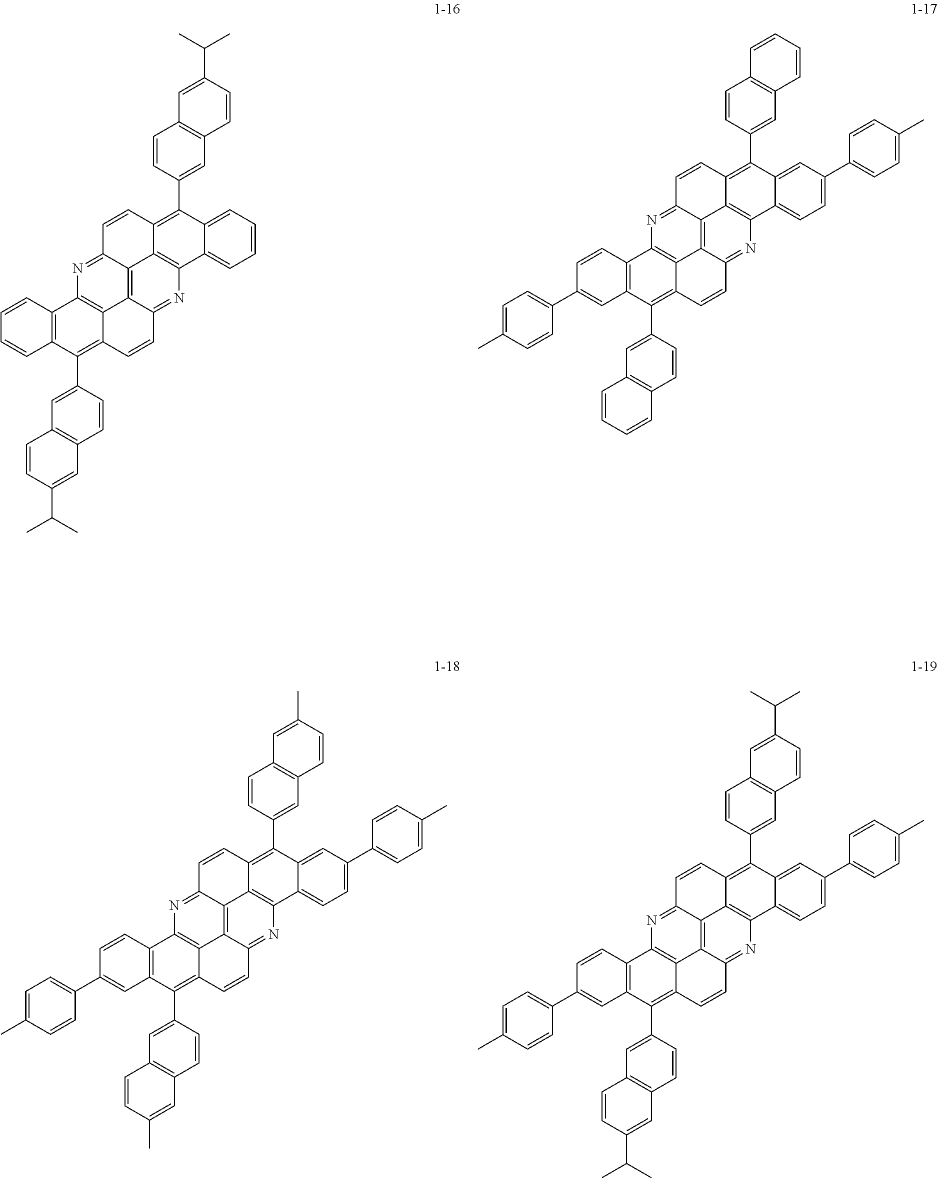

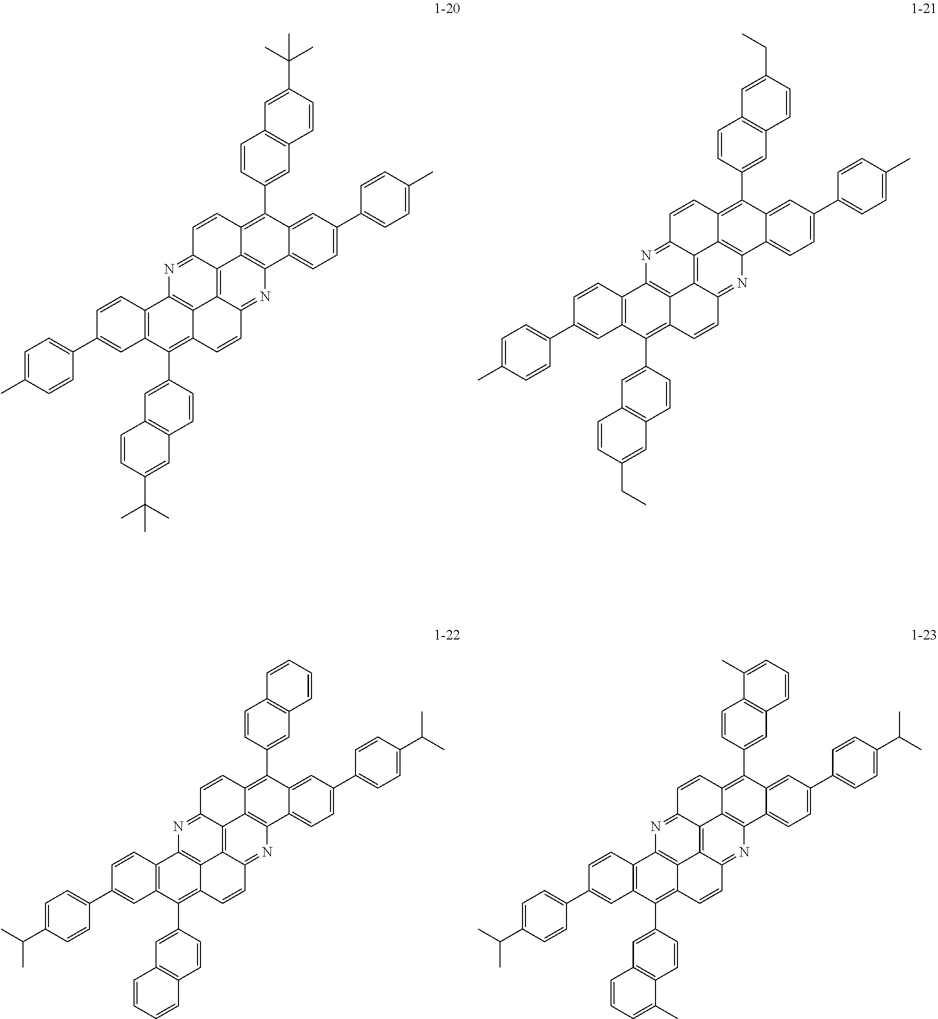

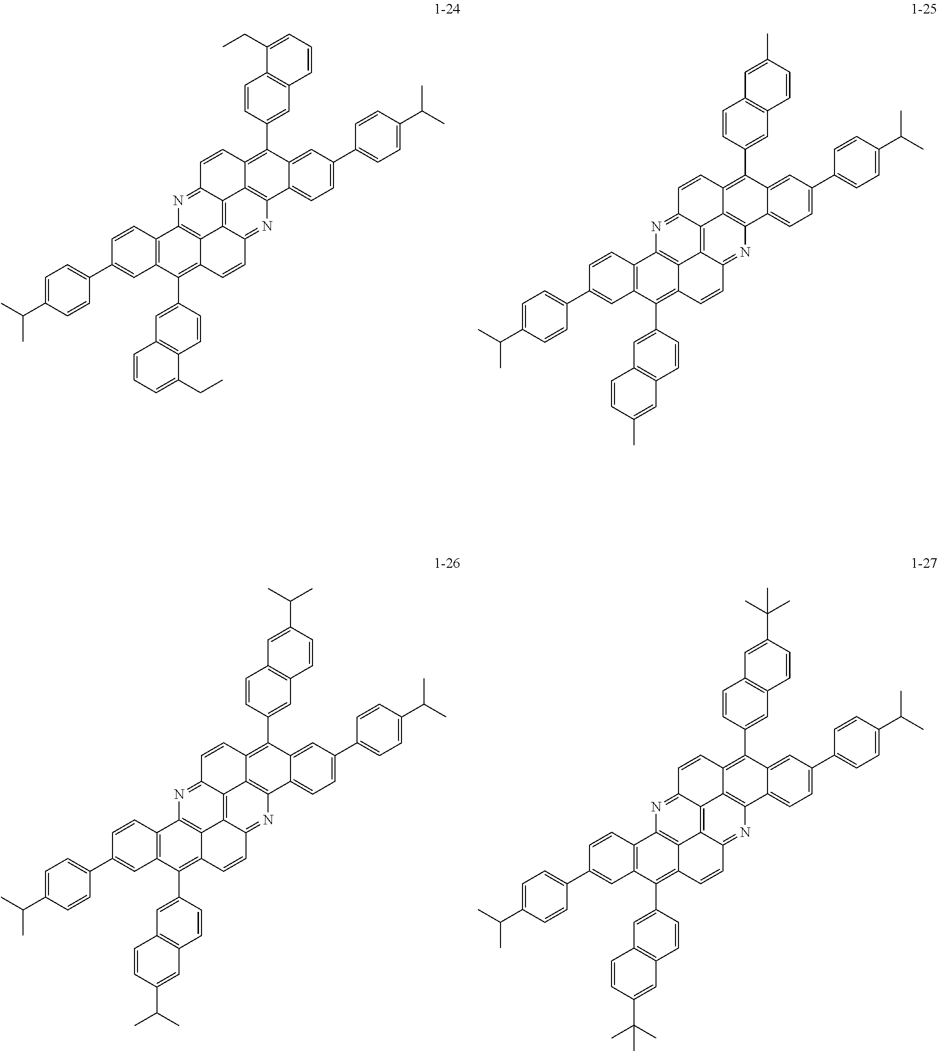

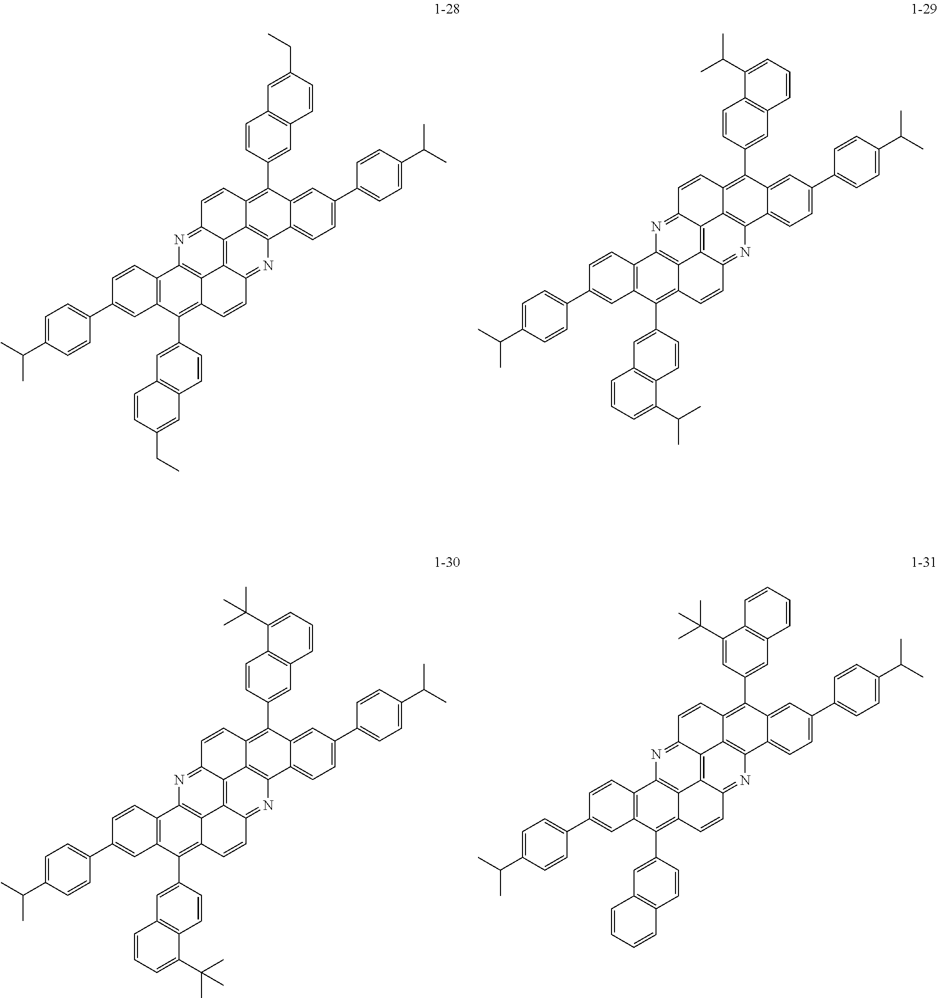

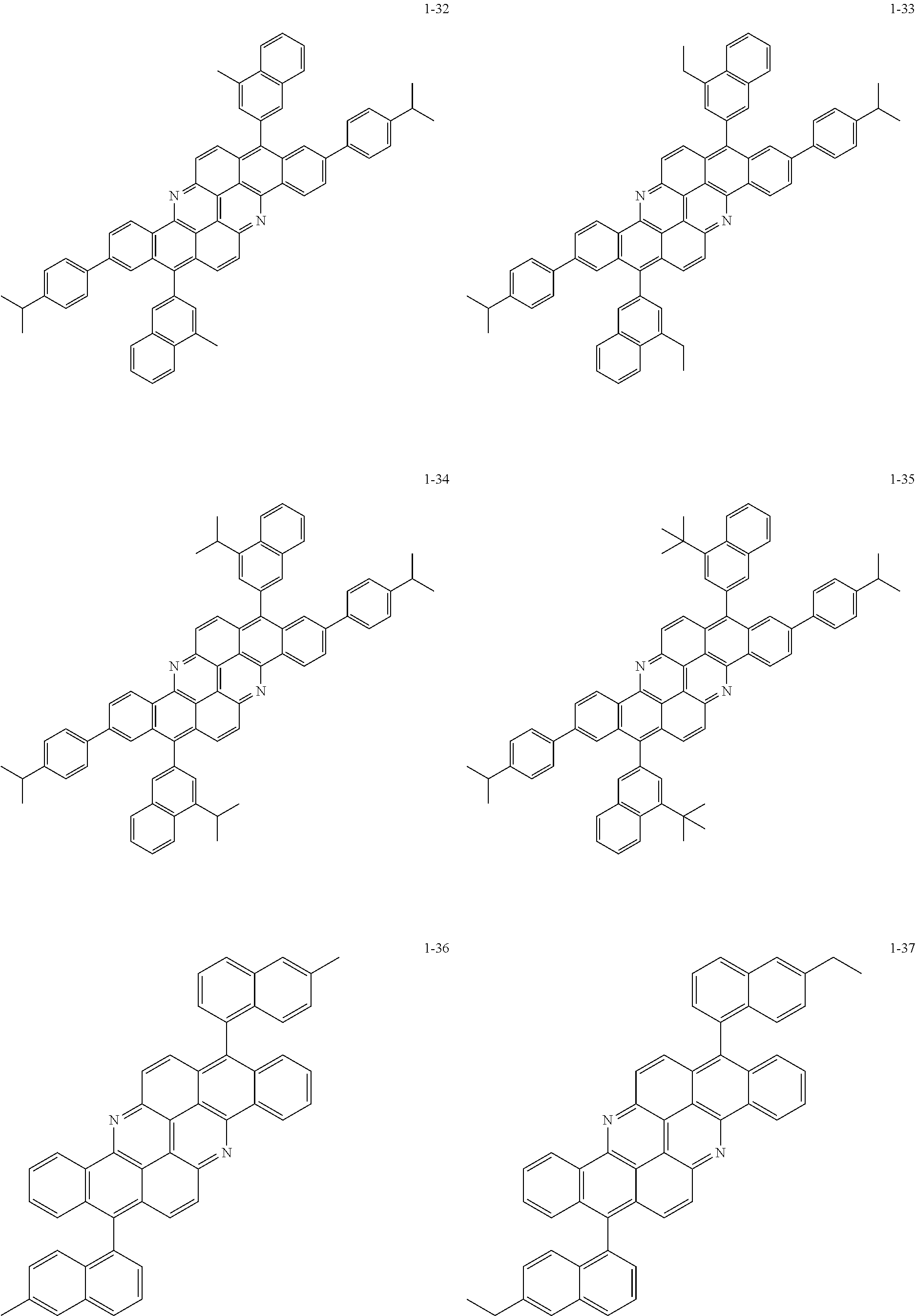

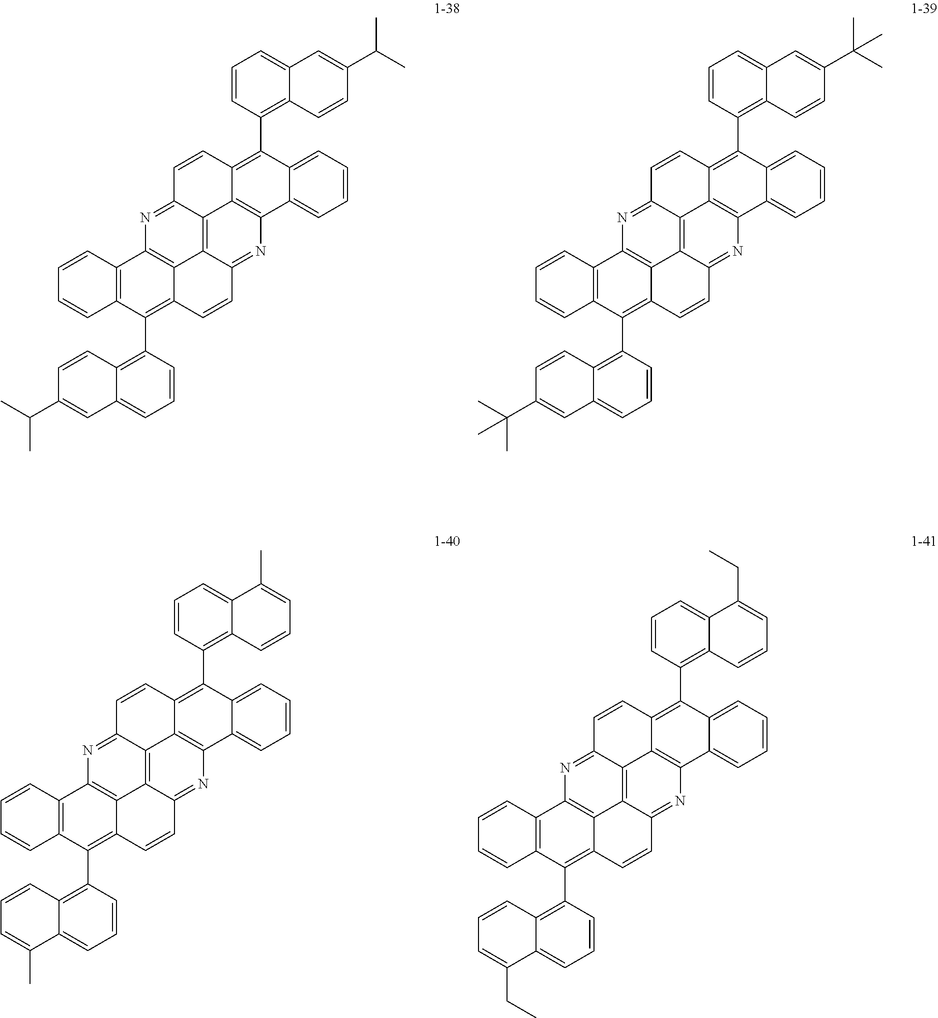 [SMILES: CC(C)c1ccc2c(-c3c4ccccc4c4nc5ccc6c(-c7cccc8cc(C(C)C)ccc78)c7ccccc7c7nc8ccc3c4c8c5c67)cccc2c1 ; CC(C)(C)c1ccc2c(-c3c4ccccc4c4nc5ccc6c(-c7cccc8cc(C(C)(C)C)ccc78)c7ccccc7c7nc8ccc3c4c8c5c67)cccc2c1 ; Cc1cccc2c(-c3c4ccccc4c4nc5ccc6c(-c7cccc8c(C)cccc78)c7ccccc7c7nc8ccc3c4c8c5c67)cccc12 ; CCc1cccc2c(-c3c4ccccc4c4nc5ccc6c(-c7cccc8c(CC)cccc78)c7ccccc7c7nc8ccc3c4c8c5c67)cccc12]

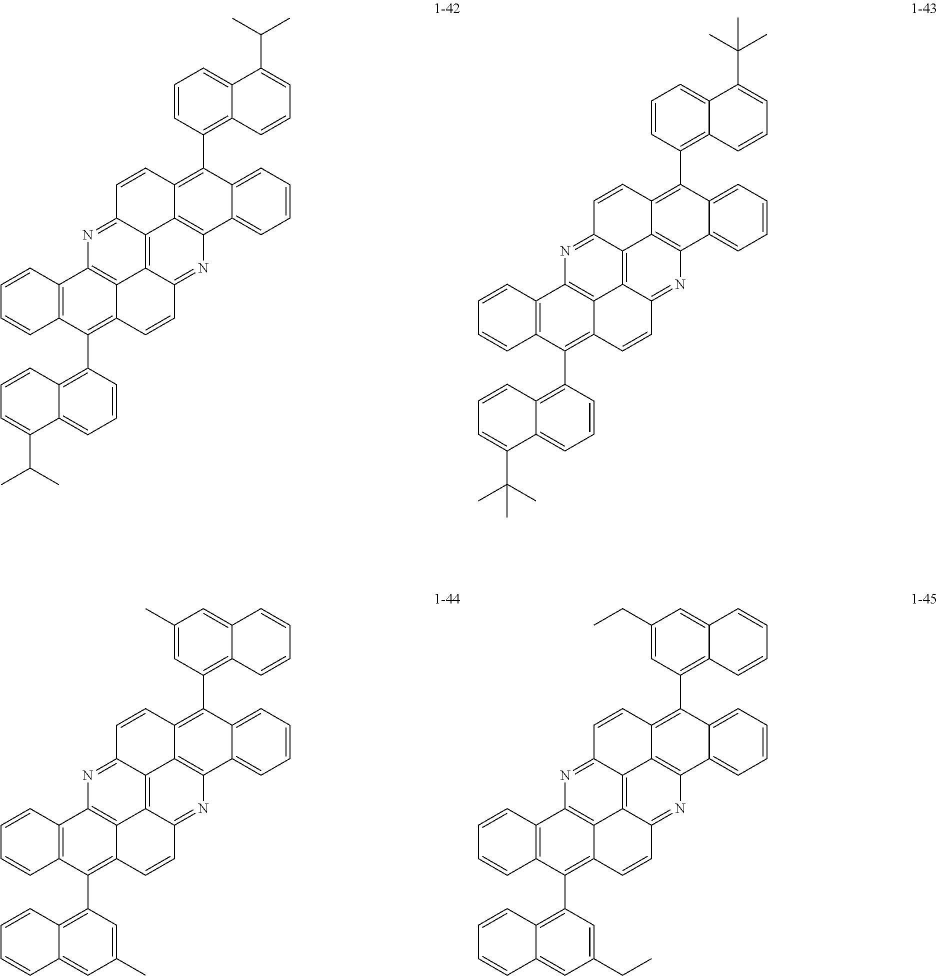 [SMILES: CC(C)c1cccc2c(-c3c4ccccc4c4nc5ccc6c(-c7cccc8c(C(C)C)cccc78)c7ccccc7c7nc8ccc3c4c8c5c67)cccc12 ; CC(C)(C)c1cccc2c(-c3c4ccccc4c4nc5ccc6c(-c7cccc8c(C(C)(C)C)cccc78)c7ccccc7c7nc8ccc3c4c8c5c67)cccc12 ; Cc1cc(-c2c3ccccc3c3nc4ccc5c(-c6cc(C)cc7ccccc67)c6ccccc6c6nc7ccc2c3c7c4c56)c2ccccc2c1 ; CCc1cc(-c2c3ccccc3c3nc4ccc5c(-c6cc(CC)cc7ccccc67)c6ccccc6c6nc7ccc2c3c7c4c56)c2ccccc2c1]

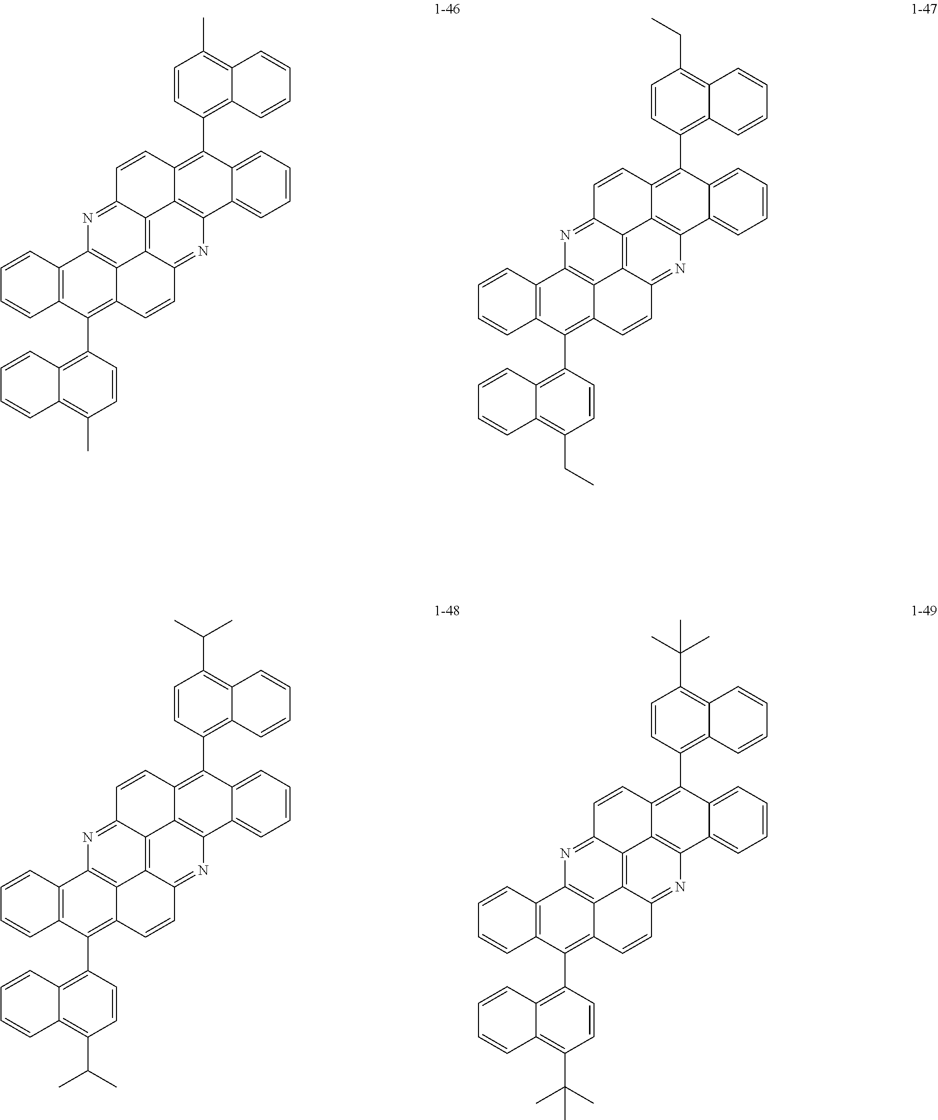 [SMILES: Cc1ccc(-c2c3ccccc3c3nc4ccc5c(-c6ccc(C)c7ccccc67)c6ccccc6c6nc7ccc2c3c7c4c56)c2ccccc12 ; CCc1ccc(-c2c3ccccc3c3nc4ccc5c(-c6ccc(CC)c7ccccc67)c6ccccc6c6nc7ccc2c3c7c4c56)c2ccccc12 ; CC(C)c1ccc(-c2c3ccccc3c3nc4ccc5c(-c6ccc(C(C)C)c7ccccc67)c6ccccc6c6nc7ccc2c3c7c4c56)c2ccccc12 ; CC(C)(C)c1ccc(-c2c3ccccc3c3nc4ccc5c(-c6ccc(C(C)(C)C)c7ccccc67)c6ccccc6c6nc7ccc2c3c7c4c56)c2ccccc12]

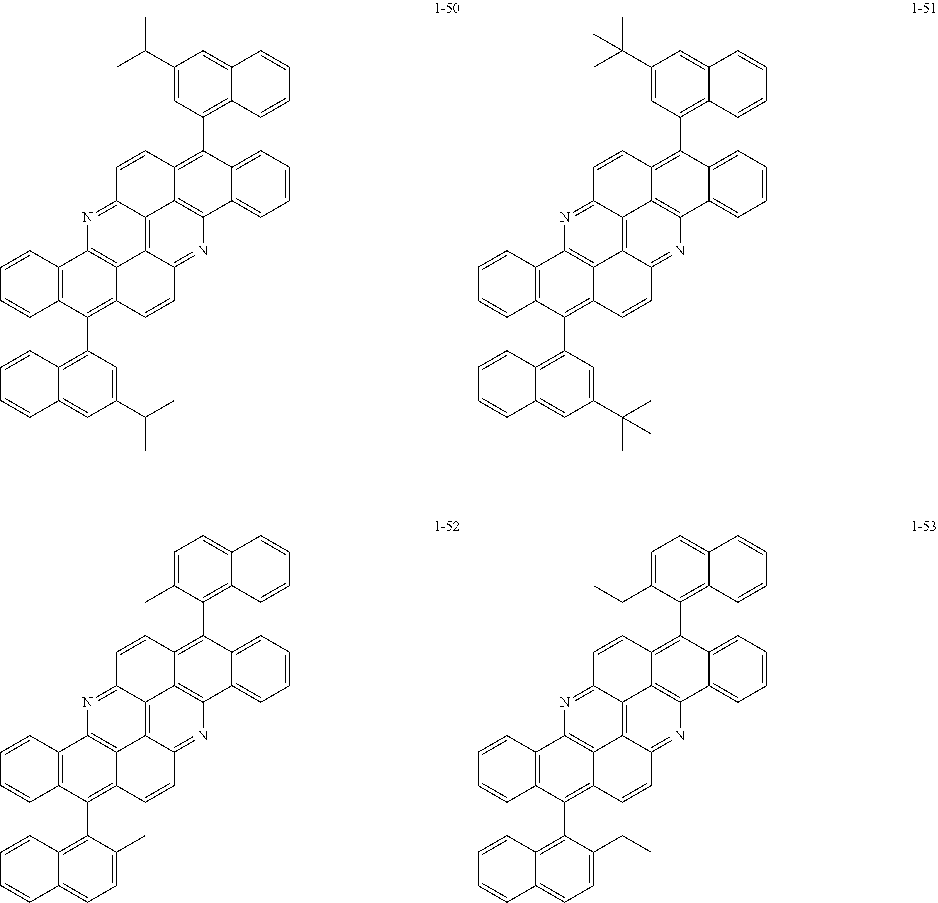 [SMILES: CC(C)c1cc(-c2c3ccccc3c3nc4ccc5c(-c6cc(C(C)C)cc7ccccc67)c6ccccc6c6nc7ccc2c3c7c4c56)c2ccccc2c1 ; CC(C)(C)c1cc(-c2c3ccccc3c3nc4ccc5c(-c6cc(C(C)(C)C)cc7ccccc67)c6ccccc6c6nc7ccc2c3c7c4c56)c2ccccc2c1 ; Cc1ccc2ccccc2c1-c1c2ccccc2c2nc3ccc4c(-c5c(C)ccc6ccccc56)c5ccccc5c5nc6ccc1c2c6c3c45 ; CCc1ccc2ccccc2c1-c1c2ccccc2c2nc3ccc4c(-c5c(CC)ccc6ccccc56)c5ccccc5c5nc6ccc1c2c6c3c45]

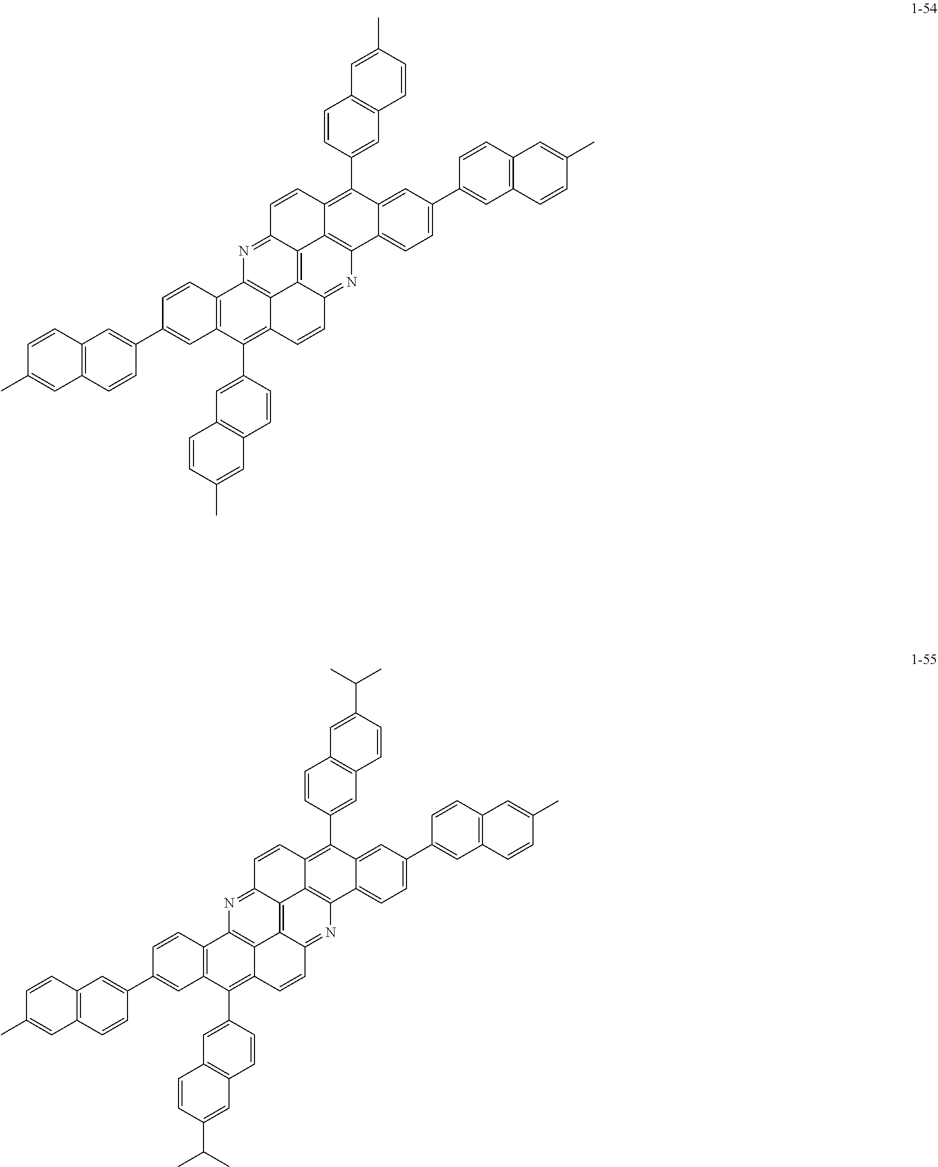

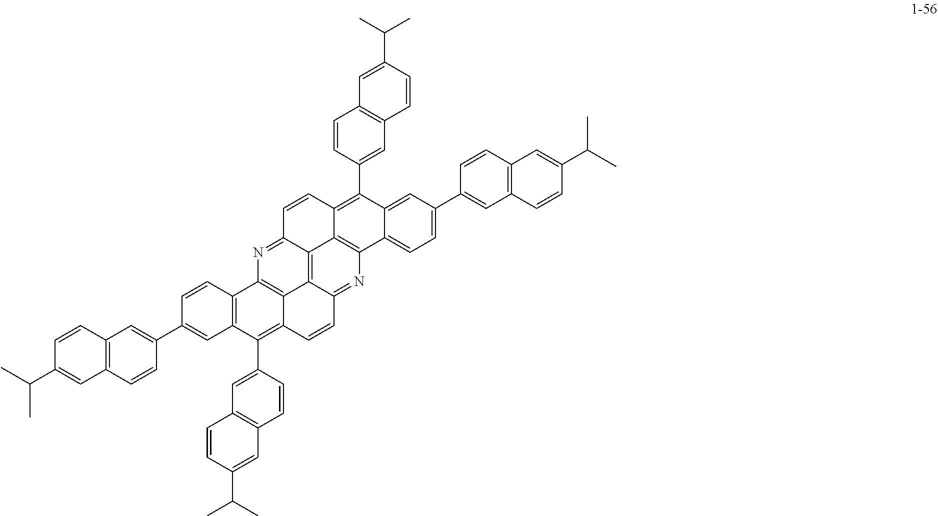 [SMILES: CC(C)c1ccc2cc(-c3ccc4c(c3)c(-c3ccc5cc(C(C)C)ccc5c3)c3ccc5nc6c7ccc(-c8ccc9cc(C(C)C)ccc9c8)cc7c(-c7ccc8cc(C(C)C)ccc8c7)c7ccc8nc4c3c5c8c76)ccc2c1]

The first compound 342 having the structure of Chemical Formulae 1 to 3 comprises fused ring system of multiple aromatic or heteroaromatic rings to have a wide plate-like structure. The singlet exciton energy of the second compound 344 may be transferred efficiently to the singlet exciton of the first compound 342 having the structure of Chemical Formulae 1 to 3. The OLED D1 may realize beneficial luminous efficiency, luminous lifespan and color purity by introducing the first compound having the structure of Chemical Formulae 1 to 3 into the EML 340.

Energy levels of the first compound 342 and the second compound 344 may be controlled in order to transfer efficiently exciton energy generated at the second compound 344 to the first compound 342. FIG. 4 illustrates a schematic diagram where exciplex between the first compound (FD) and the host (NH′) is generated when the energy level between the first compound and the host is not matched. The first compound 342 having the structure of Chemical Formulae 1 to 3 has lowest unoccupied molecular orbital (LUMO) energy level between about −3.3 eV and about −3.6 eV and highest occupied molecular orbital (HOMO) energy level between about −5.7 eV and about −6.0 eV. When the LUMO energy level of the host NH′ is too high compared to the LUMO energy level of the first compound 342 (FD), electron traps may occur in transferring excitons from the host NH′ to the first compound 342 (FD) because the first compound 342 (FD) has relatively low LUMO energy level. In this case, the driving voltage of the OLED D1 may be raised and the luminous efficiency of the OLED D1 may be reduced.

The N-type host NH′ with relatively weak electron donor property has very high LUMO energy level compared to the LUMO energy level of the first compound 342 (FD). As illustrated in FIG. 4, the excitons of relatively low LUMO state in the first compound 342 (FD) and the excitons of relatively high HOMO state in the N-type host NH′ with relatively weak electron donor property are combined to generate exciplex. In addition, the energy bandgap ΔEG1 between the HOMO energy level of the first compound 342 (FD) and the HOMO energy level of the N-type host NH′ with relatively weak electron donor property may be relatively large. In this case, the luminous efficiency of the organic light emitting diode may be reduced.

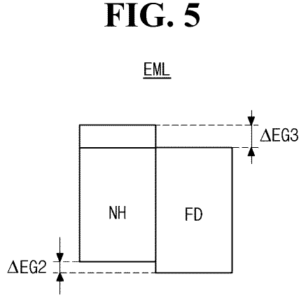

FIG. 5 illustrates a schematic diagram where no exciplex between the first compound (FD) and the host (NH) is generated and exciton energy is transferred to the first compound from the host when the energy level between the first compound and the host is matched. The N-type host 344 (second compound 344, NH) with strong electron donor property has relatively low LUMO energy level. No exciplex between the first compound 342 (FD) and the second compound 344 (NH) is generated, the exciton generated at the second compound 344 (NH) may be transferred efficiently to the first compound 342 (FD) through energy transfer mechanism so that the first compound 342 (FD) may emit light efficiently.

In addition, excitons may be transferred efficiently to the first compound 342 (FD) from the second compound 344 (NH) by designing energy bandgap ΔEG2 between the HOMO energy level of the second compound 344 (NH) with relatively strong electron donor property and the HOMO energy level of the first compound 342 (FD) and/or energy bandgap ΔEG3 between the LUMO energy level of the second compound 344 (NH) and the LUMO energy level of the first compound 342 (FD) to be small.

In one example embodiment, the energy bandgap ΔEG2 between the HOMO energy level of the second compound 344 (NH) and the HOMO energy level of the first compound 342 (FD) may be, but is not limited to, less than about 0.2 eV, for example, less than about 0.1 eV. In addition, the energy bandgap ΔEG3 between the LUMO energy level of the second compound 344 (NH) and the LUMO energy level of the first compound 342 (FD) may be, but is not limited to, less than about 0.4 eV, for example, less than about 0.3 eV.

As an example, the second compound 344 (NH) may have, but is not limited to, LUMO energy level between about −3.0 eV and about −3.5 eV, for example, about −3.1 eV and about −3.4 eV. The second compound 344 (NH) may have, but is not limited to, HOMO energy level between about −5.6 eV and about −6.0 eV, for example, about −5.7 eV and −6.0 eV. In addition, the energy bandgap between the HOMO energy level and the LUMO energy level of the second compound 344 (NH) may be, but is not limited to, between about 2.0 eV and about 3.0 eV, for example, about 2.3 eV and about 2.8 eV.

In an example embodiment illustrated in FIG. 3, the second compound 344 may be an N-type host (electron-type host) with relatively advantageous electron affinity. For example, the second compound 344 may comprise an azine-based (e.g., pyrimidine-based) organic compound. In some embodiments, the second compound 344 may comprise an organic compound having the following structure of Chemical Formula 4:

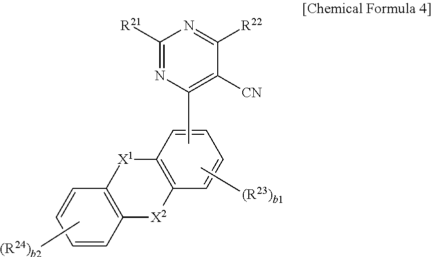

wherein, in the Chemical Formula 4,
one of X¹ and X² is a single bond and the other of X¹ and X² is NR^{A}, O or S;
each of R²¹, R²², R²³, R²⁴, and R^{A} is independently an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ heteroaryl group, an unsubstituted or substituted C₆-C₃₀ aryl amino group or an unsubstituted or substituted C₃-C₃₀ heteroaryl amino group, where each R²³ is identical to or different from each other when b1 is 2 or 3 and each R²⁴ is identical to or different from each other when b2 is 2, 3 or 4, or
optionally, two adjacent R²³ when b1 is 2 or 3 and/or two adjacent R²⁴ when b2 is 2, 3 or 4 are linked together to form an unsubstituted or substituted C₆-C₂₀ aromatic ring or an unsubstituted or substituted C₃-C₂₀ heteroaromatic ring;
b1 is 0, 1, 2 or 3; and
b2 is 0, 1, 2, 3 or 4.

For example, each of R²¹ and R²² in Chemical Formula 4 may be independently an unsubstituted or substituted C₆-C₃₀ aryl group (e.g., phenyl or naphthyl). Two adjacent R²⁴ and/or two adjacent R²⁵ in Chemical Formula 4 may be independently linked together to form an indene ring, an indole ring, a benzofuran ring and/or a benzothiophene ring each of which is independently unsubstituted or substituted with a C₆-C₃₀ aryl group (e.g., phenyl), and each of b1 and b2 in Chemical Formula 4 may be independently 0, 1 or 2. In addition, R^{A} constituting X¹ or X² in Chemical Formula 4 may be a C₁-C₁₀ alkyl-substituted C₆-C₃₀ aryl group (e.g., phenyl).

As an example, R²¹ may be unsubstituted or substituted phenyl and R²² may be unsubstituted or substituted naphthyl in Chemical Formula 4. The second compound 344 with such a structure may comprise an organic compound having the following structure of Chemical Formula 5:

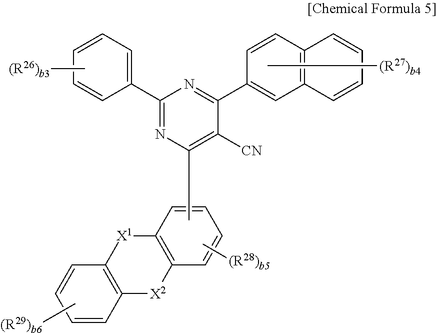

wherein, in the Chemical Formula 5,
each of X1 and X2 is identical as defined in Chemical Formula 4;
each of R²⁶, R²⁷, R²⁸, and R²⁹ is independently an unsubstituted or substituted C₆-C₃₀ aryl group or an unsubstituted or substituted C₃-C₃₀ heteroaryl group, where each R²⁶ is identical to or different from each other when b3 is 2, 3 or 4, each R²⁷ is identical to or different from each other when b4 is 2, 3, 4, 5, 6 or 7, each R²⁸ is identical to or different from each other when b5 is 2 or 3 and each R²⁹ is identical to or different from each other when b6 is 2, 3 or 4, or
optionally, two adjacent R²⁶ when b3 is 2, 3, 4 or 5, two adjacent R²⁷ when b4 is 2, 3, 4, 5, 6 or 7, two adjacent R²⁸ when b5 is 2 or 3 and/or two adjacent R²⁹ when b6 is 2, 3 or 4 are linked together to form a heteroaromatic ring having the following structure of Chemical Formula 6; and
dotted line indicate a portion where a ring of Chemical Formula 6 may be fused,

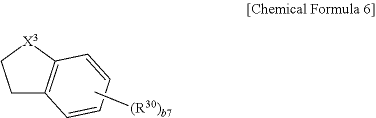

wherein, in the Chemical Formula 6,
X³ is NR^{B}, O or S;
R^{B} is hydrogen, an unsubstituted or substituted C₁-C₂₀ alkyl group, an unsubstituted or substituted C₆-C₃₀ aryl group or an unsubstituted or substituted C₃-C₃₀ heteroaryl group;
R³⁰ is an unsubstituted or substituted C₁-C₂₀ alkyl group, an unsubstituted or substituted C₁-C₂₀ alkyl amino group, an unsubstituted or substituted C₆-C₃₀ aryl group or an unsubstituted or substituted C₃-C₃₀ heteroaryl group, where each R³⁰ is identical to or different from each other when b7 is 2, 3 or 4;
b7 is 0, 1, 2, 3 or 4; and
dotted line indicate a portion fused to the dotted line in Chemical Formula 5.

For example, each of b3 and b4 in Chemical Formula 5 may be 0. Alternatively, one of b5 and b6 may be 0 and the other of b5 and b6 may be 2 in Chemical Formula 5. In this case, two adjacent R²⁸ and/or two adjacent R²⁹ in Chemical Formula 5 may be linked together to form a fused ring of Chemical Formula 6. Alternatively, R^{B} constituting X³ in Chemical 6 may be an unsubstituted or substituted C₆-C₃₀ aryl group (e.g. phenyl) and b7 may be 0.

In some embodiments, the second compound 344 may be, but is not limited to, at least one of the following compounds of Chemical Formula 7:

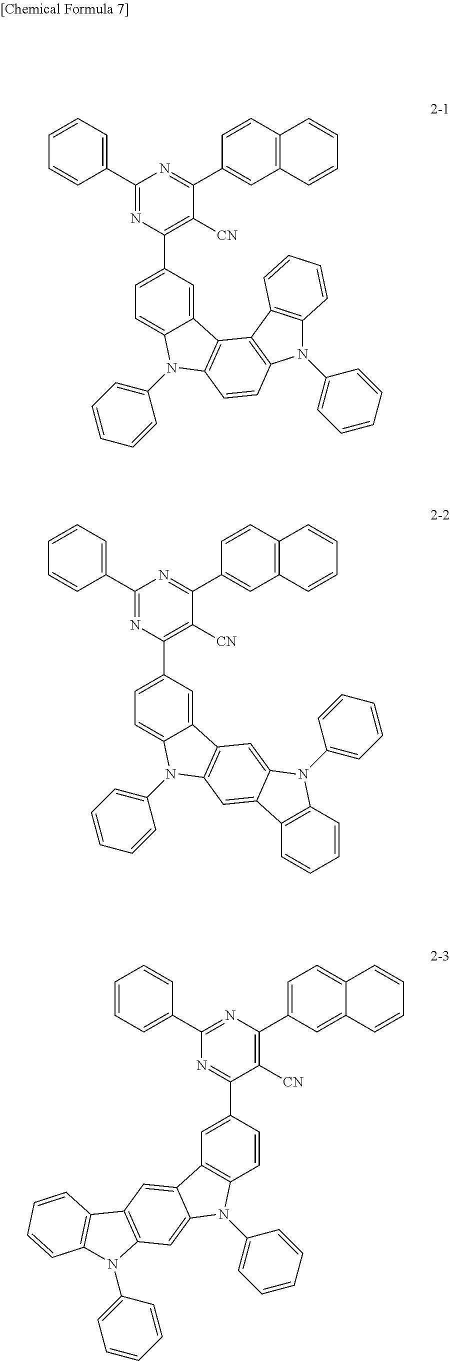 [SMILES: N#Cc1c(-c2ccc3ccccc3c2)nc(-c2ccccc2)nc1-c1ccc2c(c1)c1c3c4ccccc4n(-c4ccccc4)c3ccc1n2-c1ccccc1 ; N#Cc1c(-c2ccc3ccccc3c2)nc(-c2ccccc2)nc1-c1ccc2c(c1)c1cc3c(cc1n2-c1ccccc1)c1ccccc1n3-c1ccccc1 ; N#Cc1c(-c2ccc3ccccc3c2)nc(-c2ccccc2)nc1-c1ccc2c(c1)c1cc3c4ccccc4n(-c4ccccc4)c3cc1n2-c1ccccc1]

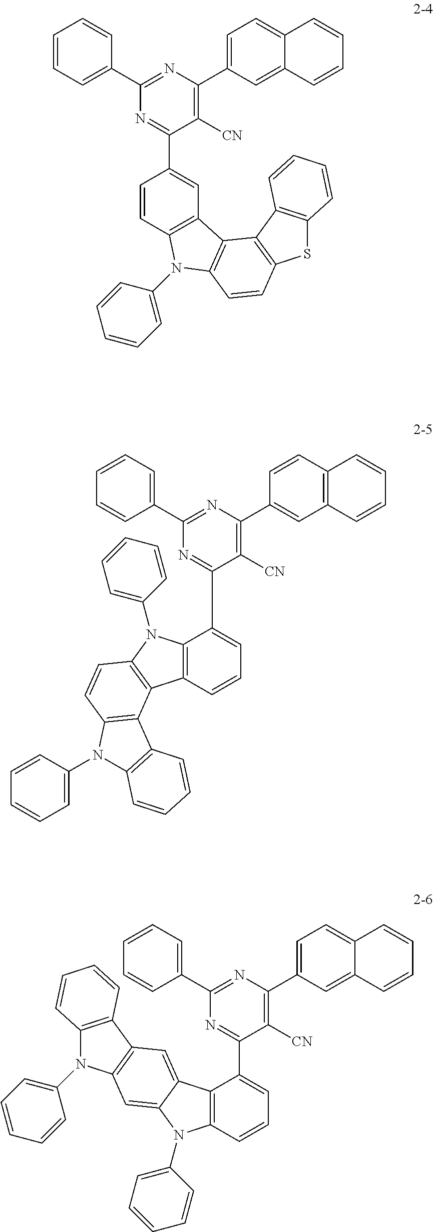 [SMILES: N#Cc1c(-c2ccc3ccccc3c2)nc(-c2ccccc2)nc1-c1ccc2c(c1)c1c3c(ccc1n2-c1ccccc1)sc1ccccc13 ; N#Cc1c(-c2ccc3ccccc3c2)nc(-c2ccccc2)nc1-c1cccc2c3c4c5ccccc5n(-c5ccccc5)c4ccc3n(-c3ccccc3)c12 ; N#Cc1c(-c2ccc3ccccc3c2)nc(-c2ccccc2)nc1-c1cccc2c1c1cc3c4ccccc4n(-c4ccccc4)c3cc1n2-c1ccccc1]

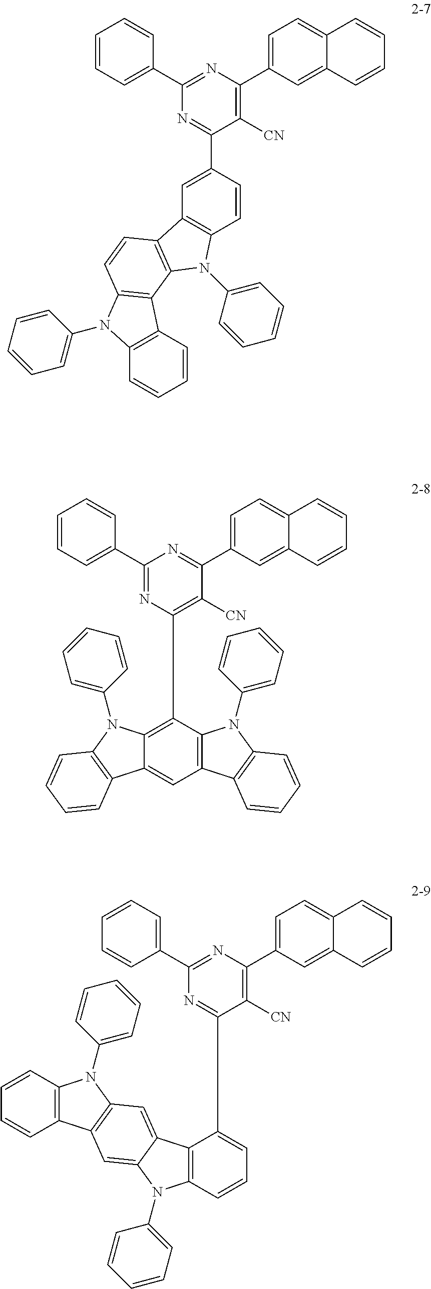 [SMILES: N#Cc1c(-c2ccc3ccccc3c2)nc(-c2ccccc2)nc1-c1ccc2c(c1)c1ccc3c(c4ccccc4n3-c3ccccc3)c1n2-c1ccccc1 ; N#Cc1c(-c2ccc3ccccc3c2)nc(-c2ccccc2)nc1-c1c2c(cc3c4ccccc4n(-c4ccccc4)c13)c1ccccc1n2-c1ccccc1 ; N#Cc1c(-c2ccc3ccccc3c2)nc(-c2ccccc2)nc1-c1cccc2c1c1cc3c(cc1n2-c1ccccc1)c1ccccc1n3-c1ccccc1]

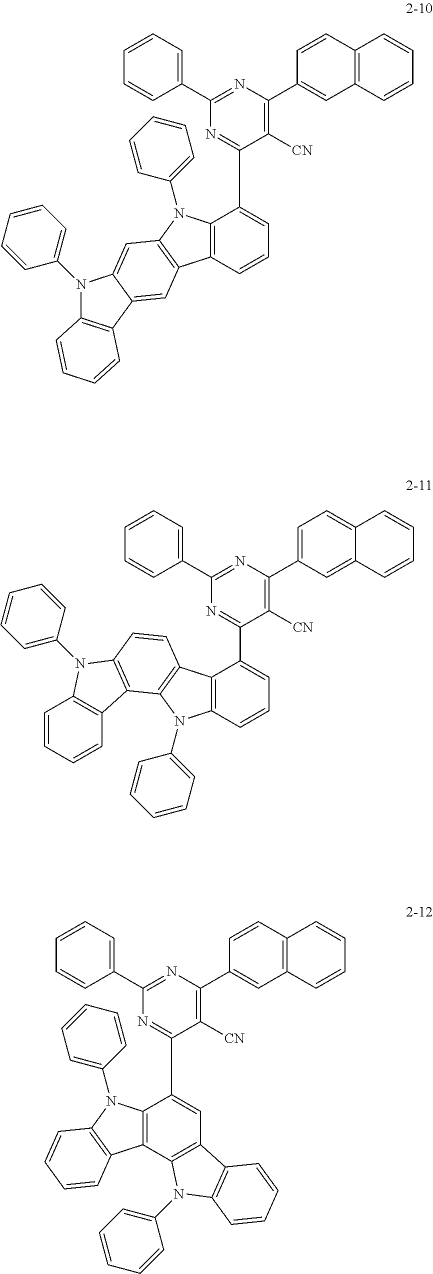 [SMILES: N#Cc1c(-c2ccc3ccccc3c2)nc(-c2ccccc2)nc1-c1cccc2c3cc4c5ccccc5n(-c5ccccc5)c4cc3n(-c3ccccc3)c12 ; N#Cc1c(-c2ccc3ccccc3c2)nc(-c2ccccc2)nc1-c1cccc2c1c1ccc3c(c4ccccc4n3-c3ccccc3)c1n2-c1ccccc1 ; N#Cc1c(-c2ccc3ccccc3c2)nc(-c2ccccc2)nc1-c1cc2c3ccccc3n(-c3ccccc3)c2c2c3ccccc3n(-c3ccccc3)c12]

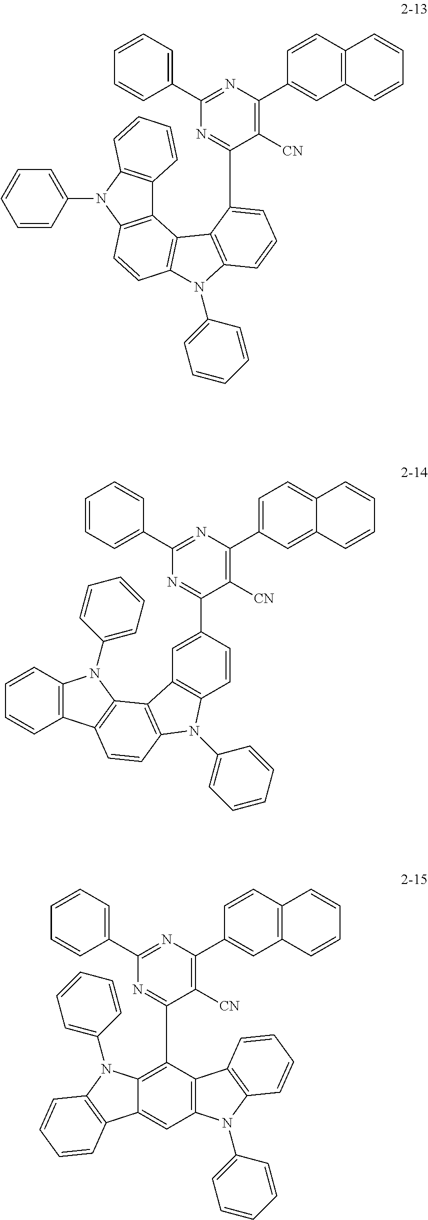 [SMILES: N#Cc1c(-c2ccc3ccccc3c2)nc(-c2ccccc2)nc1-c1cccc2c1c1c3c4ccccc4n(-c4ccccc4)c3ccc1n2-c1ccccc1 ; N#Cc1c(-c2ccc3ccccc3c2)nc(-c2ccccc2)nc1-c1ccc2c(c1)c1c(ccc3c4ccccc4n(-c4ccccc4)c31)n2-c1ccccc1 ; N#Cc1c(-c2ccc3ccccc3c2)nc(-c2ccccc2)nc1-c1c2c3ccccc3n(-c3ccccc3)c2cc2c3ccccc3n(-c3ccccc3)c12]

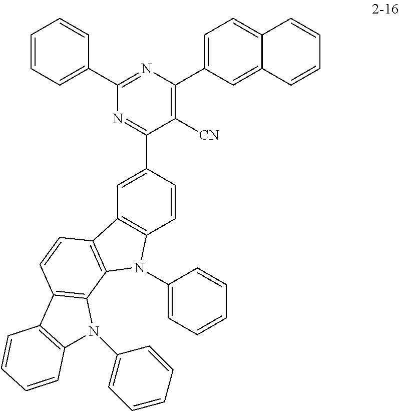 [SMILES: N#Cc1c(-c2ccc3ccccc3c2)nc(-c2ccccc2)nc1-c1ccc2c(c1)c1ccc3c4ccccc4n(-c4ccccc4)c3c1n2-c1ccccc1]

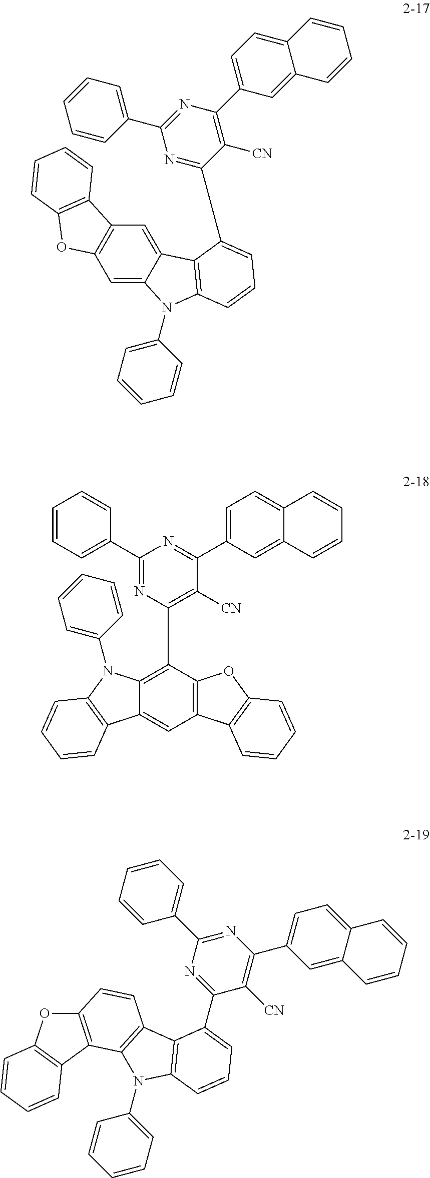 [SMILES: N#Cc1c(-c2ccc3ccccc3c2)nc(-c2ccccc2)nc1-c1cccc2c1c1cc3c(cc1n2-c1ccccc1)oc1ccccc13 ; N#Cc1c(-c2ccc3ccccc3c2)nc(-c2ccccc2)nc1-c1c2oc3ccccc3c2cc2c3ccccc3n(-c3ccccc3)c12 ; N#Cc1c(-c2ccc3ccccc3c2)nc(-c2ccccc2)nc1-c1cccc2c1c1ccc3oc4ccccc4c3c1n2-c1ccccc1]

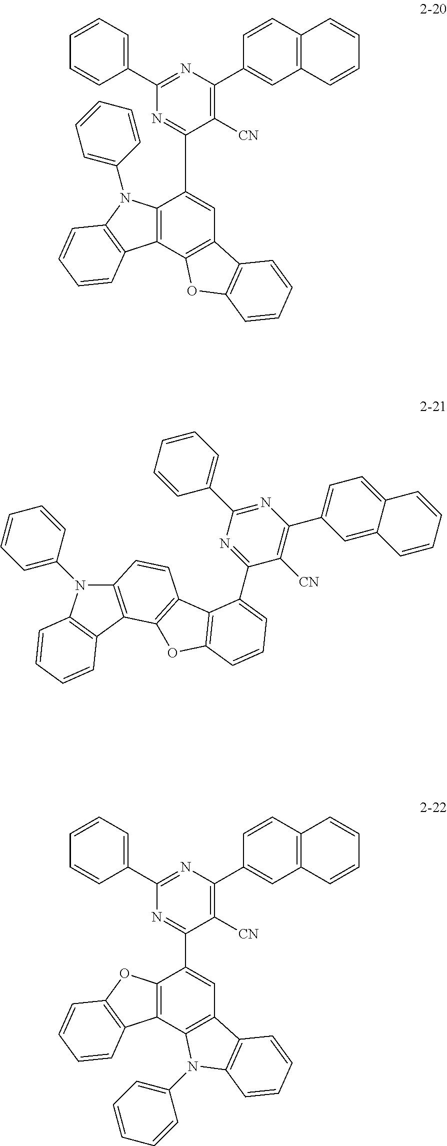 [SMILES: N#Cc1c(-c2ccc3ccccc3c2)nc(-c2ccccc2)nc1-c1cc2c3ccccc3oc2c2c3ccccc3n(-c3ccccc3)c12 ; N#Cc1c(-c2ccc3ccccc3c2)nc(-c2ccccc2)nc1-c1cccc2oc3c(ccc4c3c3ccccc3n4-c3ccccc3)c12 ; N#Cc1c(-c2ccc3ccccc3c2)nc(-c2ccccc2)nc1-c1cc2c3ccccc3n(-c3ccccc3)c2c2c1oc1ccccc12]

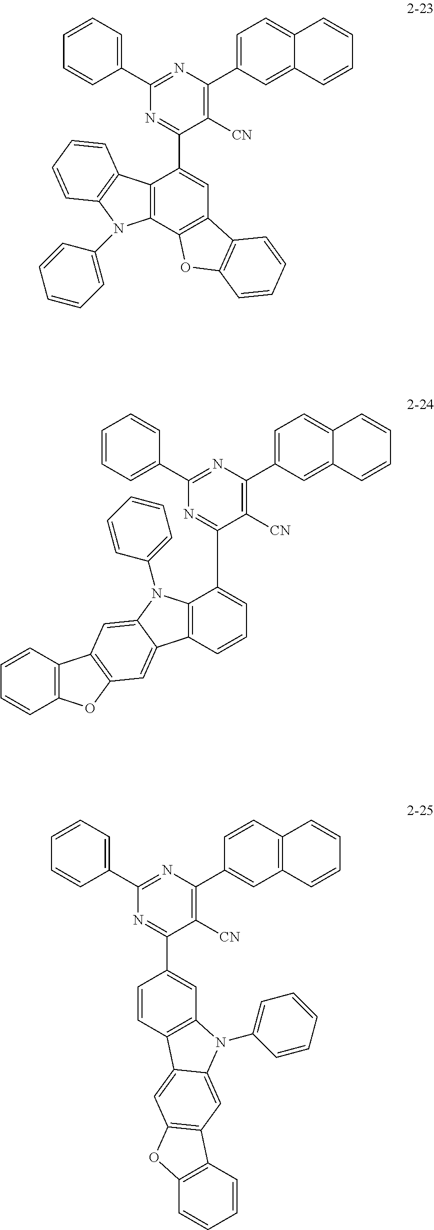 [SMILES: N#Cc1c(-c2ccc3ccccc3c2)nc(-c2ccccc2)nc1-c1cc2c3ccccc3oc2c2c1c1ccccc1n2-c1ccccc1 ; N#Cc1c(-c2ccc3ccccc3c2)nc(-c2ccccc2)nc1-c1cccc2c3cc4oc5ccccc5c4cc3n(-c3ccccc3)c12 ; N#Cc1c(-c2ccc3ccccc3c2)nc(-c2ccccc2)nc1-c1ccc2c3cc4oc5ccccc5c4cc3n(-c3ccccc3)c2c1]

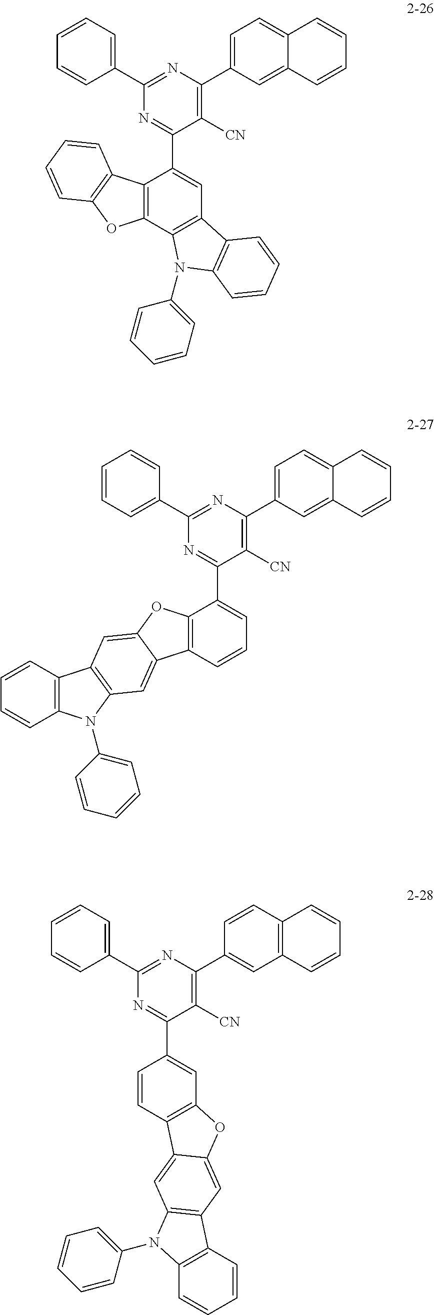 [SMILES: N#Cc1c(-c2ccc3ccccc3c2)nc(-c2ccccc2)nc1-c1cc2c3ccccc3n(-c3ccccc3)c2c2oc3ccccc3c12 ; N#Cc1c(-c2ccc3ccccc3c2)nc(-c2ccccc2)nc1-c1cccc2c1oc1cc3c4ccccc4n(-c4ccccc4)c3cc12 ; N#Cc1c(-c2ccc3ccccc3c2)nc(-c2ccccc2)nc1-c1ccc2c(c1)oc1cc3c4ccccc4n(-c4ccccc4)c3cc12]

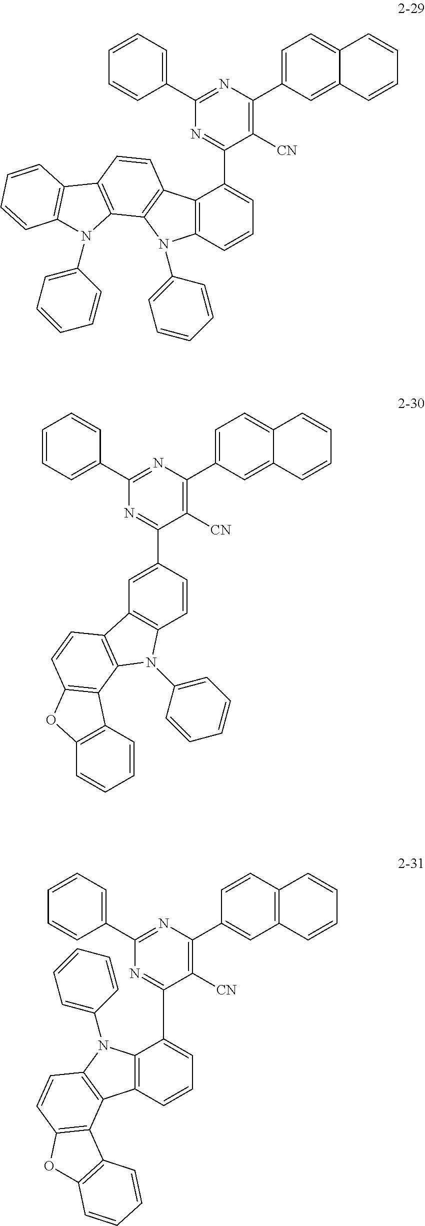 [SMILES: N#Cc1c(-c2ccc3ccccc3c2)nc(-c2ccccc2)nc1-c1cccc2c1c1ccc3c4ccccc4n(-c4ccccc4)c3c1n2-c1ccccc1 ; N#Cc1c(-c2ccc3ccccc3c2)nc(-c2ccccc2)nc1-c1ccc2c(c1)c1ccc3oc4ccccc4c3c1n2-c1ccccc1 ; N#Cc1c(-c2ccc3ccccc3c2)nc(-c2ccccc2)nc1-c1cccc2c3c4c(ccc3n(-c3ccccc3)c12)oc1ccccc14]

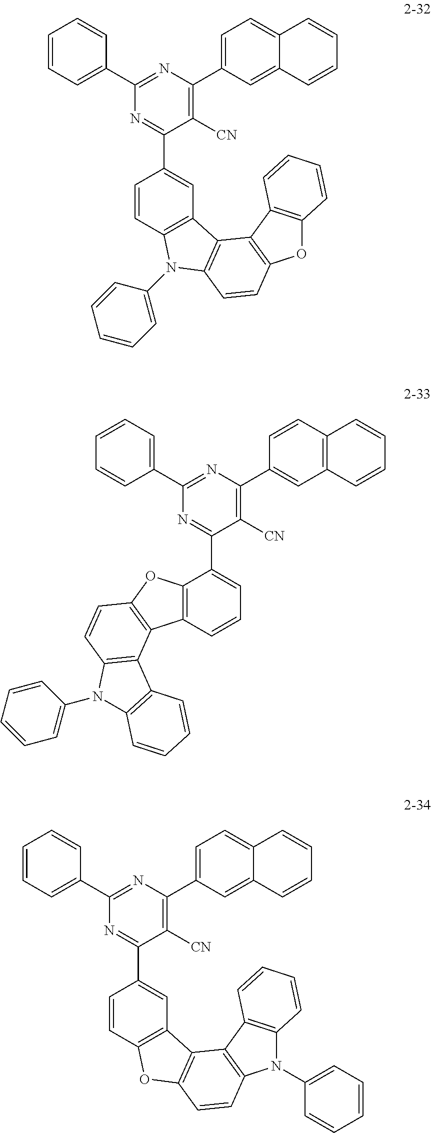 [SMILES: N#Cc1c(-c2ccc3ccccc3c2)nc(-c2ccccc2)nc1-c1ccc2c(c1)c1c3c(ccc1n2-c1ccccc1)oc1ccccc13 ; N#Cc1c(-c2ccc3ccccc3c2)nc(-c2ccccc2)nc1-c1cccc2c1oc1ccc3c(c4ccccc4n3-c3ccccc3)c12 ; N#Cc1c(-c2ccc3ccccc3c2)nc(-c2ccccc2)nc1-c1ccc2oc3ccc4c(c5ccccc5n4-c4ccccc4)c3c2c1]

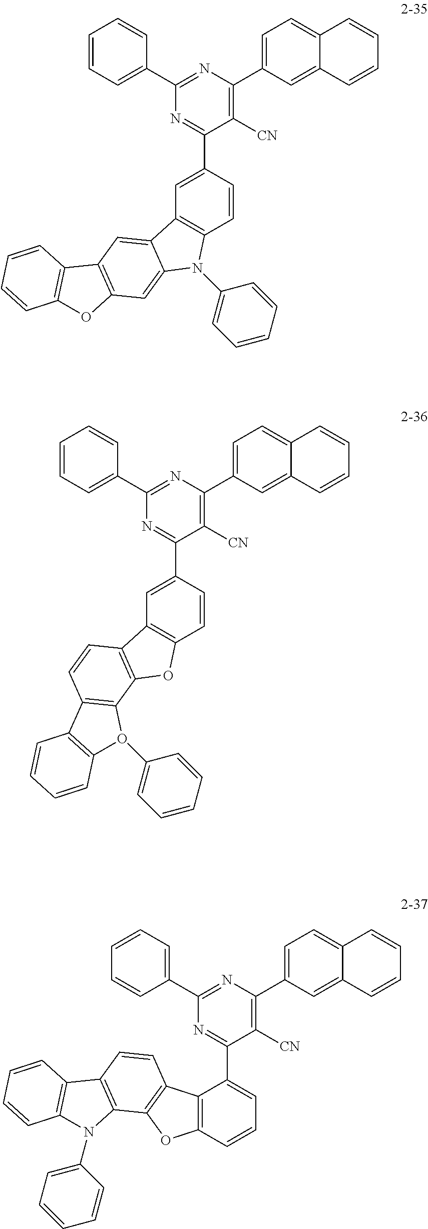

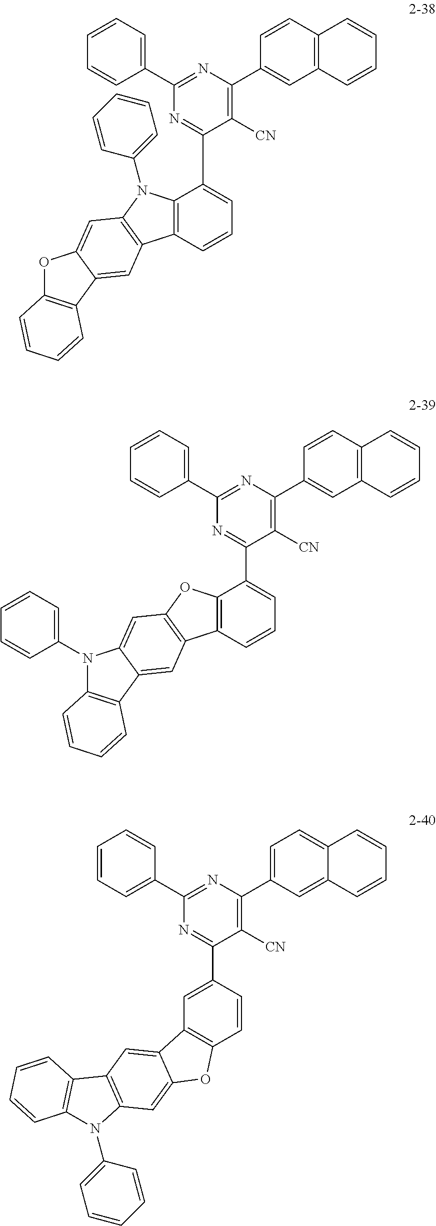 [SMILES: N#Cc1c(-c2ccc3ccccc3c2)nc(-c2ccccc2)nc1-c1cccc2c3cc4c(cc3n(-c3ccccc3)c12)oc1ccccc14 ; N#Cc1c(-c2ccc3ccccc3c2)nc(-c2ccccc2)nc1-c1cccc2c1oc1cc3c(cc12)c1ccccc1n3-c1ccccc1 ; N#Cc1c(-c2ccc3ccccc3c2)nc(-c2ccccc2)nc1-c1ccc2oc3cc4c(cc3c2c1)c1ccccc1n4-c1ccccc1]

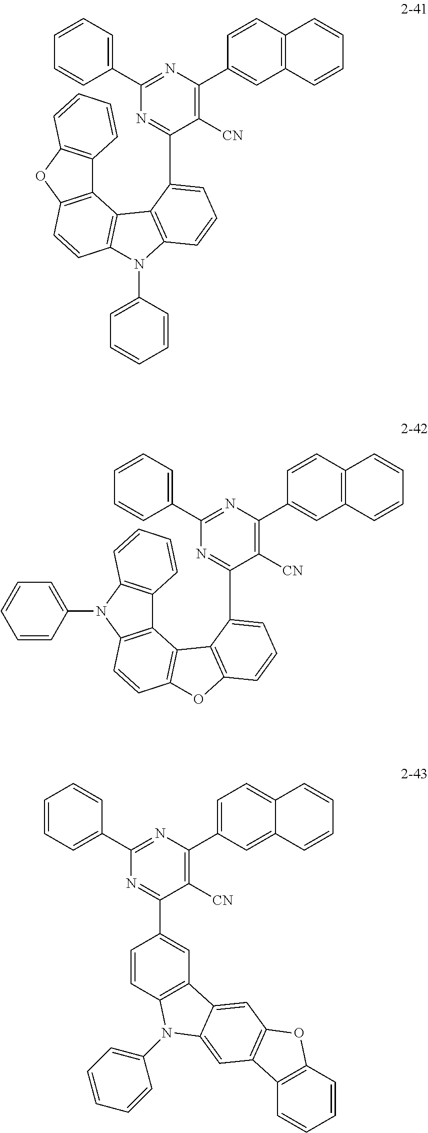 [SMILES: N#Cc1c(-c2ccc3ccccc3c2)nc(-c2ccccc2)nc1-c1cccc2c1c1c3c(ccc1n2-c1ccccc1)oc1ccccc13 ; N#Cc1c(-c2ccc3ccccc3c2)nc(-c2ccccc2)nc1-c1cccc2oc3ccc4c(c5ccccc5n4-c4ccccc4)c3c12 ; N#Cc1c(-c2ccc3ccccc3c2)nc(-c2ccccc2)nc1-c1ccc2c(c1)c1cc3oc4ccccc4c3cc1n2-c1ccccc1]

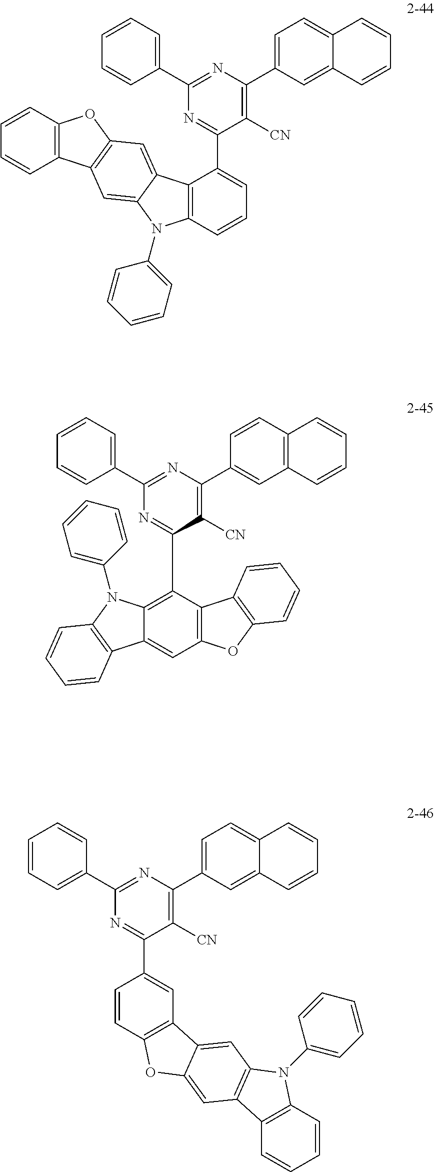

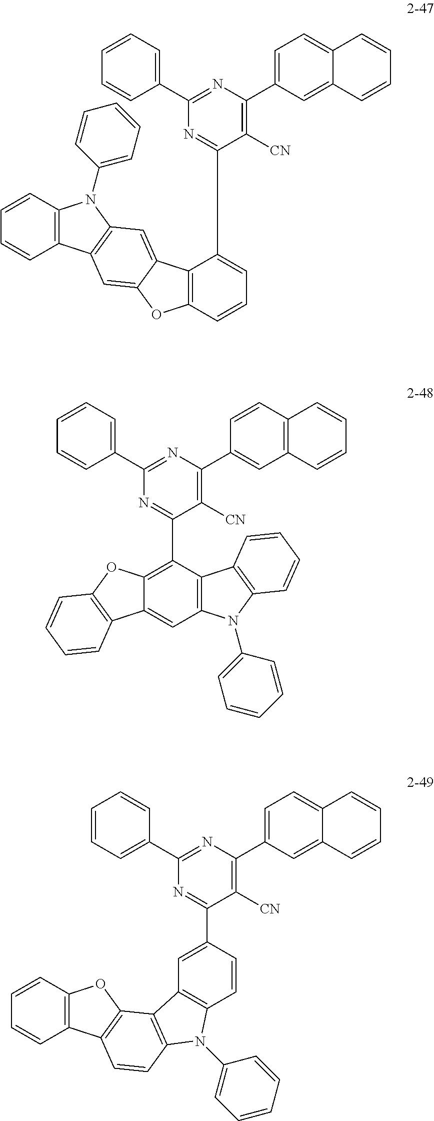 [SMILES: N#Cc1c(-c2ccc3ccccc3c2)nc(-c2ccccc2)nc1-c1cccc2oc3cc4c5ccccc5n(-c5ccccc5)c4cc3c12 ; N#Cc1c(-c2ccc3ccccc3c2)nc(-c2ccccc2)nc1-c1c2oc3ccccc3c2cc2c1c1ccccc1n2-c1ccccc1 ; N#Cc1c(-c2ccc3ccccc3c2)nc(-c2ccccc2)nc1-c1ccc2c(c1)c1c3oc4ccccc4c3ccc1n2-c1ccccc1]

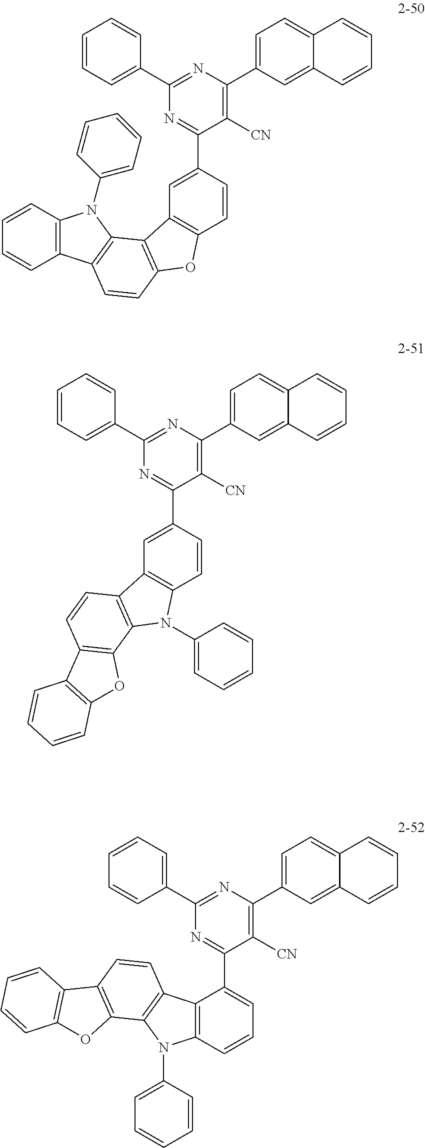 [SMILES: N#Cc1c(-c2ccc3ccccc3c2)nc(-c2ccccc2)nc1-c1ccc2oc3ccc4c5ccccc5n(-c5ccccc5)c4c3c2c1 ; N#Cc1c(-c2ccc3ccccc3c2)nc(-c2ccccc2)nc1-c1ccc2c(c1)c1ccc3c4ccccc4oc3c1n2-c1ccccc1 ; N#Cc1c(-c2ccc3ccccc3c2)nc(-c2ccccc2)nc1-c1cccc2c1c1ccc3c4ccccc4oc3c1n2-c1ccccc1]

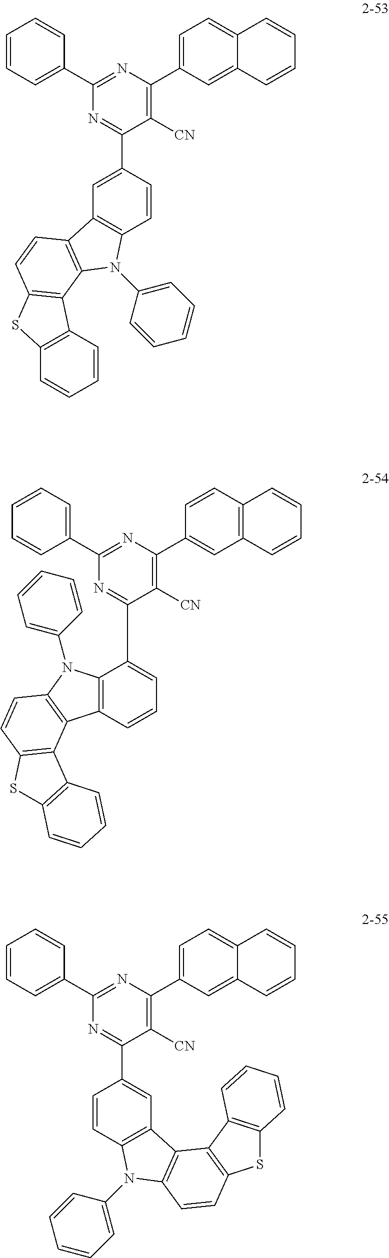 [SMILES: N#Cc1c(-c2ccc3ccccc3c2)nc(-c2ccccc2)nc1-c1ccc2c(c1)c1ccc3sc4ccccc4c3c1n2-c1ccccc1 ; N#Cc1c(-c2ccc3ccccc3c2)nc(-c2ccccc2)nc1-c1cccc2c3c4c(ccc3n(-c3ccccc3)c12)sc1ccccc14 ; N#Cc1c(-c2ccc3ccccc3c2)nc(-c2ccccc2)nc1-c1ccc2c(c1)c1c3c(ccc1n2-c1ccccc1)sc1ccccc13]

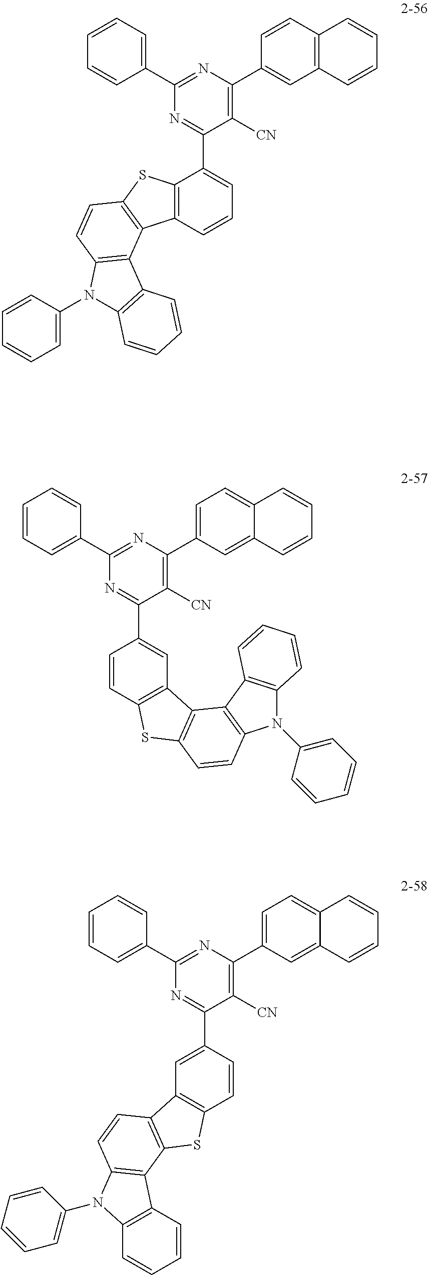 [SMILES: N#Cc1c(-c2ccc3ccccc3c2)nc(-c2ccccc2)nc1-c1cccc2c1sc1ccc3c(c4ccccc4n3-c3ccccc3)c12 ; N#Cc1c(-c2ccc3ccccc3c2)nc(-c2ccccc2)nc1-c1ccc2sc3ccc4c(c5ccccc5n4-c4ccccc4)c3c2c1 ; N#Cc1c(-c2ccc3ccccc3c2)nc(-c2ccccc2)nc1-c1ccc2sc3c(ccc4c3c3ccccc3n4-c3ccccc3)c2c1]

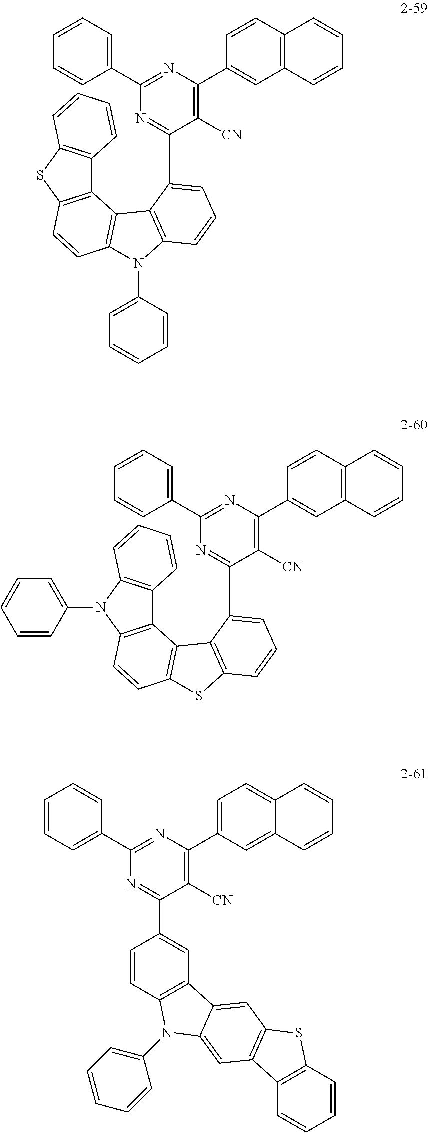 [SMILES: N#Cc1c(-c2ccc3ccccc3c2)nc(-c2ccccc2)nc1-c1cccc2c1c1c3c(ccc1n2-c1ccccc1)sc1ccccc13 ; N#Cc1c(-c2ccc3ccccc3c2)nc(-c2ccccc2)nc1-c1cccc2sc3ccc4c(c5ccccc5n4-c4ccccc4)c3c12 ; N#Cc1c(-c2ccc3ccccc3c2)nc(-c2ccccc2)nc1-c1ccc2c(c1)c1cc3sc4ccccc4c3cc1n2-c1ccccc1]

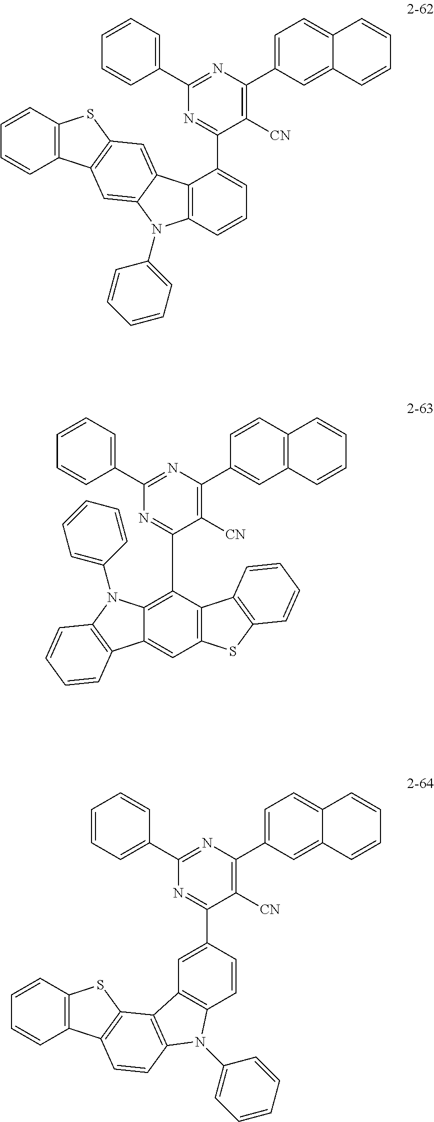 [SMILES: N#Cc1c(-c2ccc3ccccc3c2)nc(-c2ccccc2)nc1-c1cccc2c1c1cc3sc4ccccc4c3cc1n2-c1ccccc1 ; N#Cc1c(-c2ccc3ccccc3c2)nc(-c2ccccc2)nc1-c1c2c(cc3c4ccccc4n(-c4ccccc4)c13)sc1ccccc12 ; N#Cc1c(-c2ccc3ccccc3c2)nc(-c2ccccc2)nc1-c1ccc2c(c1)c1c3sc4ccccc4c3ccc1n2-c1ccccc1]

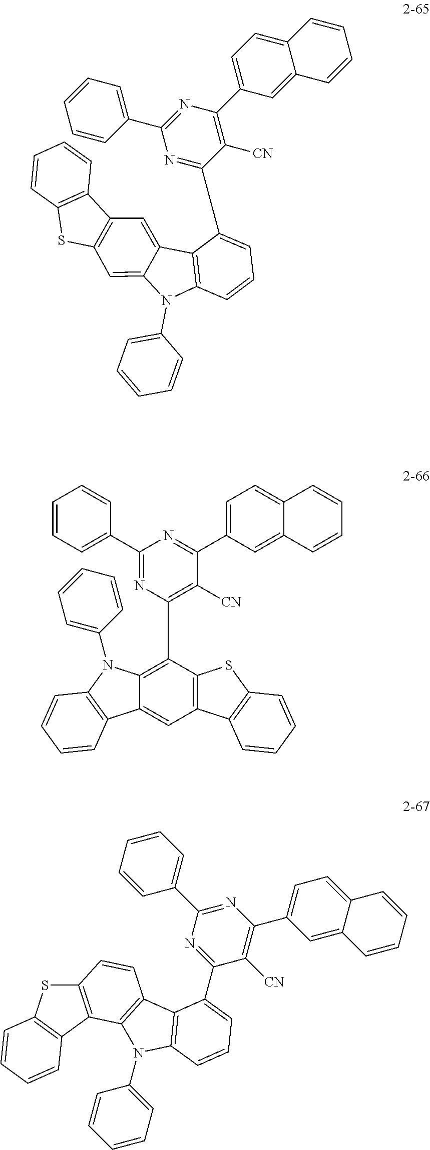 [SMILES: N#Cc1c(-c2ccc3ccccc3c2)nc(-c2ccccc2)nc1-c1cccc2c1c1cc3c(cc1n2-c1ccccc1)sc1ccccc13 ; N#Cc1c(-c2ccc3ccccc3c2)nc(-c2ccccc2)nc1-c1c2sc3ccccc3c2cc2c3ccccc3n(-c3ccccc3)c12 ; N#Cc1c(-c2ccc3ccccc3c2)nc(-c2ccccc2)nc1-c1cccc2c1c1ccc3sc4ccccc4c3c1n2-c1ccccc1]

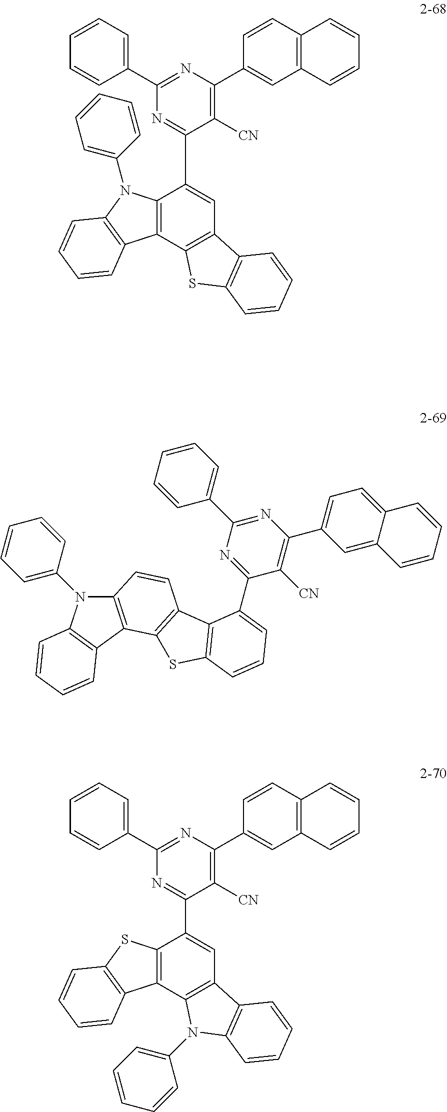 [SMILES: N#Cc1c(-c2ccc3ccccc3c2)nc(-c2ccccc2)nc1-c1cc2c3ccccc3sc2c2c3ccccc3n(-c3ccccc3)c12 ; N#Cc1c(-c2ccc3ccccc3c2)nc(-c2ccccc2)nc1-c1cccc2sc3c(ccc4c3c3ccccc3n4-c3ccccc3)c12 ; N#Cc1c(-c2ccc3ccccc3c2)nc(-c2ccccc2)nc1-c1cc2c3ccccc3n(-c3ccccc3)c2c2c1sc1ccccc12]

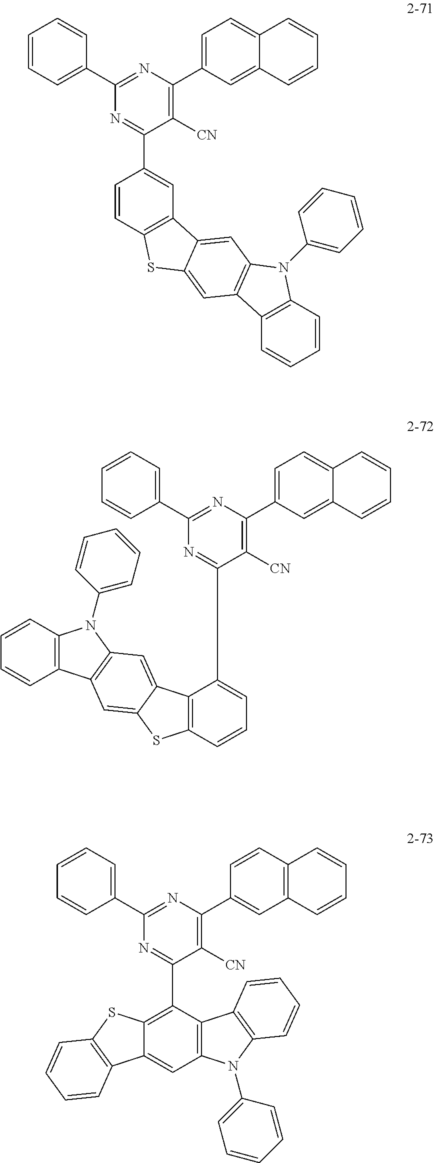 [SMILES: N#Cc1c(-c2ccc3ccccc3c2)nc(-c2ccccc2)nc1-c1ccc2sc3cc4c5ccccc5n(-c5ccccc5)c4cc3c2c1 ; N#Cc1c(-c2ccc3ccccc3c2)nc(-c2ccccc2)nc1-c1cccc2sc3cc4c5ccccc5n(-c5ccccc5)c4cc3c12 ; N#Cc1c(-c2ccc3ccccc3c2)nc(-c2ccccc2)nc1-c1c2sc3ccccc3c2cc2c1c1ccccc1n2-c1ccccc1]

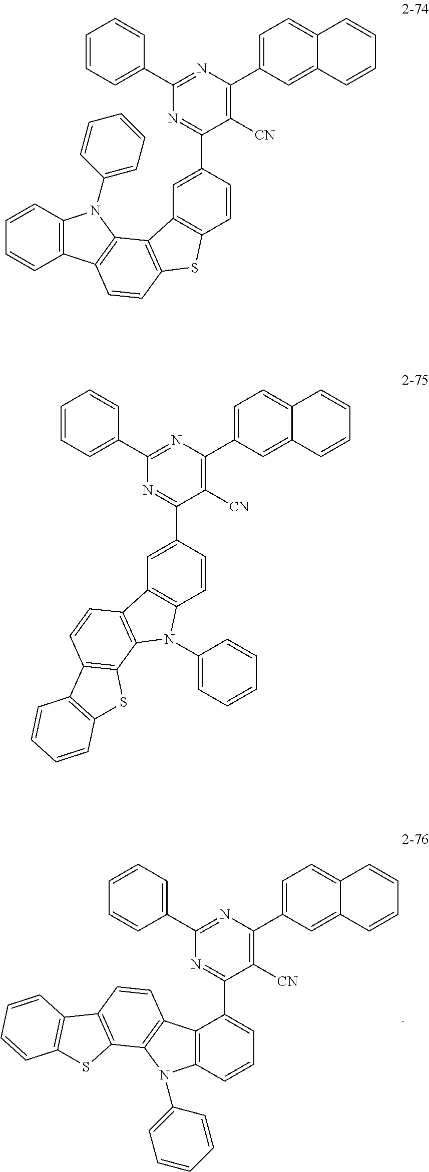 [SMILES: N#Cc1c(-c2ccc3ccccc3c2)nc(-c2ccccc2)nc1-c1ccc2sc3ccc4c5ccccc5n(-c5ccccc5)c4c3c2c1 ; N#Cc1c(-c2ccc3ccccc3c2)nc(-c2ccccc2)nc1-c1ccc2c(c1)c1ccc3c4ccccc4sc3c1n2-c1ccccc1 ; N#Cc1c(-c2ccc3ccccc3c2)nc(-c2ccccc2)nc1-c1cccc2c1c1ccc3c4ccccc4sc3c1n2-c1ccccc1]

The third compound 346 may be a P-type host (hole-type host) with relatively advantageous hole affinity. For example, the third compound 346 may comprise, but is not limited to, a carbazole-based organic compound, an aryl amine-based or heteroaryl amine-based organic compound with at least one fused aromatic or fused heteroaromatic moiety, and/or an aryl amine-based or heteroaryl amine-based organic compound with a spirofluorene moiety.

In one example embodiment, the third compound 346 may be a carbazole-based organic compound with the following structure of Chemical Formula 8:

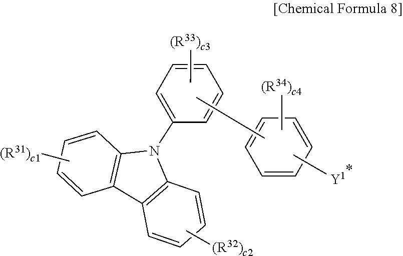

wherein, in the Chemical Formula 8,
each of R³¹ and R³² is independently an unsubstituted or substituted C₁-C₂₀ alkyl group or an unsubstituted or substituted C₆-C₃₀ aryl group, where each R³¹ is identical to or different from each other when c1 is 2, 3 or 4 and each R³² is identical to or different from each other when c2 is 2, 3 or 4;
each of R³³ and R³⁴ is independently an unsubstituted or substituted C₁-C₂₀ alkyl group or an unsubstituted or substituted C₆-C₃₀ aryl group, where each R³³ is identical to or different from each other when c3 is 2, 3 or 4 and each R³⁴ is identical to or different from each other when c4 is 2, 3 or 4, or R³³ and R³⁴ are further linked together to form a heteroring;
Y¹ is represented by following Chemical Formula 9A or Chemical Formula 9B;
each of c1, c2, c3 and c4 is independently 0, 1, 2, 3 or 4; and
asterisk indicates a link position to the Chemical Formula 9A or Chemical Formula 9B,

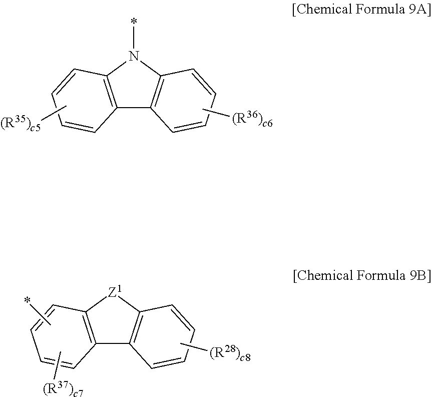

wherein, in the Chemical Formulae 9A and 9B,
each of R³⁵, R³⁶, R³⁷, and R³⁸ is independently an unsubstituted or substituted C₁-C₂₀ alkyl group or an unsubstituted or substituted C₆-C₃₀ aryl group, where each R³⁵ is identical to or different from each other when c5 is 2, 3 or 4, each R³⁶ is identical to or different from each other when c6 is 2, 3 or 4, each R³⁷ is identical to or different from each other when c7 is 2 or 3 and each R³⁸ is identical to or different from each other when c8 is 2, 3 or 4;
Z¹ is NR³⁹, O or S, where R³⁹ is hydrogen, an unsubstituted or substituted C₁-C₂₀ alkyl group or an unsubstituted or substituted C₆-C₃₀ aryl group;
each of c5, c6, and c8 is independently 0, 1, 2, 3 or 4;
c7 is 0, 1, 2 or 3; and
asterisk indicates a link position.

For example, the carbazolyl moiety comprising R³¹ and R³² and the phenyl moiety comprising R³⁴ in Chemical Formula 8 may be linked to an ortho-, meta- or para-position to the benzene ring with R³³. In addition, R³³ and R³⁴ are further linked together to form a 5-membered heteroaromatic ring comprising a nitrogen atom, an oxygen atom and/or a sulfur atom. The nitrogen atom in the 5-membered heteroaromatic ring formed by R³³ and R³⁴ may be unsubstituted or substituted with a C₆-C₂₀ aryl group (e.g., phenyl). In some embodiments, R³³ or R³⁴ may be linked to the adjacent 6-membered aromatic ring to form a heteroring that includes a nitrogen atom, an oxygen atom and/or a sulfur atom and that is optionally substituted with an unsubstituted or substituted C₆-C₃₀ aryl group.

As an example, the third compound 346 having the structure of Chemical Formula 8 may be, but is not limited to, the following organic compounds of Chemical Formula 10:

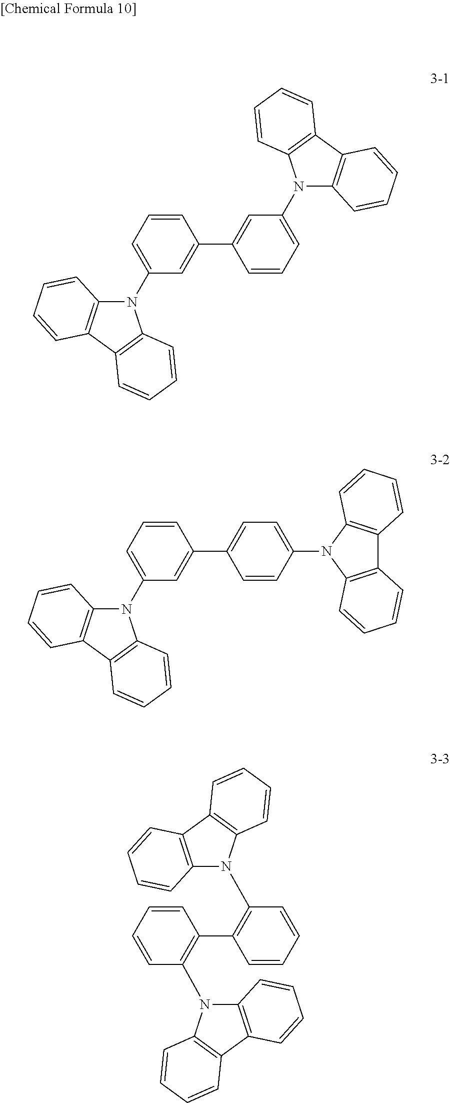 [SMILES: c1cc(-c2cccc(-n3c4ccccc4c4ccccc43)c2)cc(-n2c3ccccc3c3ccccc32)c1 ; c1cc(-c2ccc(-n3c4ccccc4c4ccccc43)cc2)cc(-n2c3ccccc3c3ccccc32)c1 ; c1ccc(-n2c3ccccc3c3ccccc32)c(-c2ccccc2-n2c3ccccc3c3ccccc32)c1]

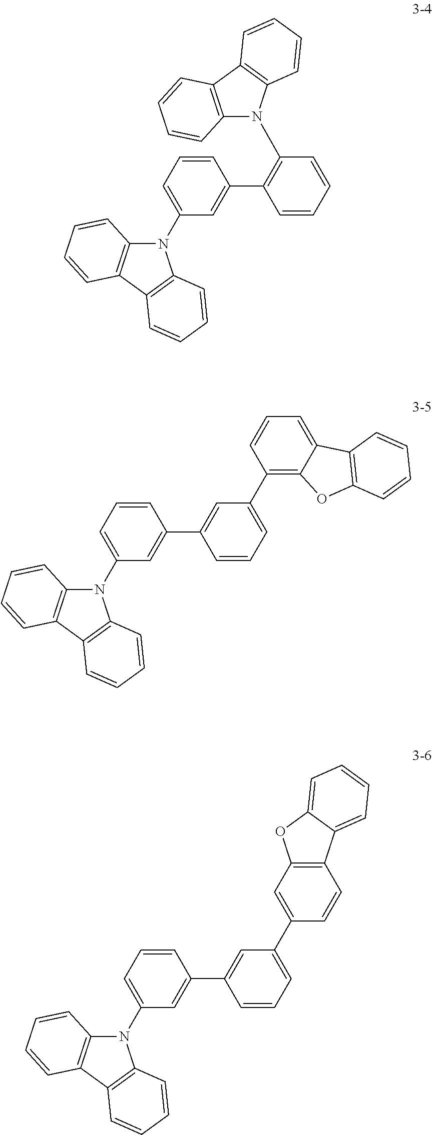 [SMILES: c1cc(-c2ccccc2-n2c3ccccc3c3ccccc32)cc(-n2c3ccccc3c3ccccc32)c1 ; c1cc(-c2cccc(-n3c4ccccc4c4ccccc43)c2)cc(-c2cccc3c2oc2ccccc23)c1 ; c1cc(-c2cccc(-n3c4ccccc4c4ccccc43)c2)cc(-c2ccc3c(c2)oc2ccccc23)c1]

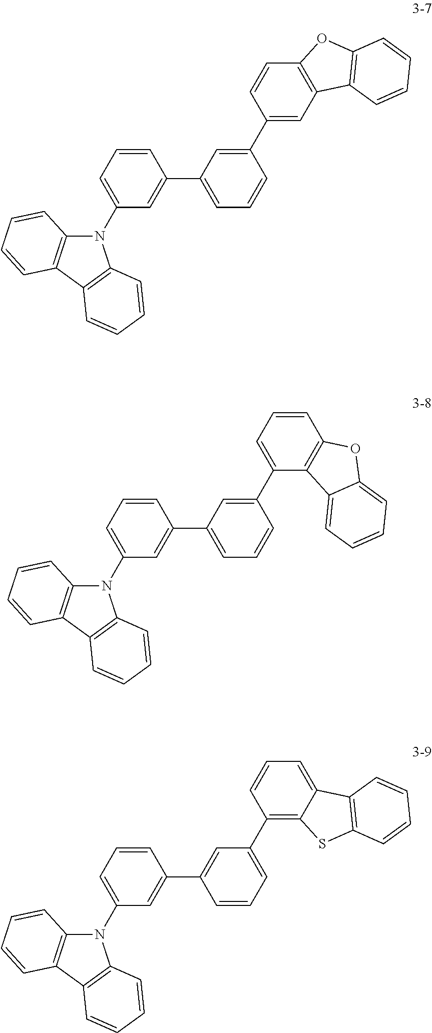 [SMILES: c1cc(-c2cccc(-n3c4ccccc4c4ccccc43)c2)cc(-c2ccc3oc4ccccc4c3c2)c1 ; c1cc(-c2cccc(-n3c4ccccc4c4ccccc43)c2)cc(-c2cccc3oc4ccccc4c23)c1 ; c1cc(-c2cccc(-n3c4ccccc4c4ccccc43)c2)cc(-c2cccc3c2sc2ccccc23)c1]

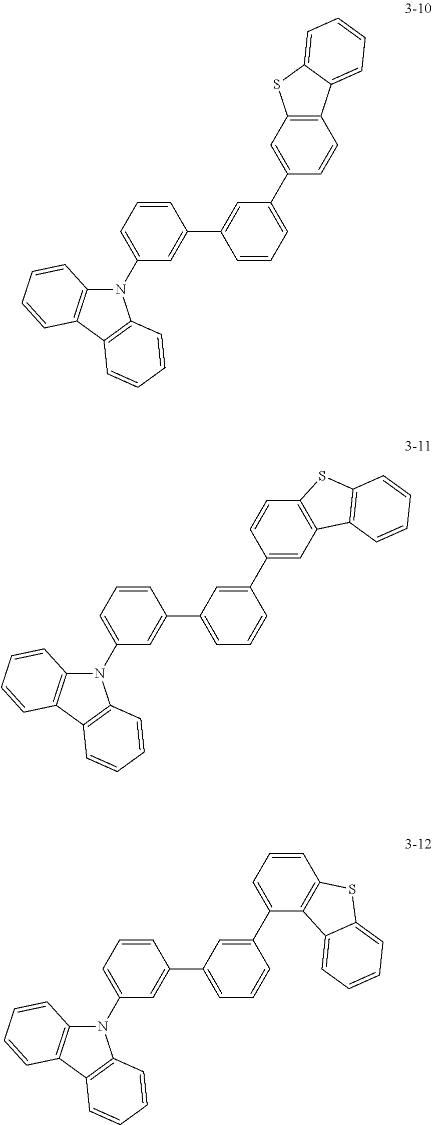 [SMILES: c1cc(-c2cccc(-n3c4ccccc4c4ccccc43)c2)cc(-c2ccc3c(c2)sc2ccccc23)c1 ; c1cc(-c2cccc(-n3c4ccccc4c4ccccc43)c2)cc(-c2ccc3sc4ccccc4c3c2)c1 ; c1cc(-c2cccc(-n3c4ccccc4c4ccccc43)c2)cc(-c2cccc3sc4ccccc4c23)c1]

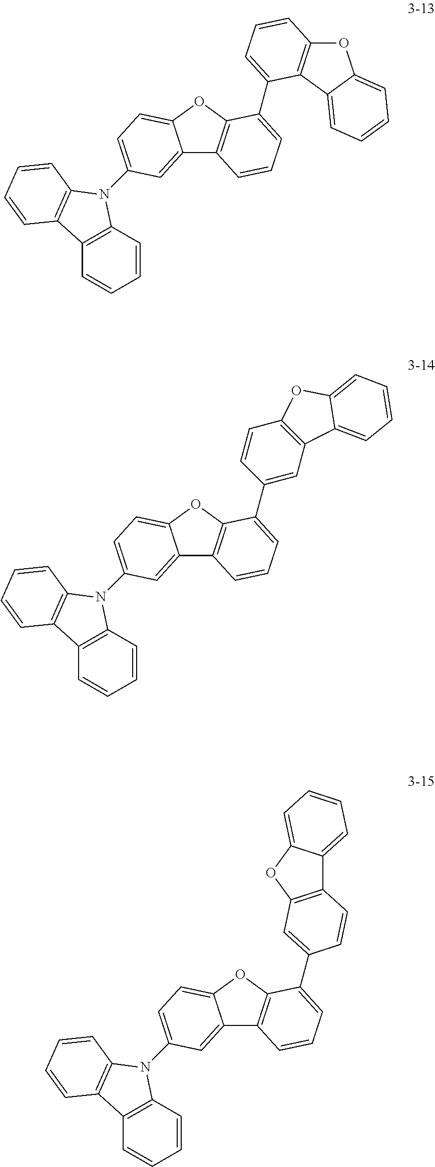 [SMILES: c1ccc2c(c1)oc1cccc(-c3cccc4c3oc3ccc(-n5c6ccccc6c6ccccc65)cc34)c12 ; c1ccc2c(c1)oc1ccc(-c3cccc4c3oc3ccc(-n5c6ccccc6c6ccccc65)cc34)cc12 ; c1ccc2c(c1)oc1cc(-c3cccc4c3oc3ccc(-n5c6ccccc6c6ccccc65)cc34)ccc12]

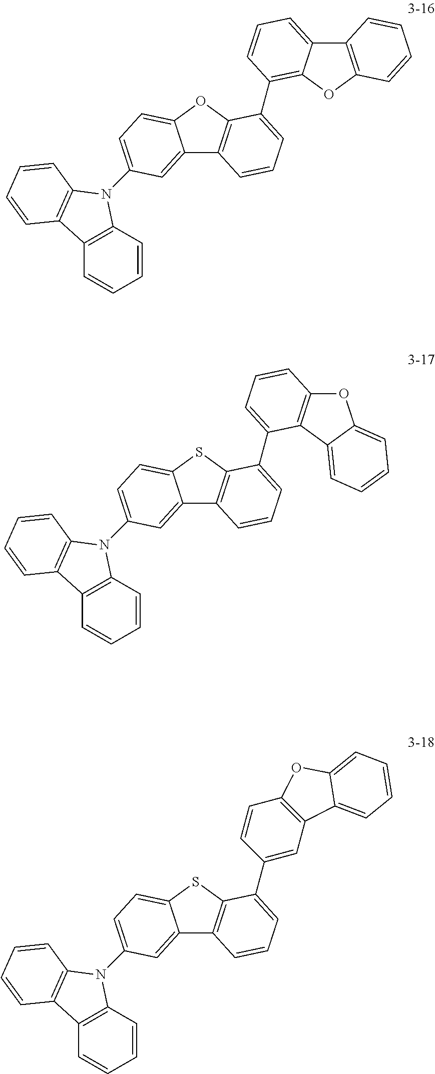 [SMILES: c1ccc2c(c1)oc1c(-c3cccc4c3oc3ccc(-n5c6ccccc6c6ccccc65)cc34)cccc12 ; c1ccc2c(c1)oc1cccc(-c3cccc4c3sc3ccc(-n5c6ccccc6c6ccccc65)cc34)c12 ; c1ccc2c(c1)oc1ccc(-c3cccc4c3sc3ccc(-n5c6ccccc6c6ccccc65)cc34)cc12]

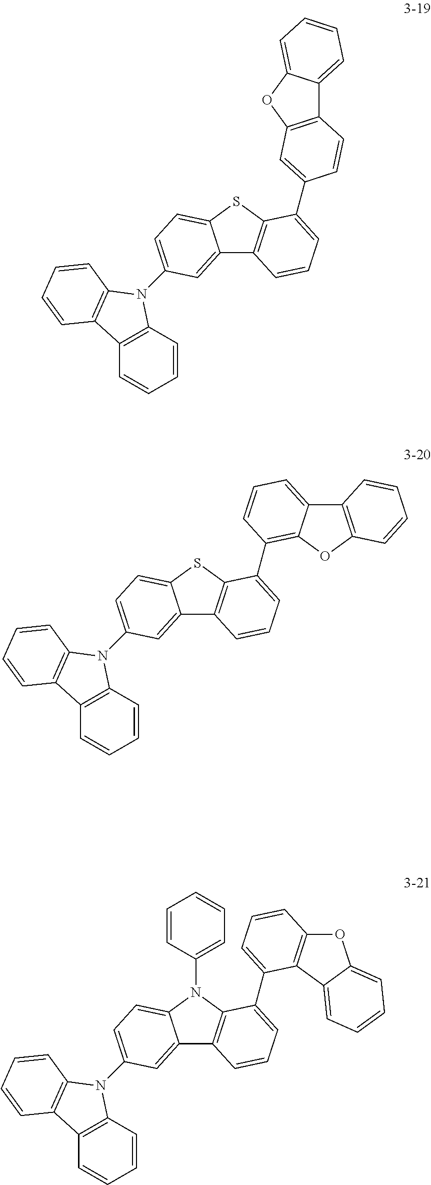 [SMILES: c1ccc2c(c1)oc1cc(-c3cccc4c3sc3ccc(-n5c6ccccc6c6ccccc65)cc34)ccc12 ; c1ccc2c(c1)oc1c(-c3cccc4c3sc3ccc(-n5c6ccccc6c6ccccc65)cc34)cccc12 ; c1ccc(-n2c3ccc(-n4c5ccccc5c5ccccc54)cc3c3cccc(-c4cccc5oc6ccccc6c45)c32)cc1]

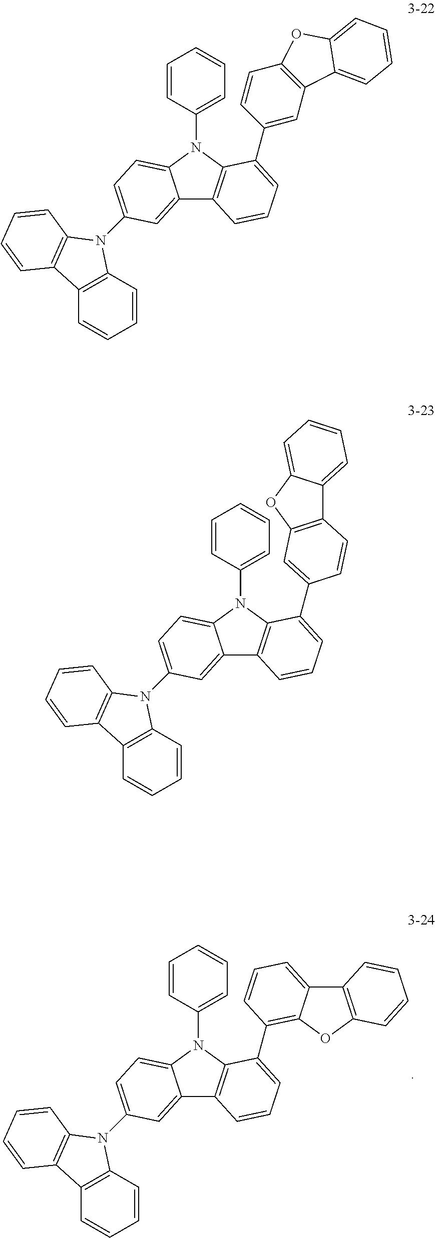 [SMILES: c1ccc(-n2c3ccc(-n4c5ccccc5c5ccccc54)cc3c3cccc(-c4ccc5oc6ccccc6c5c4)c32)cc1 ; c1ccc(-n2c3ccc(-n4c5ccccc5c5ccccc54)cc3c3cccc(-c4ccc5c(c4)oc4ccccc45)c32)cc1 ; c1ccc(-n2c3ccc(-n4c5ccccc5c5ccccc54)cc3c3cccc(-c4cccc5c4oc4ccccc45)c32)cc1]

The contents of the host comprising the second compound 344 and the third compound 346 in the EML 340 may be about 50 wt % to about 99 wt %, for example, about 80 wt % to about 95 wt %, and the contents of the first compound 342 in the EML 340 may be about 1 wt % to about 50 wt %, for example, about 5 wt % to about 20 wt %, but is not limited thereto. When the EML 340 comprises both the second compound 344 and the third compound 346, the second compound 344 and the third compound 346 may be admixed, but is not limited to, with a weight ratio of about 4:1 to about 1:4, for example about 3:1 to about 1:3. As an example, the EML 340 may have a thickness of, but is not limited to, about 100 Å to about 500 Å.

The ETL 360 and the EIL 370 may be laminated sequentially between the EML 340 and the second electrode 220. An electron transporting material comprised in the ETL 360 has high electron mobility so as to provide electrons stably with the EML 340 by fast electron transportation.

In one example embodiment, electron transporting material of the ETL 360 may comprise at least one of an oxadiazole-based compound, a triazole-based compound, a phenanthroline-based compound, a benzoxazole-based compound, a benzothiazole-based compound, a benzimidazole-based compound and a triazine-based compound.

For example, the electron transporting material of the ETL 360 may include, but is not limited to, tris-(8-hydroxyquinoline aluminum (Alq₃), 2-biphenyl-4-yl-5-(4-t-butylphenyl)-1,3,4-oxadiazole (PBD), spiro-PBD, lithium quinolate (Liq), 1,3,5-Tris(N-phenylbenzimidazol-2-yl)benzene (TPBi), Bis(2-methyl-8-quinolinolato-N1,O8)-(1,1′-biphenyl-4-olato)aluminum (BAlq), 4,7-diphenyl-1,10-phenanthroline (Bphen), 2,9-Bis(naphthalene-2-yl)4,7-diphenyl-1,10-phenanthroline (NBphen), 2,9-Dimethyl-4,7-diphenyl-1,10-phenathroline (BCP), 3-(4-Biphenyl)-4-phenyl-5-tert-butylphenyl-1,2,4-triazole (TAZ), 4-(Naphthalen-1-yl)-3,5-diphenyl-4H-1,2,4-triazole (NTAZ), 1,3,5-Tri(p-pyrid-3-yl-phenyl)benzene (TpPyPB), 2,4,6-Tris(3′-(pyridin-3-yl)biphenyl-3-yl)1,3,5-triazine (TmPPPyTz), Poly[9,9-bis(3′-((N,N-dimethyl)-N-ethylammonium)-propyl)-2,7-fluorene]-alt-2,7-(9,9-dioctylfluorene)] (PFNBr), tris(phenylquinoxaline (TPQ), TSPO1, 2-[4-(9,10-Di-2-naphthalen2-yl-2-anthracen-2-yl)phenyl]-1-phenyl-1H-benzimidazole (ZADN), and/or combinations thereof.

The EIL 370 is disposed between the second electrode 220 and the ETL 360, and may improve physical properties of the second electrode 220 and therefore, may enhance the lifespan of the OLED D1. In one example embodiment, electron injection material of the EIL 370 may comprise, but is not limited to, an alkali metal halide or an alkaline earth metal halide such as LiF, CsF, NaF, BaF₂ and the like, and/or an organometallic compound such as Liq, lithium benzoate, sodium stearate, and the like. In certain embodiments, the EIL 370 may be omitted.

When holes are transferred to the second electrode 220 via the EML 340 and/or electrons are transferred to the first electrode 210 via the EML 340, the OLED D1 may have short lifespan and reduced luminous efficiency. In order to prevent or reduce those phenomena, the OLED D1 in accordance with this aspect of the present disclosure may have at least one exciton blocking layer adjacent to the EML 340.

As an example, the OLED D1 may comprise the EBL 330 disposed between the HTL 320 and the EML 340 so as to control and prevent or reduce electron transfers. In one example embodiment, electron blocking material of the EBL 330 may comprise, but is not limited to, TCTA, Tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, 1,3-Bis(carbazol-9-yl)benzene (mCP), 3,3-Di(9H-carbazol-O-yl)biphenyl (mCBP), CuPc, DNTPD, TDAPB, DCDPA, 2,8-bis(9-phenyl-9H-carbazol-3-yl)dibenzo[b,d]thiophene and/or combinations thereof.

In addition, the OLED D1 may further comprise the HBL 350 as a second exciton blocking layer between the EML 340 and the ETL 360 so that holes may not be transferred from the EML 340 to the ETL 360. In one example embodiment, hole blocking material of the HBL 350 may comprise, but is not limited to, at least one of an oxadiazole-based compound, a triazole-based compound, a phenanthroline-based compound, a benzoxazole-based compound, a benzothiazole-based compound, a benzimidazole-based compound, and a triazine-based compound.

For example, the HBL 350 may comprise material having a relatively low HOMO energy level compared to the luminescent materials in EML 340. The hole blocking material of the HBL 350 may comprise, but is not limited to, BCP, BAlq, Alq₃, PBD, spiro-PBD, Liq, Bis-4,5-(3,5-di-3-pyridylphenyl)-2-methylpyrimidine (B3PYMPM), DPEPO, 9-(6-(9H-carbazol-9-yl)pyridine-3-yl)-9H-3,9′-bicarbazole, TSPO1 and/or combinations thereof.

The first compound 342 having the structure of Chemical Formulae 1 to 3 is fluorescent emitter with a wide plate-like structure. The singlet exciton energy of the second compound 344 and/or the third compound 346 may be transferred efficiently to the first compound 342 by FRET mechanism. Accordingly, the luminous efficiency and the luminous lifetime of the OLED D1 may be improved.

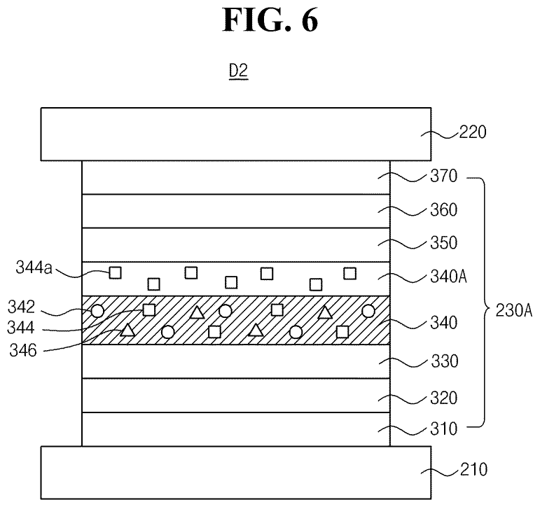

An organic light emitting diode of the present disclosure may further comprise a charge control layer. FIG. 6 illustrates a schematic cross-sectional view of an organic light emitting diode having a single emitting part in accordance with another example embodiment of the present disclosure. As illustrated in FIG. 6, the organic light emitting diode (OLED) D2 in accordance with the present disclosure comprises first and second electrodes 210 and 220 facing each other and an emissive layer 230A disposed between the first and second electrodes 210 and 220. The organic light emitting display device 100 comprises a red pixel region, a green pixel region and a blue pixel region, and the OLED D2 may be disposed in the red pixel region, the green pixel region and the blue pixel region. As an example, the OLED D2 may be disposed in the red pixel region.

In an example embodiment, the emissive layer 230A comprises an EML 340 disposed between the first and second electrodes 210 and 220. The emissive layer 230A further comprises a charge control layer (CCL) 340A disposed between the EML 340 and the second electrode 220, for example, between the EML 340 and an HBL 350.

Also, the emissive layer 230A may comprise at least one of an HTL 320 disposed between the first electrode 210 and the EML 340 and an ETL 360 disposed between the second electrode 220 and the EML 340. In addition, the emissive layer 230A may further comprise at least one of an HIL 310 disposed between the first electrode 210 and the HTL 320 and an EIL 370 disposed between the second electrode 220 and the ETL 360. Alternatively, the emissive layer 230A may further comprise a first exciton blocking layer, i.e. an EBL 330 disposed between the HTL 320 and the EML 340 and/or a second exciton blocking layer, i.e. an HBL 350 disposed between the EML 340 and the ETL 360. The configuration except the CCL 340A may be identical to the configuration disclosed in example embodiments described in connection with FIGS. 3 to 5.

The CCL 340A may comprise charge control material 344a. The charge control material 344a may be material with beneficial electron affinity property and may be the organic compound having the structure of Chemical Formulae 4 to 7. For example, the charge control material 344a may be identical to the second compound 344. The charge control layer 340A comprising the charge control material 344a having the structure of Chemical Formulae 4 to 7 with relatively advantageous electron donor property is disposed between the EML 340 and the HBL 350 so that electron transfer and electron injection speed into the EML 340 may be further improved. Accordingly, the driving voltage of the OLED D2 may be further lowered and the luminous efficiency of the OLED D2 may be further improved.

The organic light emitting device and the OLED D1 and/or D2 with a single emitting part are shown in FIGS. 2 and 6. In another example embodiment, an organic light emitting display device may implement full-color comprising white color.

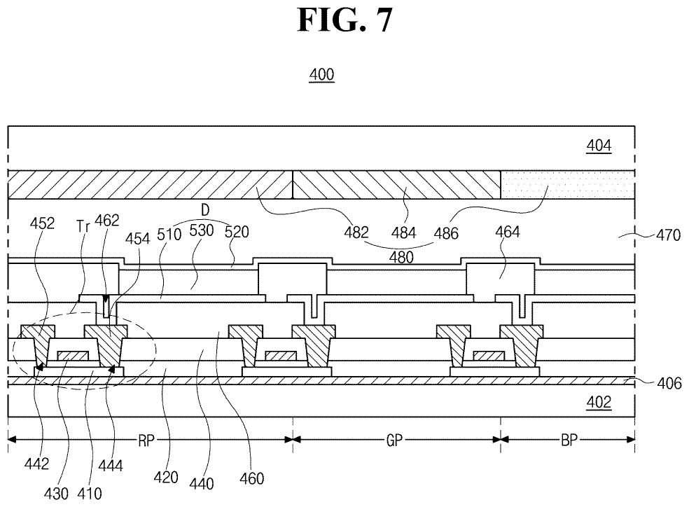

FIG. 7 illustrates a schematic cross-sectional view of an organic light emitting display device in accordance with another example embodiment of the present disclosure. As illustrated in FIG. 7, the organic light emitting display device 400 comprises a first substrate 402 that defines each of a red pixel region RP, a green pixel region GP and a blue pixel region BP, a second substrate 404 facing the first substrate 402, a thin film transistor Tr on the first substrate 402, an OLED D disposed between the first and second substrates 402 and 404 and emitting white (W) light and a color filter layer 480 disposed between the OLED D and the second substrate 404.

Each of the first and second substrates 402 and 404 may comprise, but is not limited to, glass, flexible material and/or polymer plastics. For example, each of the first and second substrates 402 and 404 may be made of PI, PES, PEN, PET, PC and/or combinations thereof. In certain embodiments, the second substrate 404 may be omitted. The first substrate 402, on which a thin film transistor Tr and the OLED D are arranged, forms an array substrate.

A buffer layer 406 may be disposed on the first substrate 402. The thin film transistor Tr is disposed on the buffer layer 406 correspondingly to each of the red pixel region RP, the green pixel region GP and the blue pixel region BP. In certain embodiments, the buffer layer 406 may be omitted.

A semiconductor layer 410 is disposed on the buffer layer 406. The semiconductor layer 410 may be made of or comprise oxide semiconductor material or polycrystalline silicon.

A gate insulating layer 420 comprising an insulating material, for example, inorganic insulating material such as silicon oxide (SiOₓ, wherein 0<x≤2) or silicon nitride (SiNₓ, wherein 0<x≤2) is disposed on the semiconductor layer 410.

A gate electrode 430 made of a conductive material such as a metal is disposed over the gate insulating layer 420 so as to correspond to a center of the semiconductor layer 410. An interlayer insulating layer 440 comprising an insulating material, for example, inorganic insulating material such as SiOₓ or SiNₓ (wherein 0<x≤2), or an organic insulating material such as benzocyclobutene or photo-acryl, is disposed on the gate electrode 430.

The interlayer insulating layer 440 has first and second semiconductor layer contact holes 442 and 444 that expose or do not cover a portion of the surface nearer to the opposing ends than to a center of the semiconductor layer 410. The first and second semiconductor layer contact holes 442 and 444 are disposed on opposite sides of the gate electrode 430 with spacing apart from the gate electrode 430.

A source electrode 452 and a drain electrode 454, which are made of or comprise a conductive material such as a metal, are disposed on the interlayer insulating layer 440. The source electrode 452 and the drain electrode 454 are spaced apart from each other with respect to the gate electrode 430. The source electrode 452 and the drain electrode 454 contact both sides of the semiconductor layer 410 through the first and second semiconductor layer contact holes 442 and 444, respectively.

The semiconductor layer 410, the gate electrode 430, the source electrode 452 and the drain electrode 454 constitute the thin film transistor Tr, which acts as a driving element.

Although not shown in FIG. 7, the gate line GL and the data line DL, which cross each other to define the pixel region P, and a switching element Ts, which is connected to the gate line GL and the data line DL, may be further formed in the pixel region P. The switching element Ts is connected to the thin film transistor Tr, which is a driving element. In addition, the power line PL is spaced apart in parallel from the gate line GL or the data line DL, and the thin film transistor Tr may further comprise the storage capacitor Cst configured to constantly keep a voltage of the gate electrode 430 for one frame.

A passivation layer 460 is disposed on the source electrode 452 and the drain electrode 454 and covers the thin film transistor Tr over the whole first substrate 402. The passivation layer 460 has a drain contact hole 462 that exposes or does not cover the drain electrode 454 of the thin film transistor Tr.

The OLED D is located on the passivation layer 460. The OLED D comprises a first electrode 510 that is connected to the drain electrode 454 of the thin film transistor Tr, a second electrode 520 facing the first electrode 510 and an emissive layer 530 disposed between the first and second electrodes 510 and 520.

The first electrode 510 formed for each pixel region RP, GP or BP may be an anode and may comprise a conductive material having relatively high work function value. For example, the first electrode 510 may comprise, but is not limited to, ITO, IZO, ITZO, SnO, ZnO, ICO, AZO, and/or combinations thereof. Alternatively, a reflective electrode or a reflective layer may be disposed under the first electrode 510. For example, the reflective electrode or the reflective layer may comprise, but is not limited to, Ag or APC alloy.

A bank layer 464 is disposed on the passivation layer 460 in order to cover edges of the first electrode 510. The bank layer 464 exposes or does not cover a center of the first electrode 510 corresponding to each of the red pixel RP, the green pixel GP and the blue pixel BP. In certain embodiments, the bank layer 464 may be omitted.

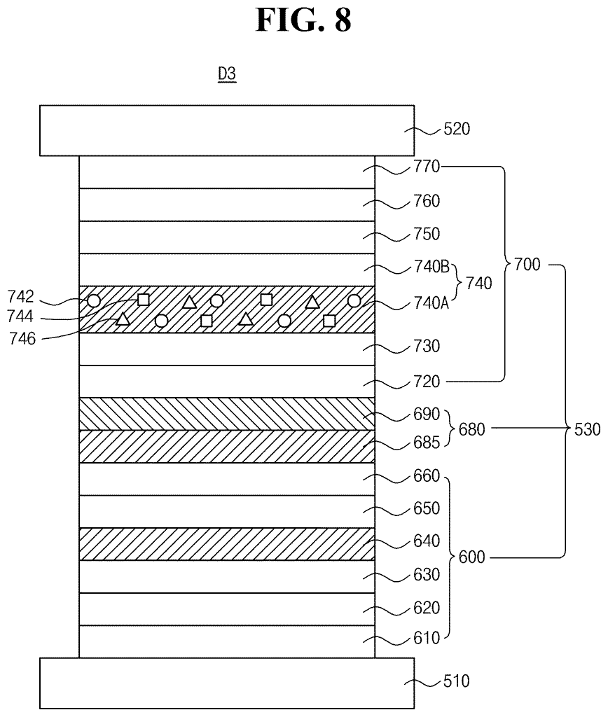

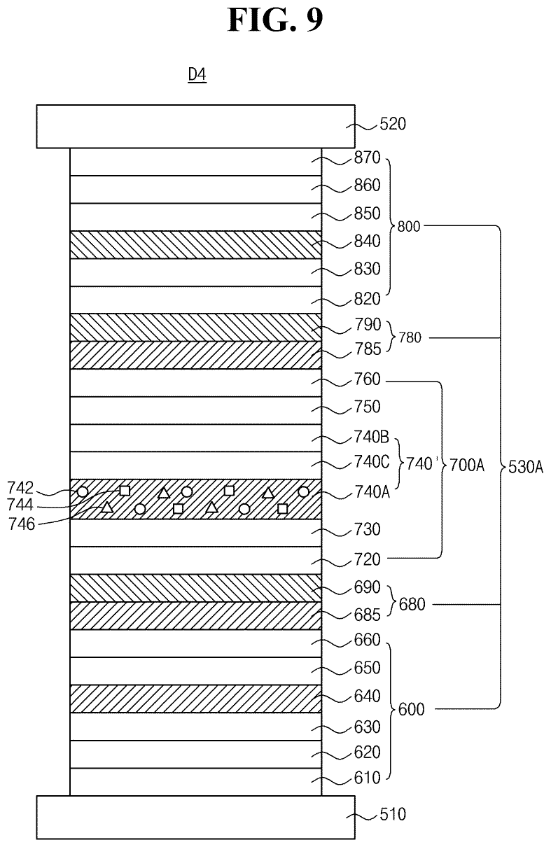

An emissive layer 530 that may comprise multiple emitting parts is disposed on the first electrode 510. As illustrated in FIGS. 8 and 9, the emissive layer 530 may comprise multiple emitting parts 600, 700, 700A, and 800 and at least one charge generation layer 680 and 780. Each of the emitting parts 600, 700, 700A and 800 comprises at least one emitting material layer (EML) and may further comprise a hole injection layer (HIL), a hole transport layer (HTL), an electron blocking layer (EBL), a hole blocking layer (HBL), an electron transport layer (ETL) and/or an electron injection layer (EIL).

The second electrode 520 may be disposed on the first substrate 402 above which the emissive layer 530 may be disposed. The second electrode 520 may be disposed over a whole display area, may comprise a conductive material with a relatively low work function value compared to the first electrode 510, and may be a cathode. For example, the second electrode 520 may comprise, but is not limited to, Al, Mg, Ca, Ag, alloy thereof, and/or combinations thereof such as Al—Mg.

Since the light emitted from the emissive layer 530 is incident to the color filter layer 480 through the second electrode 520 in the organic light emitting display device 400 in accordance with the second embodiment of the present disclosure, the second electrode 520 has a thin thickness so that the light may be transmitted.

The color filter layer 480 is disposed on the OLED D and comprises a red color filter pattern 482, a green color filter pattern 484 and a blue color filter pattern 486 each of which is disposed correspondingly to the red pixel RP, the green pixel GP and the blue pixel BP, respectively. Although not shown in FIG. 7, the color filter layer 480 may be attached to the OLED D through an adhesive layer. Alternatively, the color filter layer 480 may be disposed directly on the OLED D.

In addition, an encapsulation film 470 may be disposed on the second electrode 520 in order to prevent or reduce outer moisture from penetrating into the OLED D. The encapsulation film 470 may have, but is not limited to, a laminated structure comprising a first inorganic insulating film, an organic insulating film and a second inorganic insulating film (176 in FIG. 2). In addition, a polarizing plate may be attached onto the second substrate 404 to reduce reflection of external light. For example, the polarizing plate may be a circular polarizing plate.

In FIG. 7, the light emitted from the OLED D is transmitted through the second electrode 520 and the color filter layer 480 is disposed on the OLED D. In this case, the organic light emitting display device 400 may be a top-emission type. Alternatively, when the organic light emitting display device 400 is a bottom-emission type, the light emitted from the OLED D is transmitted through the first electrode 510 and the color filter layer 480 may be disposed between the OLED D and the first substrate 402.

In addition, a color conversion layer may be formed or disposed between the OLED D and the color filter layer 480. The color conversion layer may comprise a red color conversion layer, a green color conversion layer and a blue color conversion layer each of which is disposed correspondingly to each pixel (RP, GP and BP), respectively, so as to convert the white (W) color light to each of a red, green and blue color lights, respectively. Alternatively, the organic light emitting display device 400 may comprise the color conversion layer instead of the color filter layer 480.

As described above, the white (W) color light emitted from the OLED D is transmitted through the red color filter pattern 482, the green color filter pattern 484 and the blue color filter pattern 486 each of which is disposed correspondingly to the red pixel region RP, the green pixel region GP and the blue pixel region BP, respectively, so that red, green and blue color lights are displayed in the red pixel region RP, the green pixel region GP and the blue pixel region BP.

An OLED that may be applied into the organic light emitting display device will be described in more detail. FIG. 8 illustrates a schematic cross-sectional view of an organic light emitting diode having a tandem structure of two emitting parts.

As illustrated in FIG. 8, the OLED D3 in accordance with the example embodiment of the present disclosure comprises first and second electrodes 510 and 520 facing each other and an emissive layer 530 disposed between the first and second electrodes 510 and 520. The emissive layer 530 comprises a first emitting part 600 disposed between the first and second electrodes 510 and 520, a second emitting part 700 disposed between the first emitting part 600 and the second electrode 520 and a charge generation layer (CGL) 680 disposed between the first and second emitting parts 600 and 700.

The first electrode 510 may be an anode and may comprise a conductive material having relatively high work function value such as TCO. For example, the first electrode 510 may comprise, but is not limited to, ITO, IZO, ITZO, SnO, ZnO, ICO, AZO, and/or combinations thereof. The second electrode 520 may be a cathode and may comprise a conductive material with a relatively low work function value. For example, the second electrode 520 may comprise, but is not limited to, highly reflective material such as Al, Mg, Ca, Ag, alloy thereof and/or combinations thereof such as Al—Mg.

The first emitting part 600 comprises a first emitting material layer (EML1) 640. The first emitting part 600 may further comprise at least one of a hole injection layer (HIL) 610 disposed between the first electrode 510 and the EML1 640, a first hole transport layer (HTL1) 620 disposed between the HIL 610 and the EML1 640, and a first electron transport layer (ETL1) 660 disposed between the EML1 640 and the CGL 680. Alternatively, the first emitting part 600 may further comprise a first electron blocking layer (EBL1) 630 disposed between the HTL1 620 and the EML1 640 and/or a first hole blocking layer (HBL1) 650 disposed between the EML1 640 and the ETL1 660.

The second emitting part 700 comprises a second emitting material layer (EML2) 740. The second emitting part 700 may further comprise at least one of a second hole transport layer (HTL2) 720 disposed between the CGL 680 and the EML2 740, a second electron transport layer (ETL2) 760 disposed between the second electrode 520 and the EML2 740 and an electron injection layer (EIL) 770 disposed between the second electrode 520 and the ETL2 760. Alternatively, the second emitting part 700 may further comprise a second electron blocking layer (EBL2) 730 disposed between the HTL2 720 and the EML2 740 and/or a second hole blocking layer (HBL2) 750 disposed between the EML2 740 and the ETL2 760.

At least one of the EML1 640 and the EML2 740 may comprise a first compound having the structure of Chemical Formulae 1 to 3 so that it may emit red to green color light, and the other of the EML1 640 and the EML2 740 may emit blue color light, so that the OLED D2 may realize white (W) emission. Hereinafter, the OLED D3 where the EML2 740 comprises the first compound having the structure of Chemical Formulae 1 to 3 to emit red to green color light will be described in detail.

The HIL 610 is disposed between the first electrode 510 and the HTL1 620 and improves an interface property between the inorganic first electrode 510 and the organic HTL1 620. In one embodiment, hole injecting material of the HIL 610 may comprise, but is not limited to, MTDATA, NATA, 1T-NATA, 2T-NATA, CuPc, TCTA, NPB (NPD), DNTPD, HAT-CN, F4-TCNQ, F6-TCNNQ, TDAPB, PEDOT/PSS, N-(biphenyl-4-yl)-9,9-dimethyl-N-(4-(9-phenyl-9H-carbazol-3-yl)phenyl)-9H-fluoren-2-amine, NPNPB and/or combinations thereof. Alternatively, the HIL 610 may comprise hole transporting material doped with hole injecting material. In certain embodiments, the HIL 610 may be omitted in compliance of the OLED D3 property.

In one example embodiment, each of hole transporting materials of the HTL1 620 and the HTL2 720 may independently comprise, but is not limited to, TPD, NPB (NPD), DNTPD, CBP, poly-TPD, TFB, TAPC, DCDPA, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, N-([1,1′-Biphenyl]-4-yl)-9,9-dimethyl-N-(4-(9-phenyl-9H-carbazol-3-yl)phenyl)-9H-fluoren-2-amine and/or combinations thereof.

Each of the ETL1 660 and the ETL2 760 facilitates electron transportation in each of the first emitting part 600 and the second emitting part 700, respectively. As an example, each of electron transporting materials of the ETL1 660 and the ETL2 760 may comprise at least one of an oxadiazole-based compound, a triazole-based compound, a phenanthroline-based compound, a benzoxazole-based compound, a benzothiazole-based compound, a benzimidazole-based compound and a triazine-based compound. For example, each of the electrons transporting materials of the ETL1 660 and the ETL2 760 may comprise, but is not limited to, Alq₃, PBD, spiro-PBD, Liq, TPBi, BAlq, Bphen, NBphen, BCP, TAZ, NTAZ, TpPyPB, TmPPPyTz, PFNBr, TPQ, TSPO1, ZADN and/or combinations thereof.

The EIL 770 is disposed between the second electrode 520 and the ETL2 760, and may improve physical properties of the second electrode 520 and therefore, may enhance the lifespan of the OLED D2. In one example embodiment, electron injecting material of the EIL 770 may comprise, but is not limited to, an alkali metal halide or an alkaline earth metal halide such as LiF, CsF, NaF, BaF₂ and the like, and/or an organometallic Compound such as Liq, lithium benzoate, sodium stearate, and the like. In certain embodiments, the EIL 770 may be omitted.

Each of electron blocking materials of the EBL1 630 and the EBL2 730 may independently comprise, but is not limited to, TCTA, Tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, mCP, mCBP, CuPc, DNTPD, TDAPB, DCDPA, 2,8-bis(9-phenyl-9H-carbazol-3-yl)dibenzo[b,d]thiophene and/or combinations thereof, respectively.

Each of hole blocking materials of the HBL1 650 and the HBL2 750 may comprise, but is not limited to, at least one of an oxadiazole-based compound, a triazole-based compound, a phenanthroline-based compound, a benzoxazole-based compound, a benzothiazole-based compound, a benzimidazole-based compound, and a triazine-based compound. For example, each of the hole blocking materials of the HBL1 650 and the HBL2 750 may independently comprise, but is not limited to, BCP, BAlq, Alq₃, PBD, spiro-PBD, Liq, B3PYMPM, DPEPO, 9-(6-(9H-carbazol-9-yl)pyridine-3-yl)-9H-3,9′-bicarbazole, TSPO1 and/or combinations thereof, respectively.

The CGL 680 is disposed between the first emitting part 600 and the second emitting part 700. The CGL 680 comprises an N-type charge generation layer (N-CGL) 685 disposed adjacent to the first emitting part 600 and a P-type charge generation layer (P-CGL) 690 disposed adjacent to the second emitting part 700. The N-CGL 685 injects electrons to the EML1 640 of the first emitting part 600 and the P-CGL 690 injects holes to the EML2 740 of the second emitting part 700.

The N-CGL 685 may be an organic layer comprising electron transporting material doped with an alkali metal such as Li, Na, K and Cs and/or an alkaline earth metal such as Mg, Sr, Ba and Ra. For example, the contents of the alkali metal or the alkaline earth metal in the N-CGL 685 may be, but is not limited to, between about 0.01 wt % and about 30 wt %.

The P-CGL 690 may comprise, but is not limited to, inorganic material selected from the group consisting of tungsten oxide (WOₓ), molybdenum oxide (MoOₓ), beryllium oxide (Be₂O₃), vanadium oxide (V₂O₅) and/or combinations thereof. In another example embodiment, the P-CGL 690 may comprise hole transporting material doped with hole injecting material (e.g., HAT-CN, F4-TCNQ and/or F6-TCNNQ). The contents of the hole injecting material in the P-CGL 690 may be, but is not limited to, between about 2 wt % and about 15 wt %.

The EML1 640 may be a blue EML. In this case, the EML1 640 may be a blue EML, a sky-blue EML or a deep-blue EML. The EML1 640 may comprise a blue host and blue emitter (dopant).

The blue host may comprise at least one of a P-type blue host and an N-type blue host. For example, the blue host may comprise, but is not limited to, mCP, 9-(3-(9H-carbazol-9-yl)phenyl)-9H-carbazole-3-carbonitrile (mCP-CN), mCBP, CBP-CN, 9-(3-(9H-Carbazol-9-yl)phenyl)-3-(diphenylphosphoryl)-9H-carbazole (mCPPO1) 3,5-Di(9H-carbazol-9-yl)biphenyl (Ph-mCP), TSPO1, 9-(3′-(9H-carbazol-9-yl)-[1,1′-biphenyl]-3-yl)-9H-pyrido[2,3-b]indole (CzBPCb), Bis(2-methylphenyl)diphenylsilane (UGH-1), 1,4-Bis(triphenylsilyl)benzene (UGH-2), 1,3-Bis(triphenylsilyl)benzene (UGH-3), 9,9-Spirobifluoren-2-yl-diphenyl-phosphine oxide (SPPO1), 9,9′-(5-(Triphenylsilyl)-1,3-phenylene)bis(9H-carbazole) (SimCP) and/or combinations thereof.

The blue emitter may comprise at least one of blue phosphorescent material, blue fluorescent material and blue delayed fluorescent material. As an example, the blue emitter may comprise, but is not limited to, perylene, 4,4′-Bis[4-(di-p-tolylamino)styryl]biphenyl (DPAVBi), 4-(Di-p-tolylamino)-4-4′-[(di-p-tolylamino)styryl]stilbene (DPAVB), 4,4′-Bis[4-(diphenylamino)styryl]biphenyl (BDAVBi), 2,7-Bis(4-diphenylamino)styryl)-9,9-spirofluorene (spiro-DPVBi), [1,4-bis[2-[4-[N,N-di(p-tolyl)amino]phenyl]vinyl]benzene (DSB), 1-4-di-[4-(N,N-diphenyl)amino]styryl-benzene (DSA), 2,5,8,11-Tetra-tert-butylperylene (TBPe), Bis(2-hydroxylphenyl)-pyridine)beryllium (Bepp₂), 9-(9-Phenylcarbazole-3-yl)-10-(naphthalene-1-yl)anthracene (PCAN), mer-Tris(1-phenyl-3-methylimidazolin-2-ylidene-C,C(2)′iridium(III) (mer-Ir(pmi)₃), fac-Tris(1,3-diphenyl-benzimidazolin-2-ylidene-C,C(2)′iridium(III) (fac-Ir(dpbic)₃), Bis(3,4,5-trifluoro-2-(2-pyridyl)phenyl-(2-carboxypyridyl)iridium(III) (Ir(tfpd)₂pic), tris(2-(4,6-difluorophenyl)pyridine))iridium(III) (Ir(Fppy)₃), Bis[2-(4,6-difluorophenyl)pyridinato-C²,N](picolinato)iridium(III) (FIrpic) and/or combinations thereof.

The contents of the blue host in the EML1 640 may be about 50 wt % to about 99 wt %, for example, about 80 wt % to about 95 wt %, and the contents of the blue emitter in the EML1 640 may be about 1 wt % to about 50 wt %, for example, about 5 wt % to about 20 wt %, but is not limited thereto. When the EML1 640 comprises both the P-type blue host and the N-type blue host, the P-type blue host and the N-type blue host may be admixed, but is not limited to, with a weight ratio of about 4:1 to about 1:4, for example about 3:1 to about 1:3.

The EML2 740 may comprise a first layer (lower EML) 740A disposed between the EBL2 730 and the HBL2 750 and a second layer (upper EML) 740B disposed between the first layer 740A and the HBL2 750. One of the first layer 740A and the second layer 740B may emit red to yellow color light and the other of the first layer 740A and the second layer 740B may emit green color light. Hereinafter, the EML2 740 where the first layer 740A emits a red to yellow color light and the second layer 740B emits a green color light will be described in detail.

The first layer 740A comprises a first compound 742, a second compound 744, and optionally, a third compound 746. The first compound 742 is fluorescent emitter (fluorescent dopant) having the structure of Chemical Formulae 1 to 3, and may emit red to yellow color light.

The second compound 744 may be an N-type host of an azine-based organic compound. The second compound 744 may comprise the organic compound having the structure of Chemical Formulae 4 to 7. The third compound 746 may be a P-type host of a carbazole-based organic compound. The third compound 746 may comprise the organic compound having the structure of Chemical Formulae 8 to 10. The contents of the first compound 742, the second compound 744, and the third compound 746 may be identical to the corresponding materials described in an example embodiment disclosed in connection with FIG. 3.

The second layer 740B may comprise a green host and a green emitter (green dopant). The green host may comprise at least one of a P-type green host and an N-type green host. In one example embodiment, the green host may be identical to the third compound 746 and/or the fourth compound 748. In another example embodiment, the green host may comprise, but is not limited to, mCP-CN, CBP, mCBP, mCP, DPEPO, PPT, TmPyPB, PYD-2Cz, DCzDBT, DCzTPA, pCzB-2CN, mCzB-2CN, TSPO1, CCP, 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicabazole, BCzPh, BCZ, TCP, TCTA, CDBP, DMFL-CBP, Spiro-CBP, TCzl and/or combinations thereof.

The green emitter may comprise at least one of green phosphorescent material, green fluorescent material and green delayed fluorescent material. As an example, the green emitter may comprise, but is not limited to, [Bis(2-phenylpyridine)](pyridyl-2-benzofuro[2,3-b]pyridine)iridium, Tris[2-phenylpyridine]iridium(III) (Ir(ppy)₃), fac-Tris(2-phenylpyridine)iridium(III) (fac-Ir(ppy)₃), Bis(2-phenylpyridine)(acetylacetonate)iridium(III) (Ir(ppy)₂(acac)), Tris[2-(p-tolyl)pyridine]iridium(III) (Ir(mppy)₃), Bis(2-(naphthalen-2-yl)pyridine)(acetylacetonate)iridium(III) (Ir(npy)₂acac), Tris(2-phenyl-3-methyl-pyridine)iridium (Ir(3mppy)₃), fac-Tris(2-(3-p-xylyl)phenyl)pyridine iridium(III) (TEG) and/or combinations thereof.

The contents of the green host in the second layer 740B may be about 50 wt % to about 99 wt %, for example, about 80 wt % to about 95 wt %, and the contents of the green emitter in the second layer 740B may be about 1 wt % to about 50 wt %, for example, about 5 wt % to about 20 wt %, but is not limited thereto. When the second layer 740B comprises both the P-type green host and the N-type green host, the P-type green host and the N-type green host may be admixed, but is not limited to, with a weight ratio of about 4:1 to about 1:4, for example about 3:1 to about 1:3.

Alternatively, the EML2 740 may further comprise a third layer (740C in FIG. 9) that may emit yellow-green color light and may be disposed between the first layer 740A of the red EML and the second layer 740B of the green EML.

The OLED D3 with a tandem structure in accordance with this embodiment comprises the first compound 742 of the organic compound having the structure of Chemical Formulae 1 to 3, the second compound 744 of the organic compound having the structure of Chemical Formulae 4 to 7, and optionally, the third compound 746 of the organic compound having the structure of Chemical Formulae 8 to 10. The first compound 742 having the structure of Chemical Formulae 1 to 3 has a wide plate-like structure and may receive singlet exciton energy from the second compound 744 and/or the third compound 746. The luminous efficiency and the luminous lifespan of the OLED D3 may be improved.

An OLED may have three or more emitting parts to form a tandem structure. FIG. 9 is a schematic cross-sectional view illustrating an organic light emitting diode in accordance with yet another example embodiment of the present disclosure.

As illustrated in FIG. 9, the OLED D4 comprises first and second electrodes 510 and 520 facing each other and an emissive layer 530A disposed between the first and second electrodes 510 and 520. The emissive layer 530A comprises a first emitting part 600 disposed between the first and second electrodes 510 and 520, a second emitting part 700A disposed between the first emitting part 600 and the second electrode 520, a third emitting part 800 disposed between the second emitting part 700A and the second electrode 520, a first charge generation layer (CGL1) 680 disposed between the first and second emitting parts 600 and 700A, and a second charge generation layer (CGL2) 780 disposed between the second and third emitting parts 700A and 800.

The first emitting part 600 comprises a first emitting material layer (EML1) 640. The first emitting part 600 may further comprise at least one of a hole injection layer (HIL) 610 disposed between the first electrode 510 and the EML1 640, a first hole transport layer (HTL1) 620 disposed between the HIL 610 and the EML1 640, a first electron transport layer (ETL1) 660 disposed between the EML1 640 and the CGL1 680. Alternatively, the first emitting part 600 may further comprise a first electron blocking layer (EBL1) 630 disposed between the HTL1 620 and the EML1 640 and/or a first hole blocking layer (HBL1) 650 disposed between the EML1 640 and the ETL1 660.

The second emitting part 700A comprises a second emitting material layer (EML2) 740′. The second emitting part 700A may further comprise at least one of a second hole transport layer (HTL2) 720 disposed between the CGL1 680 and the EML2 740′ and a second electron transport layer (ETL2) 760 disposed between the EML2 740′ and the CGL2 780. Alternatively, the second emitting part 700A may further comprise a second electron blocking layer (EBL2) 730 disposed between the HTL2 720 and the EML2 740′ and/or a second hole blocking layer (HBL2) 750 disposed between the EML2 740′ and the ETL2 760.

The third emitting part 800 comprises a third emitting material layer (EML3) 840. The third emitting part 800 may further comprise at least one of a third hole transport layer (HTL3) 820 disposed between the CGL2 780 and the EML3 840, a third electron transport layer (ETL3) 860 disposed between the second electrode 520 and the EML3 840 and an electron injection layer (EIL) 870 disposed between the second electrode 520 and the ETL3 860. Alternatively, the third emitting part 800 may further comprise a third electron blocking layer (EBL3) 830 disposed between the HTL3 820 and the EML3 840 and/or a third hole blocking layer (HBL3) 850 disposed between the EML3 840 and the ETL3 860.

The CGL1 680 is disposed between the first emitting part 600 and the second emitting part 700A and the CGL2 780 is disposed between the second emitting part 700A and the third emitting part 800. The CGL1 680 comprises a first N-type charge generation layer (N-CGL1) 685 disposed adjacent to the first emitting part 600 and a first P-type charge generation layer (P-CGL1) 690 disposed adjacent to the second emitting part 700A. The CGL2 780 comprises a second N-type charge generation layer (N-CGL2) 785 disposed adjacent to the second emitting part 700A and a second P-type charge generation layer (P-CGL2) 790 disposed adjacent to the third emitting part 800. Each of the N-CGL1 685 and the N-CGL2 785 injects electrons to the EML1 640 of the first emitting part 600 and the EML2 740′ of the second emitting part 700A, respectively, and each of the P-CGL1 690 and the P-CGL2 790 injects holes to the EML2 740′ of the second emitting part 700A and the EML3 840 of the third emitting part 800, respectively.

The materials comprised in the HIL 610, the HTL1 to the HTL3 620, 720 and 820, the EBL1 to the EBL3 630, 730 and 830, the HBL1 to the HBL3 650, 750 and 850, the ETL1 to the ETL3 660, 760 and 860, the EIL 870, the CGL1 680, and the CGL2 780 may be identical to the materials disclosed in example embodiments described in connection with FIGS. 3 and 8.

At least one of the EML1 640, the EML2 740′ and the EML3 840 may comprise a first compound having the structure of Chemical Formulae 1 to 3. For example, one of the EML1 640, the EML2 740′ and the EML3 840 may emit red to green color light, and the other of the EML1 640, the EML2 740′ and the EML3 840 may emit blue color light so that the OLED D4 may realize white (W) emission. Hereinafter, the OLED D4 where the EML2 740′ comprises the first compound having the structure of Chemical Formulae 1 to 3 and emits red to green color light, and each of the EML1 640 and the EML3 840 emits blue color light will be described in detail.

Each of the EML1 640 and the EML3 840 may be independently a blue EML. In this case, each of the EML1 640 and the EML3 840 may be independently a blue EML, a sky-blue EML or a deep-blue EML. Each of the EML1 640 and the EML3 840 may independently comprise a blue host and a blue emitter (dopant). Each of the blue host and the blue emitter may be identical to corresponding materials disclosed in an example embodiment described in connection with FIG. 8. For example, the blue emitter may comprise at least one of blue phosphorescent material, blue fluorescent material and blue delayed fluorescent material. Alternatively, the blue emitter in the EML1 640 may be identical to or different from the blue emitter in the EML3 840 in terms of color and/or luminous efficiency.

The EML2 740′ may comprise a first layer (lower EML) 740A disposed between the EBL2 730 and the HBL2 750, a second layer (upper EML) 740B disposed between the first layer 740A and the HBL2 750, and a third layer (middle EML) 740C disposed between the first layer 740A and the second layer 740B. One of the first layer 740A and the second layer 740B may emit red to yellow color and the other of the first layer 740A and the second layer 740B may emit green color. Hereinafter, the EML2 740′ where the first layer 740A emits a red to yellow color and the second layer 740B emits a green color will be described in detail.

The first layer 740A may comprise a first compound 742, a second compound 744, and optionally, a third compound 746. The first compound 742 may comprise the organic compound having the structure of Chemical Formulae 1 to 3 and may be fluorescent emitter (fluorescent dopant). The second compound 744 may comprise the azine-based organic compound having the structure of Chemical Formulae 4 to 7 and may be an N-type host. The third compound 746 may be the carbazole-based organic compound having the structure of Chemical Formulae 6 to 8 and may be the P-type host. The contents of the first compound 742, the second compound 744 and the third compound 746 in the first layer 740A may be identical to the corresponding materials described in an example embodiment disclosed in connection with FIG. 3.

The second layer 740B may comprise a green host and green emitter (green dopant). The kinds and the contents of the green host and the green emitter may be identical to the corresponding materials described in an example embodiment disclosed in connection with FIG. 8. For example, the green emitter may comprise at least one of green phosphorescent material, green fluorescent material and green delayed fluorescent material.

The third layer 740C may be a yellow-green emitting material layer. The third layer 740C may comprise a yellow-green host and a yellow-green emitter (dopant). The yellow-green host may comprise at least one of a P-type yellow-green host and an N-type yellow-green host. As an example, the yellow-green host may be identical to the third compound 746, the fourth compound 748 and/or the green host.

The yellow-green emitter may comprise at least one of yellow-green fluorescent material, yellow-green phosphorescent material and yellow-green delayed fluorescent material. For example, the yellow-green emitter may comprise, but is not limited to, 5,6,11,12-Tetraphenylnaphthalene (Rubrene), 2,8-Di-tert-butyl-5,11-bis(4-tert-butylphenyl)-6,12-diphenyltetracene (TBRb), Bis(2-phenylbenzothiazolato)(acetylacetonate)iridium(III) (Ir(BT)₂(acac)), Bis(2-(9,9-diethyl-fluoren-2-yl)-1-phenyl-1H-benzo[d]imdiazolato)(acetylacetonate)iridium(III) (Ir(fbi)₂(acac)), Bis(2-phenylpyridine)(3-(fac-Ir(ppy)₂Pc), Bis(2-(2,4-(pyridine-2-yl)-2H-chromen-2-onate)iridium(III) difluorophenyl)quinoline)(picolinate)iridium(III) (FPQIrpic), Bis(4-phenylthieno[3,2-c]pyridinato-N,C2′) (acetylacetonate) iridium(III) (PO-01) and/or combinations thereof.

The contents of the yellow-green host in the third layer 740C may be about 50 wt % to about 99 wt %, for example, about 80 wt % to about 95 wt %, and the contents of the yellow-green emitter in the third layer 740C may be about 1 wt % to about 50 wt %, for example, about 5 wt % to about 20 wt %, but is not limited thereto. When the third layer 740C comprises both the P-type yellow-green host and the N-type yellow-green host, the P-type yellow-green host and the N-type yellow-green host may be admixed, but is not limited to, with a weight ratio of about 4:1 to about 1:4, for example about 3:1 to about 1:3.

The OLED D4 with a tandem structure in accordance with this embodiment comprises the first compound 742 of the organic compound having the structure of Chemical Formulae 1 to 3 in the at least one emitting material layer. Since the first compound 742 has a wide plate-like structure, the first compound may receive efficiently singlet exciton energy from the second compound 744 and/or the third compound 746. The OLED D4 with three emitting parts comprising the first compound 742 and the second compound 744 may implement white emission with improved luminous efficiency and the luminous lifespan. In addition, the organic light emitting diode may comprise four or more emitting parts.

### Synthesis Example 1: Synthesis of Compound 1-1

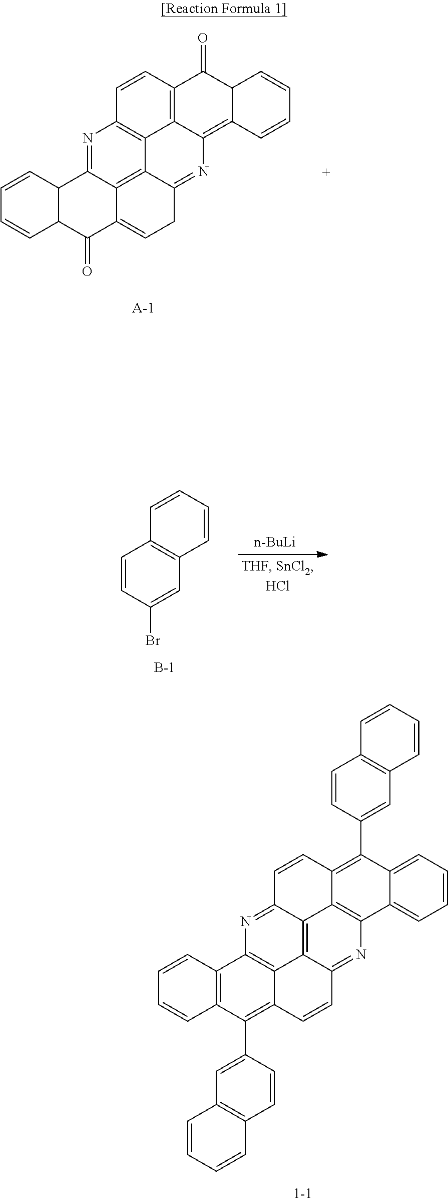

Compound A-1 (3.0 g, 7.3 mmol) and compound B-1 (4.55 g, 22.1 mmol) dissolved in anhydrous tetrahydrofuran (THF, 50 ml) were added into a 100 ml round bottom flask under nitrogen atmosphere, and then the solution was stirred at −78° C. n-BuLi (8.8 ml, 2.5 M) was added dropwise into the round bottom flask and then the solution was stirred again for 3 hours. After the reaction was complete, the temperature was raised to room temperature, and then the mixture was stirred for 12 hours. 3M HCl solution (50 ml) and SnCl₂ (2.08 g, 11 mmol) were added into the round bottom flask under nitrogen atmosphere, and the solution was stirred for 3 hours. Triethylamine was added into the solution to adjust pH of the solution to be neutral, the solution was stirred for 3 hours. Organic phase was extracted with water and dichloromethane and treated with anhydrous MgSO₄. The organic phase was filtered and subjected to reduced pressure to obtain a crude product. The crude product was purified with column chromatography (eluent: dichloromethane) and recrystallized to give a solid Compound 1-1 (0.55 g, 12%).

### Synthesis Example 2: Synthesis of Compound 1-2

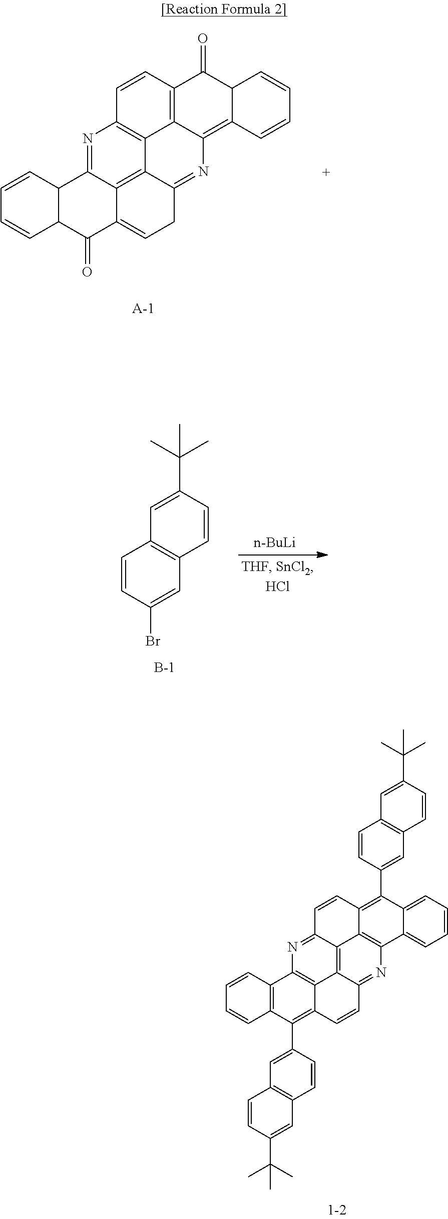

Compound A-1 (3.0 g, 7.3 mmol) and compound B-2 (5.79 g, 22.1 mmol) dissolved in anhydrous tetrahydrofuran (THF, 50 ml) were added into a 100 ml round bottom flask under nitrogen atmosphere, and then the solution was stirred at −78° C. n-BuLi (8.8 ml, 2.5 M) was added dropwise into the round bottom flask and then the solution was stirred again for 3 hours. After the reaction was complete, the temperature was raised to room temperature, and then the mixture was stirred for 12 hours. 3M HCl solution (50 ml) and SnCl₂ (2.08 g, 11 mmol) were added into the round bottom flask under nitrogen atmosphere, and the solution was stirred for 3 hours. Triethylamine was added into the solution to adjust pH of the solution to be neutral, the solution was stirred for 3 hours. Organic phase was extracted with water and dichloromethane and treated with anhydrous MgSO₄. The organic phase was filtered and subjected to reduced pressure to obtain a crude product. The crude product was purified with column chromatography (eluent: dichloromethane) and recrystallized to give a solid Compound 1-2 (0.71 g, 13%).

### Synthesis Example 3: Synthesis of Compound 1-3

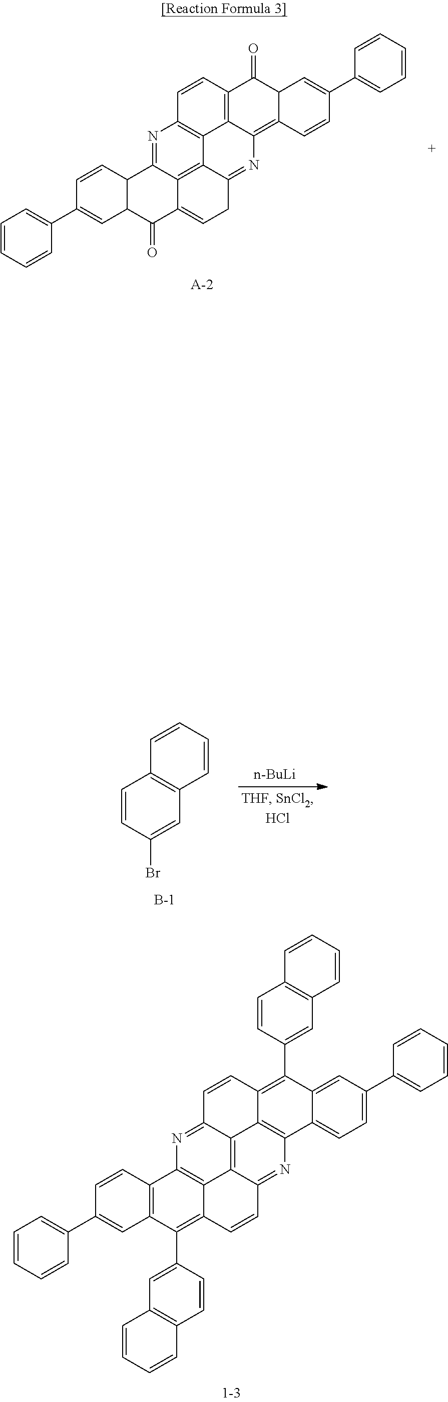

Compound A-2 (4.1 g, 7.3 mmol) and compound B-1 (4.55 g, 22.1 mmol) dissolved in anhydrous tetrahydrofuran (THF, 50 ml) were added into a 100 ml round bottom flask under nitrogen atmosphere, and then the solution was stirred at −78° C. n-BuLi (8.8 ml, 2.5 M) was added dropwise into the round bottom flask and then the solution was stirred again for 3 hours. After the reaction was complete, the temperature was raised to room temperature, and then the mixture was stirred for 12 hours. 3M HCl solution (50 ml) and SnCl₂ (2.08 g, 11 mmol) were added into the round bottom flask under nitrogen atmosphere, and the solution was stirred for 3 hours. Triethylamine was added into the solution to adjust pH of the solution to be neutral, the solution was stirred for 3 hours. Organic phase was extracted with water and dichloromethane and treated with anhydrous MgSO₄. The organic phase was filtered and subjected to reduced pressure to obtain a crude product. The crude product was purified with column chromatography (eluent: dichloromethane) and recrystallized to give a solid Compound 1-3 (0.42 g, 10%).

### Synthesis Example 4: Synthesis of Compound 1-4

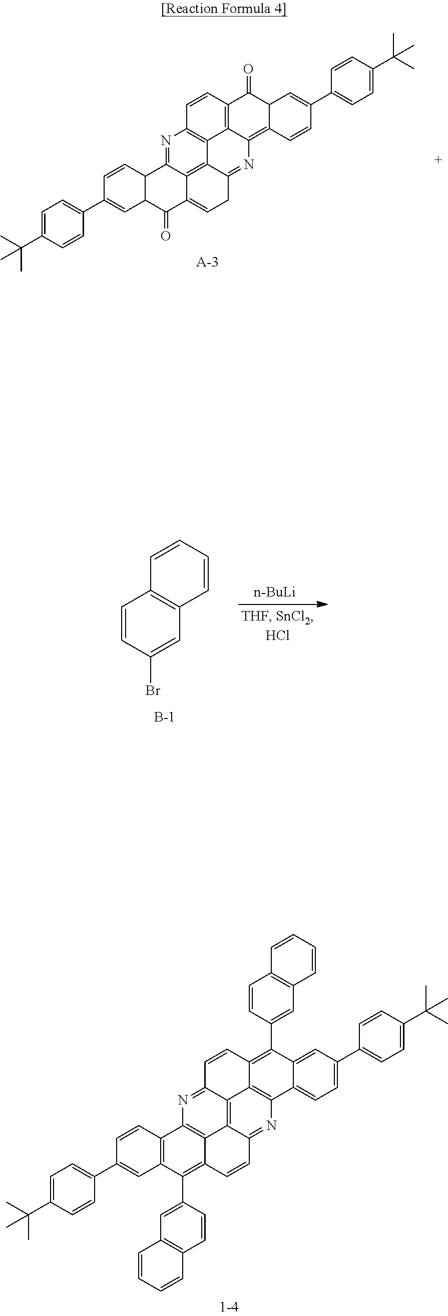

Compound A-3 (4.93 g, 7.3 mmol) and compound B-1 (4.55 g, 22.1 mmol) dissolved in anhydrous tetrahydrofuran (THF, 50 ml) were added into a 100 ml round bottom flask under nitrogen atmosphere, and then the solution was stirred at −78° C. n-BuLi (8.8 ml, 2.5 M) was added dropwise into the round bottom flask and then the solution was stirred again for 3 hours. After the reaction was complete, the temperature was raised to room temperature, and then the mixture was stirred for 12 hours. 3M HCl solution (50 ml) and SnCl₂ (2.08 g, 11 mmol) were added into the round bottom flask under nitrogen atmosphere, and the solution was stirred for 3 hours. Triethylamine was added into the solution to adjust pH of the solution to be neutral, the solution was stirred for 3 hours. Organic phase was extracted with water and dichloromethane and treated with anhydrous MgSO₄. The organic phase was filtered and subjected to reduced pressure to obtain a crude product. The crude product was purified with column chromatography (eluent: dichloromethane) and recrystallized to give a solid Compound 1-4 (0.44 g, 11%).

### Synthesis Example 5: Synthesis of Compound 1-5

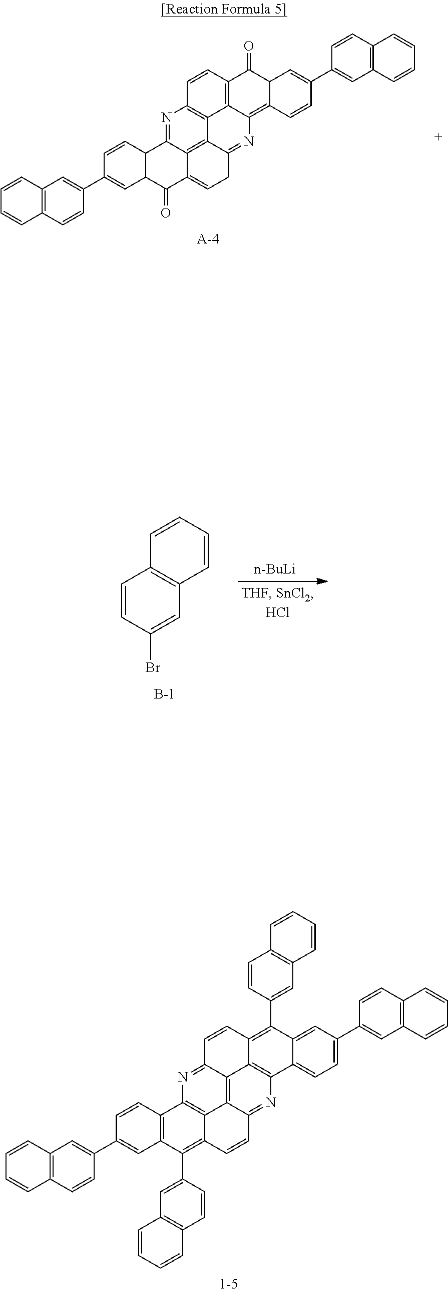

Compound A-4 (4.9 g, 7.3 mmol) and compound B-1 (4.55 g, 22.1 mmol) dissolved in anhydrous tetrahydrofuran (THF, 50 ml) were added into a 100 ml round bottom flask under nitrogen atmosphere, and then the solution was stirred at −78° C. n-BuLi (8.8 ml, 2.5 M) was added dropwise into the round bottom flask and then the solution was stirred again for 3 hours. After the reaction was complete, the temperature was raised to room temperature, and then the mixture was stirred for 12 hours. 3M HCl solution (50 ml) and SnCl₂ (2.08 g, 11 mmol) were added into the round bottom flask under nitrogen atmosphere, and the solution was stirred for 3 hours. Triethylamine was added into the solution to adjust pH of the solution to be neutral, the solution was stirred for 3 hours. Organic phase was extracted with water and dichloromethane and treated with anhydrous MgSO₄. The organic phase was filtered and subjected to reduced pressure to obtain a crude product. The crude product was purified with column chromatography (eluent: dichloromethane) and recrystallized to give a solid Compound 1-5 (0.16 g, 11%).

### Synthesis Example 6: Synthesis of Compound 1-6

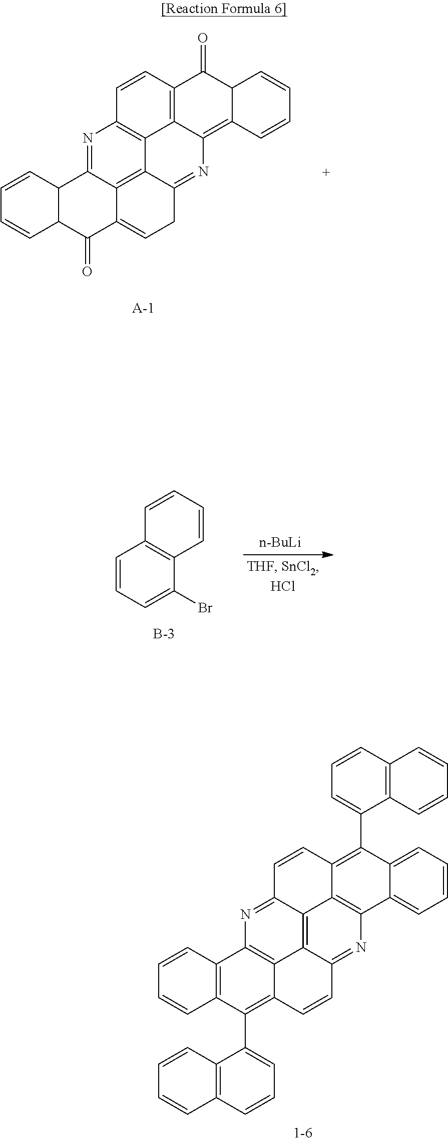

Compound A-1 (3.0 g, 7.3 mmol) and compound B-3 (4.55 g, 22.1 mmol) dissolved in anhydrous tetrahydrofuran (THF, 50 ml) were added into a 100 ml round bottom flask under nitrogen atmosphere, and then the solution was stirred at −78° C. n-BuLi (8.8 ml, 2.5 M) was added dropwise into the round bottom flask and then the solution was stirred again for 3 hours. After the reaction was complete, the temperature was raised to room temperature, and then the mixture was stirred for 12 hours. 3M HCl solution (50 ml) and SnCl₂ (2.08 g, 11 mmol) were added into the round bottom flask under nitrogen atmosphere, and the solution was stirred for 3 hours. Triethylamine was added into the solution to adjust pH of the solution to be neutral, the solution was stirred for 3 hours. Organic phase was extracted with water and dichloromethane and treated with anhydrous MgSO₄. The organic phase was filtered and subjected to reduced pressure to obtain a crude product. The crude product was purified with column chromatography (eluent: dichloromethane) and recrystallized to give a solid Compound 1-6 (0.69 g, 15%).

### Synthesis Example 7: Synthesis of Compound 1-7

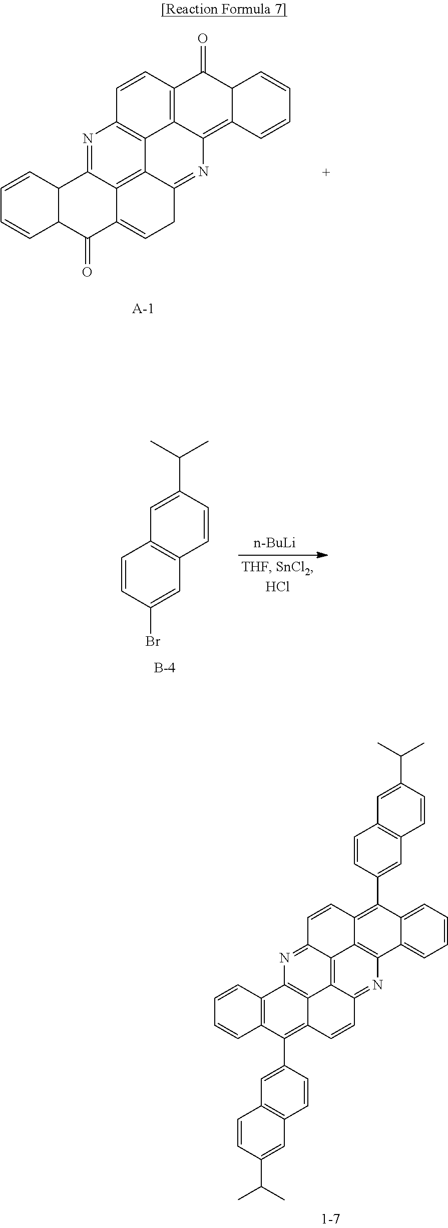

Compound A-1 (3.01 g, 7.3 mmol) and compound B-4 (5.48 g, 22.1 mmol) dissolved in anhydrous tetrahydrofuran (THF, 50 ml) were added into a 100 ml round bottom flask under nitrogen atmosphere, and then the solution was stirred at −78° C. n-BuLi (8.8 ml, 2.5 M) was added dropwise into the round bottom flask and then the solution was stirred again for 3 hours. After the reaction was complete, the temperature was raised to room temperature, and then the mixture was stirred for 12 hours. 3M HCl solution (50 ml) and SnCl₂ (2.08 g, 11 mmol) were added into the round bottom flask under nitrogen atmosphere, and the solution was stirred for 3 hours. Triethylamine was added into the solution to adjust pH of the solution to be neutral, the solution was stirred for 3 hours. Organic phase was extracted with water and dichloromethane and treated with anhydrous MgSO₄. The organic phase was filtered and subjected to reduced pressure to obtain a crude product. The crude product was purified with column chromatography (eluent: dichloromethane) and recrystallized to give a solid Compound 1-7 (0.53 g, 10%).

### Synthesis Example 8: Synthesis of Compound 1-17

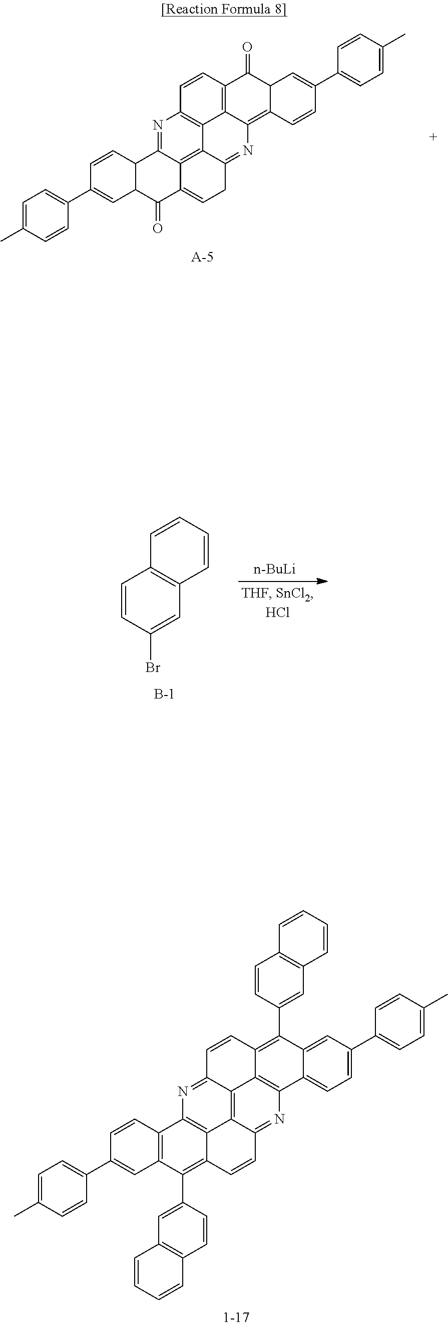

Compound A-4 (4.3 g, 7.3 mmol) and compound B-1 (4.55 g, 22.1 mmol) dissolved in anhydrous tetrahydrofuran (THF, 50 ml) were added into a 100 ml round bottom flask under nitrogen atmosphere, and then the solution was stirred at −78° C. n-BuLi (8.8 ml, 2.5 M) was added dropwise into the round bottom flask and then the solution was stirred again for 3 hours. After the reaction was complete, the temperature was raised to room temperature, and then the mixture was stirred for 12 hours. 3M HCl solution (50 ml) and SnCl₂ (2.08 g, 11 mmol) were added into the round bottom flask under nitrogen atmosphere, and the solution was stirred for 3 hours. Triethylamine was added into the solution to adjust pH of the solution to be neutral, the solution was stirred for 3 hours. Organic phase was extracted with water and dichloromethane and treated with anhydrous MgSO₄. The organic phase was filtered and subjected to reduced pressure to obtain a crude product. The crude product was purified with column chromatography (eluent: dichloromethane) and recrystallized to give a solid Compound 1-17 (0.45 g, 12%).

### Example 1 (Ex. 1): Fabrication of OLED

An organic light emitting diode where Compound 1-1 of Synthesis Example 1 as a first compound (fluorescent emitter), Compound 2-1 in Chemical Formula 7 as a second compound (N-type host) and Compound 3-1 in Chemical Formula 10 as a third compound (P-type host) were included in an emitting material layer was fabricated. A glass substrate onto which ITO (50 nm) was coated as a thin film was washed and ultrasonically cleaned by solvent such as isopropyl alcohol, acetone and dried at 100° C. oven. The substrate was transferred to a vacuum chamber for depositing emissive layer. Subsequently, an emissive layer and a cathode were deposited by evaporation from a heating boat under about 5×10⁻⁷ Torr to 7×10⁻⁷ Torr with setting a deposition rate 1 Å/s as the following order:

A hole injection layer (HAT-CN, 7 nm); a hole transport layer (NPB, 78 nm); an electron blocking layer (TAPC, 10 nm); an emitting material layer (Compound 3-1 in Chemical Formula 10 (mCBP, 64 wt %), Compound 2-1 (35 wt %), Compound 1-1 (1 wt %), 38 nm); a hole blocking layer (B3PYMPM, 10 nm); an electron transport layer (TPBi, 25 nm); an electron injection layer (LiF, 1 nm): and a cathode (Al, 100 nm).

The structures of hole injection material, hole transporting material, electron blocking material, hole blocking material and electron transporting material are illustrated in the following:

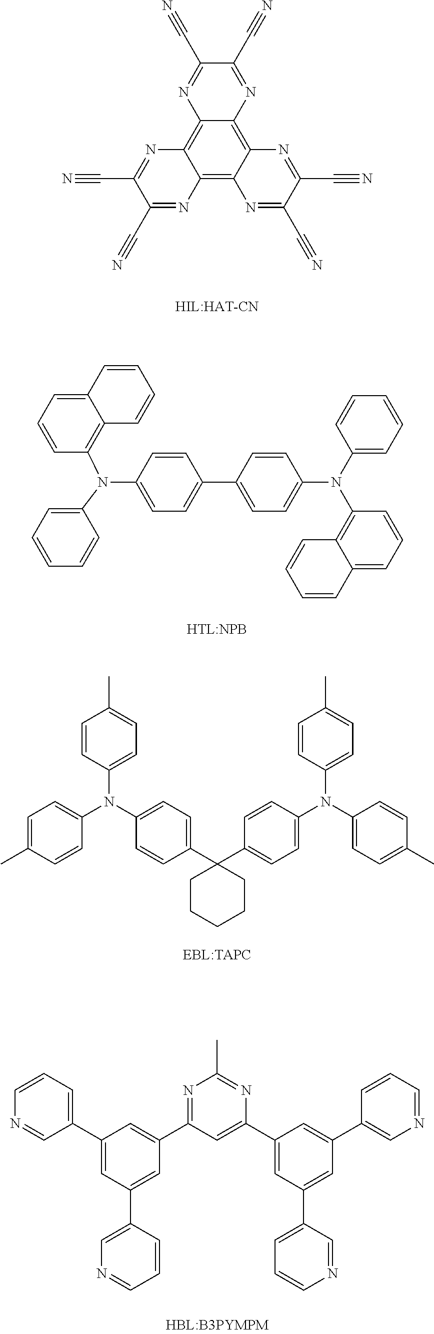

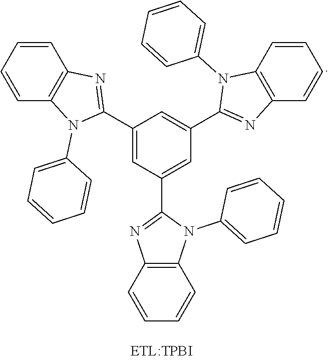 [SMILES: c1ccc(-n2c(-c3cc(-c4nc5ccccc5n4-c4ccccc4)cc(-c4nc5ccccc5n4-c4ccccc4)c3)nc3ccccc32)cc1]

### Examples 2-6 (Ex. 2-6): Fabrication of OLEDs

An OLED was fabricated using the same procedure and the same materials as Example 1, except that instead of Compound 1-1, each of Compound 1-2 (Ex. 2), Compound 1-3 (Ex. 3), Compound 1-4 (Ex. 4), Compound 1-5 (Ex. 5), and Compound 1-6 (Ex. 6) was used as the emitter in the emitting material layer in Examples 2-6, respectively.

### Comparative Examples 1-8 (Refs.1-8): Fabrication of OLED

An OLED was fabricated using the same procedure and the same materials as Example 1, except that instead of Compound 1-1, each of the following Compound Ref.1-1 (Ref. 1), Compound Ref.1-2 (Ref. 2), Compound Ref.1-3 (Ref. 3), Compound Ref.1-4 (Ref. 4), Compound Ref.1-5 (Ref. 5), Compound Ref.1-6 (Ref. 6), Compound Ref.1-7 (Ref. 7) and Compound Ref.1-8 (Ref. 8) was used as the emitter in the emitting material layer in Refs. 1-8, respectively.

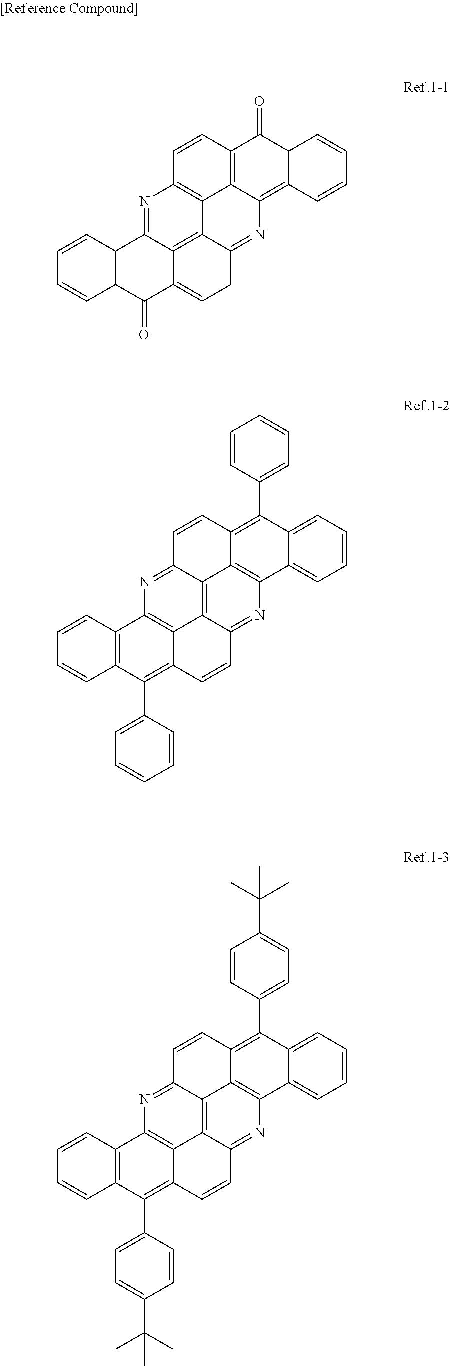 [SMILES: O=C1c2ccc3nc4c5c6c(nc(c2c36)=C2C=CC=CC12)CC=C5C(=O)C1C=CC=CC41 ; c1ccc(-c2c3ccccc3c3nc4ccc5c(-c6ccccc6)c6ccccc6c6nc7ccc2c3c7c4c56)cc1 ; CC(C)(C)c1ccc(-c2c3ccccc3c3nc4ccc5c(-c6ccc(C(C)(C)C)cc6)c6ccccc6c6nc7ccc2c3c7c4c56)cc1]

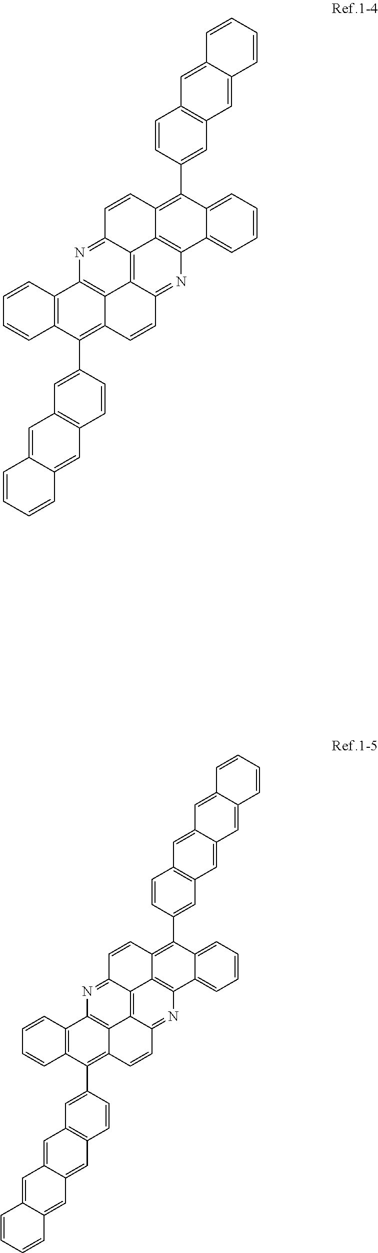 [SMILES: c1ccc2cc3cc(-c4c5ccccc5c5nc6ccc7c(-c8ccc9cc%10ccccc%10cc9c8)c8ccccc8c8nc9ccc4c5c9c6c78)ccc3cc2c1 ; c1ccc2cc3cc4cc(-c5c6ccccc6c6nc7ccc8c(-c9ccc%10cc%11cc%12ccccc%12cc%11cc%10c9)c9ccccc9c9nc%10ccc5c6c%10c7c89)ccc4cc3cc2c1]

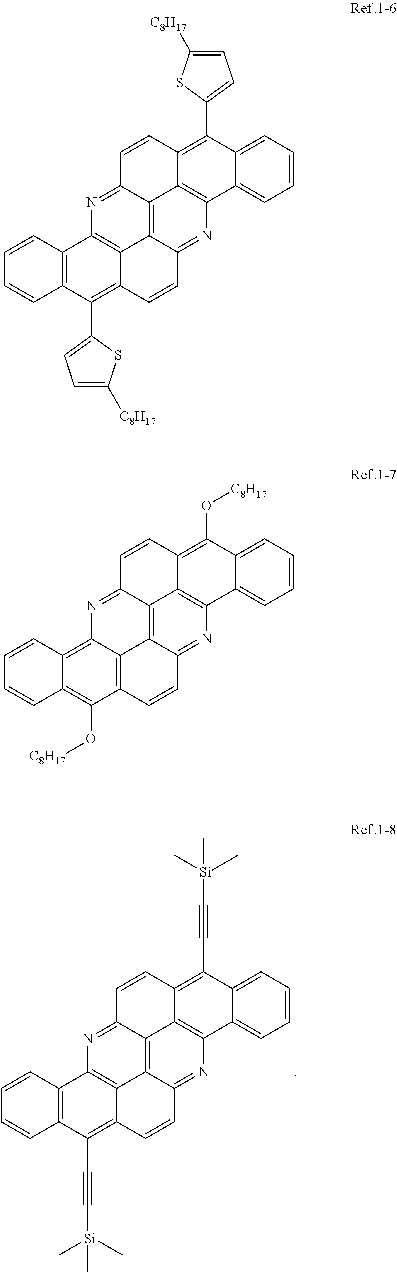

### Experimental Example 1: Measurement of Energy Level and Dipole Moment of Compounds

Luminous property for the OLEDs fabricated in Examples 1 to 6 and Comparative Examples 1 to 8 was measured. Each of the OLEDs having luminous area of 9 mm² was connected to external power source and the luminous property was measured using a current source (KEITHLEY) and a photometer (PR650) at room temperature. In particular, driving voltage (V), external quantum efficiency (EQE, relative value) and lifespan (LT₉₅, relative value) at which the luminance was reduced to 95% from initial luminance was measured at a current density 6 mA/cm². The measurement results are indicated in the following Table 1.

TABLE 1
Luminous Properties of OLED

| Sample | Emitter | V | EQE (%) | LT₉₅ (%) |
|---|---|---|---|---|
| Ref. 1 | Ref. 1-1 | 3.7 | 96% | 38% |
| Ref. 2 | Ref. 1-2 | 3.7 | 100% | 100% |
| Ref. 3 | Ref. 1-3 | 3.7 | 98% | 100% |
| Ref. 4 | Ref. 1-4 | 3.7 | 99% | 92% |
| Ref. 5 | Ref. 1-5 | 3.7 | 97% | 88% |
| Ref. 6 | Ref. 1-6 | 3.6 | 85% | 40% |
| Ref. 7 | Ref. 1-7 | 3.6 | 88% | 37% |
| Ref. 8 | Ref. 1-8 | 3.5 | 67% | 31% |
| Ex. 1 | 1-1 | 3.7 | 107% | 127% |
| Ex. 2 | 1-2 | 3.7 | 110% | 134% |
| Ex. 3 | 1-3 | 3.7 | 106% | 129% |
| Ex. 4 | 1-4 | 3.7 | 108% | 133% |
| Ex. 5 | 1-5 | 3.7 | 107% | 131% |
| Ex. 6 | 1-6 | 3.7 | 104% | 124% |

As indicated in Table 1, compared to the OLED fabricated in Ref. 2 in which Compound Ref.1-2 having a phenyl group attached to the core was used as the emitter, in the OLED fabricated in Ref. 1 in which Ref. 1-1 having an oxygen atom linked to the core by an exocyclic bond was used as the emitter, and in Ref. 4 to Ref. 8 in which Compounds Ref. 1-4 to Ref. 1-8, an anthracenyl group with three fused aromatic rings, a tetracenyl group with four fused aromatic rings, a heteroaryl group, an alkoxy group or a silyl group is attached to the core, were used as the emitter, EQE and the luminous lifespan were reduced. On the other hand, compared to the OLED fabricated in Ref. 2, in the OLED fabricated in Ex. 1 to Ex. 6 in which compounds having a naphthyl group attached to the core were used, driving voltage was similar, but EQE and luminous lifespan was improved significantly.

### Examples 7-9 (Ex. 7-9): Fabrication of OLEDs

An OLED was fabricated using the same procedure and the same materials as Example 3, except that Compound 2-2 (Ex. 7), Compound 2-3 (Ex. 8) and Compound 2-4 (Ex. 9) in Chemical Formula 7 was used as the second compound (N-type host) in the emitting material layer in Ex. 7-9, respectively.

### Example 10 (Ex. 10): Fabrication of OLED

An OLED was fabricated using the same procedure and the same materials as Example 1, except that Compound 1-17 instead of Compound 1-1 was used as the emitter in the emitting material layer.

### Examples 11-13 (Ex. 11-13): Fabrication of OLEDs

An OLED was fabricated using the same procedure and the same materials as Example 10, except that Compound 2-2 (Ex. 11), Compound 2-3 (Ex. 12) and Compound 2-4 (Ex. 13) in Chemical Formula 7 was used as the second compound (N-type host) in the emitting material layer in Ex. 11-13, respectively.

### Example 14 (Ex. 14): Fabrication of OLED

An OLED was fabricated using the same procedure and the same materials as Example 1, except that Compound 1-7 instead of Compound 1-1 as the emitter was used and Compound 2-2 instead of Compound 2-1 as the second compound (N-type host) in the emitting material layer was used.

### Example 15 (Ex. 15): Fabrication of OLED

An OLED was fabricated using the same procedure and the same materials as Example 7, except that a charge control layer (Compound 2-3 in Chemical Formula 7, 5 nm) between the emitting material layer and the hole blocking layer was further stacked.

### Example 16 (Ex. 16): Fabrication of OLED

An OLED was fabricated using the same procedure and the same materials as Example 11, except that a charge control layer (Compound 2-3 in Chemical Formula 7, 5 nm) between the emitting material layer and the hole blocking layer was further stacked.

### Comparative Examples 9-12 (Ref. 9-12): Fabrication of OLEDs

An OLED was fabricated using the same procedure and the same materials as Example 3, except that each of the following Compound Ref.2-1 (Ref. 9), Compound Ref.2-2 (Ref. 10), Compound Ref.2-3 (Ref. 11) and Compound Ref.2-4 (Ref. 12) instead of Compound 2-1 was used as the second compound (N-type host) in the emitting material layer in Ref. 9-12, respectively.

### Comparative Examples 13-16 (Ref. 13-16): Fabrication of OLEDs

An OLED was fabricated using the same procedure and the same materials as Example 10, except that each of the following Compound Ref.2-1 (Ref. 13), Compound Ref.2-2 (Ref. 14), Compound Ref.2-3 (Ref. 15) and Compound Ref.2-4 (Ref. 16) instead of Compound 2-1 was used as the second compound (N-type host) in the emitting material layer in Ref. 13-16, respectively.

### Comparative Example 17 (Ref. 17): Fabrication of OLED

An OLED was fabricated using the same procedure and the same materials as Example 14, except that the following Compound Ref.2-2 instead of Compound 2-2 was used as the second compound (N-type host) in the emitting material layer.

### Comparative Example 18 (Ref. 18): Fabrication of OLED

An OLED was fabricated using the same procedure and the same materials as Example 1, except that Compound Ref.1-2 instead of Compound 1-1 as the emitter was used and the following Compound Ref.2-1 instead of Compound 2-1 as the second compound (N-type host) in the emitting material layer was used.

### Comparative Examples 19-21 (Ref. 19-21): Fabrication of OLEDs

An OLED was fabricated using the same procedure and the same materials as Comparative Example 18, except that each of the following Compound Ref.2-2 (Ref. 19), Compound Ref.2-3 (Ref. 20) and Compound Ref.2-4 (Ref. 21) instead of the following Compound Ref.2-1 was used as the second compound (N-type host) in the emitting material layer in Ref. 19-21, respectively.

### Comparative Example 22 (Ref. 22): Fabrication of OLED

An OLED was fabricated using the same procedure and the same materials as Example 1, except that Compound Ref.1-3 instead of Compound 1-1 as the emitter was used and the following Compound Ref.2-1 instead of Compound 2-1 as the second compound (N-type host) in the emitting material layer was used.

### Comparative Examples 23-25 (Ref. 23-25): Fabrication of OLEDs

An OLED was fabricated using the same procedure and the same materials as Comparative Example 22, except that each of the following Compound Ref.2-2 (Ref. 23), Compound Ref.2-3 (Ref. 24) and Compound Ref.2-4 (Ref. 25) instead of the following Compound Ref.2-1 was used as the second compound (N-type host) in the emitting material layer in Ref. 23-25, respectively.

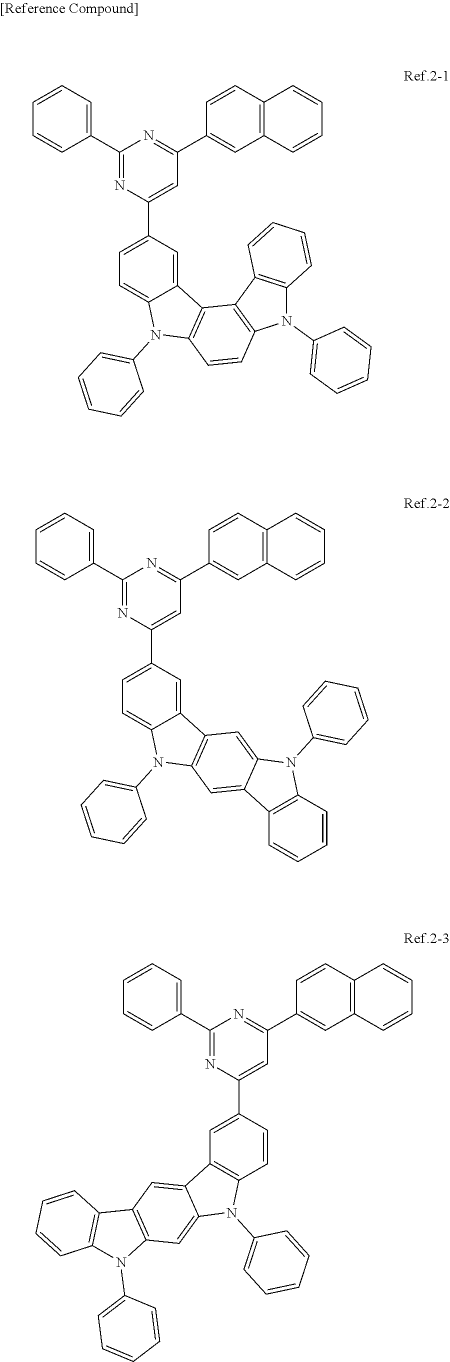 [SMILES: c1ccc(-c2nc(-c3ccc4ccccc4c3)cc(-c3ccc4c(c3)c3c5c6ccccc6n(-c6ccccc6)c5ccc3n4-c3ccccc3)n2)cc1 ; c1ccc(-c2nc(-c3ccc4ccccc4c3)cc(-c3ccc4c(c3)c3cc5c(cc3n4-c3ccccc3)c3ccccc3n5-c3ccccc3)n2)cc1 ; c1ccc(-c2nc(-c3ccc4ccccc4c3)cc(-c3ccc4c(c3)c3cc5c6ccccc6n(-c6ccccc6)c5cc3n4-c3ccccc3)n2)cc1]

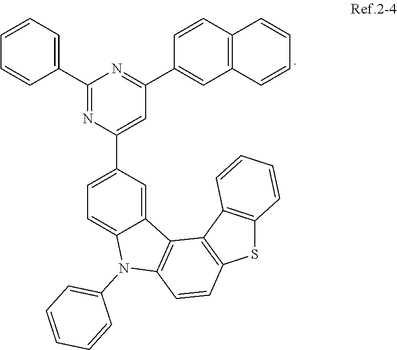 [SMILES: c1ccc(-c2nc(-c3ccc4ccccc4c3)cc(-c3ccc4c(c3)c3c5c(ccc3n4-c3ccccc3)sc3ccccc35)n2)cc1]

The following Table 2 illustrates LUMO energy levels and HOMO energy levels for the compounds as the first compound and the N-type host in Examples 3 and 7-17 and Comparative Examples 9-25.

TABLE 2
Energy levels of the Compounds

| Compound | LUMO (eV) | HOMO (eV) |
|---|---|---|
| Ref. 2-1 | −3.0 | −5.6 |
| Ref. 2-2 | −3.0 | −5.6 |
| Ref. 2-3 | −3.1 | −5.6 |
| Ref. 2-4 | −3.1 | −5.7 |
| 2-1 | −3.3 | −5.7 |
| 2-2 | −3.2 | −5.7 |
| 2-3 | −3.2 | −5.9 |
| 2-4 | −3.2 | −5.8 |
| Ref. 1-2 | −3.7 | −6.1 |
| Ref. 1-3 | −3.6 | −6.1 |
| 1-3 | −3.5 | −5.8 |
| 1-17 | −3.4 | −5.8 |
| 1-7 | −3.5 | −5.8 |

### Experimental Example 2: Measurement of Luminous Properties of OLEDs

Luminous properties, driving voltage, EQE and maximum electroluminescence wavelength (EL λₘₐₓ, nm), for each of the OLEDs fabricated in Examples 3 and 7 to 17 and Comparative Examples 9 to 25 were measured at the same conditions as Experimental Example 1. The measurement results for the OLEDs fabricated in Ref. 9-25 are indicated in the following Table 3 and the measurement results for the OLEDs fabricated in Ex. 3 and 7-17 are indicated in the following Table 4.

TABLE 3
Luminous Properties of OLED

| | | | | | EL λₘₐₓ |
|---|---|---|---|---|---|
| Sample | 1^{st} Compound | 2^{nd} Compound | V | EQE (%) | (nm) |
| Ref. 9 | 1-3 | Ref. 2-1 | 3.5 | 7.5 | 568 |
| Ref. 10 | | Ref. 2-2 | 3.6 | 8.6 | 566 |
| Ref. 11 | | Ref. 2-3 | 3.6 | 9.2 | 565 |
| Ref. 12 | | Ref. 2-4 | 3.6 | 8.9 | 566 |
| Ref. 13 | 1-17 | Ref. 2-1 | 3.6 | 7.9 | 570 |
| Ref. 14 | | Ref. 2-2 | 3.7 | 8.3 | 568 |
| Ref. 15 | | Ref. 2-3 | 3.7 | 9.1 | 566 |
| Ref. 16 | | Ref. 2-4 | 3.6 | 9.0 | 566 |
| Ref. 17 | 1-7 | Ref. 2-2 | 3.6 | 8.9 | 565 |
| Ref. 18 | Ref. 1-2 | Ref. 2-1 | 3.5 | 6.8 | 564 |
| Ref. 19 | | Ref. 2-2 | 3.5 | 6.9 | 566 |
| Ref. 20 | | Ref. 2-3 | 3.6 | 7.0 | 564 |
| Ref. 21 | | Ref. 2-4 | 3.6 | 6.5 | 564 |
| Ref. 22 | Ref. 1-3 | Ref. 2-1 | 3.5 | 7.1 | 566 |
| Ref. 23 | | Ref. 2-2 | 3.5 | 7.3 | 568 |
| Ref. 24 | | Ref. 2-3 | 3.6 | 7.5 | 564 |
| Ref. 25 | | Ref. 2-4 | 3.6 | 6.9 | 564 |

TABLE 4
Luminous Properties of OLED

| | | | | | EL λₘₐₓ |
|---|---|---|---|---|---|
| Sample | 1^{st} Compound | 2^{nd} Compound | V | EQE (%) | (nm) |
| Ex. 3 | 1-3 | 2-1 | 3.7 | 18.2 | 532 |
| Ex. 7 | | 2-2 | 3.7 | 18.9 | 530 |
| Ex. 8 | | 2-3 | 3.6 | 16.3 | 530 |
| Ex. 9 | | 2-4 | 3.8 | 14.4 | 530 |
| Ex. 10 | 1-17 | 2-1 | 3.7 | 18.4 | 534 |
| Ex. 11 | | 2-2 | 3.7 | 18.8 | 532 |
| Ex. 12 | | 2-3 | 3.7 | 16.6 | 534 |
| Ex. 13 | | 2-4 | 3.9 | 15.2 | 532 |
| Ex. 14 | 1-7 | 2-2 | 3.8 | 18.8 | 530 |
| Ex. 15 | 1-3 | 2-2 | 3.5 | 19.3 | 530 |
| Ex. 16 | 1-17 | 2-2 | 3.5 | 19.4 | 532 |
| Ex. 17 | 1-7 | 2-2 | 3.6 | 19.1 | 530 |

Ex. 15-17: Charge control layer

As indicated in Tables 3 and 4, compared to the OLEDs fabricated in Ref. 9-25 where the energy bandgap between the HOMO and/or LUMO energy level of the first compound and the HOMO and/or LUMO energy level of the N-type host is relatively large, in the OLEDs fabricated in Ex. 3 and 7-14, the driving voltage maintained at similar levels and EQE was improved by up to 189.2%, and emitted green color light was of short wavelength. Particularly, compared to the OLEDs fabricated in Ref. 9-25, in the OLEDs fabricated in Ex. 15-17 where the charge control layer consisting of the N-type host between the emitting material layer and the hole blocking layer was disposed, EQE was improved by up to 198.5%.

### Comparative Examples 26-31 (Ref. 26-31): Fabrication of OLEDs

An OLED was fabricated using the same procedure and the same materials as Example 7, except that each of Compound Ref.1-1 (Ref. 26), Compound Ref.1-4 (Ref. 27), Compound Ref.1-5 (Ref. 28), Compound Ref.1-6 (Ref. 29), Compound Ref.1-7 (Ref. 30) and Compound Ref.1-8 (Ref. 31) instead of Compound 2-2 was used as the first compound (fluorescent emitter) in the emitting material layer in Ref. 26-31, respectively.

### Experimental Example 3: Measurement of Luminous Properties of OLEDs

Luminous properties, driving voltage and current efficiency (cd/A, relative), for each of the OLEDs fabricated in Examples 7 and Comparative Examples 26 to 31 were measured at the same conditions as Experimental Example 1. The measurement results are indicated in the following Table 5.

TABLE 5
Luminous Properties of OLED

| Sample | 2^{nd} Compound | 1^{st} Compound | V | cd/A |
|---|---|---|---|---|
| Ref. 26 | 2-2 | Ref. 1-1 | 3.7 | 36% |
| Ref. 27 | 2-2 | Ref. 1-4 | 3.7 | 45% |
| Ref. 28 | 2-2 | Ref. 1-5 | 3.7 | 47% |
| Ref. 29 | 2-2 | Ref. 1-6 | 3.6 | 38% |
| Ref. 30 | 2-2 | Ref. 1-7 | 3.6 | 40% |
| Ref. 31 | 2-2 | Ref. 1-8 | 3.5 | 34% |
| Ex. 7 | 2-2 | 1-3 | 3.7 | 100% |

As indicated in Table 5, compared to the OLEDs fabricated in Ref. 26-31, in the OLED fabricated in Ex. 7, the driving voltage maintained at similar levels and improved current efficiency by at least two times.

Summing up the results of Tables 1 to 5, it may be possible to realize an organic light emitting diode having improved luminous properties by using the fluorescent emitter having a naphthalene moiety at the terminal of the core as the first compound and the N-type host having HOMO energy level and/or LUMO energy level similar to the HOMO energy level and/or the LUMO energy level of the first compound.

It will be apparent to those skilled in the art that various modifications and variations may be made in the present disclosure without departing from the scope of the disclosure. Thus, it is intended that the present disclosure cover the modifications and variations of the present disclosure provided they come within the scope of the appended claims and their equivalents.

What is claimed is:

1. An organic light emitting diode, comprising:
a first electrode;
a second electrode facing the first electrode; and
an emissive layer disposed between the first electrode and the second electrode, the emissive layer comprises at least one emitting material layer that comprises:
a first compound comprising a first organic compound represented by Chemical Formula 1, and
a second compound comprising a second organic compound represented by Chemical Formula 4: 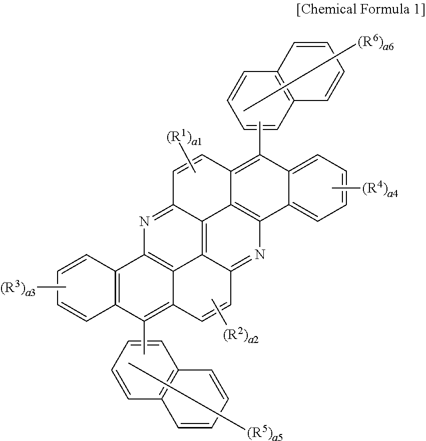
wherein, in the Chemical Formula 1,
each of R¹, R², R³, R⁴, R⁵, and R⁶ is independently a halogen atom, a cyano group, an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ heteroaryl group, an unsubstituted or substituted C₆-C₃₀ aryl amino group or an unsubstituted or substituted C₃-C₃₀ heteroaryl amino group, where each R¹ is identical to or different from each other when a1 is 2, each R² is identical to or different from each other when a2 is 2, each R³ is identical to or different from each other when a3 is 2, 3 or 4, each R⁴ is identical to or different from each other when a4 is 2, 3 or 4, each R⁵ is identical to or different from each other when a5 is 2, 3, 4, 5, 6 or 7 and each R⁶ is identical to or different from each other when a6 is 2, 3, 4, 5, 6 or 7;
each of a1 and a2 is independently 0, 1 or 2;
each of a3 and a4 is independently 0, 1, 2, 3 or 4; and
each of a5 and a6 is independently 0, 1, 2, 3, 4, 5, 6 or 7, 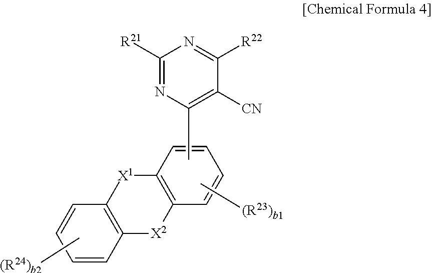
wherein, in the Chemical Formula 4,
one of X¹ and X² is a single bond and the other of X¹ and X² is NR^{A}, O or S;
each of R²¹, R²², R²³, R²⁴, and R^{A} is independently an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ heteroaryl group, an unsubstituted or substituted C₆-C₃₀ aryl amino group or an unsubstituted or substituted C₃-C₃₀ heteroaryl amino group, where each R²³ is identical to or different from each other when b1 is 2 or 3 and each R²⁴ is identical to or different from each other when b2 is 2, 3 or 4, or
optionally, two adjacent R²³ are linked together to form an unsubstituted or substituted C₆-C₂₀ aromatic ring or an unsubstituted or substituted C₃-C₂₀ heteroaromatic ring when b1 is 2 or 3 and/or two adjacent R²⁴ are linked together to form an unsubstituted or substituted C₆-C₂₀ aromatic ring or an unsubstituted or substituted C₃-C₂₀ heteroaromatic ring when b2 is 2, 3 or 4;
b1 is 0, 1, 2 or 3; and
b2 is 0, 1, 2, 3 or 4.

2. The organic light emitting diode of claim 1, wherein the first organic compound is represented by Chemical Formula 2A or Chemical Formula 2B: 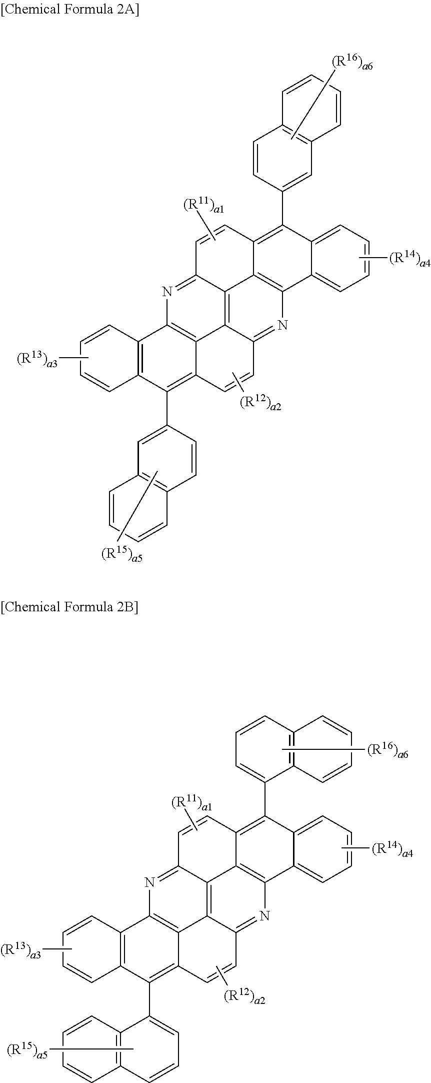
wherein, in the Chemical Formulae 2A and 2B,
each of a1, a2, a3, a4, a5, and a6 is as defined in Chemical Formula 1,
each of R¹¹, R¹², R¹³, R¹⁴, R¹⁵, and R¹⁶ is independently an unsubstituted or a substituted C₁-C₂₀ alkyl group or an unsubstituted or C₁-C₁₀ alkyl-substituted C₆-C₃₀ aryl group, where each R¹¹ is identical to or different from each other when a1 is 2, each R¹² is identical to or different from each other when a2 is 2, each R¹³ is identical to or different from each other when a3 is 2, 3 or 4, each R¹⁴ is identical to or different from each other when a4 is 2, 3 or 4, each R¹⁵ is identical to or different from each other when a5 is 2, 3, 4, 5, 6 or 7 and each R¹⁶ is identical to or different from each other when a6 is 2, 3, 4, 5, 6 or 7.

3. The organic light emitting diode of claim 1, wherein each of a1 and a2 is 0, each of a3, a4, a5, and a6 is independently 0 or 1, and each of R³, R⁴, R⁵, and R⁶ is independently an unsubstituted or a substituted C₁-C₁₀ alkyl group or an unsubstituted or C₁-C₁₀ alkyl-substituted C₆-C₃₀ aryl group.

4. The organic light emitting diode of claim 1, wherein each of a1 and a2 is 0, each of R³ and R⁴ is independently an unsubstituted or C₁-C₁₀ alkyl-substituted C₆-C₃₀ aryl group, each of a3 and a4 is independently 0 or 1, each of R⁵ and R⁶ is independently an unsubstituted or a substituted C₁-C₁₀ alkyl group, and each of a5 and a6 is independently 0 or 1.

5. The organic light emitting diode of claim 1, wherein the first organic compound includes at least one of the following compounds:

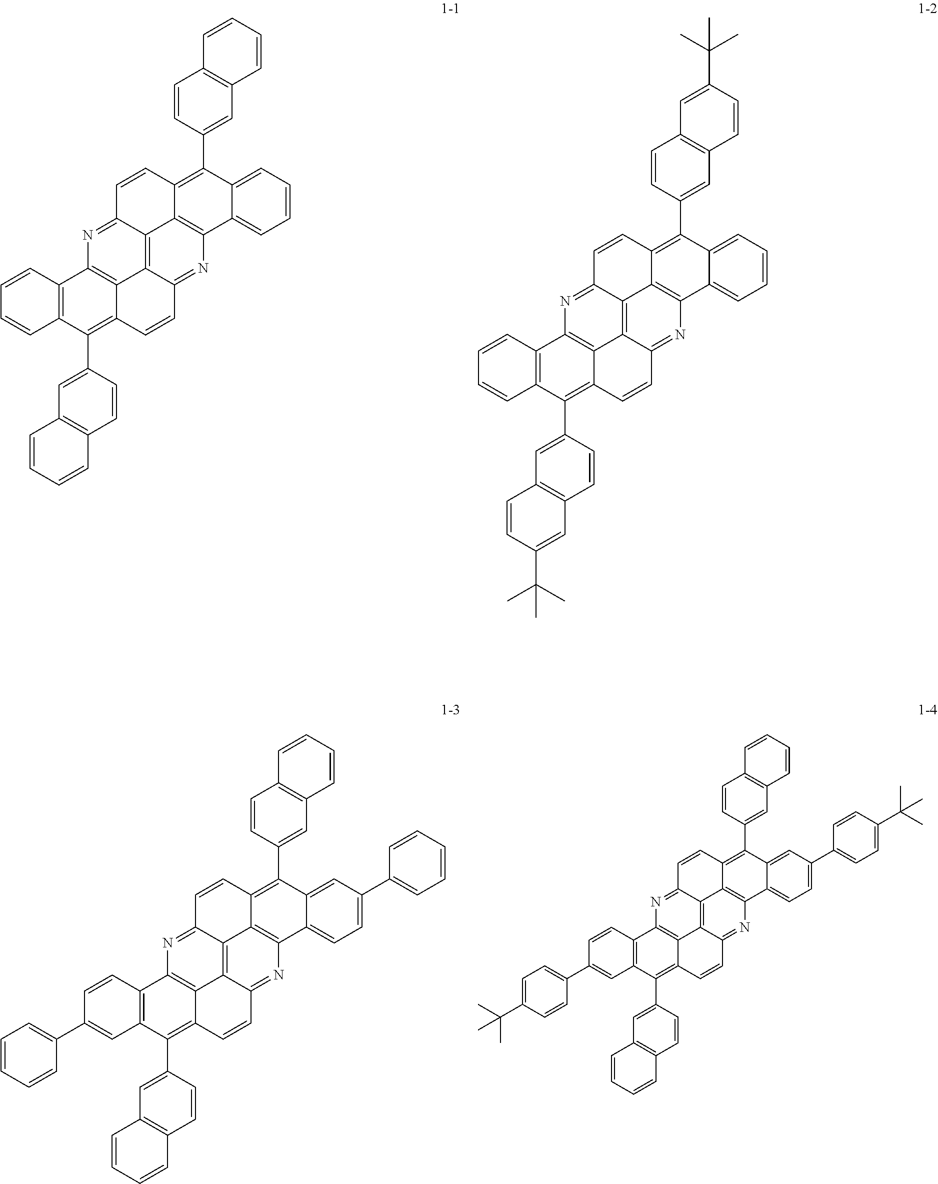 [SMILES: c1ccc2cc(-c3c4ccccc4c4nc5ccc6c(-c7ccc8ccccc8c7)c7ccccc7c7nc8ccc3c4c8c5c67)ccc2c1 ; CC(C)(C)c1ccc2cc(-c3c4ccccc4c4nc5ccc6c(-c7ccc8cc(C(C)(C)C)ccc8c7)c7ccccc7c7nc8ccc3c4c8c5c67)ccc2c1 ; c1ccc(-c2ccc3c(c2)c(-c2ccc4ccccc4c2)c2ccc4nc5c6ccc(-c7ccccc7)cc6c(-c6ccc7ccccc7c6)c6ccc7nc3c2c4c7c65)cc1 ; CC(C)(C)c1ccc(-c2ccc3c(c2)c(-c2ccc4ccccc4c2)c2ccc4nc5c6ccc(-c7ccc(C(C)(C)C)cc7)cc6c(-c6ccc7ccccc7c6)c6ccc7nc3c2c4c7c65)cc1]

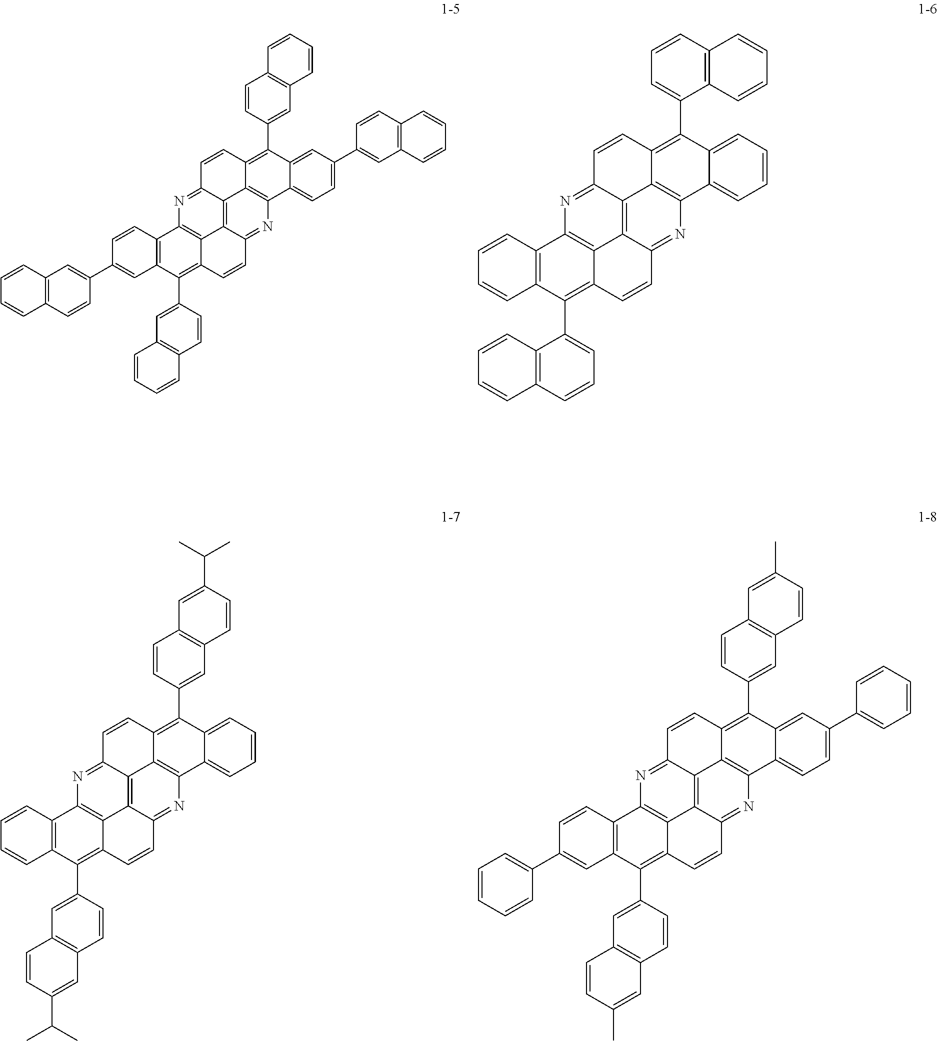 [SMILES: c1ccc2cc(-c3ccc4c(c3)c(-c3ccc5ccccc5c3)c3ccc5nc6c7ccc(-c8ccc9ccccc9c8)cc7c(-c7ccc8ccccc8c7)c7ccc8nc4c3c5c8c76)ccc2c1 ; c1ccc2c(-c3c4ccccc4c4nc5ccc6c(-c7cccc8ccccc78)c7ccccc7c7nc8ccc3c4c8c5c67)cccc2c1 ; CC(C)c1ccc2cc(-c3c4ccccc4c4nc5ccc6c(-c7ccc8cc(C(C)C)ccc8c7)c7ccccc7c7nc8ccc3c4c8c5c67)ccc2c1 ; Cc1ccc2cc(-c3c4cc(-c5ccccc5)ccc4c4nc5ccc6c(-c7ccc8cc(C)ccc8c7)c7cc(-c8ccccc8)ccc7c7nc8ccc3c4c8c5c67)ccc2c1]

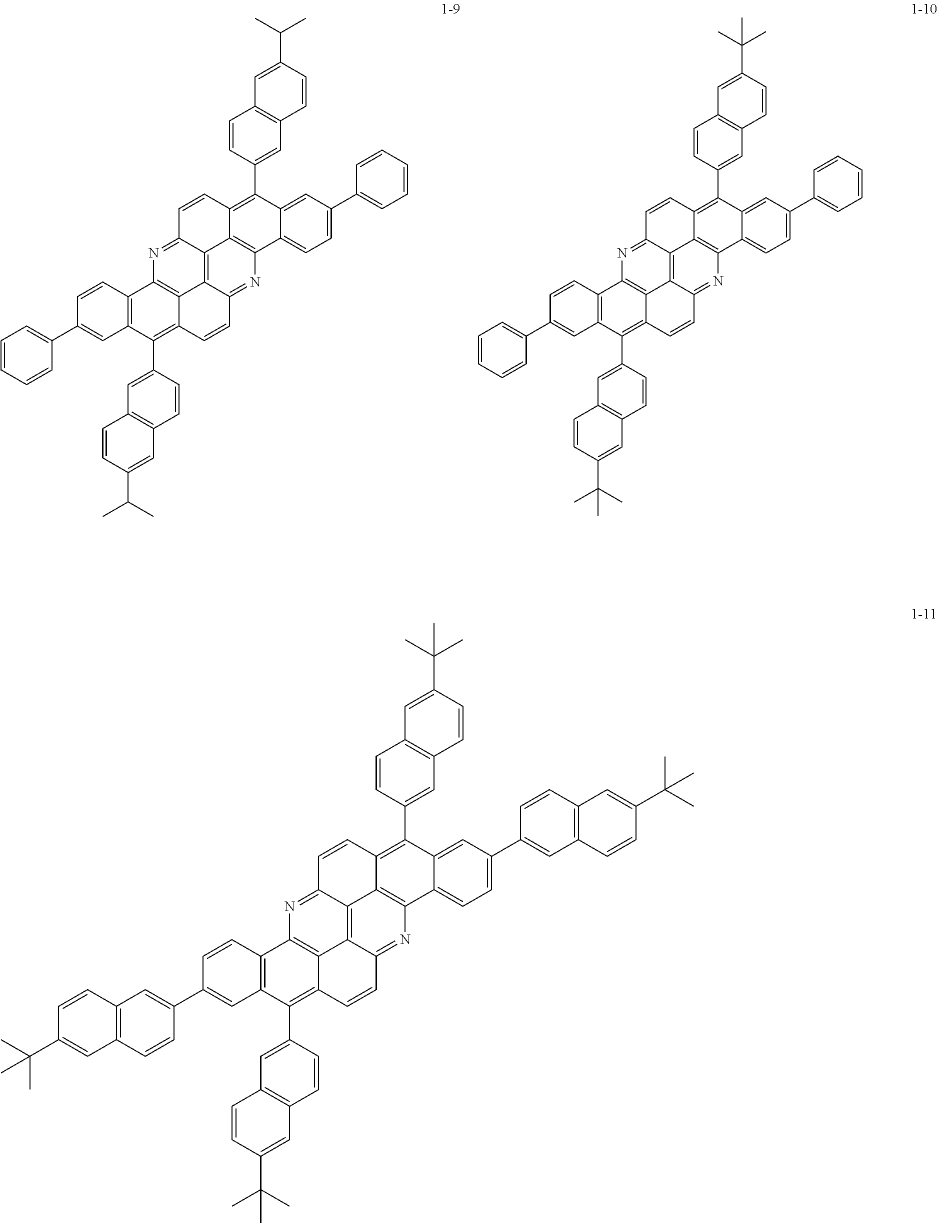 [SMILES: CC(C)c1ccc2cc(-c3c4cc(-c5ccccc5)ccc4c4nc5ccc6c(-c7ccc8cc(C(C)C)ccc8c7)c7cc(-c8ccccc8)ccc7c7nc8ccc3c4c8c5c67)ccc2c1 ; CC(C)(C)c1ccc2cc(-c3c4cc(-c5ccccc5)ccc4c4nc5ccc6c(-c7ccc8cc(C(C)(C)C)ccc8c7)c7cc(-c8ccccc8)ccc7c7nc8ccc3c4c8c5c67)ccc2c1 ; CC(C)(C)c1ccc2cc(-c3ccc4c(c3)c(-c3ccc5cc(C(C)(C)C)ccc5c3)c3ccc5nc6c7ccc(-c8ccc9cc(C(C)(C)C)ccc9c8)cc7c(-c7ccc8cc(C(C)(C)C)ccc8c7)c7ccc8nc4c3c5c8c76)ccc2c1]

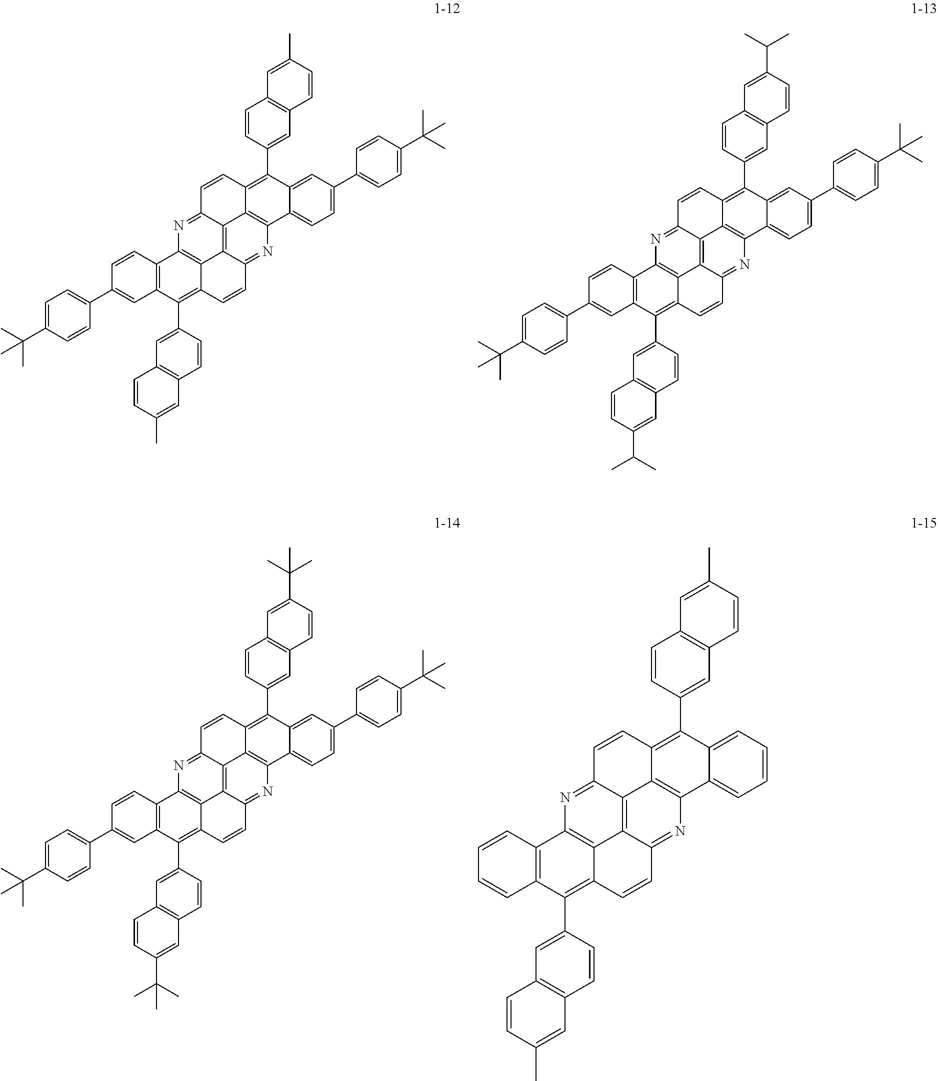

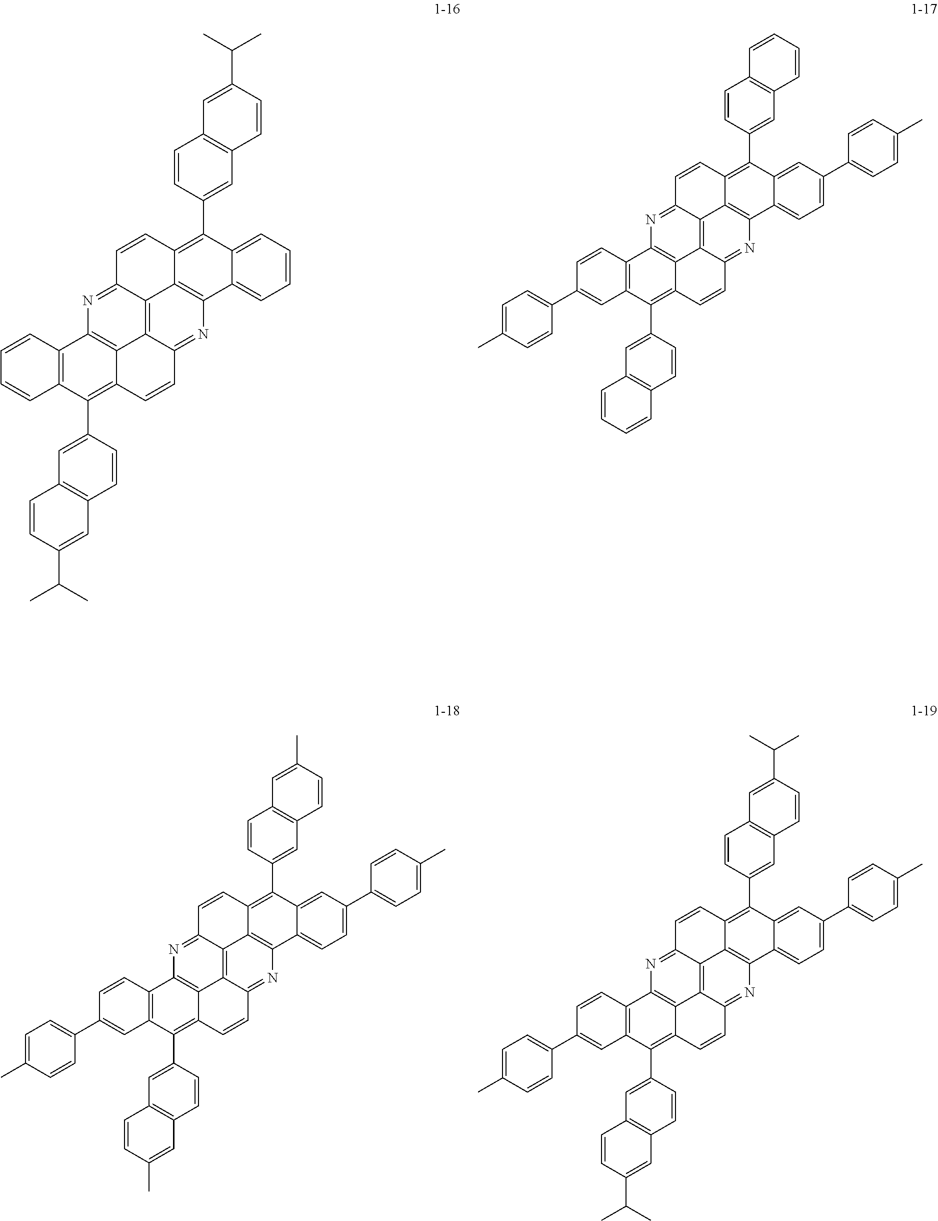

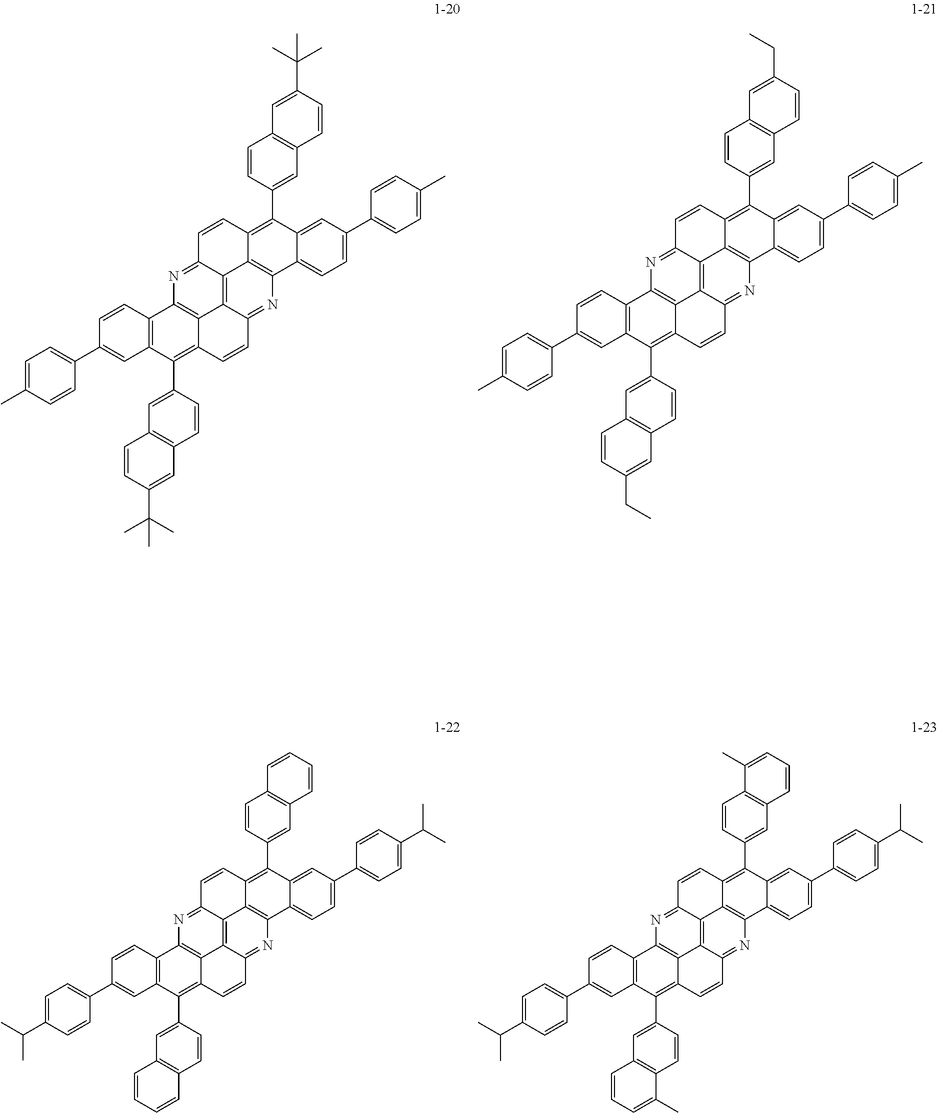

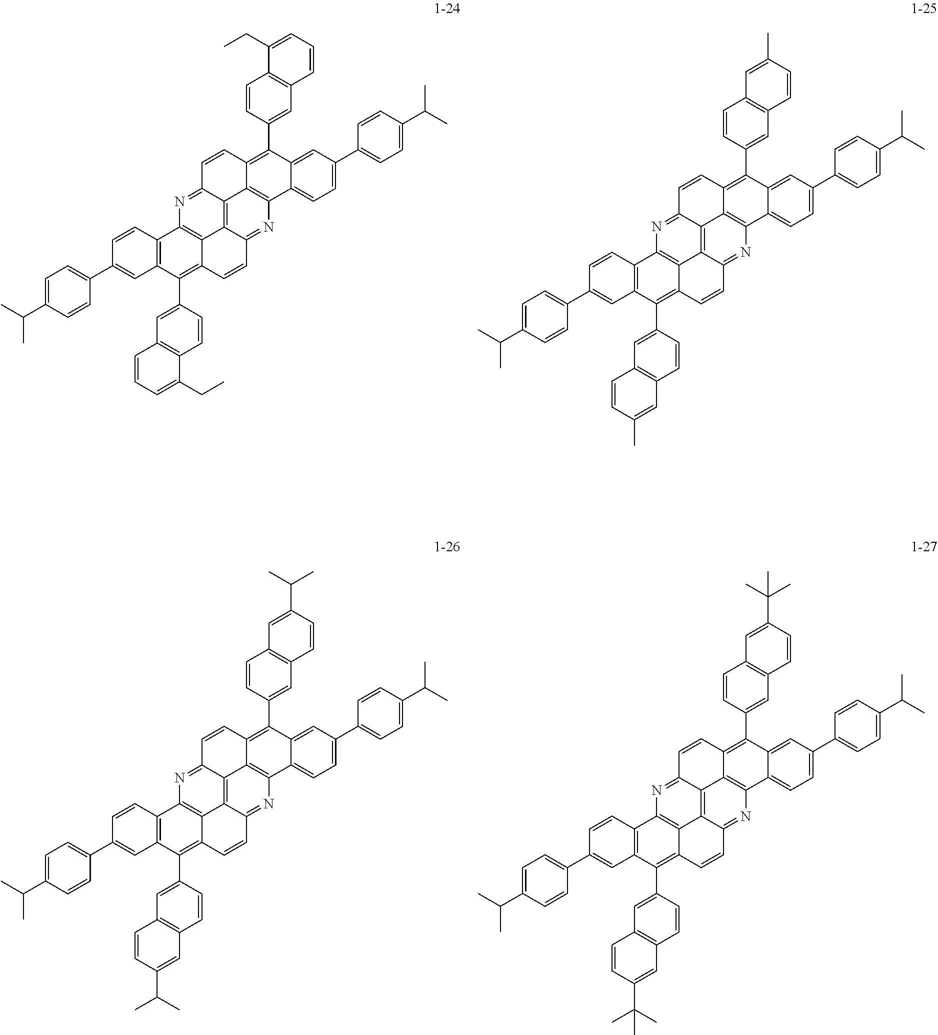

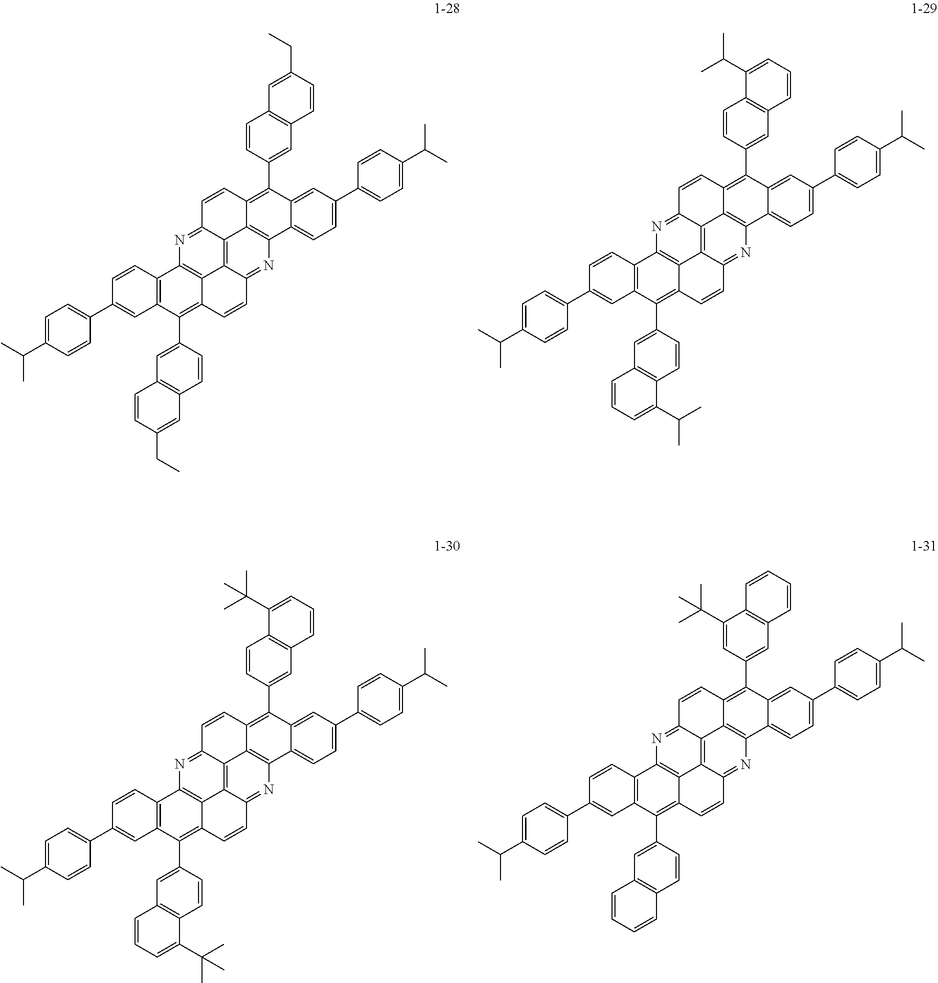

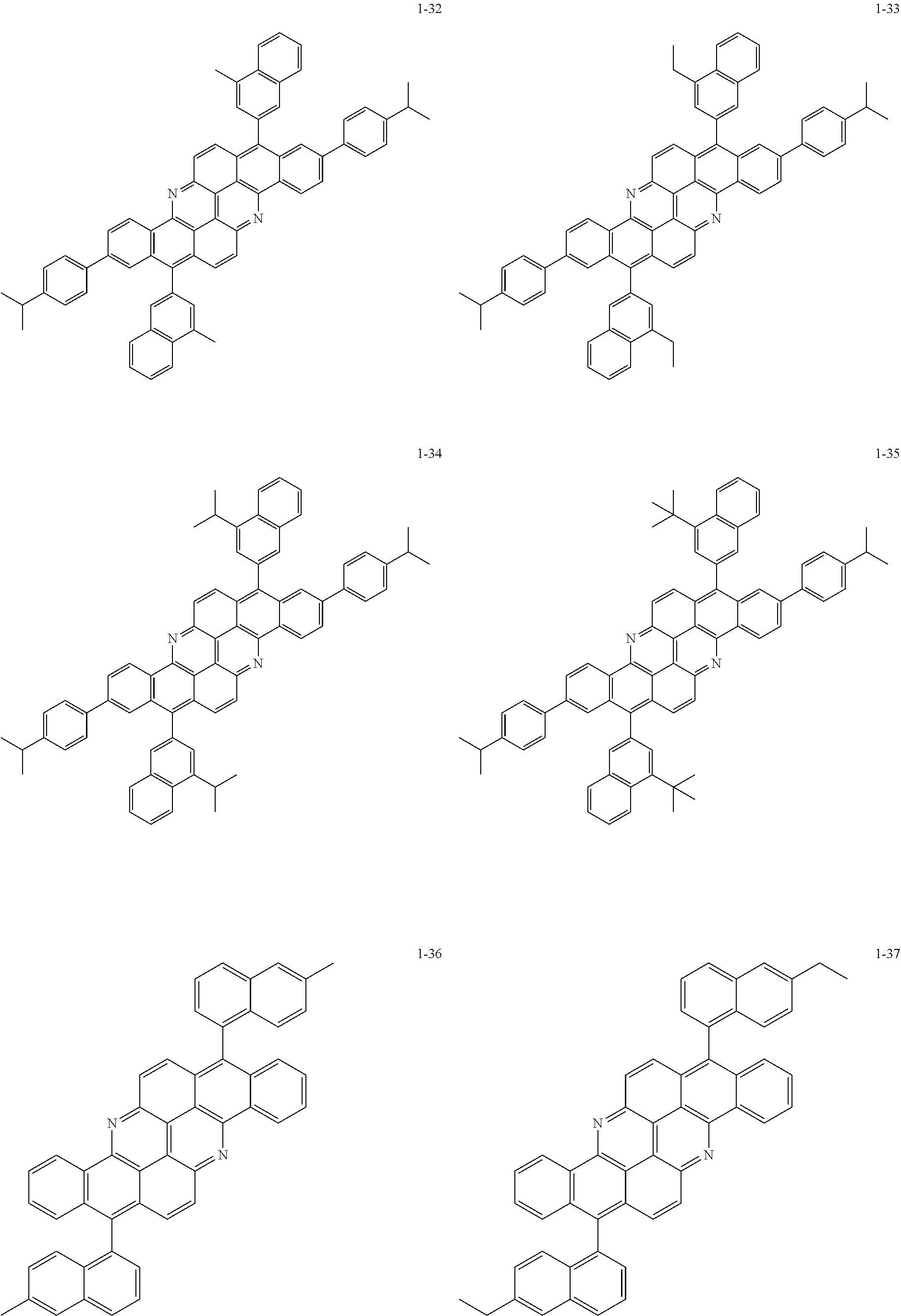

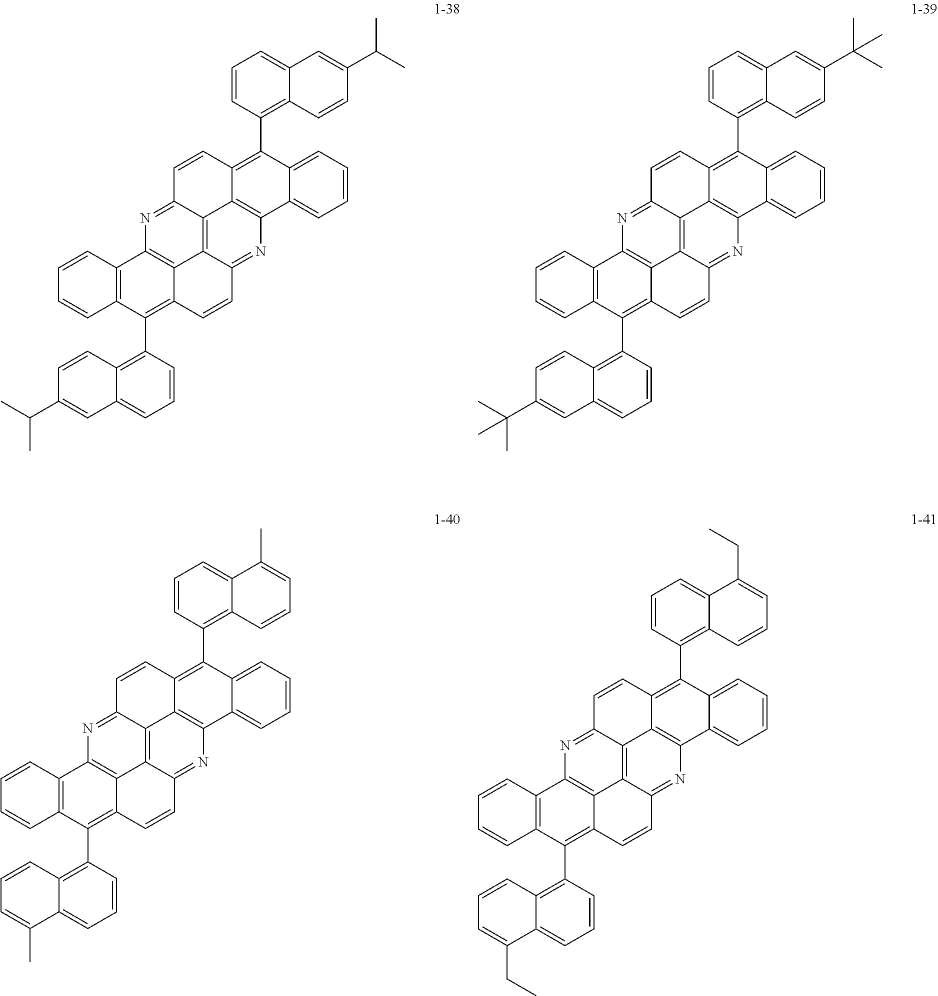 [SMILES: CC(C)c1ccc2c(-c3c4ccccc4c4nc5ccc6c(-c7cccc8cc(C(C)C)ccc78)c7ccccc7c7nc8ccc3c4c8c5c67)cccc2c1 ; CC(C)(C)c1ccc2c(-c3c4ccccc4c4nc5ccc6c(-c7cccc8cc(C(C)(C)C)ccc78)c7ccccc7c7nc8ccc3c4c8c5c67)cccc2c1 ; Cc1cccc2c(-c3c4ccccc4c4nc5ccc6c(-c7cccc8c(C)cccc78)c7ccccc7c7nc8ccc3c4c8c5c67)cccc12 ; CCc1cccc2c(-c3c4ccccc4c4nc5ccc6c(-c7cccc8c(CC)cccc78)c7ccccc7c7nc8ccc3c4c8c5c67)cccc12]

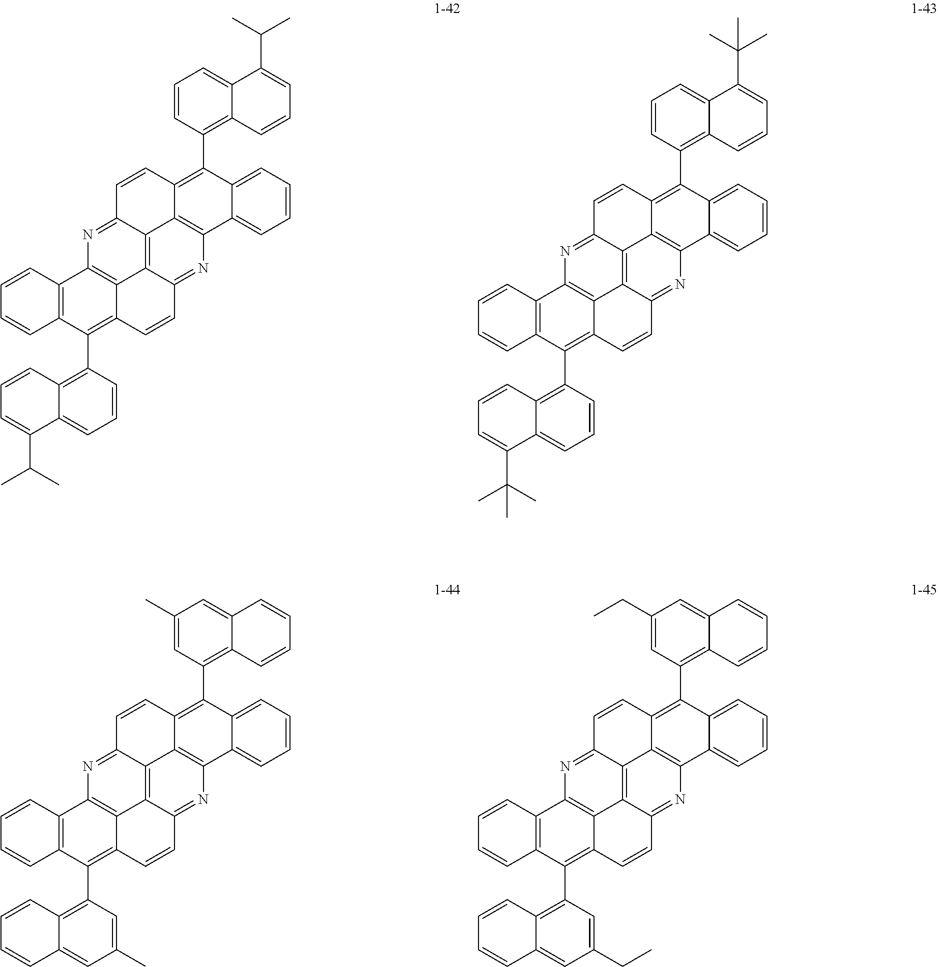 [SMILES: CC(C)c1cccc2c(-c3c4ccccc4c4nc5ccc6c(-c7cccc8c(C(C)C)cccc78)c7ccccc7c7nc8ccc3c4c8c5c67)cccc12 ; CC(C)(C)c1cccc2c(-c3c4ccccc4c4nc5ccc6c(-c7cccc8c(C(C)(C)C)cccc78)c7ccccc7c7nc8ccc3c4c8c5c67)cccc12 ; Cc1cc(-c2c3ccccc3c3nc4ccc5c(-c6cc(C)cc7ccccc67)c6ccccc6c6nc7ccc2c3c7c4c56)c2ccccc2c1 ; CCc1cc(-c2c3ccccc3c3nc4ccc5c(-c6cc(CC)cc7ccccc67)c6ccccc6c6nc7ccc2c3c7c4c56)c2ccccc2c1]

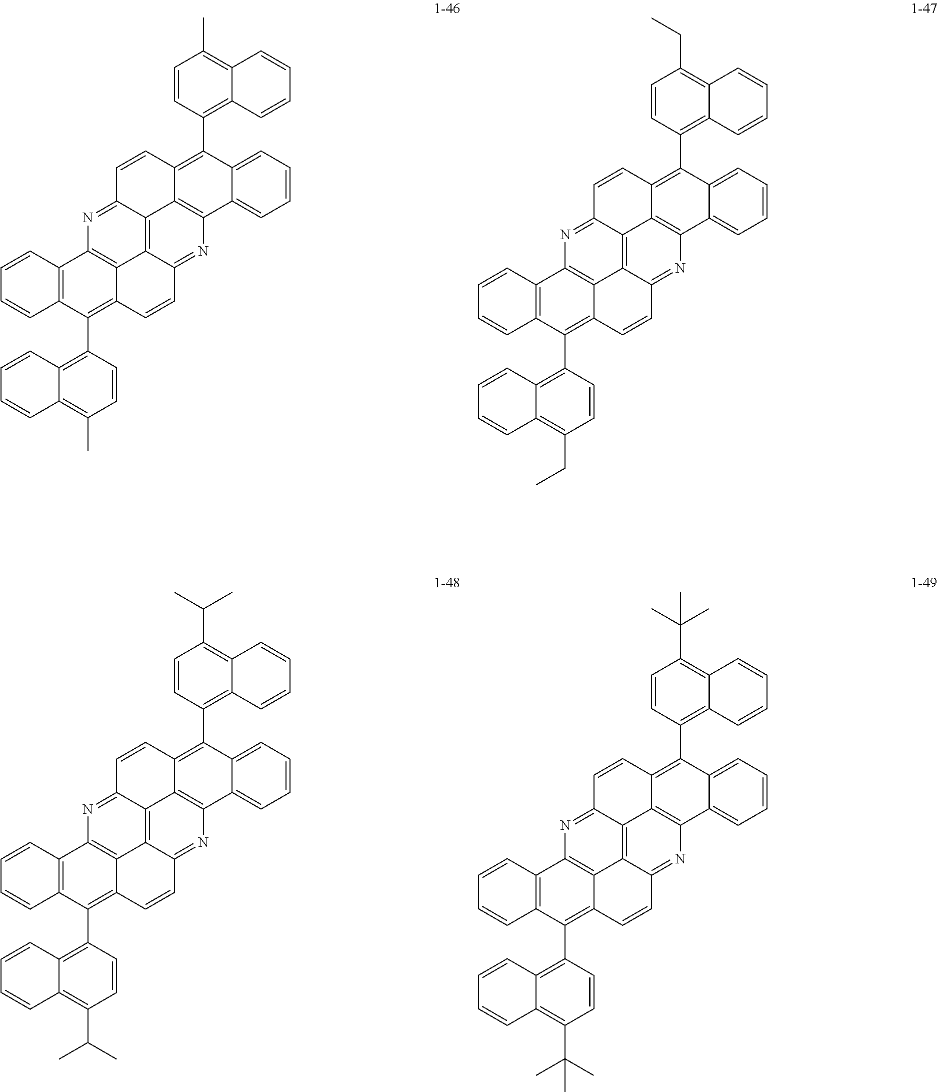 [SMILES: Cc1ccc(-c2c3ccccc3c3nc4ccc5c(-c6ccc(C)c7ccccc67)c6ccccc6c6nc7ccc2c3c7c4c56)c2ccccc12 ; CCc1ccc(-c2c3ccccc3c3nc4ccc5c(-c6ccc(CC)c7ccccc67)c6ccccc6c6nc7ccc2c3c7c4c56)c2ccccc12 ; CC(C)c1ccc(-c2c3ccccc3c3nc4ccc5c(-c6ccc(C(C)C)c7ccccc67)c6ccccc6c6nc7ccc2c3c7c4c56)c2ccccc12 ; CC(C)(C)c1ccc(-c2c3ccccc3c3nc4ccc5c(-c6ccc(C(C)(C)C)c7ccccc67)c6ccccc6c6nc7ccc2c3c7c4c56)c2ccccc12]

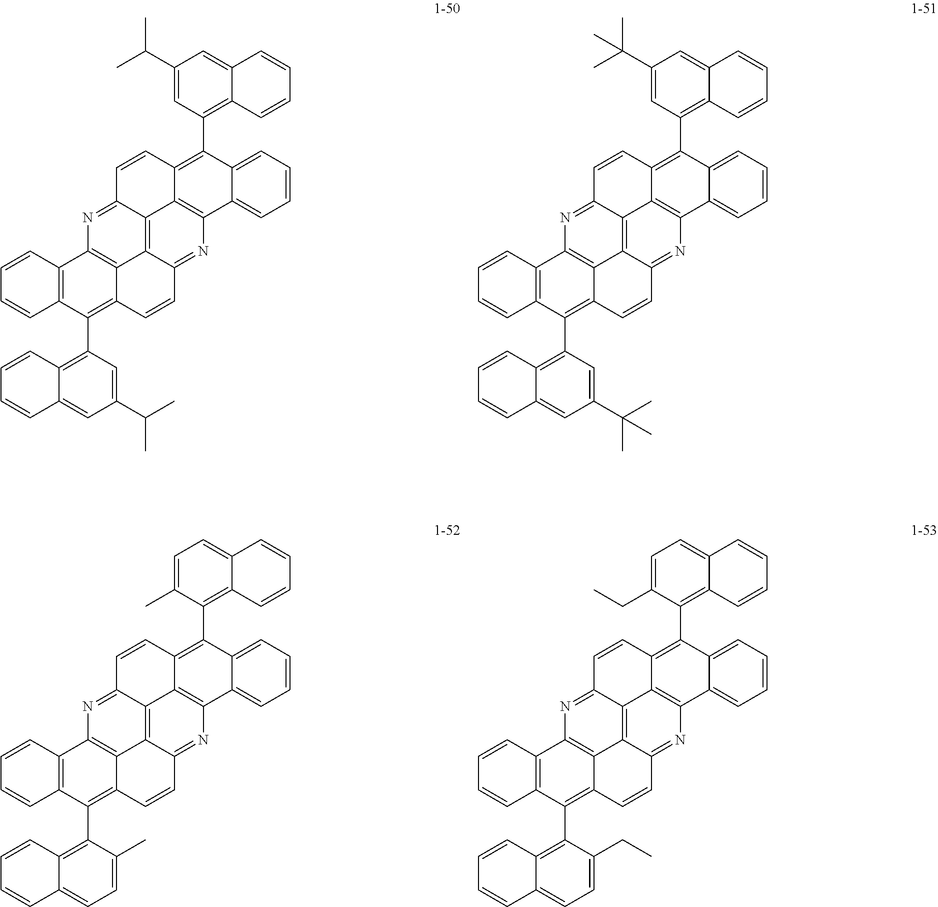 [SMILES: CC(C)c1cc(-c2c3ccccc3c3nc4ccc5c(-c6cc(C(C)C)cc7ccccc67)c6ccccc6c6nc7ccc2c3c7c4c56)c2ccccc2c1 ; CC(C)(C)c1cc(-c2c3ccccc3c3nc4ccc5c(-c6cc(C(C)(C)C)cc7ccccc67)c6ccccc6c6nc7ccc2c3c7c4c56)c2ccccc2c1 ; Cc1ccc2ccccc2c1-c1c2ccccc2c2nc3ccc4c(-c5c(C)ccc6ccccc56)c5ccccc5c5nc6ccc1c2c6c3c45 ; CCc1ccc2ccccc2c1-c1c2ccccc2c2nc3ccc4c(-c5c(CC)ccc6ccccc56)c5ccccc5c5nc6ccc1c2c6c3c45]

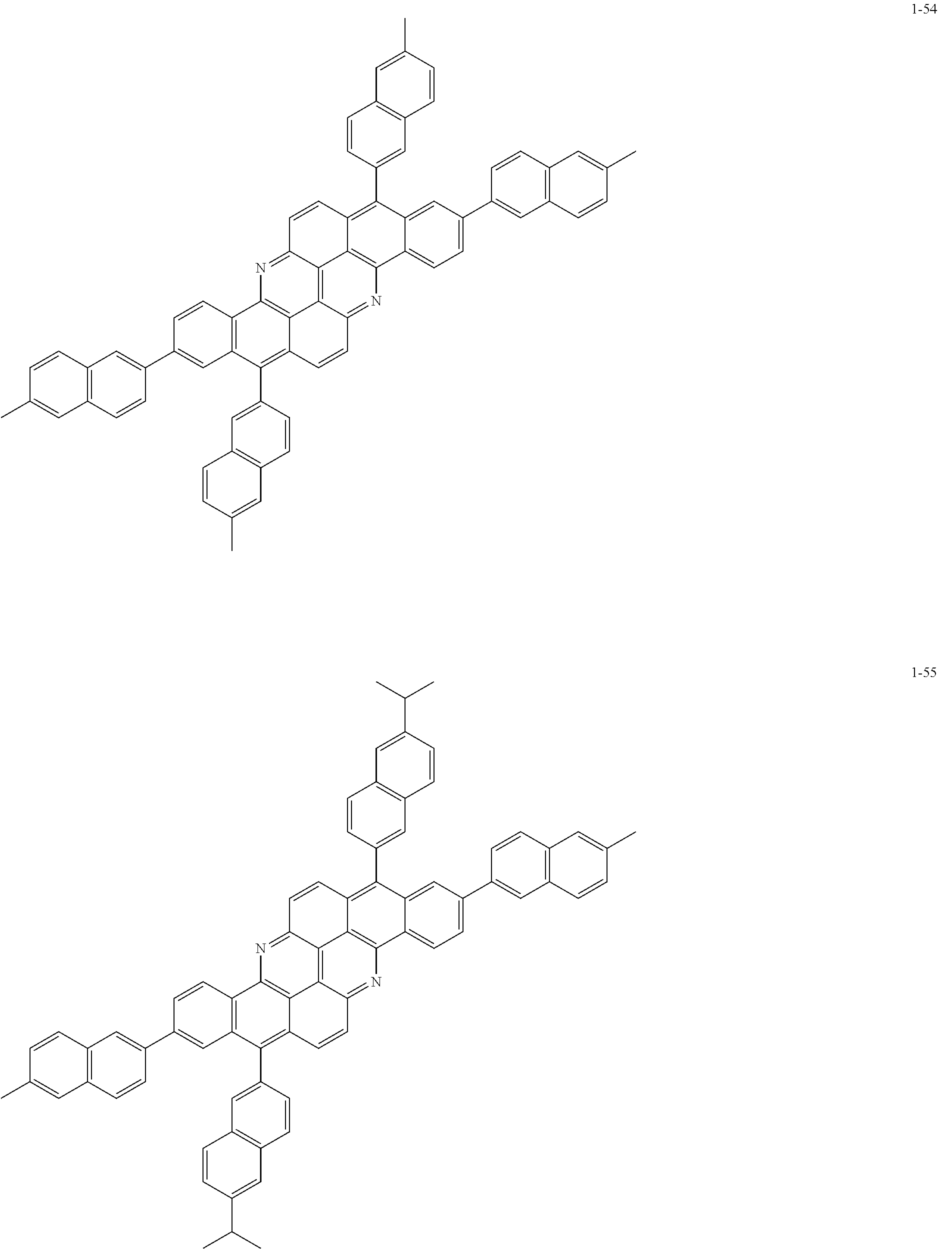

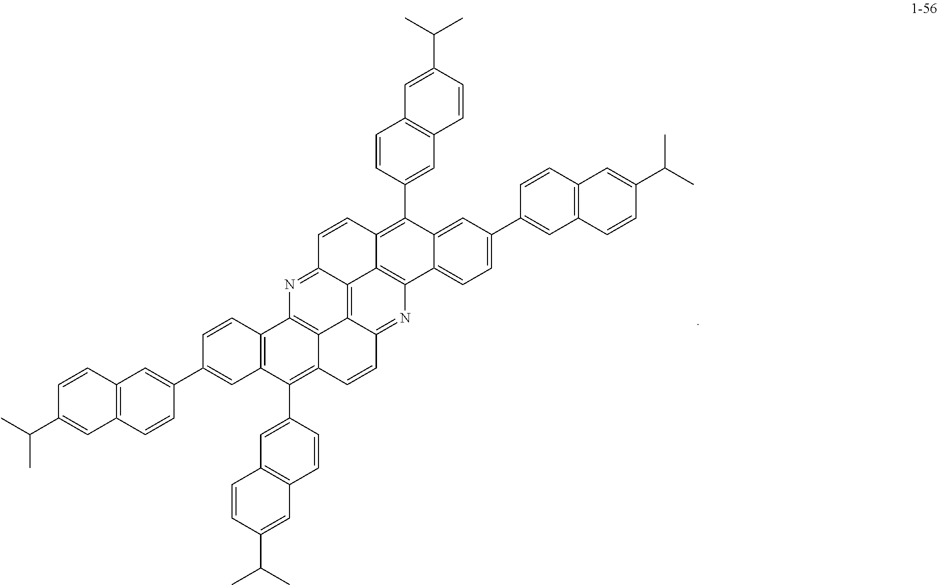 [SMILES: CC(C)c1ccc2cc(-c3ccc4c(c3)c(-c3ccc5cc(C(C)C)ccc5c3)c3ccc5nc6c7ccc(-c8ccc9cc(C(C)C)ccc9c8)cc7c(-c7ccc8cc(C(C)C)ccc8c7)c7ccc8nc4c3c5c8c76)ccc2c1]

6. The organic light emitting diode of claim 1, wherein the second organic compound is represented by Chemical Formula 5: 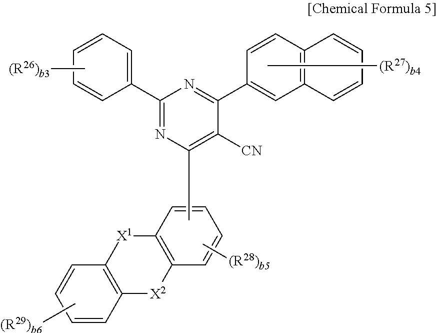
wherein, in the Chemical Formula 5,
each of X¹ and X² is as defined in Chemical Formula 4;
b3 is 0, 1, 2, 3, 4 or 5;
b4 is 0, 1, 2, 3, 4, 5, 6 or 7;
b5 is 0, 1, 2 or 3;
b6 is 0, 1, 2, 3 or 4;
each of R²⁶, R²⁷, R²⁸, and R²⁹ is independently an unsubstituted or substituted C₆-C₃₀ aryl group or an unsubstituted or substituted C₃-C₃₀ heteroaryl group, where each R²⁶ is identical to or different from each other when b3 is 2, 3, 4 or 5, each R²⁷ is identical to or different from each other when b4 is 2, 3, 4, 5, 6 or 7, each R²⁸ is identical to or different from each other when b5 is 2 or 3 and each R²⁹ is identical to or different from each other when b6 is 2, 3 or 4, or
optionally, two adjacent R²⁶ are linked together to form a heteroaromatic ring represented by Chemical Formula 6 when b3 is 2, 3, 4 or 5, two adjacent R²⁷ are linked together to form the heteroaromatic ring represented by Chemical Formula 6 when b4 is 2, 3, 4, 5, 6 or 7, two adjacent R²⁸ are linked together to form the heteroaromatic ring represented by Chemical Formula 6 when b5 is 2 or 3 and/or two adjacent R²⁹ are linked together to form the heteroaromatic ring represented by Chemical Formula 6 when b6 is 2, 3 or 4; and
the dotted line indicates a portion optionally fused to the ring represented by the Chemical Formula 6, 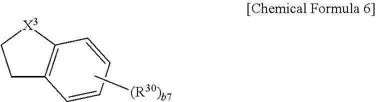
wherein, in the Chemical Formula 6,
X³ is NR^{B}, O or S;
R^{B} is hydrogen, an unsubstituted or substituted C₁-C₂₀ alkyl group, an unsubstituted or substituted C₆-C₃₀ aryl group or an unsubstituted or substituted C₃-C₃₀ heteroaryl group;
R³⁰ is an unsubstituted or substituted C₁-C₂₀ alkyl group, an unsubstituted or substituted C₁-C₂₀ alkyl amino group, an unsubstituted or substituted C₆-C₃₀ aryl group or an unsubstituted or substituted C₃-C₃₀ heteroaryl group, where each R³⁰ is identical to or different from each other when b7 is 2, 3 or 4;
b7 is 0, 1, 2, 3 or 4; and
the dotted line indicates a portion fused to the dotted line in Chemical Formula 5.

7. The organic light emitting diode of claim 1, wherein an energy bandgap between a highest occupied molecular orbital (HOMO) energy level of the first compound and a HOMO energy level of the second compound is less than 0.2 eV.

8. The organic light emitting diode of claim 1, wherein an energy bandgap between a lowest unoccupied molecular orbital (LUMO) energy level of the first compound and a LUMO energy level of the second compound is less than about 0.4 eV.

9. The organic light emitting diode of claim 1, wherein the second organic compound includes at least one of the following compounds:

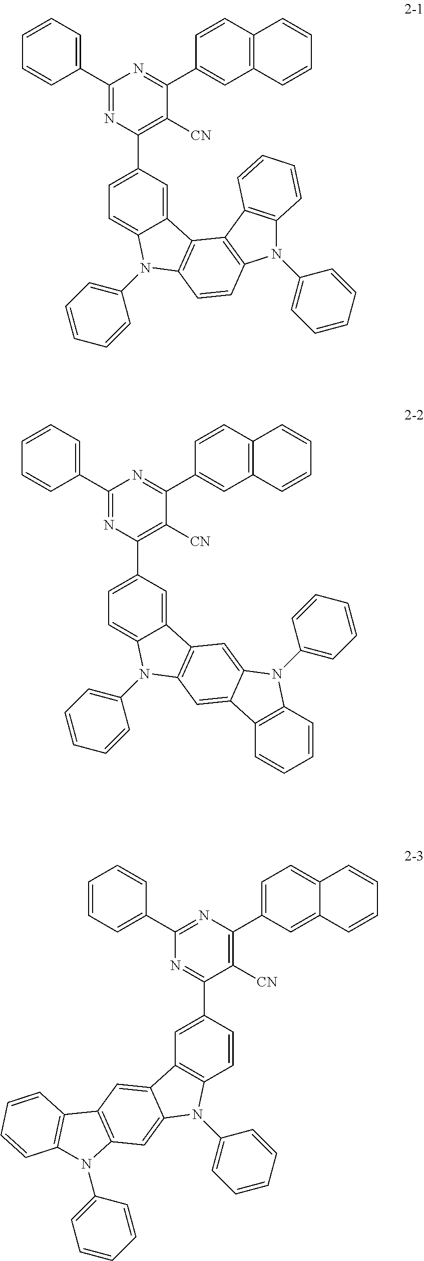 [SMILES: N#Cc1c(-c2ccc3ccccc3c2)nc(-c2ccccc2)nc1-c1ccc2c(c1)c1c3c4ccccc4n(-c4ccccc4)c3ccc1n2-c1ccccc1 ; N#Cc1c(-c2ccc3ccccc3c2)nc(-c2ccccc2)nc1-c1ccc2c(c1)c1cc3c(cc1n2-c1ccccc1)c1ccccc1n3-c1ccccc1 ; N#Cc1c(-c2ccc3ccccc3c2)nc(-c2ccccc2)nc1-c1ccc2c(c1)c1cc3c4ccccc4n(-c4ccccc4)c3cc1n2-c1ccccc1]

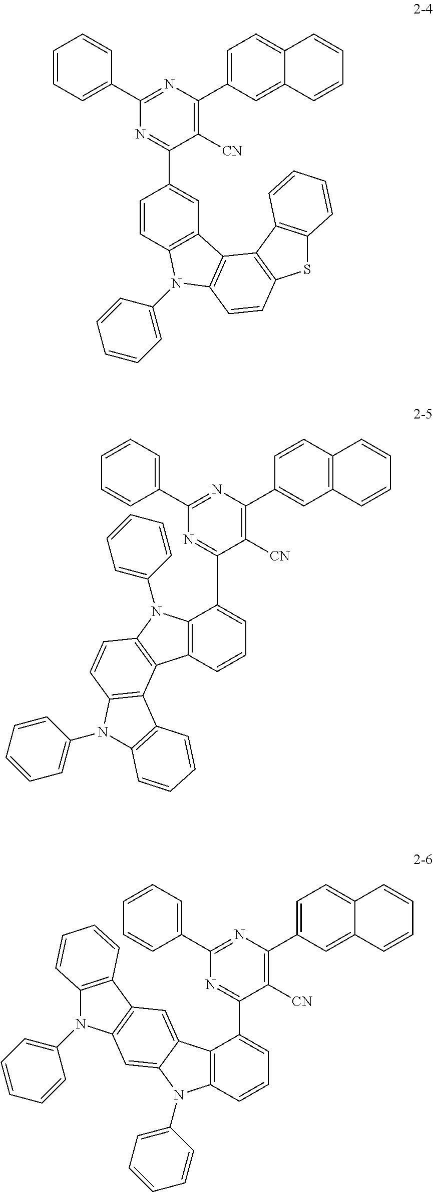 [SMILES: N#Cc1c(-c2ccc3ccccc3c2)nc(-c2ccccc2)nc1-c1ccc2c(c1)c1c3c(ccc1n2-c1ccccc1)sc1ccccc13 ; N#Cc1c(-c2ccc3ccccc3c2)nc(-c2ccccc2)nc1-c1cccc2c3c4c5ccccc5n(-c5ccccc5)c4ccc3n(-c3ccccc3)c12 ; N#Cc1c(-c2ccc3ccccc3c2)nc(-c2ccccc2)nc1-c1cccc2c1c1cc3c4ccccc4n(-c4ccccc4)c3cc1n2-c1ccccc1]

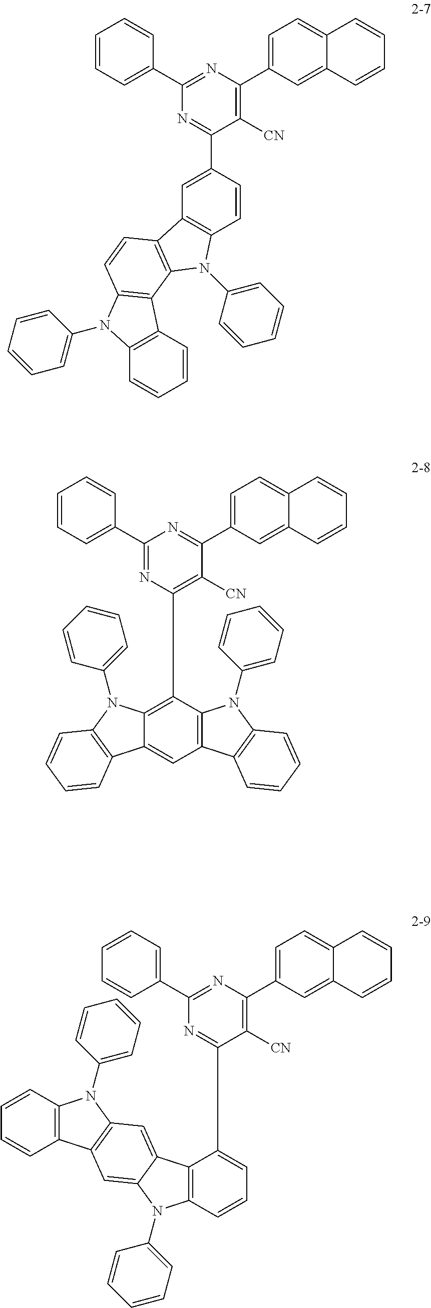 [SMILES: N#Cc1c(-c2ccc3ccccc3c2)nc(-c2ccccc2)nc1-c1ccc2c(c1)c1ccc3c(c4ccccc4n3-c3ccccc3)c1n2-c1ccccc1 ; N#Cc1c(-c2ccc3ccccc3c2)nc(-c2ccccc2)nc1-c1c2c(cc3c4ccccc4n(-c4ccccc4)c13)c1ccccc1n2-c1ccccc1 ; N#Cc1c(-c2ccc3ccccc3c2)nc(-c2ccccc2)nc1-c1cccc2c1c1cc3c(cc1n2-c1ccccc1)c1ccccc1n3-c1ccccc1]

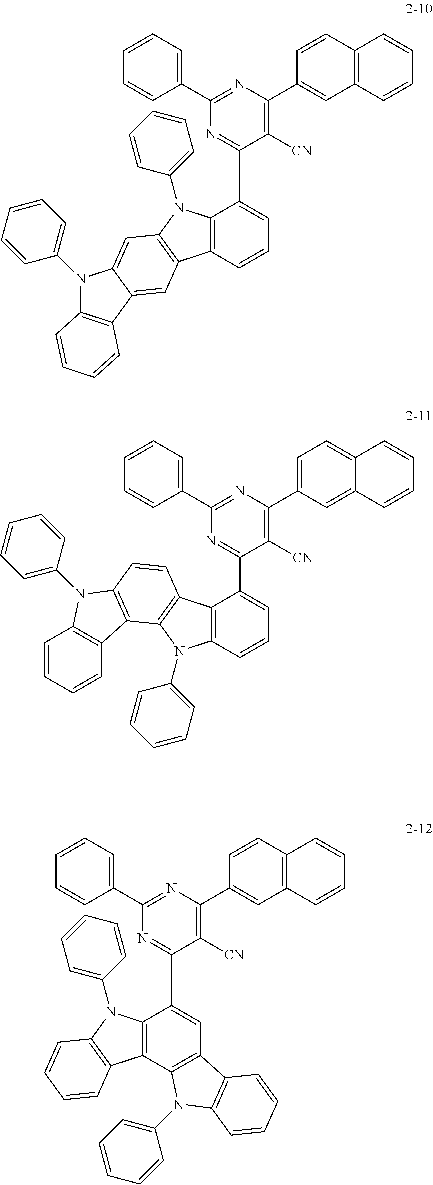 [SMILES: N#Cc1c(-c2ccc3ccccc3c2)nc(-c2ccccc2)nc1-c1cccc2c3cc4c5ccccc5n(-c5ccccc5)c4cc3n(-c3ccccc3)c12 ; N#Cc1c(-c2ccc3ccccc3c2)nc(-c2ccccc2)nc1-c1cccc2c1c1ccc3c(c4ccccc4n3-c3ccccc3)c1n2-c1ccccc1 ; N#Cc1c(-c2ccc3ccccc3c2)nc(-c2ccccc2)nc1-c1cc2c3ccccc3n(-c3ccccc3)c2c2c3ccccc3n(-c3ccccc3)c12]

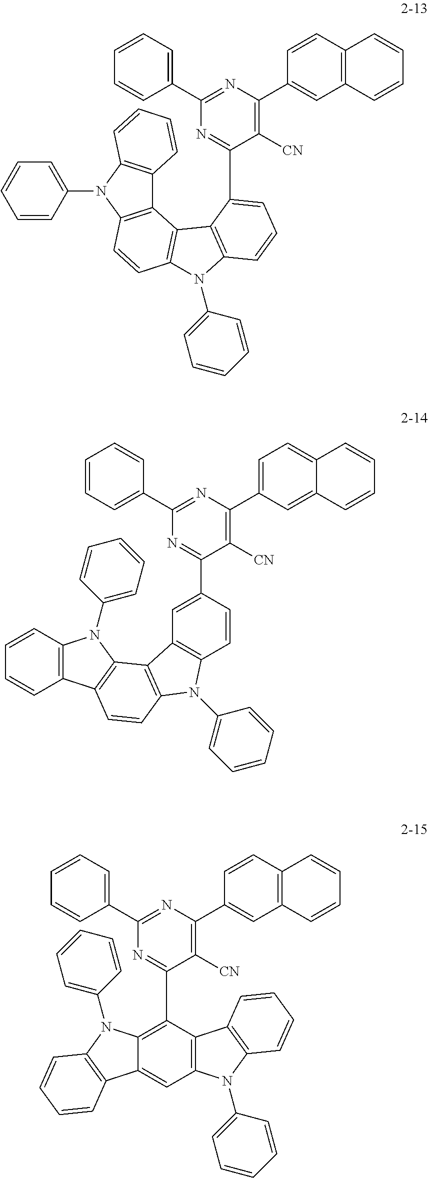 [SMILES: N#Cc1c(-c2ccc3ccccc3c2)nc(-c2ccccc2)nc1-c1cccc2c1c1c3c4ccccc4n(-c4ccccc4)c3ccc1n2-c1ccccc1 ; N#Cc1c(-c2ccc3ccccc3c2)nc(-c2ccccc2)nc1-c1ccc2c(c1)c1c(ccc3c4ccccc4n(-c4ccccc4)c31)n2-c1ccccc1 ; N#Cc1c(-c2ccc3ccccc3c2)nc(-c2ccccc2)nc1-c1c2c3ccccc3n(-c3ccccc3)c2cc2c3ccccc3n(-c3ccccc3)c12]

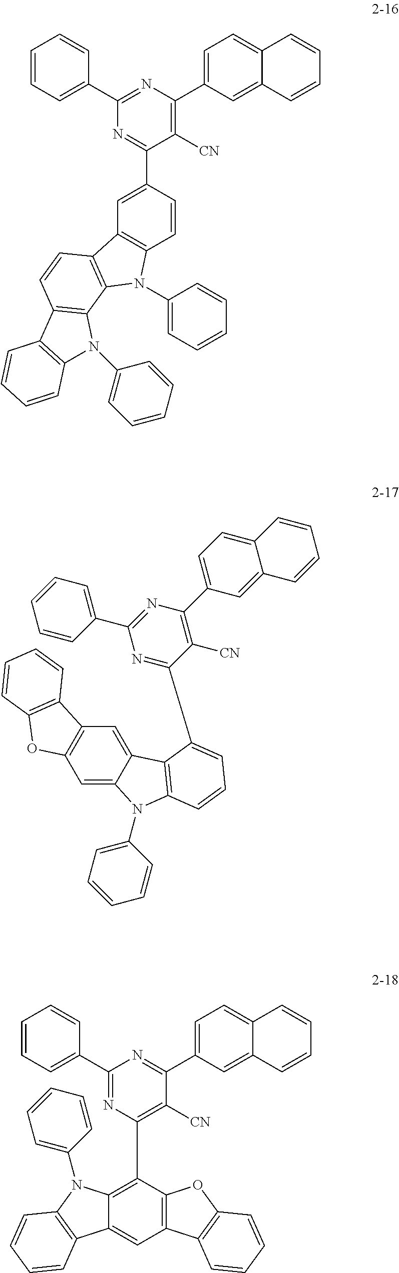 [SMILES: N#Cc1c(-c2ccc3ccccc3c2)nc(-c2ccccc2)nc1-c1ccc2c(c1)c1ccc3c4ccccc4n(-c4ccccc4)c3c1n2-c1ccccc1 ; N#Cc1c(-c2ccc3ccccc3c2)nc(-c2ccccc2)nc1-c1cccc2c1c1cc3c(cc1n2-c1ccccc1)oc1ccccc13 ; N#Cc1c(-c2ccc3ccccc3c2)nc(-c2ccccc2)nc1-c1c2oc3ccccc3c2cc2c3ccccc3n(-c3ccccc3)c12]

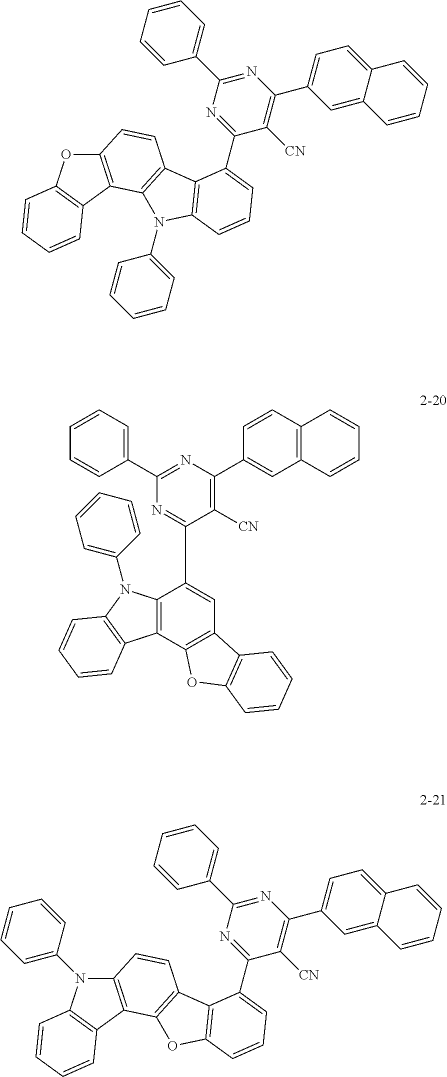 [SMILES: N#Cc1c(-c2ccc3ccccc3c2)nc(-c2ccccc2)nc1-c1cccc2c1c1ccc3oc4ccccc4c3c1n2-c1ccccc1 ; N#Cc1c(-c2ccc3ccccc3c2)nc(-c2ccccc2)nc1-c1cc2c3ccccc3oc2c2c3ccccc3n(-c3ccccc3)c12 ; N#Cc1c(-c2ccc3ccccc3c2)nc(-c2ccccc2)nc1-c1cccc2oc3c(ccc4c3c3ccccc3n4-c3ccccc3)c12]

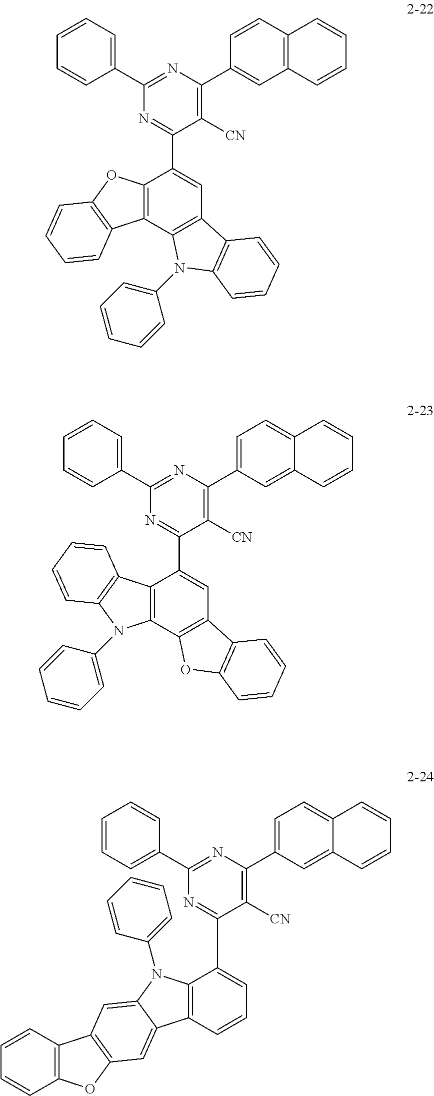 [SMILES: N#Cc1c(-c2ccc3ccccc3c2)nc(-c2ccccc2)nc1-c1cc2c3ccccc3n(-c3ccccc3)c2c2c1oc1ccccc12 ; N#Cc1c(-c2ccc3ccccc3c2)nc(-c2ccccc2)nc1-c1cc2c3ccccc3oc2c2c1c1ccccc1n2-c1ccccc1 ; N#Cc1c(-c2ccc3ccccc3c2)nc(-c2ccccc2)nc1-c1cccc2c3cc4oc5ccccc5c4cc3n(-c3ccccc3)c12]

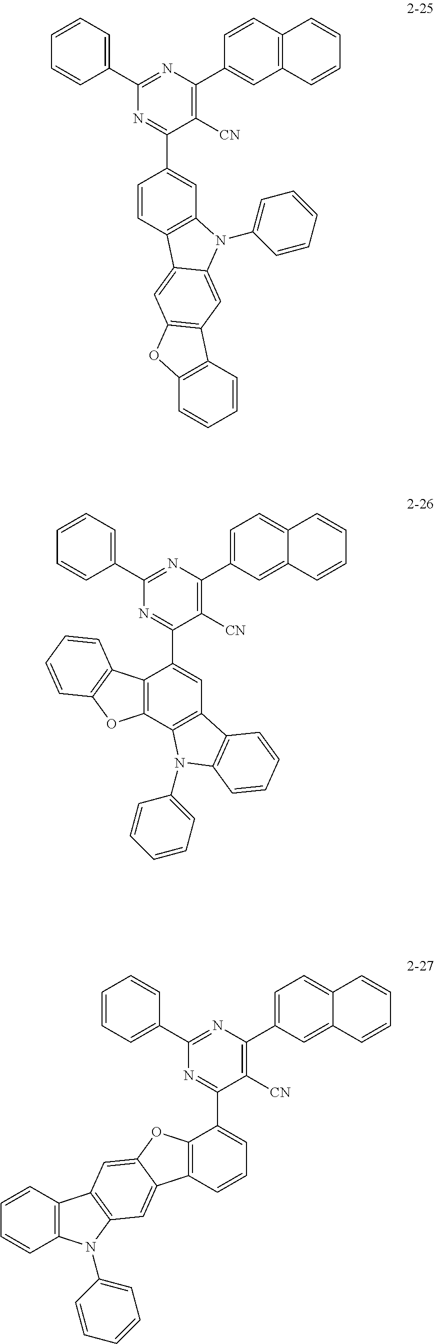 [SMILES: N#Cc1c(-c2ccc3ccccc3c2)nc(-c2ccccc2)nc1-c1ccc2c3cc4oc5ccccc5c4cc3n(-c3ccccc3)c2c1 ; N#Cc1c(-c2ccc3ccccc3c2)nc(-c2ccccc2)nc1-c1cc2c3ccccc3n(-c3ccccc3)c2c2oc3ccccc3c12 ; N#Cc1c(-c2ccc3ccccc3c2)nc(-c2ccccc2)nc1-c1cccc2c1oc1cc3c4ccccc4n(-c4ccccc4)c3cc12]

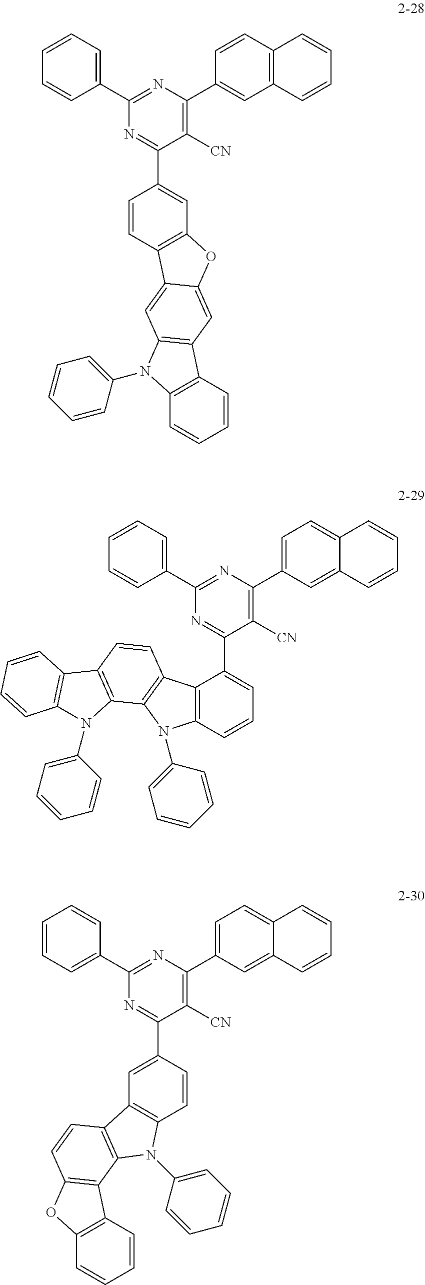 [SMILES: N#Cc1c(-c2ccc3ccccc3c2)nc(-c2ccccc2)nc1-c1ccc2c(c1)oc1cc3c4ccccc4n(-c4ccccc4)c3cc12 ; N#Cc1c(-c2ccc3ccccc3c2)nc(-c2ccccc2)nc1-c1cccc2c1c1ccc3c4ccccc4n(-c4ccccc4)c3c1n2-c1ccccc1 ; N#Cc1c(-c2ccc3ccccc3c2)nc(-c2ccccc2)nc1-c1ccc2c(c1)c1ccc3oc4ccccc4c3c1n2-c1ccccc1]

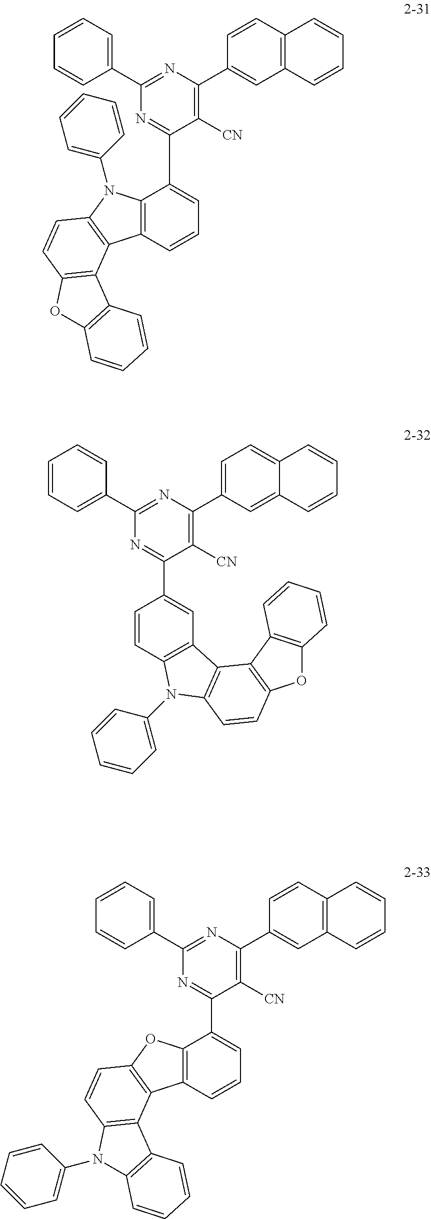 [SMILES: N#Cc1c(-c2ccc3ccccc3c2)nc(-c2ccccc2)nc1-c1cccc2c3c4c(ccc3n(-c3ccccc3)c12)oc1ccccc14 ; N#Cc1c(-c2ccc3ccccc3c2)nc(-c2ccccc2)nc1-c1ccc2c(c1)c1c3c(ccc1n2-c1ccccc1)oc1ccccc13 ; N#Cc1c(-c2ccc3ccccc3c2)nc(-c2ccccc2)nc1-c1cccc2c1oc1ccc3c(c4ccccc4n3-c3ccccc3)c12]

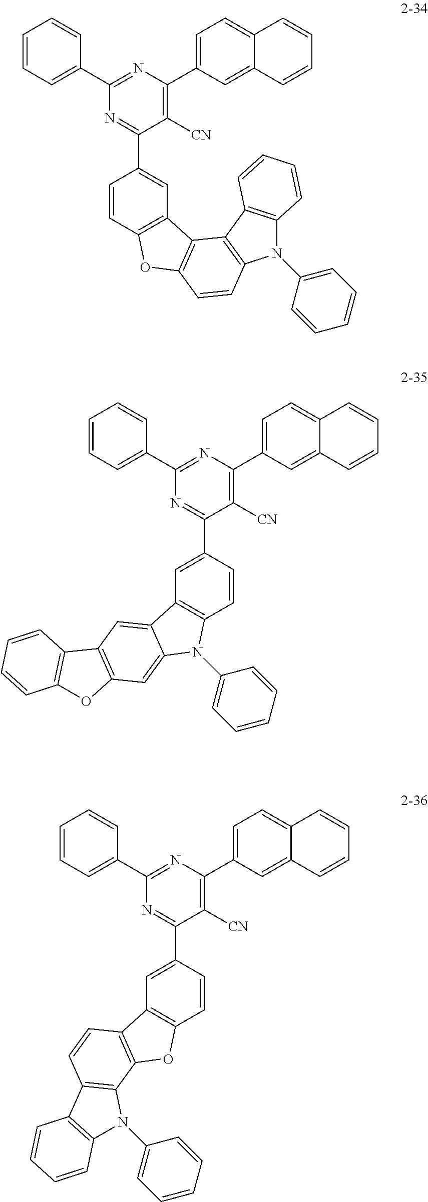 [SMILES: N#Cc1c(-c2ccc3ccccc3c2)nc(-c2ccccc2)nc1-c1ccc2oc3ccc4c(c5ccccc5n4-c4ccccc4)c3c2c1 ; N#Cc1c(-c2ccc3ccccc3c2)nc(-c2ccccc2)nc1-c1ccc2c(c1)c1cc3c(cc1n2-c1ccccc1)oc1ccccc13 ; N#Cc1c(-c2ccc3ccccc3c2)nc(-c2ccccc2)nc1-c1ccc2oc3c(ccc4c5ccccc5n(-c5ccccc5)c43)c2c1]

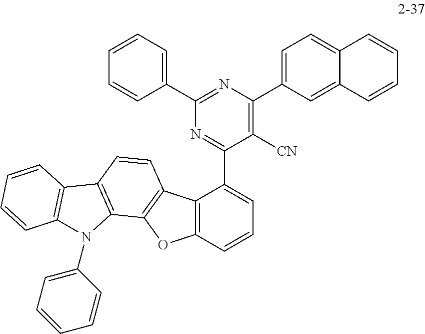 [SMILES: N#Cc1c(-c2ccc3ccccc3c2)nc(-c2ccccc2)nc1-c1cccc2oc3c(ccc4c5ccccc5n(-c5ccccc5)c43)c12]

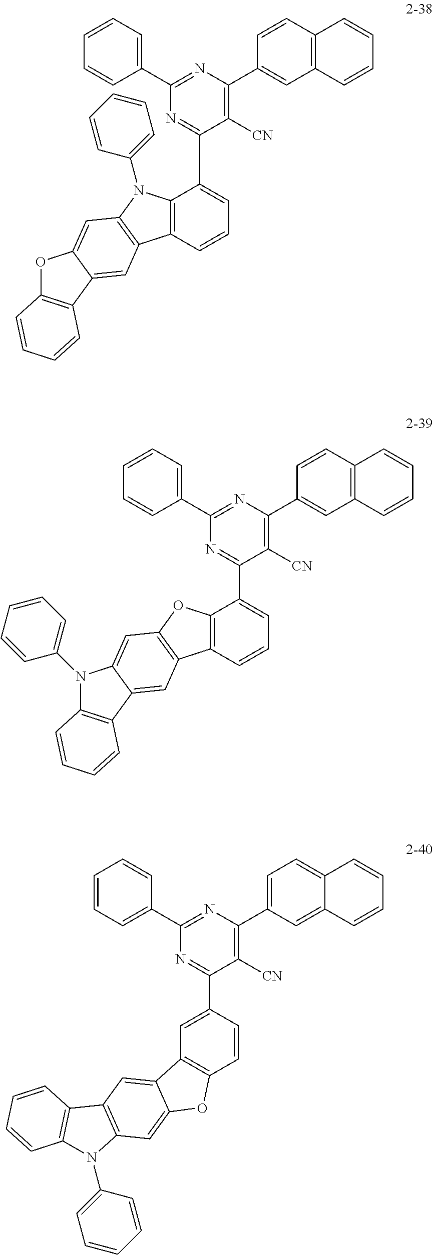 [SMILES: N#Cc1c(-c2ccc3ccccc3c2)nc(-c2ccccc2)nc1-c1cccc2c3cc4c(cc3n(-c3ccccc3)c12)oc1ccccc14 ; N#Cc1c(-c2ccc3ccccc3c2)nc(-c2ccccc2)nc1-c1cccc2c1oc1cc3c(cc12)c1ccccc1n3-c1ccccc1 ; N#Cc1c(-c2ccc3ccccc3c2)nc(-c2ccccc2)nc1-c1ccc2oc3cc4c(cc3c2c1)c1ccccc1n4-c1ccccc1]

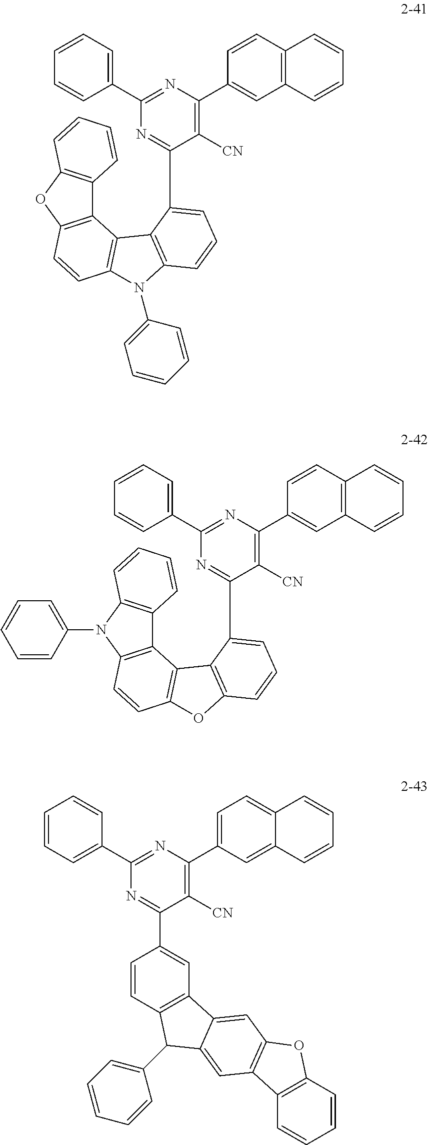 [SMILES: N#Cc1c(-c2ccc3ccccc3c2)nc(-c2ccccc2)nc1-c1cccc2c1c1c3c(ccc1n2-c1ccccc1)oc1ccccc13 ; N#Cc1c(-c2ccc3ccccc3c2)nc(-c2ccccc2)nc1-c1cccc2oc3ccc4c(c5ccccc5n4-c4ccccc4)c3c12 ; N#Cc1c(-c2ccc3c(c2)-c2cc4oc5ccccc5c4cc2C3c2ccccc2)nc(-c2ccccc2)nc1-c1ccc2ccccc2c1]

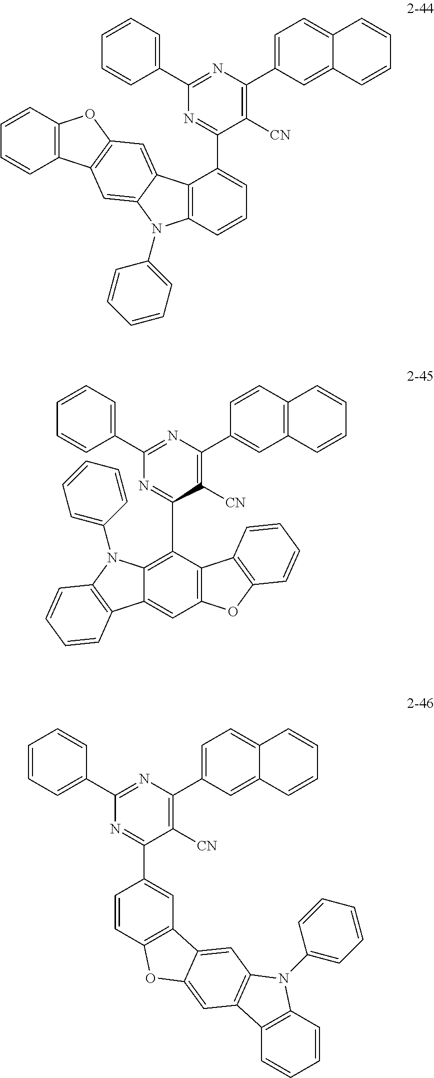

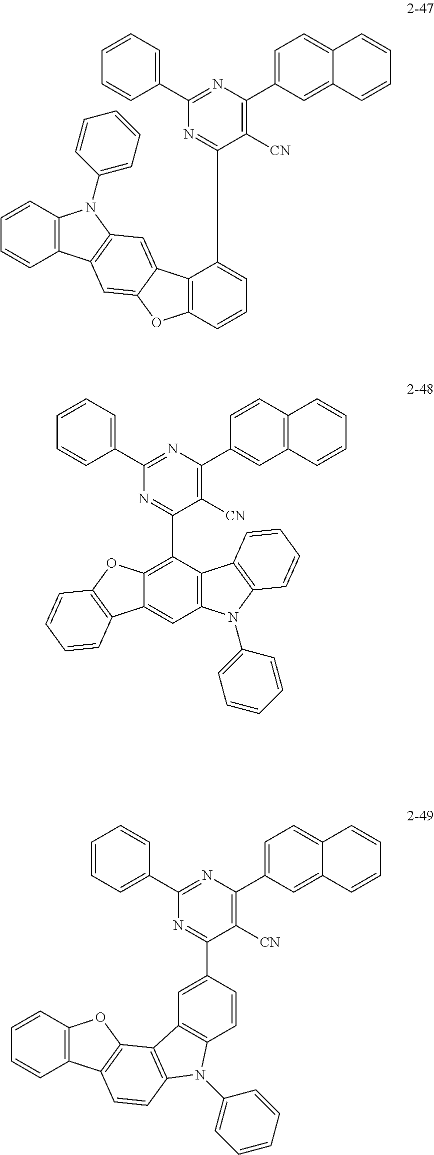 [SMILES: N#Cc1c(-c2ccc3ccccc3c2)nc(-c2ccccc2)nc1-c1cccc2oc3cc4c5ccccc5n(-c5ccccc5)c4cc3c12 ; N#Cc1c(-c2ccc3ccccc3c2)nc(-c2ccccc2)nc1-c1c2oc3ccccc3c2cc2c1c1ccccc1n2-c1ccccc1 ; N#Cc1c(-c2ccc3ccccc3c2)nc(-c2ccccc2)nc1-c1ccc2c(c1)c1c3oc4ccccc4c3ccc1n2-c1ccccc1]

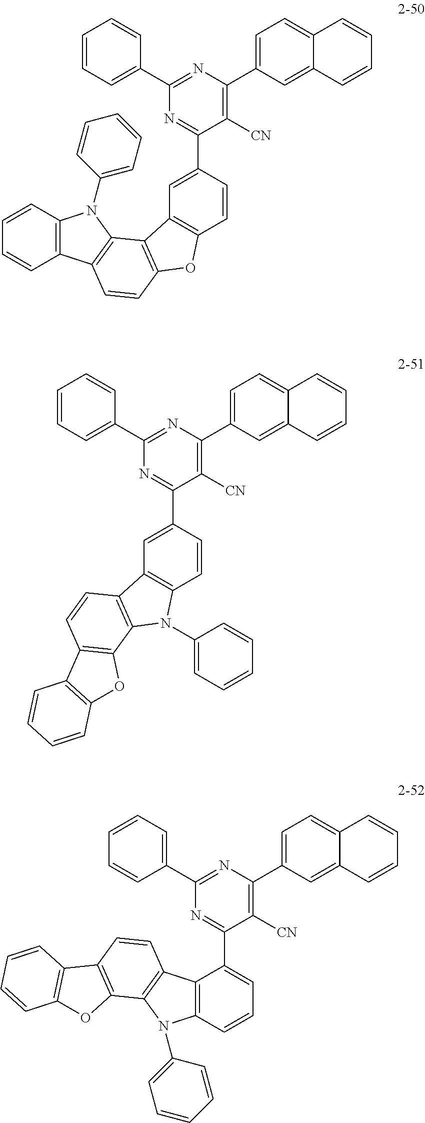 [SMILES: N#Cc1c(-c2ccc3ccccc3c2)nc(-c2ccccc2)nc1-c1ccc2oc3ccc4c5ccccc5n(-c5ccccc5)c4c3c2c1 ; N#Cc1c(-c2ccc3ccccc3c2)nc(-c2ccccc2)nc1-c1ccc2c(c1)c1ccc3c4ccccc4oc3c1n2-c1ccccc1 ; N#Cc1c(-c2ccc3ccccc3c2)nc(-c2ccccc2)nc1-c1cccc2c1c1ccc3c4ccccc4oc3c1n2-c1ccccc1]

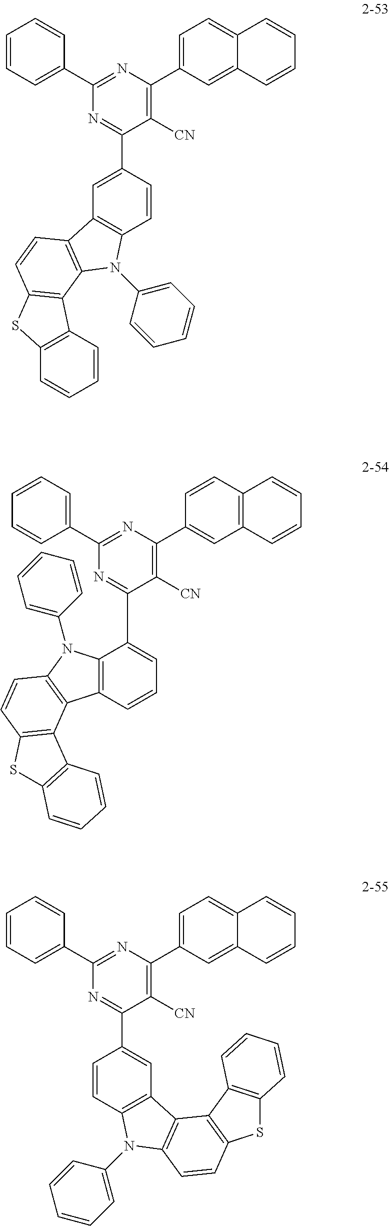 [SMILES: N#Cc1c(-c2ccc3ccccc3c2)nc(-c2ccccc2)nc1-c1ccc2c(c1)c1ccc3sc4ccccc4c3c1n2-c1ccccc1 ; N#Cc1c(-c2ccc3ccccc3c2)nc(-c2ccccc2)nc1-c1cccc2c3c4c(ccc3n(-c3ccccc3)c12)sc1ccccc14 ; N#Cc1c(-c2ccc3ccccc3c2)nc(-c2ccccc2)nc1-c1ccc2c(c1)c1c3c(ccc1n2-c1ccccc1)sc1ccccc13]

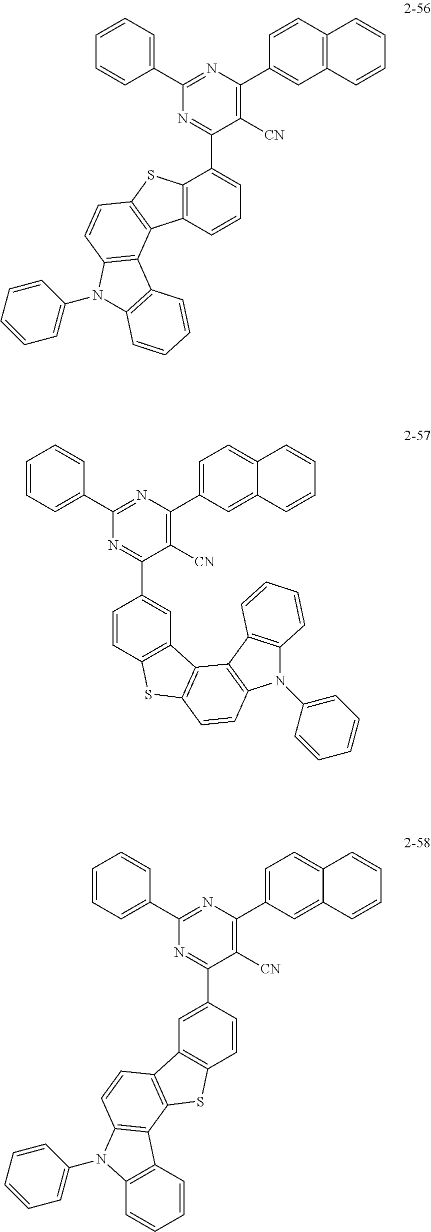 [SMILES: N#Cc1c(-c2ccc3ccccc3c2)nc(-c2ccccc2)nc1-c1cccc2c1sc1ccc3c(c4ccccc4n3-c3ccccc3)c12 ; N#Cc1c(-c2ccc3ccccc3c2)nc(-c2ccccc2)nc1-c1ccc2sc3ccc4c(c5ccccc5n4-c4ccccc4)c3c2c1 ; N#Cc1c(-c2ccc3ccccc3c2)nc(-c2ccccc2)nc1-c1ccc2sc3c(ccc4c3c3ccccc3n4-c3ccccc3)c2c1]

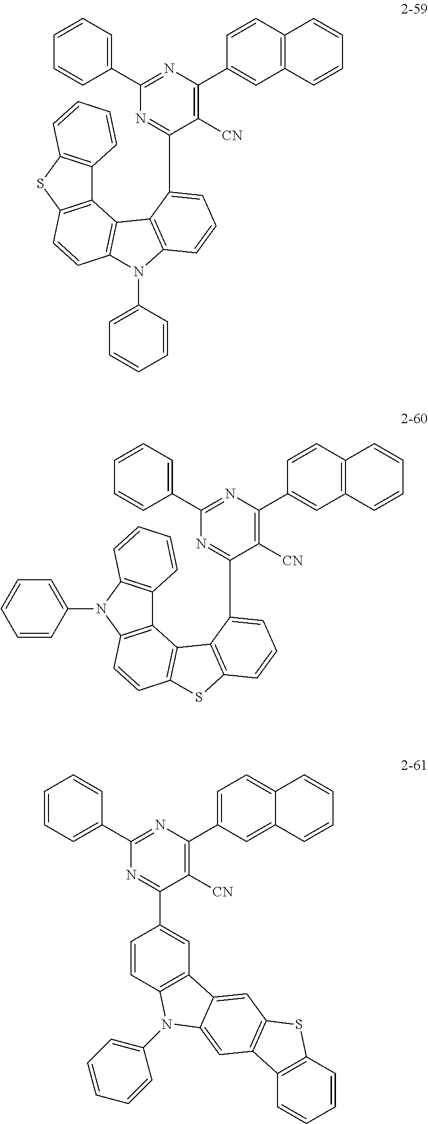 [SMILES: N#Cc1c(-c2ccc3ccccc3c2)nc(-c2ccccc2)nc1-c1cccc2c1c1c3c(ccc1n2-c1ccccc1)sc1ccccc13 ; N#Cc1c(-c2ccc3ccccc3c2)nc(-c2ccccc2)nc1-c1cccc2sc3ccc4c(c5ccccc5n4-c4ccccc4)c3c12 ; N#Cc1c(-c2ccc3ccccc3c2)nc(-c2ccccc2)nc1-c1ccc2c(c1)c1cc3sc4ccccc4c3cc1n2-c1ccccc1]

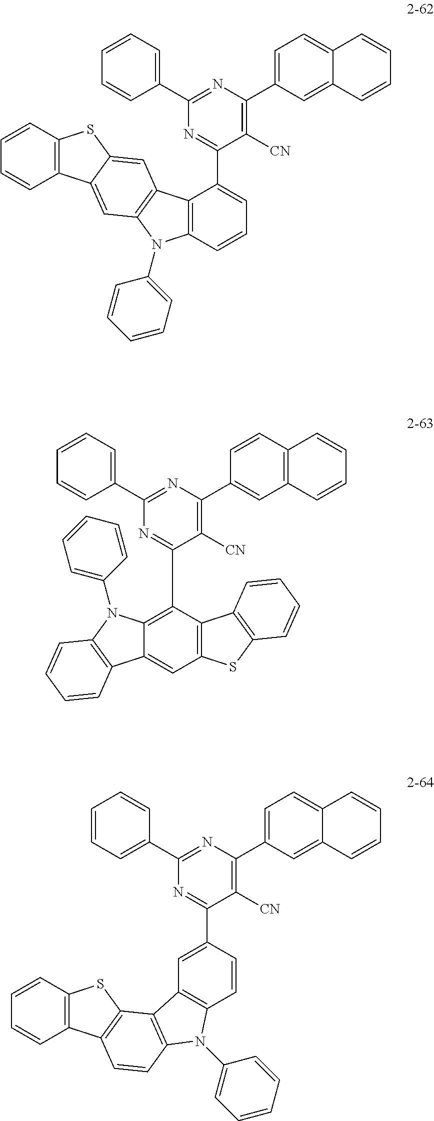 [SMILES: N#Cc1c(-c2ccc3ccccc3c2)nc(-c2ccccc2)nc1-c1cccc2c1c1cc3sc4ccccc4c3cc1n2-c1ccccc1 ; N#Cc1c(-c2ccc3ccccc3c2)nc(-c2ccccc2)nc1-c1c2c(cc3c4ccccc4n(-c4ccccc4)c13)sc1ccccc12 ; N#Cc1c(-c2ccc3ccccc3c2)nc(-c2ccccc2)nc1-c1ccc2c(c1)c1c3sc4ccccc4c3ccc1n2-c1ccccc1]

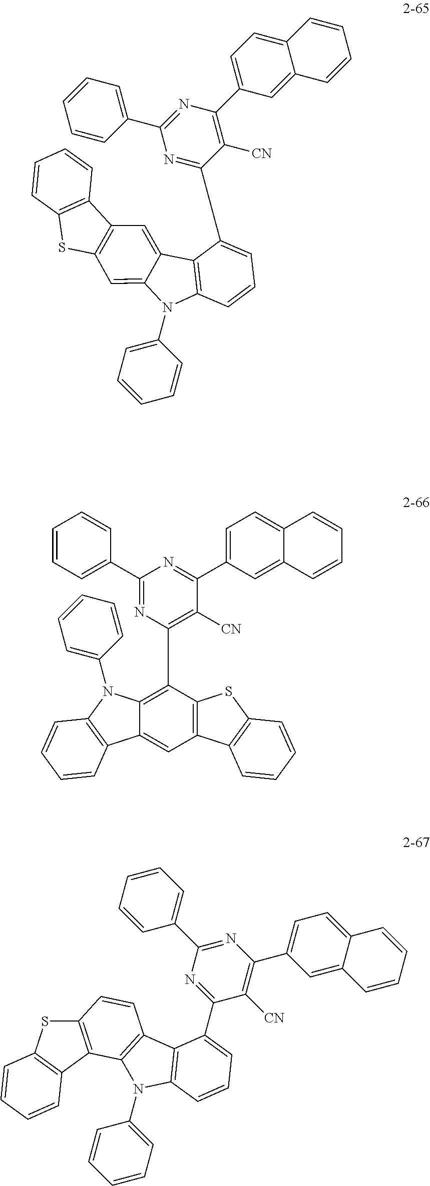 [SMILES: N#Cc1c(-c2ccc3ccccc3c2)nc(-c2ccccc2)nc1-c1cccc2c1c1cc3c(cc1n2-c1ccccc1)sc1ccccc13 ; N#Cc1c(-c2ccc3ccccc3c2)nc(-c2ccccc2)nc1-c1c2sc3ccccc3c2cc2c3ccccc3n(-c3ccccc3)c12 ; N#Cc1c(-c2ccc3ccccc3c2)nc(-c2ccccc2)nc1-c1cccc2c1c1ccc3sc4ccccc4c3c1n2-c1ccccc1]

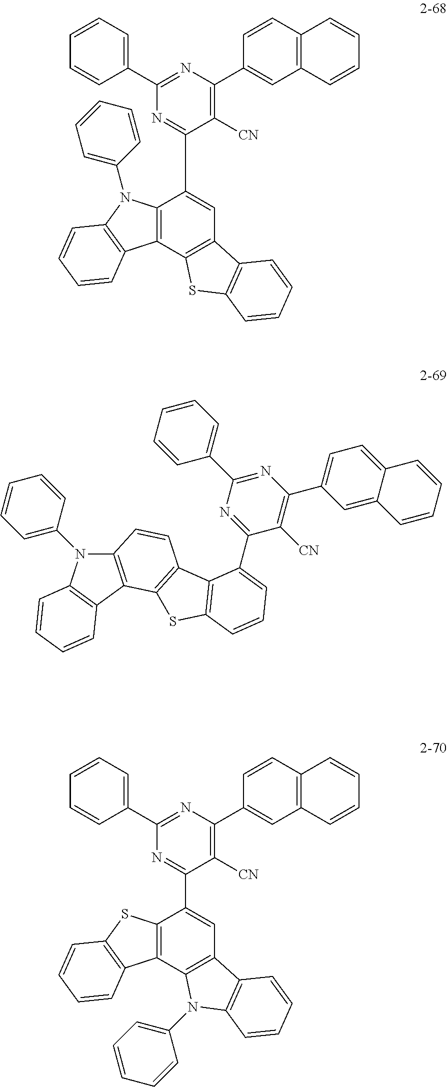 [SMILES: N#Cc1c(-c2ccc3ccccc3c2)nc(-c2ccccc2)nc1-c1cc2c3ccccc3sc2c2c3ccccc3n(-c3ccccc3)c12 ; N#Cc1c(-c2ccc3ccccc3c2)nc(-c2ccccc2)nc1-c1cccc2sc3c(ccc4c3c3ccccc3n4-c3ccccc3)c12 ; N#Cc1c(-c2ccc3ccccc3c2)nc(-c2ccccc2)nc1-c1cc2c3ccccc3n(-c3ccccc3)c2c2c1sc1ccccc12]

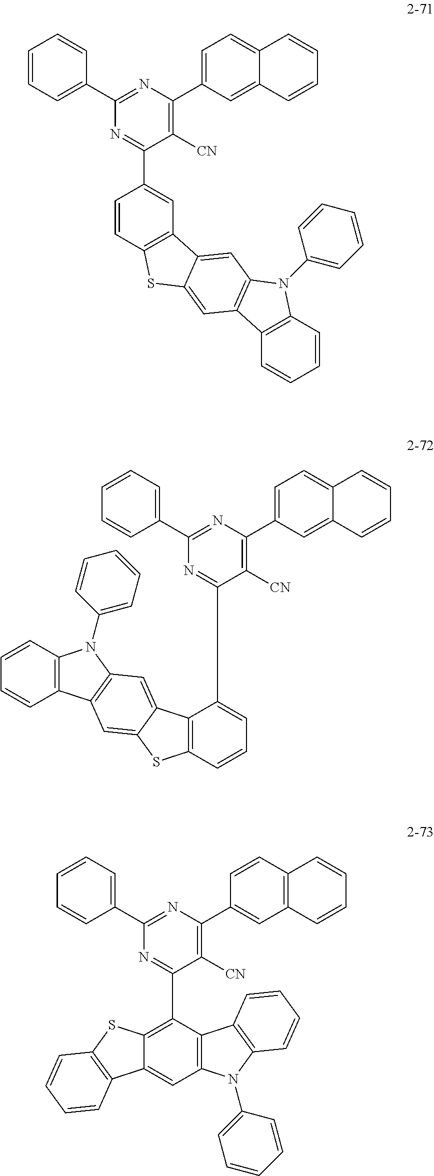 [SMILES: N#Cc1c(-c2ccc3ccccc3c2)nc(-c2ccccc2)nc1-c1ccc2sc3cc4c5ccccc5n(-c5ccccc5)c4cc3c2c1 ; N#Cc1c(-c2ccc3ccccc3c2)nc(-c2ccccc2)nc1-c1cccc2sc3cc4c5ccccc5n(-c5ccccc5)c4cc3c12 ; N#Cc1c(-c2ccc3ccccc3c2)nc(-c2ccccc2)nc1-c1c2sc3ccccc3c2cc2c1c1ccccc1n2-c1ccccc1]

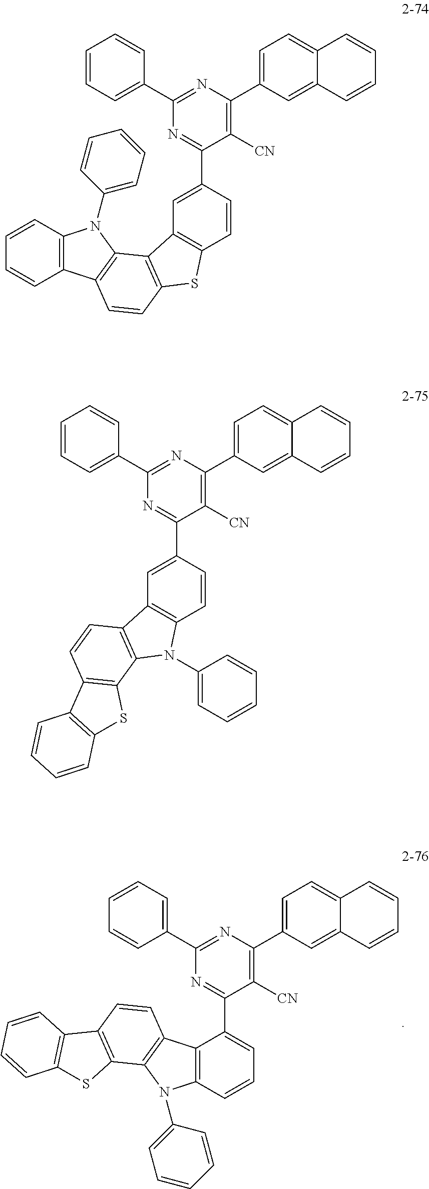 [SMILES: N#Cc1c(-c2ccc3ccccc3c2)nc(-c2ccccc2)nc1-c1ccc2sc3ccc4c5ccccc5n(-c5ccccc5)c4c3c2c1 ; N#Cc1c(-c2ccc3ccccc3c2)nc(-c2ccccc2)nc1-c1ccc2c(c1)c1ccc3c4ccccc4sc3c1n2-c1ccccc1 ; N#Cc1c(-c2ccc3ccccc3c2)nc(-c2ccccc2)nc1-c1cccc2c1c1ccc3c4ccccc4sc3c1n2-c1ccccc1]

10. The organic light emitting diode of claim 1, wherein the at least one emitting material layer further comprises a third compound.

11. The organic light emitting diode of claim 10, the third compound comprises a third organic compound represented by Chemical Formula 8: 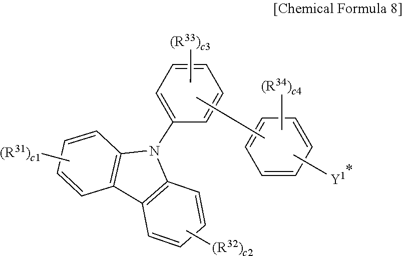
wherein, in the Chemical Formula 8,
each of R³¹ and R³² is independently an unsubstituted or substituted C₁-C₂₀ alkyl group or an unsubstituted or substituted C₆-C₃₀ aryl group, where each R³¹ is identical to or different from each other when c1 is 2, 3 or 4 and each R³² is identical to or different from each other when c2 is 2, 3 or 4;
each of R³³ and R³⁴ is independently an unsubstituted or substituted C₁-C₂₀ alkyl group or an unsubstituted or substituted C₆-C₃₀ aryl group, where each R³³ is identical to or different from each other when c3 is 2, 3 or 4 and each R³⁴ is identical to or different from each other when c4 is 2, 3 or 4, or R³³ or R³⁴ is linked to the adjacent 6-membered aromatic ring to form a heteroring that is optionally substituted with an unsubstituted or substituted C₆-C₃₀ aryl group;
Y¹ is represented by Chemical Formula 9A or Chemical Formula 9B;
each of c1, c2, c3 and c4 is independently 0, 1, 2, 3 or 4; and
an asterisk indicates a link position to the Chemical Formula 9A or Chemical Formula 9B, 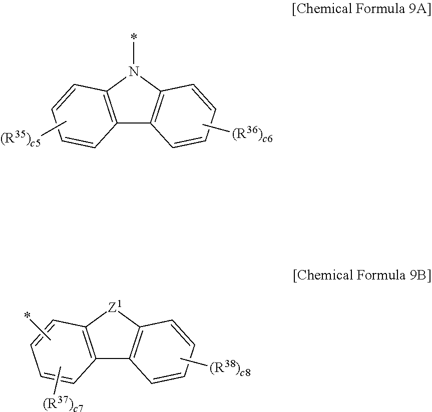
wherein, in the Chemical Formulae 9A and 9B,
each of R³⁵, R³⁶, R³⁷, and R³⁸ is independently an unsubstituted or substituted C₁-C₂₀ alkyl group or an unsubstituted or substituted C₆-C₃₀ aryl group, where each R³⁵ is identical to or different from each other when c5 is 2, 3 or 4, each R³⁶ is identical to or different from each other when c6 is 2, 3 or 4, each R³⁷ is identical to or different from each other when c7 is 2 or 3 and each R³⁸ is identical to or different from each other when c8 is 2, 3 or 4;
Z¹ is NR³⁹, O or S, where R³⁹ is hydrogen, an unsubstituted or substituted C₁-C₂₀ alkyl group or an unsubstituted or substituted C₆-C₃₀ aryl group;
each of c5, c6, and c8 is independently 0, 1, 2, 3 or 4;
c7 is 0, 1, 2 or 3; and
an asterisk indicates a link position to the Chemical Formula 8.

12. The organic light emitting diode of claim 11, wherein the third organic compound includes at least one of the following compounds:

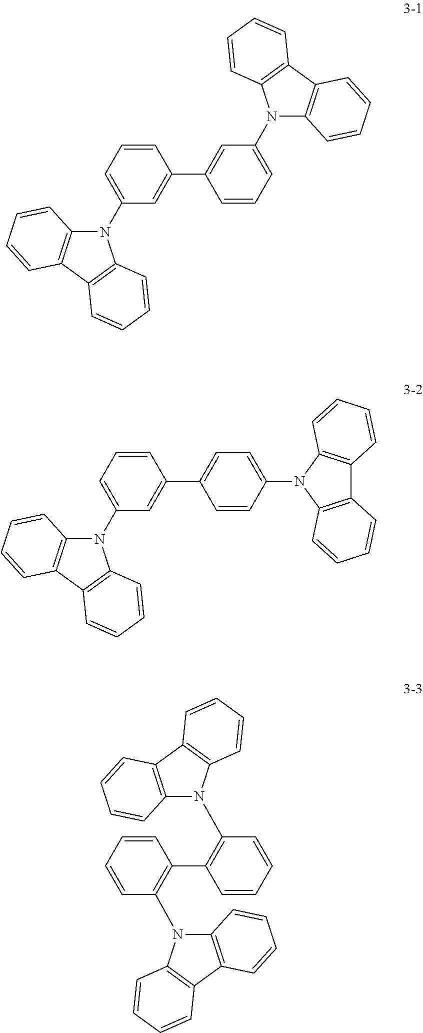 [SMILES: c1cc(-c2cccc(-n3c4ccccc4c4ccccc43)c2)cc(-n2c3ccccc3c3ccccc32)c1 ; c1cc(-c2ccc(-n3c4ccccc4c4ccccc43)cc2)cc(-n2c3ccccc3c3ccccc32)c1 ; c1ccc(-n2c3ccccc3c3ccccc32)c(-c2ccccc2-n2c3ccccc3c3ccccc32)c1]

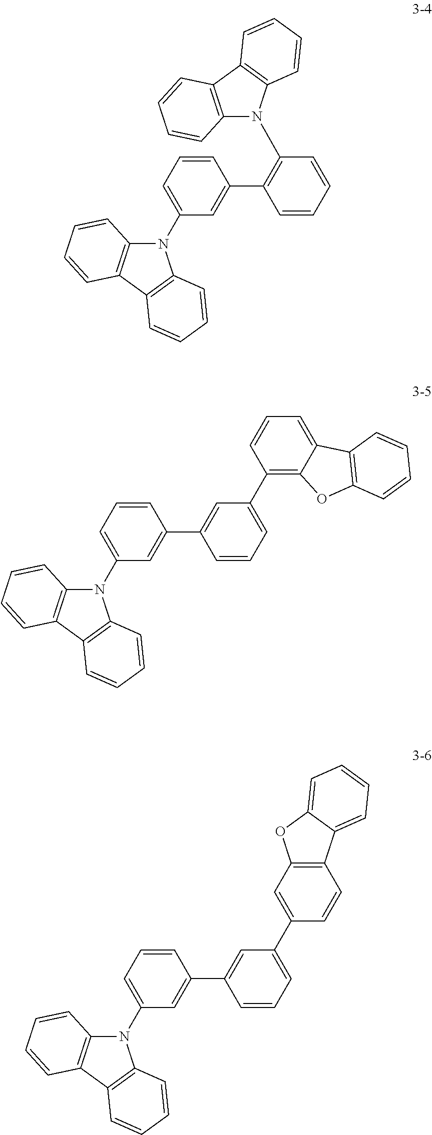 [SMILES: c1cc(-c2ccccc2-n2c3ccccc3c3ccccc32)cc(-n2c3ccccc3c3ccccc32)c1 ; c1cc(-c2cccc(-n3c4ccccc4c4ccccc43)c2)cc(-c2cccc3c2oc2ccccc23)c1 ; c1cc(-c2cccc(-n3c4ccccc4c4ccccc43)c2)cc(-c2ccc3c(c2)oc2ccccc23)c1]

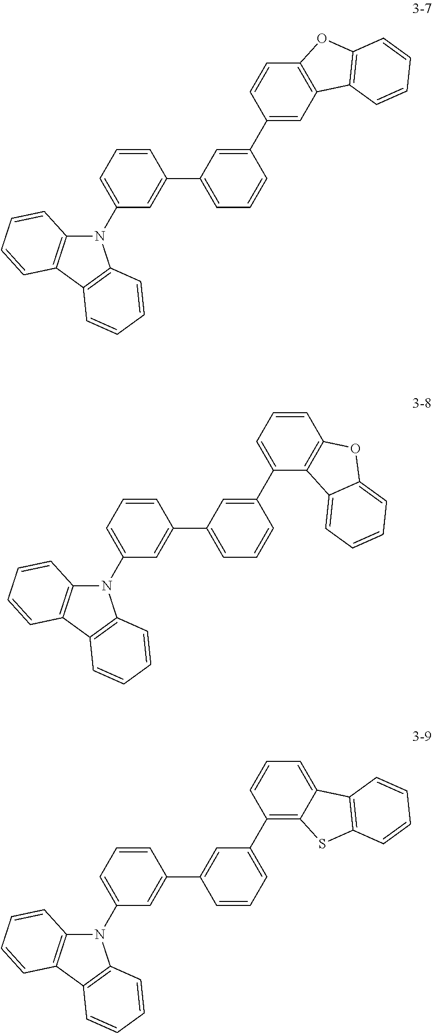 [SMILES: c1cc(-c2cccc(-n3c4ccccc4c4ccccc43)c2)cc(-c2ccc3oc4ccccc4c3c2)c1 ; c1cc(-c2cccc(-n3c4ccccc4c4ccccc43)c2)cc(-c2cccc3oc4ccccc4c23)c1 ; c1cc(-c2cccc(-n3c4ccccc4c4ccccc43)c2)cc(-c2cccc3c2sc2ccccc23)c1]

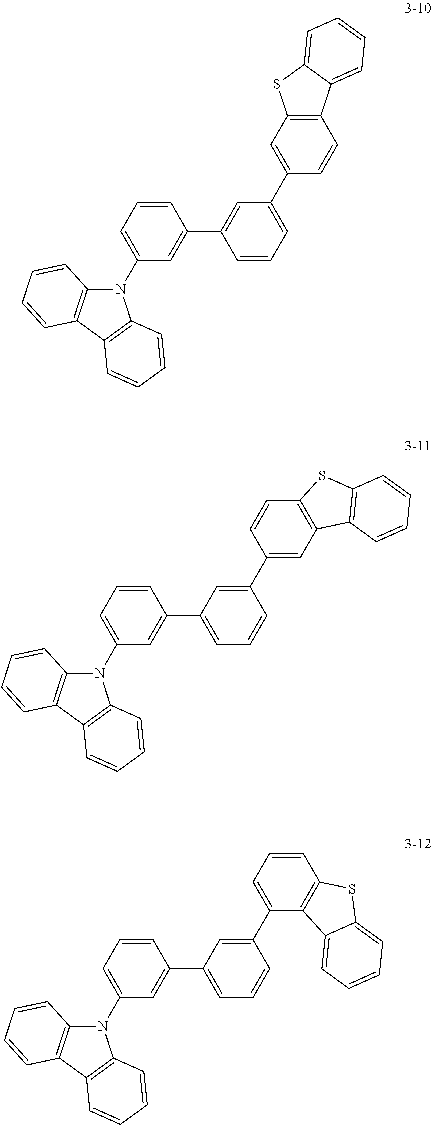 [SMILES: c1cc(-c2cccc(-n3c4ccccc4c4ccccc43)c2)cc(-c2ccc3c(c2)sc2ccccc23)c1 ; c1cc(-c2cccc(-n3c4ccccc4c4ccccc43)c2)cc(-c2ccc3sc4ccccc4c3c2)c1 ; c1cc(-c2cccc(-n3c4ccccc4c4ccccc43)c2)cc(-c2cccc3sc4ccccc4c23)c1]

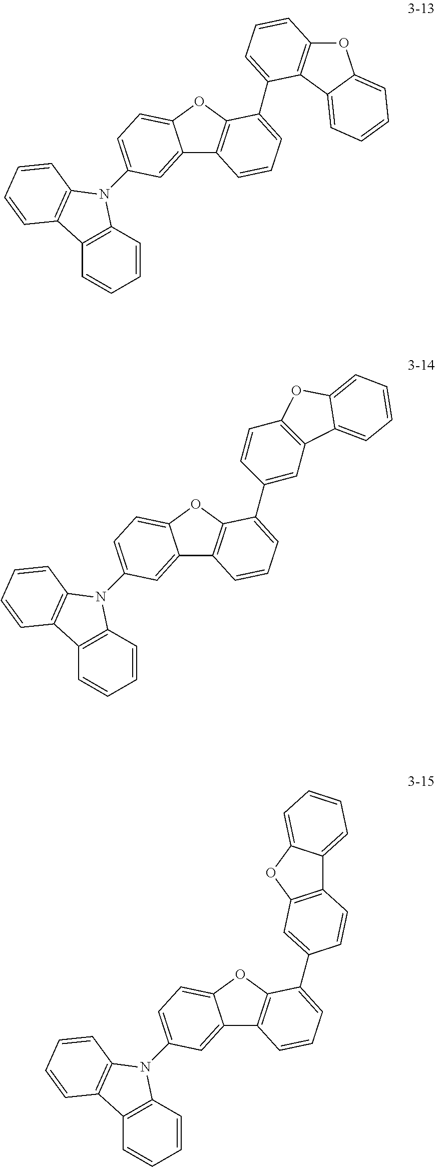 [SMILES: c1ccc2c(c1)oc1cccc(-c3cccc4c3oc3ccc(-n5c6ccccc6c6ccccc65)cc34)c12 ; c1ccc2c(c1)oc1ccc(-c3cccc4c3oc3ccc(-n5c6ccccc6c6ccccc65)cc34)cc12 ; c1ccc2c(c1)oc1cc(-c3cccc4c3oc3ccc(-n5c6ccccc6c6ccccc65)cc34)ccc12]

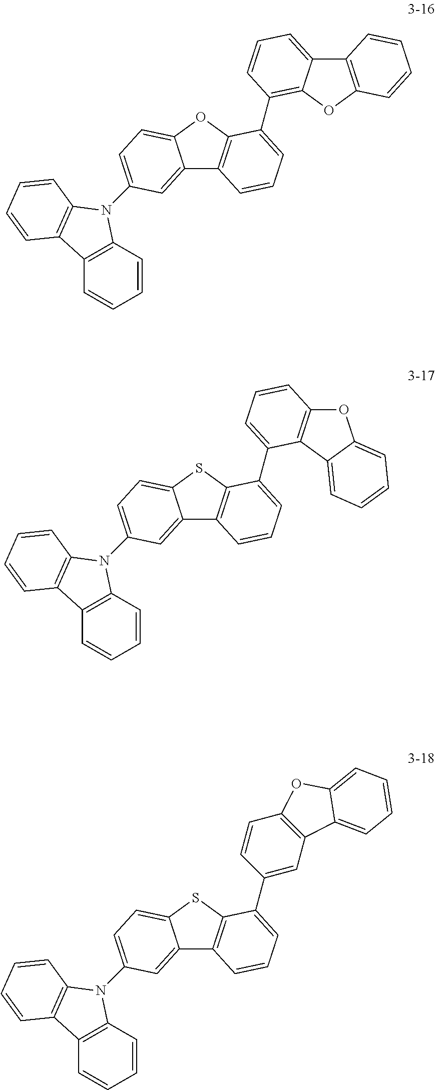 [SMILES: c1ccc2c(c1)oc1c(-c3cccc4c3oc3ccc(-n5c6ccccc6c6ccccc65)cc34)cccc12 ; c1ccc2c(c1)oc1cccc(-c3cccc4c3sc3ccc(-n5c6ccccc6c6ccccc65)cc34)c12 ; c1ccc2c(c1)oc1ccc(-c3cccc4c3sc3ccc(-n5c6ccccc6c6ccccc65)cc34)cc12]

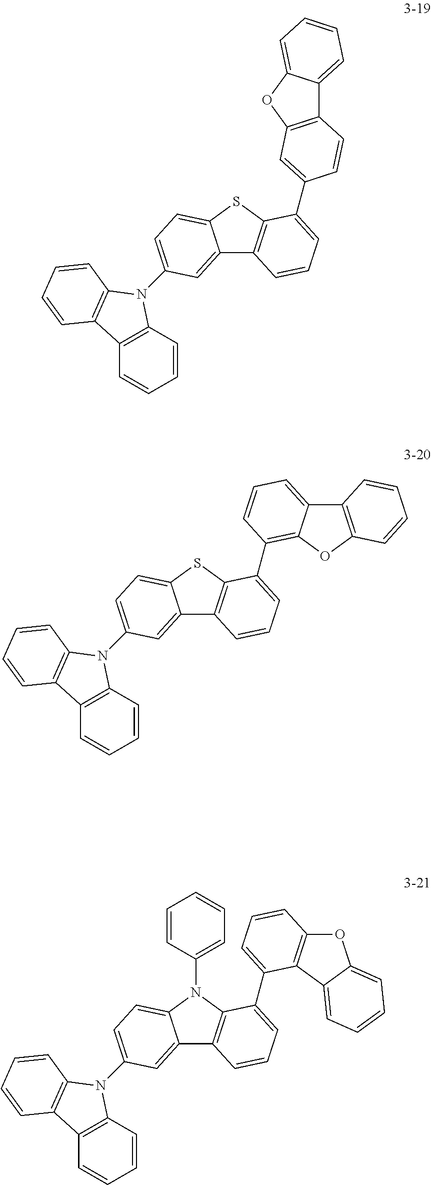 [SMILES: c1ccc2c(c1)oc1cc(-c3cccc4c3sc3ccc(-n5c6ccccc6c6ccccc65)cc34)ccc12 ; c1ccc2c(c1)oc1c(-c3cccc4c3sc3ccc(-n5c6ccccc6c6ccccc65)cc34)cccc12 ; c1ccc(-n2c3ccc(-n4c5ccccc5c5ccccc54)cc3c3cccc(-c4cccc5oc6ccccc6c45)c32)cc1]

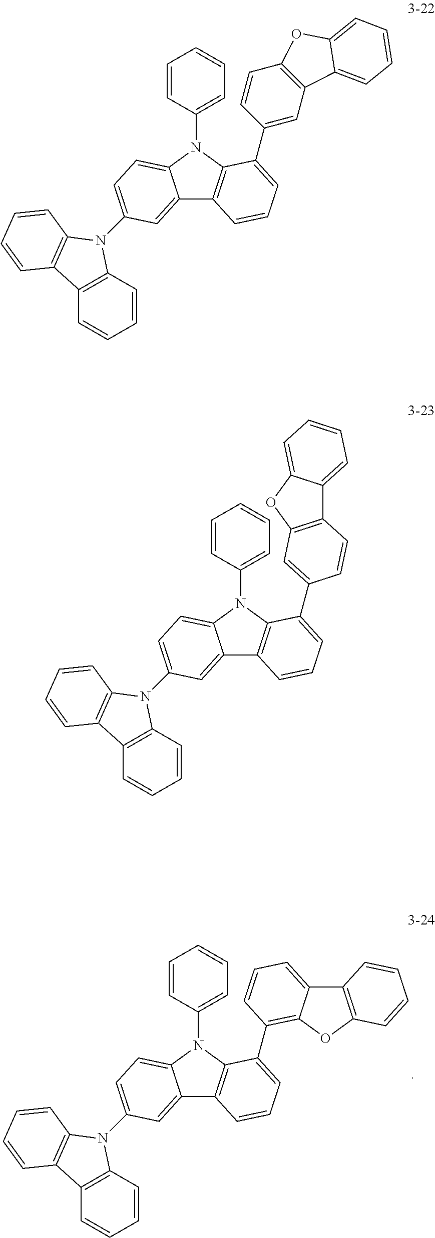 [SMILES: c1ccc(-n2c3ccc(-n4c5ccccc5c5ccccc54)cc3c3cccc(-c4ccc5oc6ccccc6c5c4)c32)cc1 ; c1ccc(-n2c3ccc(-n4c5ccccc5c5ccccc54)cc3c3cccc(-c4ccc5c(c4)oc4ccccc45)c32)cc1 ; c1ccc(-n2c3ccc(-n4c5ccccc5c5ccccc54)cc3c3cccc(-c4cccc5c4oc4ccccc45)c32)cc1]

13. The organic light emitting diode of claim 1, wherein the emissive layer further comprises a charge control layer disposed between the at least one emitting material layer and the second electrode, and wherein the charge control layer comprises the second organic compound.

14. The organic light emitting diode of claim 1, wherein the emissive layer has a single emitting part.

15. The organic light emitting diode of claim 1, wherein the emissive layer includes:
a first emitting part disposed between the first and second electrodes and comprising a first emitting material layer;
a second emitting part disposed between the first emitting part and the second electrode and comprising a second emitting material layer; and
a first charge generation layer disposed between the first emitting part and the second emitting part,
wherein at least one of the first emitting material layer and the second emitting material layer comprises the first compound and the second compound.

16. The organic light emitting diode of claim 15, wherein the second emitting material layer comprises the first compound and the second compound.

17. The organic light emitting diode of claim 16, wherein the second emitting material layer comprises:
a first layer disposed between the first charge generation layer and the second electrode; and
a second layer disposed between the first layer and the second electrode,
wherein at least one of the first layer and the second layer comprises the first compound and the second compound.

18. The organic light emitting diode of claim 15, wherein the emissive layer further comprises:
a third emitting part disposed between the second emitting part and the second electrode and comprising a third emitting material layer; and
a second charge generation layer disposed between the second emitting part and the third emitting part,
wherein the second emitting material layer comprises the first compound and the second compound.

19. The organic light emitting diode of claim 18, wherein the second emitting material layer comprises:
a first layer disposed between the first charge generation layer and the second charge generation layer; and
a second layer disposed between the first layer and the second charge generation layer, and
wherein at least one of the first layer and the second layer comprises the first compound and the second compound.
